(19) United States
(12) Patent Application Publication
(10) Pub. No.: US 2024/0324443 A1
(43) Pub. Date: Sep. 26, 2024

(54) LIGHT-EMITTING DEVICE INCLUDING ORGANOMETALLIC COMPOUND, ELECTRONIC APPARATUS AND ELECTRONIC EQUIPMENT INCLUDING THE LIGHT-EMITTING DEVICE, AND THE ORGANOMETALLIC COMPOUND

(71) Applicant: Samsung Display Co., Ltd., Yongin-si (KR)

(72) Inventors: Soobyung Ko, Yongin-si (KR); Changwoong Chu, Yongin-si (KR); IIjoon Kang, Yongin-si (KR); Seihwan Ahn, Yongin-si (KR); Eunyoung Lee, Yongin-si (KR); Jihyung Lee, Yongin-si (KR); Junghoon Han, Yongin-si (KR)

(73) Assignee: Samsung Display Co., Ltd., Yongin-si (KR)

(21) Appl. No.: 18/604,793

(22) Filed: Mar. 14, 2024

(30) Foreign Application Priority Data
Mar. 24, 2023 (KR) 10-2023-0039030
Jan. 5, 2024 (KR) 10-2024-0002302

(51) Int. Cl. H10K 85/30; C07F 15/00; C09K 11/06; H10K 50/11

(52) U.S. Cl. CPC H10K 85/346; C07F 15/0086; C09K 11/06; C09K 2211/1044; C09K 2211/185; H10K 50/11

(57) ABSTRACT

Embodiments provide an organometallic compound, a light-emitting device including the organometallic compound, an electronic apparatus including the light-emitting device, and an electronic including the light-emitting device. The light-emitting device includes a first electrode, a second electrode facing the first electrode, an interlayer between the first electrode and the second electrode and including an emission layer, and the organometallic compound. The organometallic compound is represented by Formula 1, which is explained in the specification.

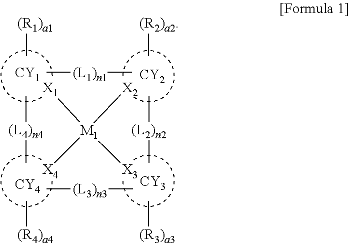

### CROSS-REFERENCE TO RELATED APPLICATION(S)

This application claims priority to and benefits of Korean Patent Application Nos. 10-2023-0039030 and 10-2024-0002302 under 35 U.S.C. § 119, respectively filed on Mar. 24, 2023 and Jan. 5, 2024 in the Korean Intellectual Property Office, the entire contents of which are incorporated herein by reference.

### BACKGROUND

### 1. Technical Field

Embodiments relate to a light-emitting device including an organometallic compound, an electronic apparatus including the light-emitting device, an electronic equipment including the light-emitting device, and the organometallic compound.

### 2. Description of the Related Art

Light-emitting devices are self-emissive devices that have wide viewing angles, high contrast ratios, short response times, and excellent characteristics in terms of luminance, driving voltage, and response speed.

In a light-emitting device, a first electrode may be arranged on a substrate, and a hole transport region, an emission layer, an electron transport region, and a second electrode may be sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. The excitons may transition from an excited state to a ground state, thereby generating light.

### SUMMARY

Embodiments include a light-emitting device including an organometallic compound, an electronic apparatus including the light-emitting device, an electronic equipment including the light-emitting device, and the organometallic compound.

Additional aspects will be set forth in part in the description which follows and, in part, will be apparent from the description, or may be learned by practice of the embodiments of the disclosure.

According to embodiments, a light-emitting device may include
a first electrode,
a second electrode facing the first electrode,
an interlayer between the first electrode and the second electrode and including an emission layer, and
an organometallic compound represented by Formula 1:

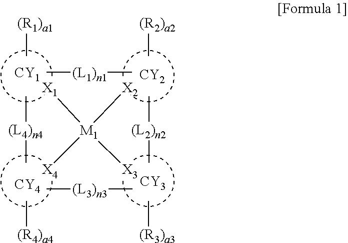

In Formula 1,
M₁ may be platinum (Pt), palladium (Pd), copper (Cu), silver (Ag), gold (Au), rhodium (Rh), iridium (Ir), ruthenium (Ru), or osmium (Os),
ring CY₁ to ring CY₄ may each independently be a C₅-C₆₀ carbocyclic group unsubstituted or substituted with R₁₀ₐ or a C₁-C₆₀ heterocyclic group unsubstituted or substituted with R₁₀ₐ,
X₁, X₂, X₃, and X₄ may each independently be a carbon atom (C) or a nitrogen atom (N),
L₁ may be a C₅-C₆₀ carbocyclic group unsubstituted or substituted with at least one R_{10b} or a C₁-C₆₀ heterocyclic group unsubstituted or substituted with at least one R_{10b},
L₂ to L₄ may each independently be *—O—*′, *—S—*′, *—C(R₅)(R₆)—*′, *—C(R₅)═*′, *═C(R₅)—*′,*—C(R₅)═C(R₆)—*′, *—C(═O)—*′, *—C(═S)—*′, *—C≡C—*′,*—B(R₅)—*′,*—N(R₅)—*′, *—P(R₅)—*′, *—Si(R₅)(R₆)—*′, *—P(R₅)(R₆)—*′, or *—Ge(R₅)(R₆)—*′,
n1 may be an integer from 2 to 5,
n2 to n4 may each independently be an integer from 0 to 3,
a moiety represented by *-(L₂)ₙ₂-*′ may be a single bond when n2 is 0,
a moiety represented by *-(L₃)ₙ₃-*′ may be a single bond when n3 is 0,
a moiety represented by *-(L₄)ₙ₄-*′ may be a single bond when n4 is 0,
R¹ to R⁶, R₁₀ₐ, and R_{10b} may each independently be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ may each independently be hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof,
a1 to a4 may each independently be an integer from 0 to 8, and
* and *′ each indicate a binding site to a neighboring atom.

In an embodiment, the interlayer may include the organometallic compound.

In an embodiment, the emission layer may include the organometallic compound.

In an embodiment, the organometallic compound may be a phosphorescent dopant.

In an embodiment, the emission layer may emit blue light.

In an embodiment, the first electrode may be an anode; the second electrode may be a cathode; the interlayer may further include a hole transport region between the first electrode and the emission layer, and an electron transport region between the emission layer and the second electrode; the hole transport region may include a hole injection layer, a hole transport layer, an emission auxiliary layer, an electron blocking layer, or any combination thereof, and the electron transport region may include a hole blocking layer, an electron transport layer, an electron injection layer, or any combination thereof.

According to embodiments, an electronic apparatus may include the light-emitting device.

In an embodiment, the electronic apparatus may further include: a thin-film transistor; and a color filter, a color-conversion layer, a touch screen layer, a polarizing layer, or any combination thereof, wherein

the thin-film transistor may include a source electrode and a drain electrode; and the first electrode of the light-emitting device may be electrically connected to the source electrode or the drain electrode.

According to embodiments, an electronic equipment may include the light-emitting device, wherein the electronic equipment may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signage.

According to embodiments, an organometallic compound may be represented by Formula 1, which is explained herein.

In an embodiment, at least one of ring CY₁ to ring CY₄ may each independently include a carbene moiety.

In an embodiment, ring CY₁ may be represented by Formula 1-1-1 or Formula 1-1-2, which are explained below.

In an embodiment, ring CY₂ and ring CY₄ may each independently be a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

In an embodiment, at least one of X₁ to X₄ may each be a nitrogen atom (N).

In an embodiment, at least two of a bond between M₁ and X₁, a bond between M₁ and X₂, a bond between M₁ and X₃, and a bond between M₁ and X₄ may each be a coordinate bond.

In an embodiment, two or more of L₁ may each independently be a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

In an embodiment, two or more of L₁ may each independently be a group represented by one of Formulae 1-2-1 to 1-2-3, which are explained below.

In an embodiment, in Formula 1, a moiety represented by *-(L₁)ₙ₁-*′ may be a moiety represented by one of Formulae 1-3-1 to 1-3-3, which are explained below.

In an embodiment, R_{10b} may be:
F, —Cl, —Br, —I, a hydroxyl group, a cyano group, or a nitro group; or
a methyl group, an ethyl group, a propyl group, an isopropyl group, a butyl group, an isobutyl group, a sec-butyl group, a tertbutyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl group, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, a 3-cyclohexylpentyl group, or a deuterated derivative group thereof.

In an embodiment, the organometallic compound may be one of Compounds BD01 to BD91, which are explained below.

According to embodiments, an organometallic compound may satisfy one or more of Conditions i to iv, wherein at least Condition i is satisfied, and Conditions i to iv are explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification.

The drawings illustrate embodiments of the disclosure and principles thereof. The above and other aspects and features of the disclosure will be more apparent by describing in detail embodiments thereof with reference to the accompanying drawings, in which:

FIG. 1 is a schematic cross-sectional view of a light-emitting device according to an embodiment;

FIG. 2 is a schematic cross-sectional view of an electronic apparatus according to an embodiment;

FIG. 3 is a schematic cross-sectional view of an electronic apparatus according to another embodiment;

FIG. 4 is a schematic perspective view of an electronic equipment according to an embodiment;

FIG. 5 is a schematic perspective view of an exterior of a vehicle as an example of an electronic equipment including a light-emitting device according to an embodiment; and

FIGS. 6A to 6C are each a schematic diagram of an interior of a vehicle as an electronic equipment according to embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

In the specification, the expressions used in the singular such as “a,” “an,” and “the,” are intended to include the plural forms as well, unless the context clearly indicates otherwise.

In the specification, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element.

Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

An embodiment provides a light-emitting device which may include:
a first electrode;
a second electrode facing the first electrode;
an interlayer between the first electrode and the second electrode and including an emission layer; and
an organometallic compound represented by Formula 1:

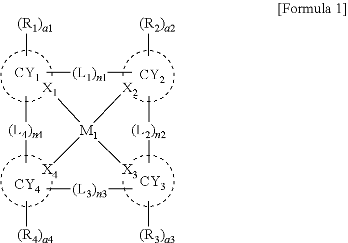

In Formula 1,
M₁ may be platinum (Pt), palladium (Pd), copper (Cu), silver (Ag), gold (Au), rhodium (Rh), iridium (Ir), ruthenium (Ru), or osmium (Os),
ring CY₁ to ring CY₄ may each independently be a C₅-C₆₀ carbocyclic group unsubstituted or substituted with R₁₀ₐ or a C₁-C₆₀ heterocyclic group unsubstituted or substituted with R₁₀ₐ,
X₁, X₂, X₃, and X₄ may each independently be a carbon atom (C) or a nitrogen atom (N),
L₁ may be a C₅-C₆₀ carbocyclic group unsubstituted or substituted with at least one R_{10b} or a C₁-C₆₀ heterocyclic group unsubstituted or substituted with at least one R_{10b},
L₂ to L₄ may each independently be *—O—*′, *—S—*′, *—C(R₅)(R₆)—*′, *—C(R₅)═*′, *═C(R₅)—*′, *—C(R₅)═C(R₆)—*′, *—C(═O)—*′, *—C(═S)—*′, *—C≡C—*′,*—B(R₅)—*′, *—N(R₅)—*′, *—P(R₅)—*′, *—Si(R₅)(R₆)—*′, *—P(R₅)(R₆)—*′, or *—Ge(R₅)(R₆)—*′,
n1 may be an integer from 2 to 5,
n2 to n4 may each independently be an integer from 0 to 3,
a moiety represented by *-(L₂)ₙ₂-*′ may be a single bond when n2 is 0,
a moiety represented by *-(L₃)ₙ₃-*′ may be a single bond when n3 is 0,
a moiety represented by *-(L₄)ₙ₄-*′ may be a single bond when n4 is 0,
R¹ to R⁶, R₁₀ₐ, and R_{10b} may each independently be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof,
a1 to a4 may each independently be an integer from 0 to 8, and
* and *′ each indicate a binding site to a neighboring atom.

In the light-emitting device according to an embodiment, the interlayer may include the organometallic compound.

In the light-emitting device according to an embodiment, the emission layer may include the organometallic compound.

In the light-emitting device according to an embodiment, the organometallic compound may be a phosphorescent dopant.

In the light-emitting device according to an embodiment, the emission layer may further include a first host and a second host, wherein the first host may be an electron-transporting host, and the second host may be a hole-transporting host.

In the light-emitting device according to an embodiment, the first host may include at least one azine moiety, and the second host may include at least one carbazole moiety.

In the light-emitting device according to an embodiment, the first host may include a compound represented by Formula 5:

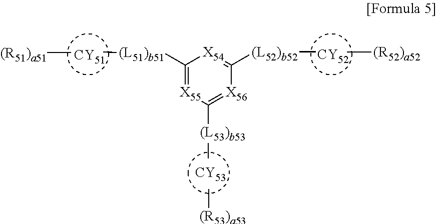

In Formula 5,

X₅₄ to X₅₆ may each independently be C(R₅₀), CH, or N; and at least one of X₅₄ to X₅₆ may each be N,
ring CY₅₁ to ring CY₅₃ may each independently be a C₅-C₆₀ carbocyclic group or a C₁-C₆₀ heterocyclic group,
L₅₁ to L₅₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
b51 to b53 may each independently be an integer from 0 to 3,
-(L₅₁)_{b51}-*′ may be a single bond when b51 is 0,
-(L₅₂)_{b52}-*′ may be a single bond when b52 is 0,
-(L₅₃)_{b53}-*′ may be a single bond when b53 is 0,
R₅₀ to R₅₃ may each independently be the same as described in connection with R₁₀ₐ in Formula 1, and
a51 to a53 may each independently be an integer from 0 to 10.

In the light-emitting device according to an embodiment, in Formula 5, ring CY₅₁ to ring CY₅₃ may each independently be a first ring, a second ring, a condensed cyclic group in which two or more first rings are condensed with each other, a condensed cyclic group in which two or more second rings are condensed with each other, or a condensed ring in which one or more first rings are condensed with one or more second rings, wherein
the first ring may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group, and
the second ring may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group.

In the light-emitting device according to an embodiment, in Formula 5, ring CY₅₁ to ring CY₅₃ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzooxadiazole group, a benzothiadiazole group, a 5,6,7,8-tetrahydroisoquinoline group, or a 5,6,7,8-tetrahydroquinoline group.

In the light-emitting device according to an embodiment, in Formula 5, L₅₁ to L₅₃ may each independently be a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzooxadiazole group, or a benzothiadiazole.

In the light-emitting device according to an embodiment, the first host may include at least one of Compounds ETH1 to ETH32:

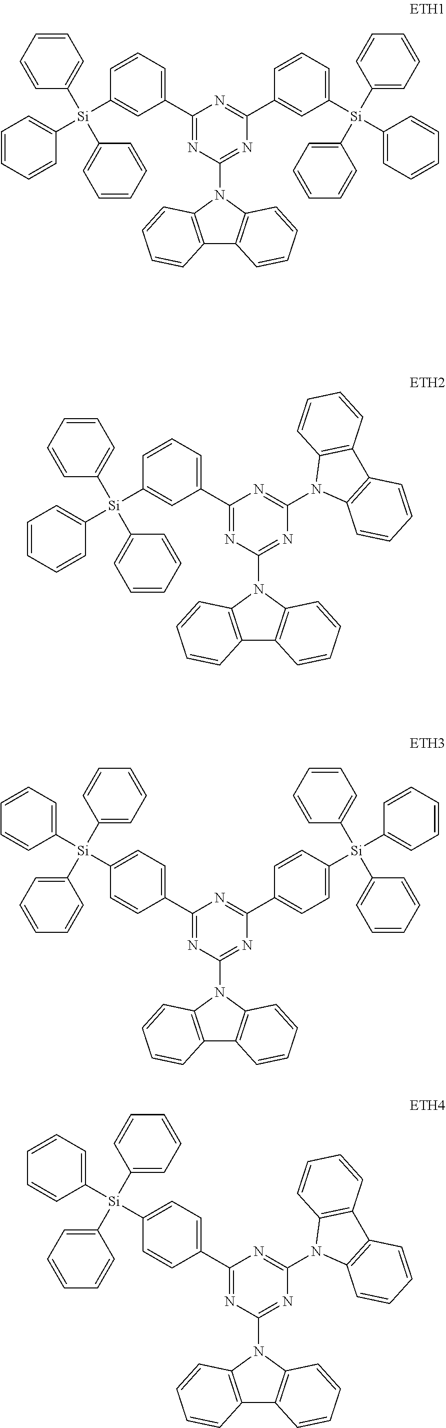 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

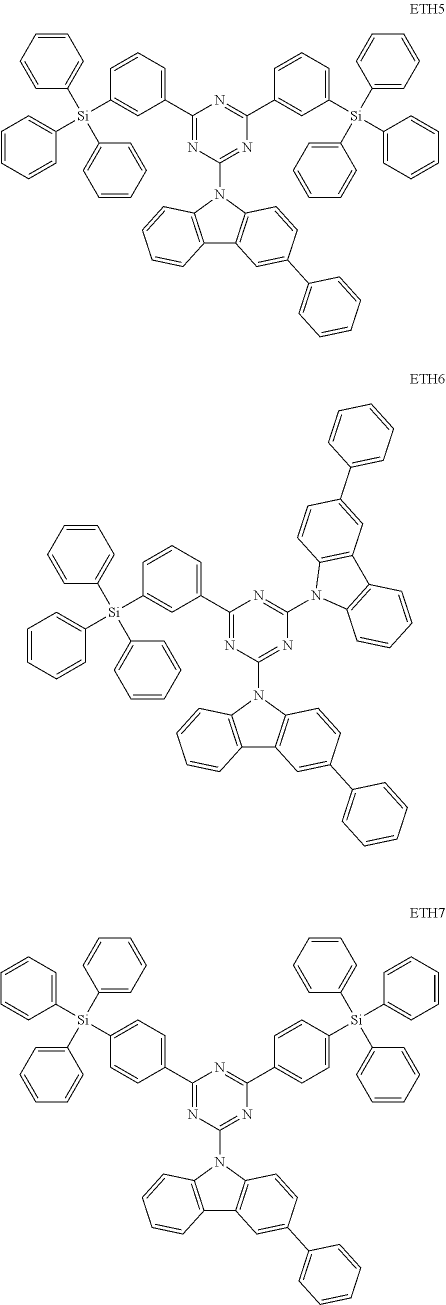 [SMILES: c1ccc(-c2ccc3c(c2)c2ccccc2n3-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2ccc3c(c2)c2ccccc2n3-c2nc(-c3ccc([Si](c4ccccc4)(c4ccccc4)c4ccccc4)cc3)nc(-c3ccc([Si](c4ccccc4)(c4ccccc4)c4ccccc4)cc3)n2)cc1]

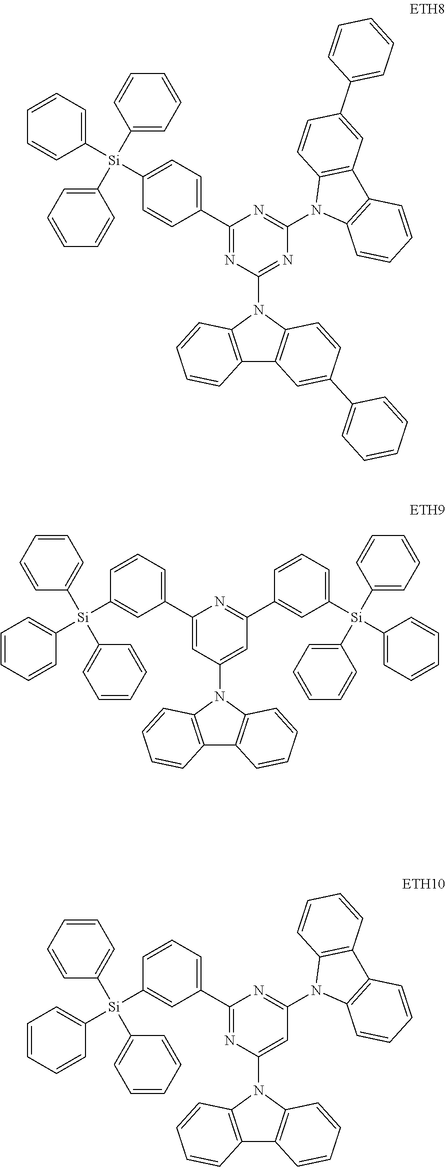 [SMILES: c1ccc(-c2ccc3c(c2)c2ccccc2n3-c2nc(-c3ccc([Si](c4ccccc4)(c4ccccc4)c4ccccc4)cc3)nc(-n3c4ccccc4c4cc(-c5ccccc5)ccc43)n2)cc1 ; c1ccc([Si](c2ccccc2)(c2ccccc2)c2cccc(-c3cc(-n4c5ccccc5c5ccccc54)cc(-c4cccc([Si](c5ccccc5)(c5ccccc5)c5ccccc5)c4)n3)c2)cc1 ; c1ccc([Si](c2ccccc2)(c2ccccc2)c2cccc(-c3nc(-n4c5ccccc5c5ccccc54)cc(-n4c5ccccc5c5ccccc54)n3)c2)cc1]

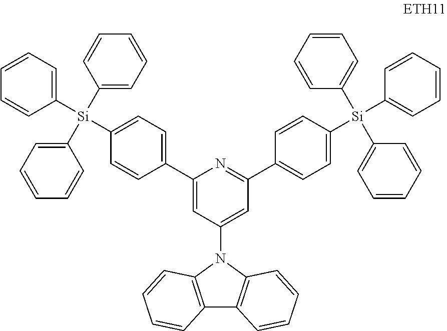 [SMILES: c1ccc([Si](c2ccccc2)(c2ccccc2)c2ccc(-c3cc(-n4c5ccccc5c5ccccc54)cc(-c4ccc([Si](c5ccccc5)(c5ccccc5)c5ccccc5)cc4)n3)cc2)cc1]

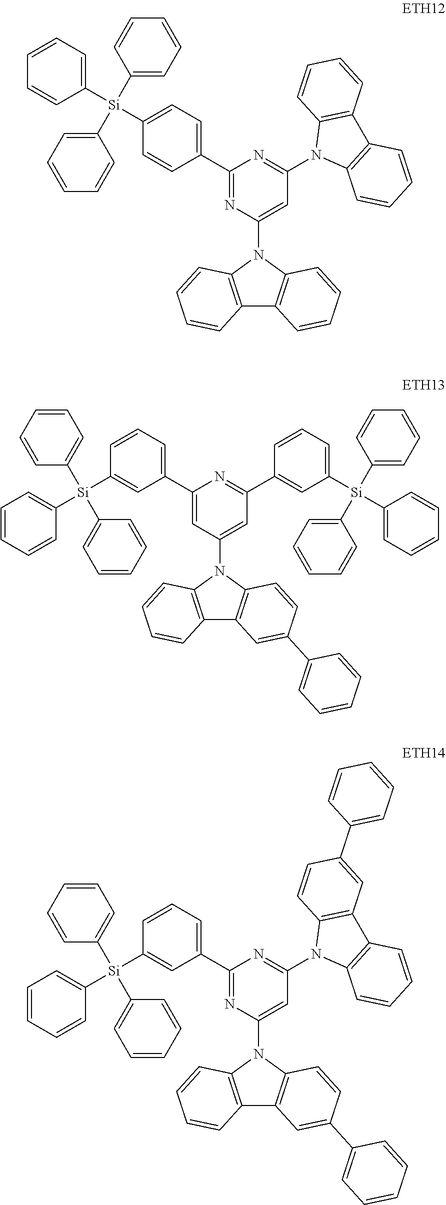 [SMILES: c1ccc([Si](c2ccccc2)(c2ccccc2)c2ccc(-c3nc(-n4c5ccccc5c5ccccc54)cc(-n4c5ccccc5c5ccccc54)n3)cc2)cc1 ; c1ccc(-c2ccc3c(c2)c2ccccc2n3-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; c1ccc(-c2ccc3c(c2)c2ccccc2n3-c2cc(-n3c4ccccc4c4cc(-c5ccccc5)ccc43)nc(-c3cccc([Si](c4ccccc4)(c4ccccc4)c4ccccc4)c3)n2)cc1]

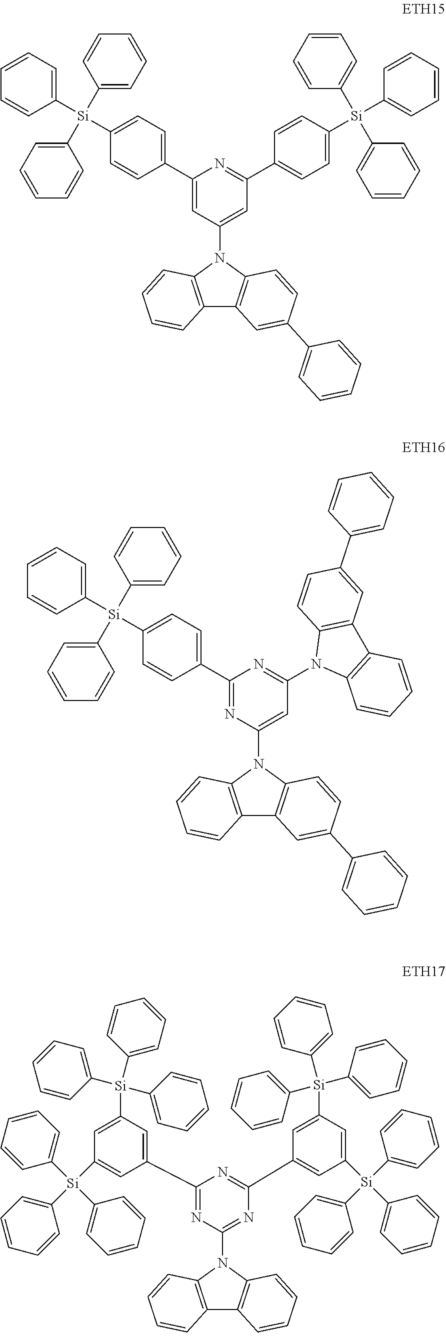

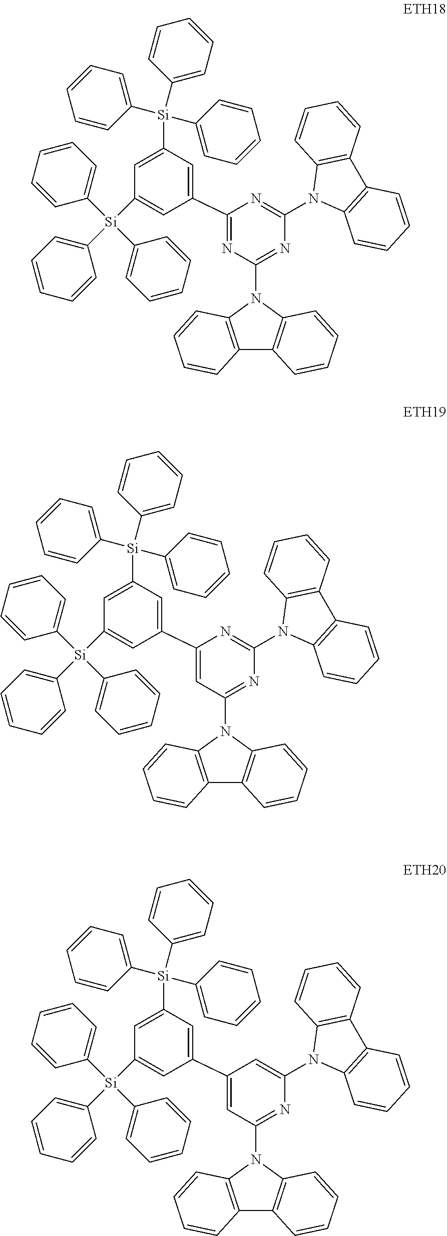

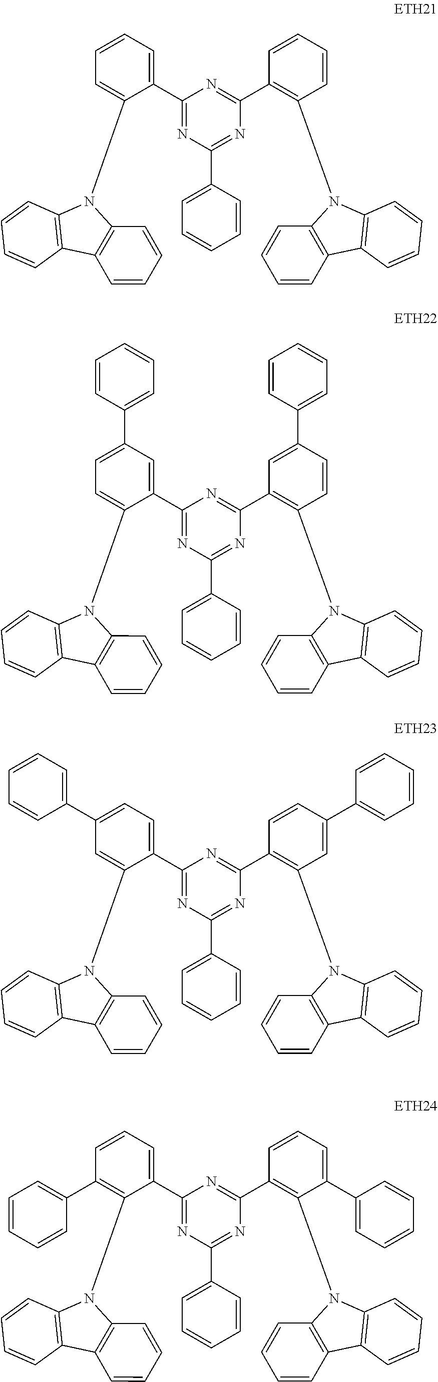 [SMILES: c1ccc(-c2nc(-c3ccccc3-n3c4ccccc4c4ccccc43)nc(-c3ccccc3-n3c4ccccc4c4ccccc43)n2)cc1 ; c1ccc(-c2ccc(-n3c4ccccc4c4ccccc43)c(-c3nc(-c4ccccc4)nc(-c4cc(-c5ccccc5)ccc4-n4c5ccccc5c5ccccc54)n3)c2)cc1 ; c1ccc(-c2ccc(-c3nc(-c4ccccc4)nc(-c4ccc(-c5ccccc5)cc4-n4c5ccccc5c5ccccc54)n3)c(-n3c4ccccc4c4ccccc43)c2)cc1 ; c1ccc(-c2nc(-c3cccc(-c4ccccc4)c3-n3c4ccccc4c4ccccc43)nc(-c3cccc(-c4ccccc4)c3-n3c4ccccc4c4ccccc43)n2)cc1]

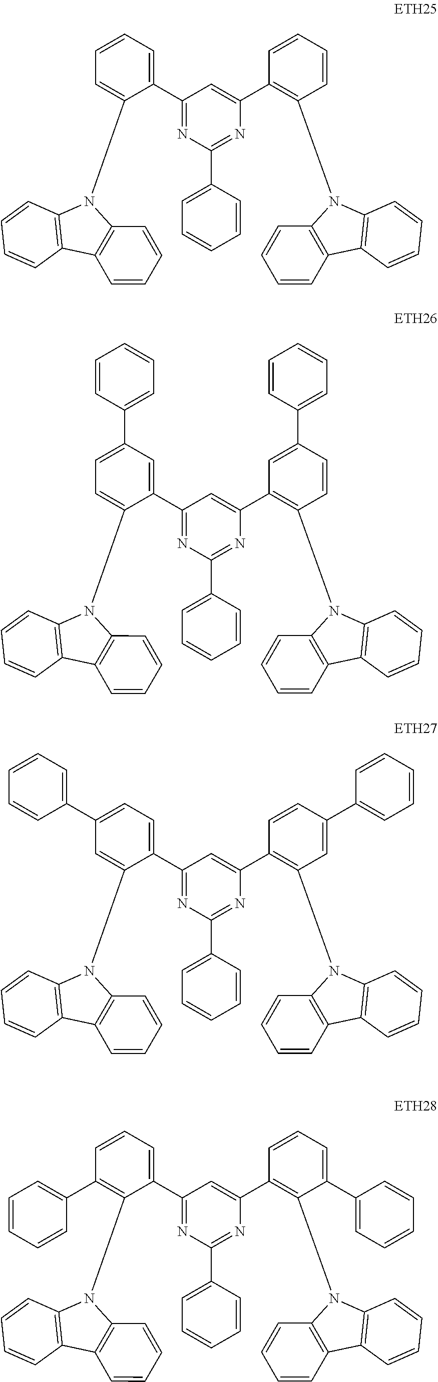 [SMILES: c1ccc(-c2nc(-c3ccccc3-n3c4ccccc4c4ccccc43)cc(-c3ccccc3-n3c4ccccc4c4ccccc43)n2)cc1 ; c1ccc(-c2ccc(-n3c4ccccc4c4ccccc43)c(-c3cc(-c4cc(-c5ccccc5)ccc4-n4c5ccccc5c5ccccc54)nc(-c4ccccc4)n3)c2)cc1 ; c1ccc(-c2ccc(-c3cc(-c4ccc(-c5ccccc5)cc4-n4c5ccccc5c5ccccc54)nc(-c4ccccc4)n3)c(-n3c4ccccc4c4ccccc43)c2)cc1 ; c1ccc(-c2nc(-c3cccc(-c4ccccc4)c3-n3c4ccccc4c4ccccc43)cc(-c3cccc(-c4ccccc4)c3-n3c4ccccc4c4ccccc43)n2)cc1]

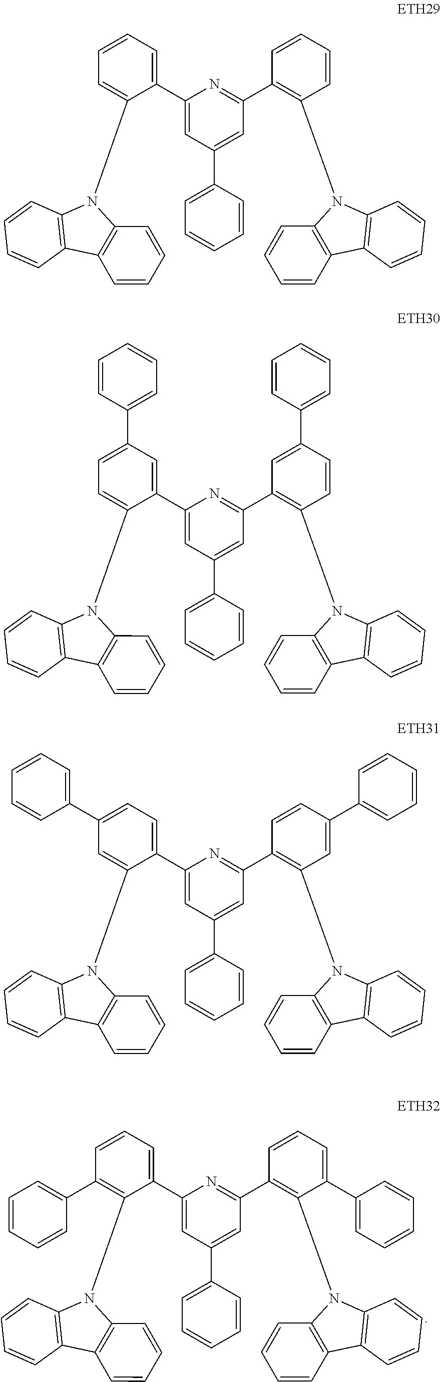 [SMILES: c1ccc(-c2cc(-c3ccccc3-n3c4ccccc4c4ccccc43)nc(-c3ccccc3-n3c4ccccc4c4ccccc43)c2)cc1 ; c1ccc(-c2cc(-c3cc(-c4ccccc4)ccc3-n3c4ccccc4c4ccccc43)nc(-c3cc(-c4ccccc4)ccc3-n3c4ccccc4c4ccccc43)c2)cc1 ; c1ccc(-c2cc(-c3ccc(-c4ccccc4)cc3-n3c4ccccc4c4ccccc43)nc(-c3ccc(-c4ccccc4)cc3-n3c4ccccc4c4ccccc43)c2)cc1 ; c1ccc(-c2cc(-c3cccc(-c4ccccc4)c3-n3c4ccccc4c4ccccc43)nc(-c3cccc(-c4ccccc4)c3-n3c4ccccc4c4ccccc43)c2)cc1]

In the light-emitting device according to an embodiment, the second host may include a moiety represented by Formula 7:

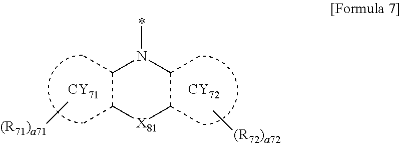

In Formula 7,
ring CY₇₁ and ring CY₇₂ may each independently be a C₅-C₆₀ carbocyclic group or a C₁-C₆₀ heterocyclic group,
X₈₁ may be a single bond, O, S, N(R₈₁), B(R₈₁), C(R₃₈₁ₐ)(R_{381b}), or Si(R₃₈₁ₐ)(R_{381b}),
R₇₁, R₇₂, R₈₁, R₈₁ₐ, and R_{81b} may each independently be the same as described in connection with R₁₀ₐ in Formula 1,
a71 and a72 may each independently be an integer from 0 to 10, and
* indicates a binding site to an atom included in the remaining part other than Formula 7 in the second compound.

In the light-emitting device according to an embodiment, in Formula 7, ring CY₇₁ and ring CY₇₂ may each independently be a first ring, a second ring, a condensed cyclic group in which two or more first rings are condensed with each other, a condensed cyclic group in which two or more second rings are condensed with each other, or a condensed ring in which one or more first rings are condensed with one or more second rings, wherein
the first ring may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group, and
the second ring may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group.

In the light-emitting device according to an embodiment, in Formula 7, ring CY₇₁ and ring CY₇₂ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzooxadiazole group, a benzothiadiazole group, a 5,6,7,8-tetrahydroisoquinoline group, or a 5,6,7,8-tetrahydroquinoline group.

In the light-emitting device according to an embodiment, the second host may include a compound represented by one of Formulae 7-1 to 7-5:

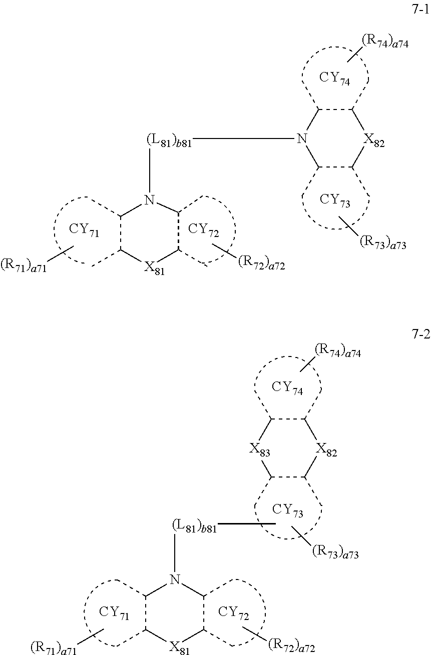

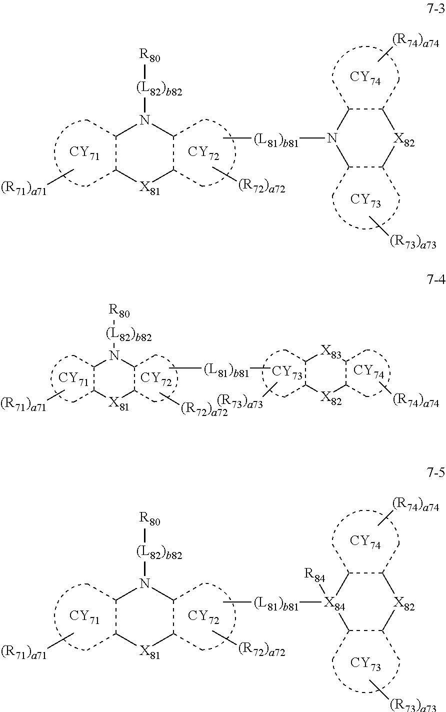

In Formulae 7-1 to 7-5,
ring CY₇₁, ring CY₇₂, X₈₁, R₇₁, R₇₂, a71, and a72 are each the same as described herein,
ring CY₇₃, ring CY₇₄, R₇₃, R₇₄, a73, and a74 may respectively be the same as described in connection with ring CY₇₁, ring CY₇₂, R₇₁, R₇₂, a71, and a72,
L₈₁ and L₈₂ may each independently be *—C(Q₄)(Q₅)-*′, *—Si(Q₄)(Q₅)-*′, a substituted or unsubstituted C₅-C₃₀ carbocyclic group, or a substituted or unsubstituted C₁-C₃₀ heterocyclic group, wherein Q₄ and Q₅ are each independently the same as described in connection with Q₁,
b81 and b82 may each independently be an integer from 0 to 5, wherein

when b81 is 0, *-(L₈₁)_{b81}-*′ may be a single bond; when b81 is 2 or more, two or more of L₈₁ may be identical to or different from each other; when b82 is 0, *-(L₈₂)_{b82}-*′ may be a single bond; and when b82 is 2 or more, two or more of L₈₂ may be identical to or different from each other,
X₈₂ may be a single bond, O, S, N(R₈₂), B(R₈₂), C(R₈₂ₐ)(R_{82b}), or Si(R₈₂ₐ)(R_{82b}),
X₈₃ may be a single bond, O, S, N(R₈₃), B(R₈₃), C(R₈₃ₐ)(R_{83b}), or Si(R₈₃ₐ)(R_{83b}),
in Formulae 7-2 and 7-4, X₈₂ and X₈₃ may not each be a single bond at the same time,
X₈₄ may be C or Si,
R₈₀, R₈₂, R₈₃, R₈₂ₐ, R_{82b}, R₈₃ₐ, R_{83b}, and R₈₄ may each independently be the same as described in connection with R₈₁, and
* and *′ each indicate a binding site to a neighboring atom.

In the light-emitting device according to an embodiment,
in Formulae 7-1 and 7-2, a moiety represented by

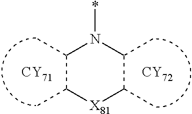

may be a moiety represented by one of Formulae CY71-1(1) to CY71-1(8),
in Formulae 7-1 and 7-3, a moiety represented by

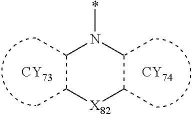

may be a moiety represented by one of Formulae CY71-2(1) to CY71-2(8),
in Formulae 7-2 and 7-4, a moiety represented by

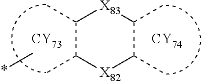

may be a moiety represented by one of Formulae CY71-3(1) to CY71-3(32),
in Formulae 7-3 to 7-5, a moiety represented by

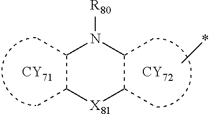

may be a moiety represented by one of Formulae CY71-4(1) to CY71-4(32), and
in Formula 7-5, a moiety represented by

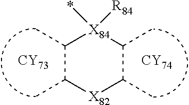

may be a moiety represented by one of Formulae CY71-5(1) to CY71-5(8):

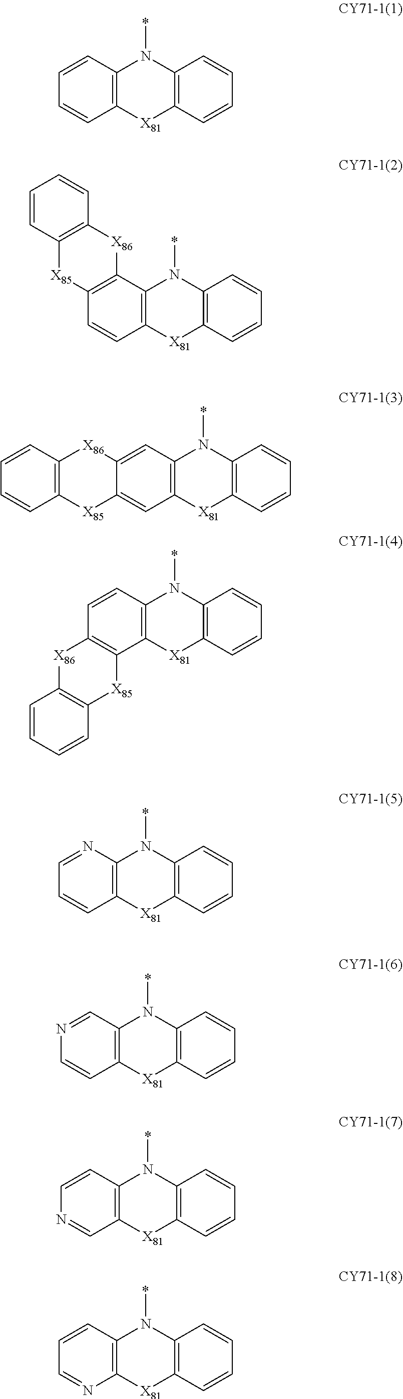

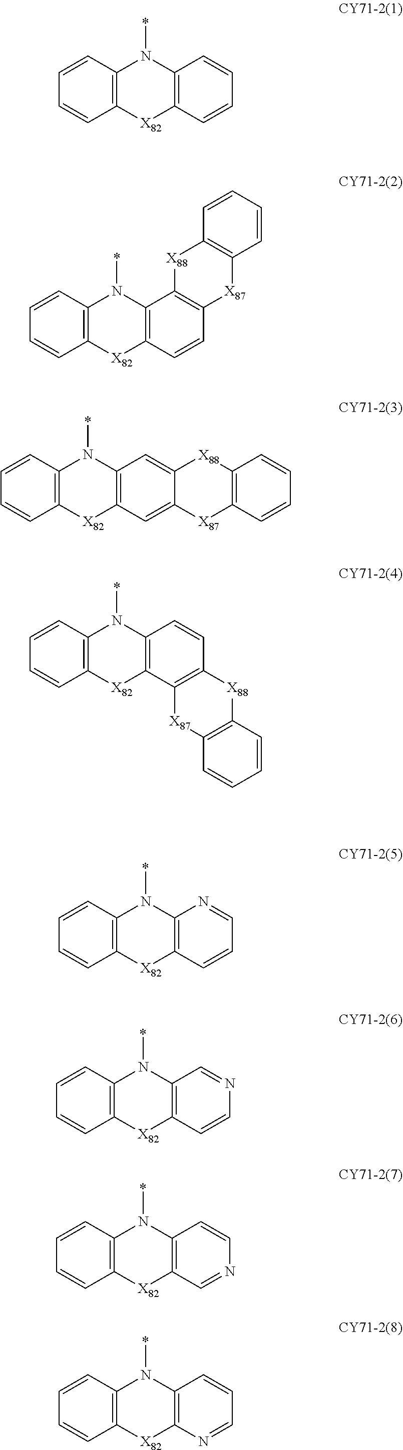

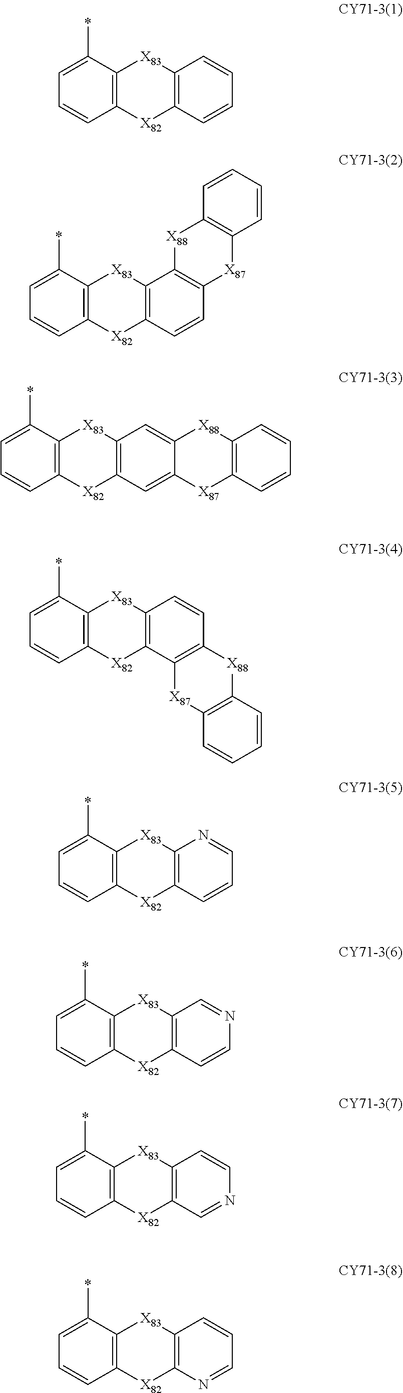

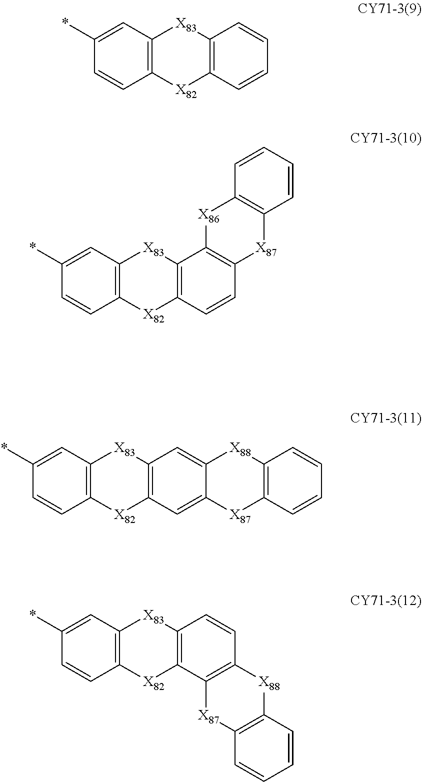

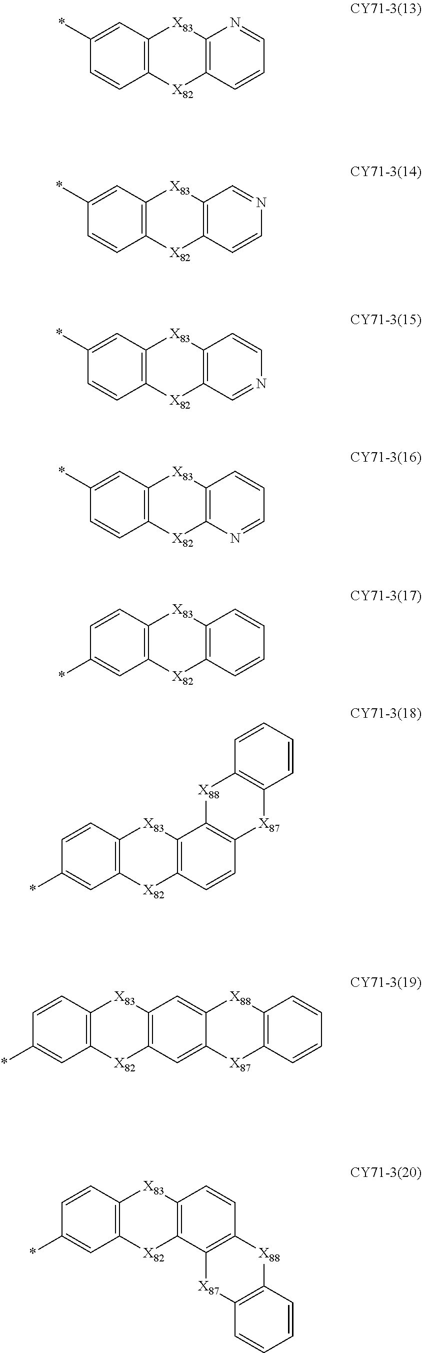

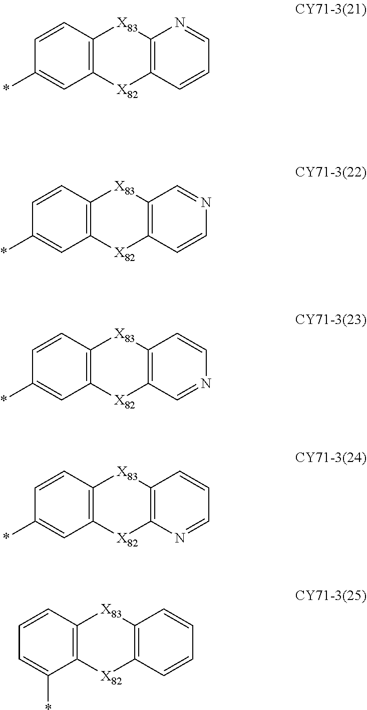

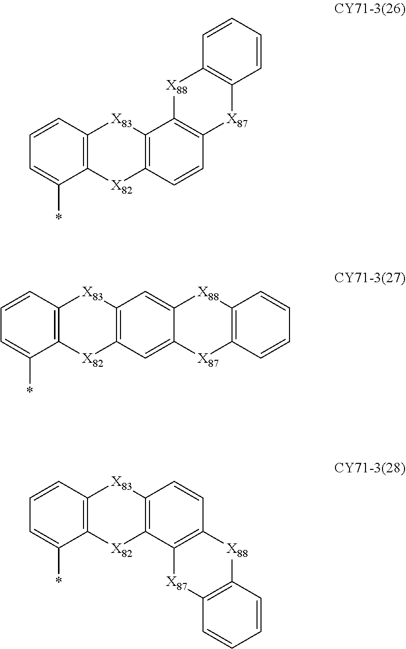

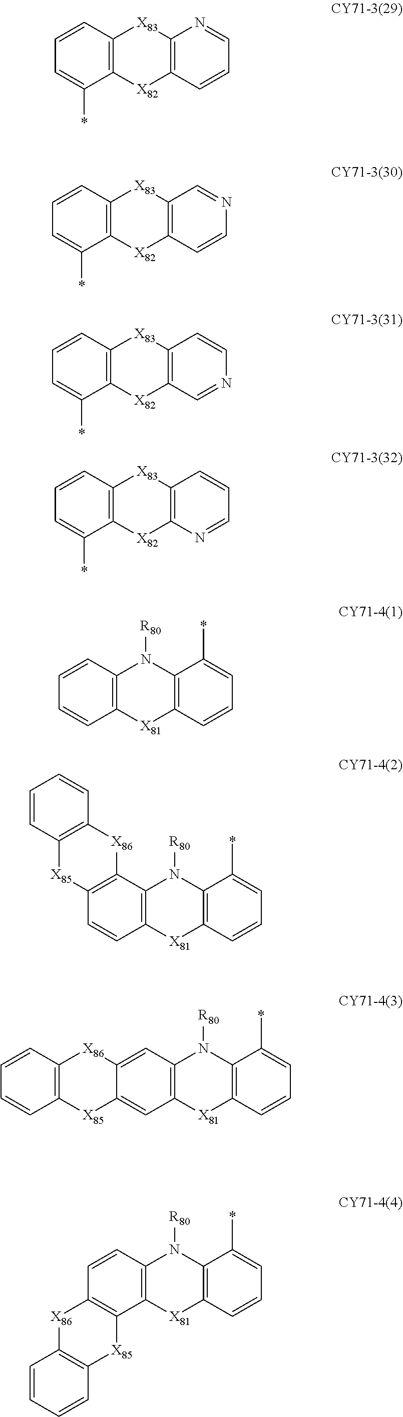

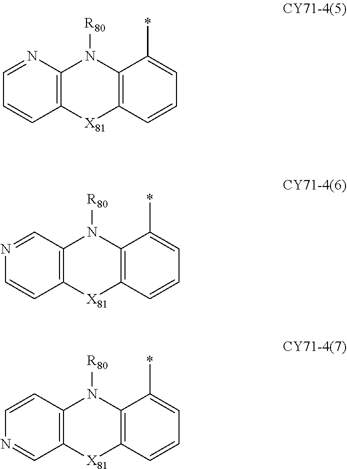

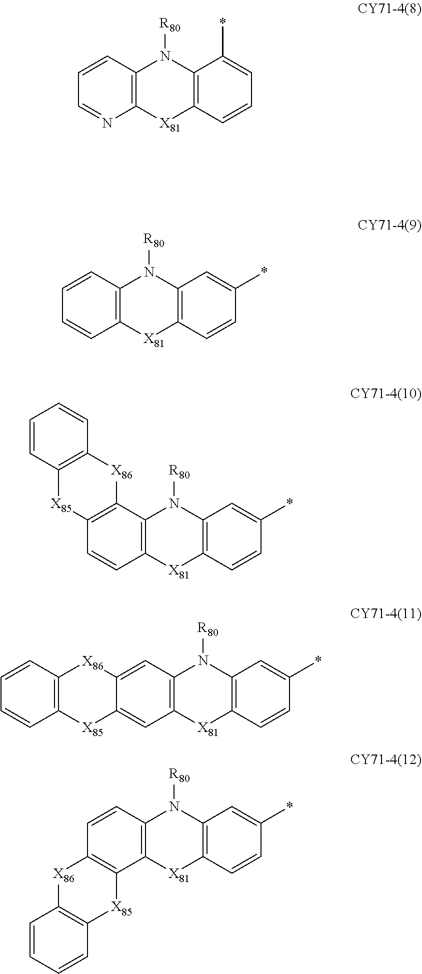

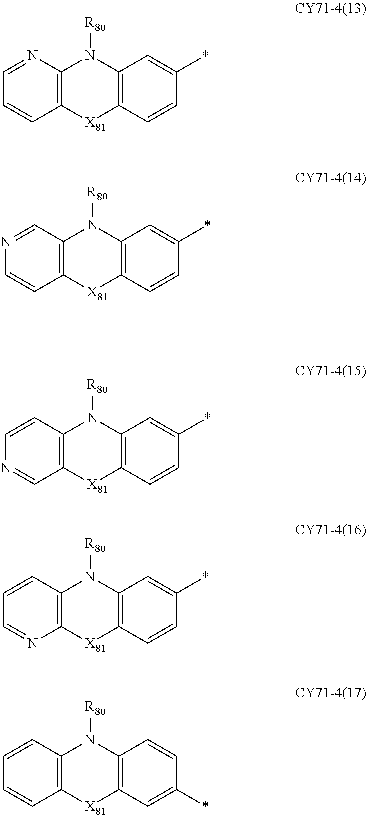

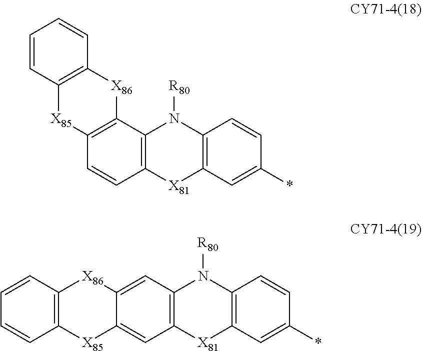

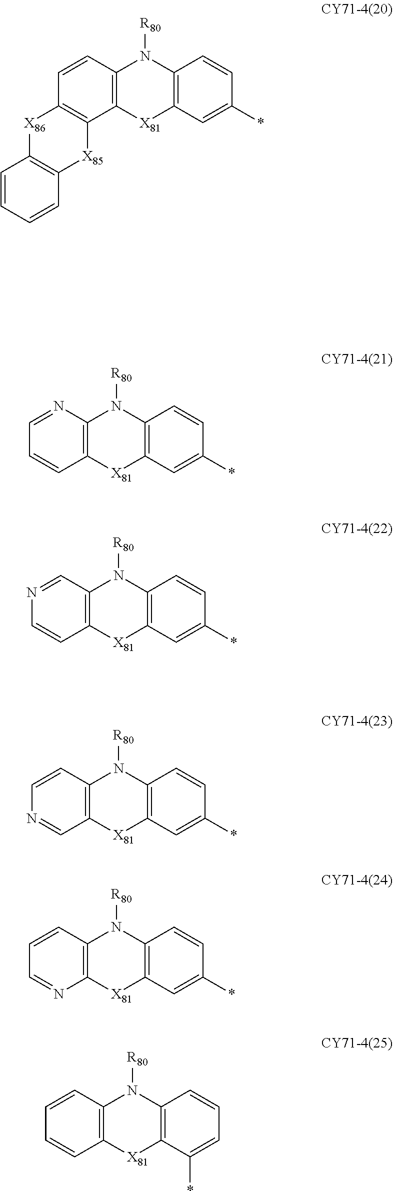

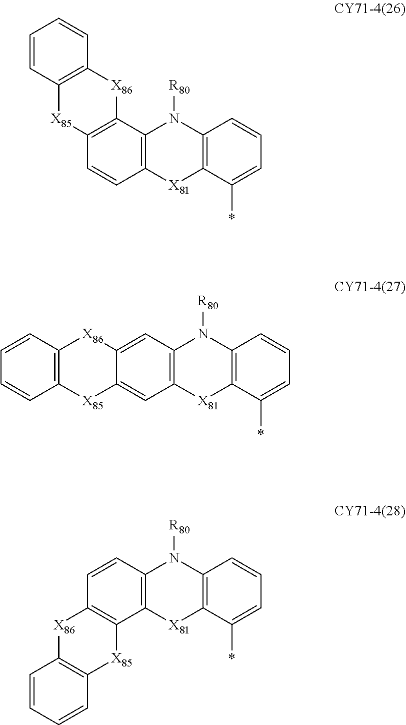

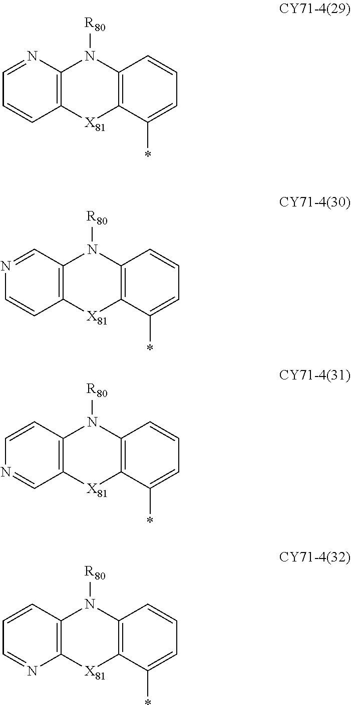

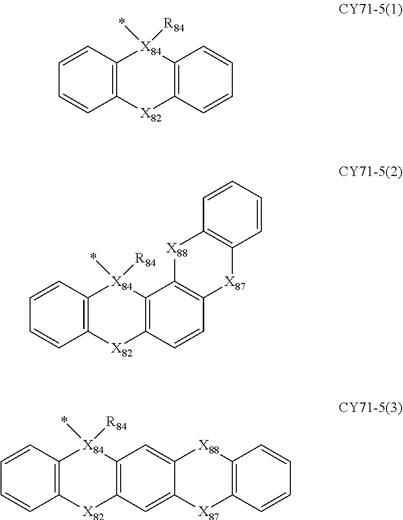

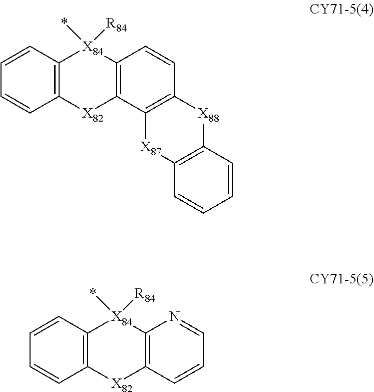

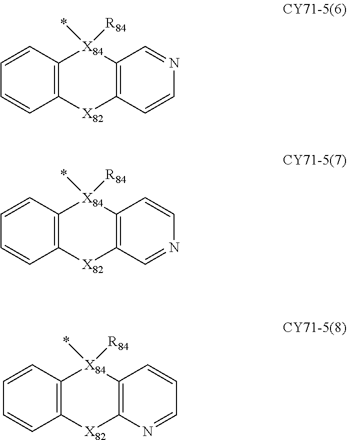

In Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),
X₈₁ to X₈₄, R₈₀, and R₈₄ are each the same as described herein,
X₈₅ may be a single bond, O, S, N(R₈₅), B(R₈₅), C(R₈₅ₐ)(R_{85b}), or Si(R₈₅ₐ)(R_{85b}),
X₈₆ may be a single bond, O, S, N(R₈₆), B(R₈₆), C(R₈₆ₐ)(R_{86b}), or Si(R₈₆ₐ)(R_{86b}),
X₈₅ and X₈₆ in Formulae CY71-1(1) to CY71-1(8) and CY71-4(1) to CY71-4(32) may not each be a single bond at the same time,
X₈₇ may be a single bond, O, S, N(R₈₇), B(R₈₇), C(R₈₇ₐ)(R_{87b}), or Si(R₈₇ₐ)(R_{87b}),
X₈₈ may be a single bond, O, S, N(R₈₈), B(R₈₈), C(R₈₈ₐ)(R_{88b}), or Si(R₈₈ₐ)(R_{88b}),
X₈₇ and X₈₈ in Formulae CY71-2(1) to CY71-2(8), CY71-3(1) to CY71-3(32), and CY71-5(1) to CY71-5(8) may not each be a single bond at the same time, and
R₈₅ to R₈₈, R₈₅ₐ, R_{85b}, R₈₆ₐ, R_{86b}, R₈₇ₐ, R_{87b}, R₈₈ₐ and R_{88b} may each independently be the same as described in connection with R₈₁.

In the light-emitting device according to an embodiment, the second host may include at least one of Compounds HTH1 to HTH40:

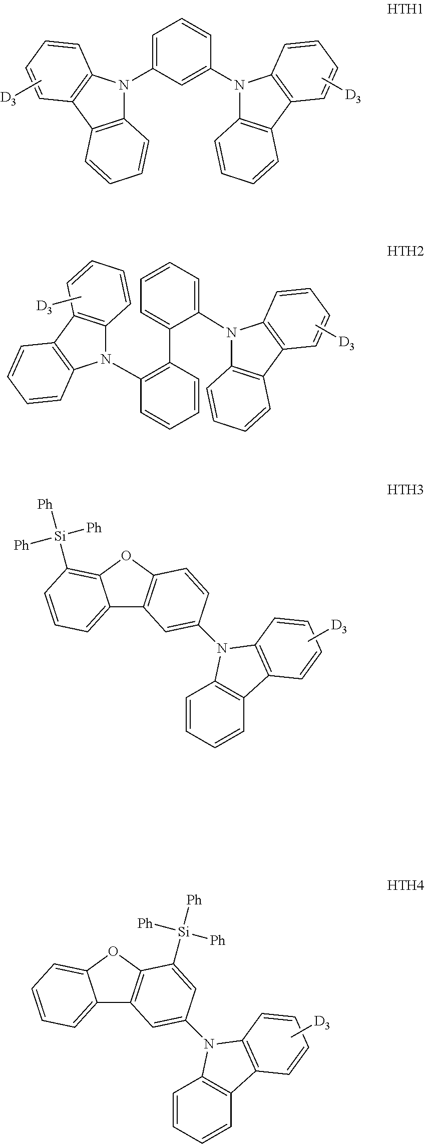

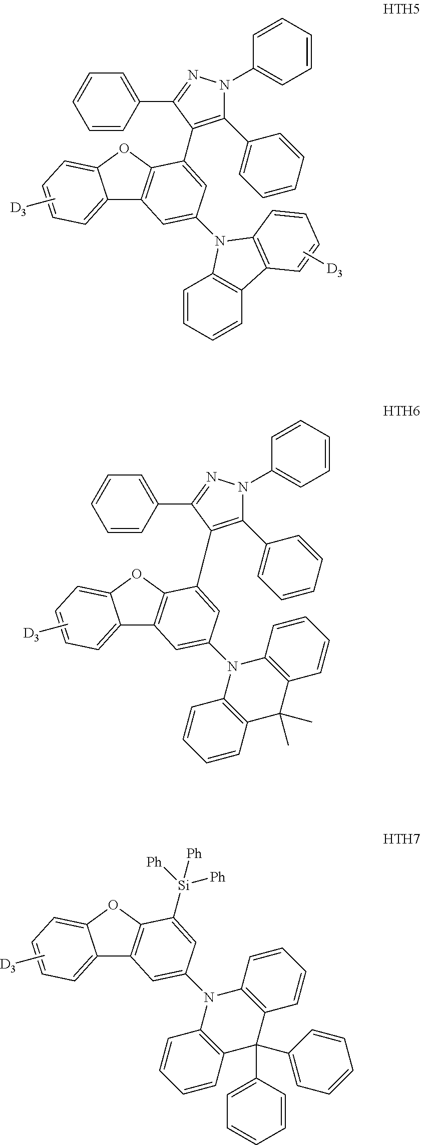

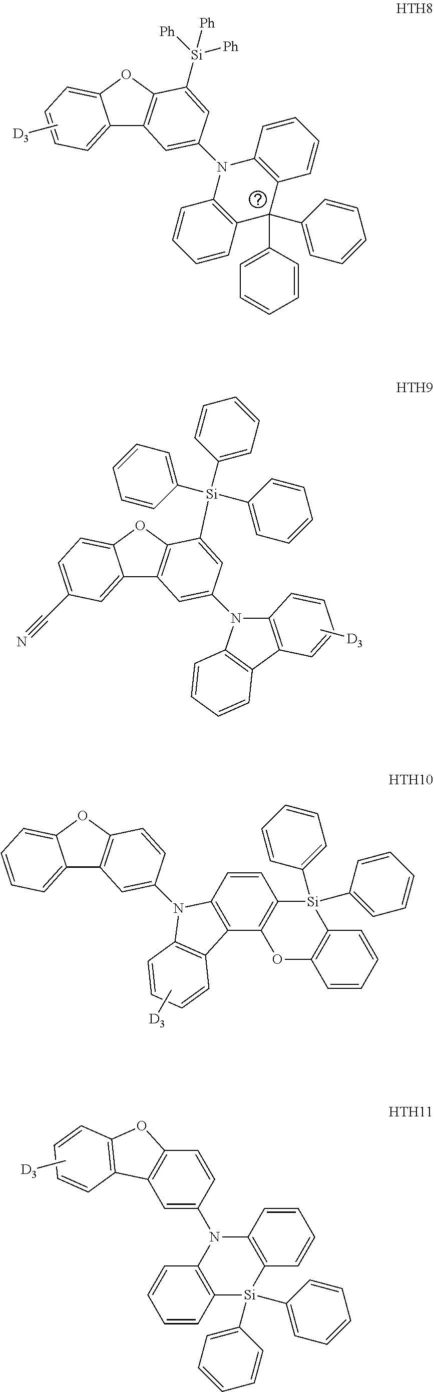

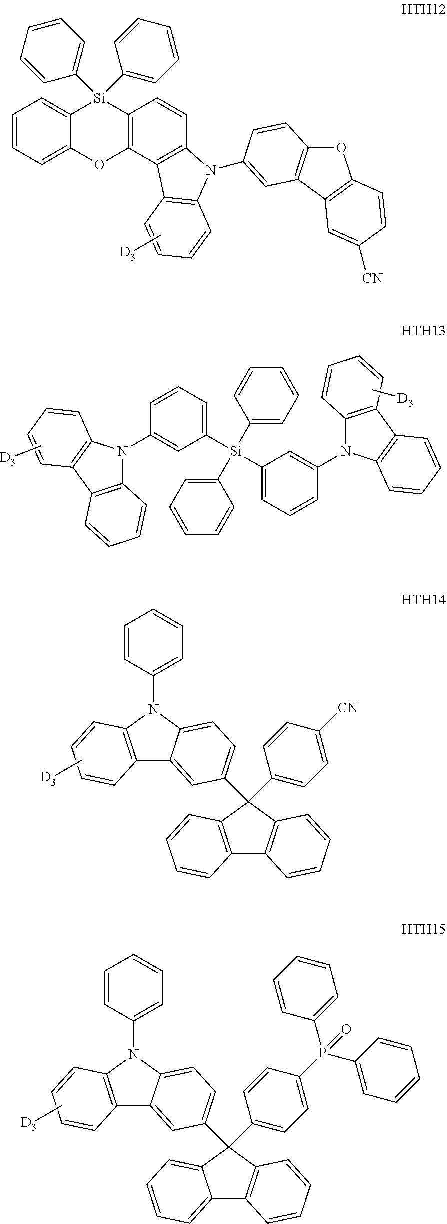

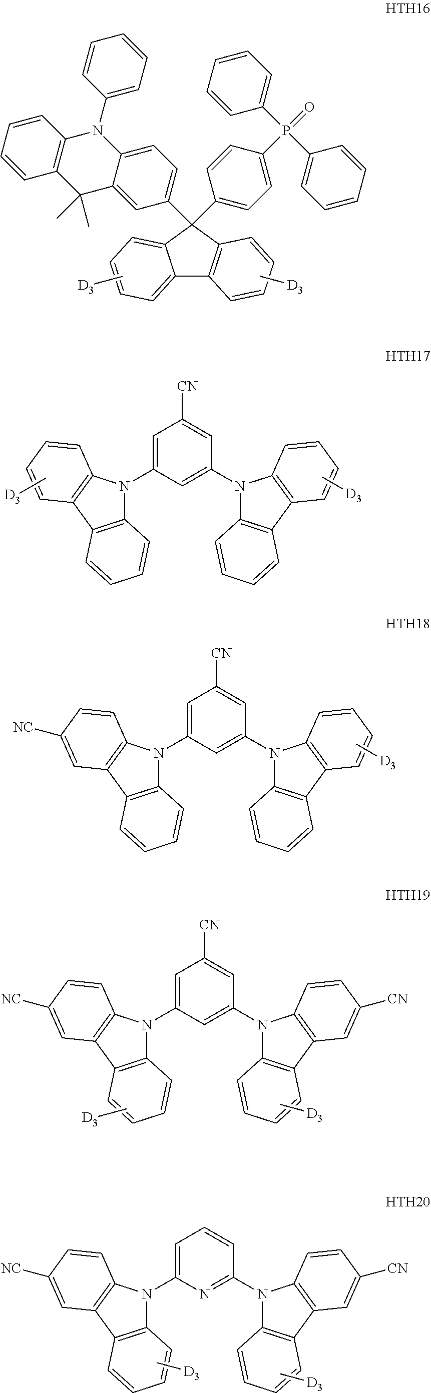

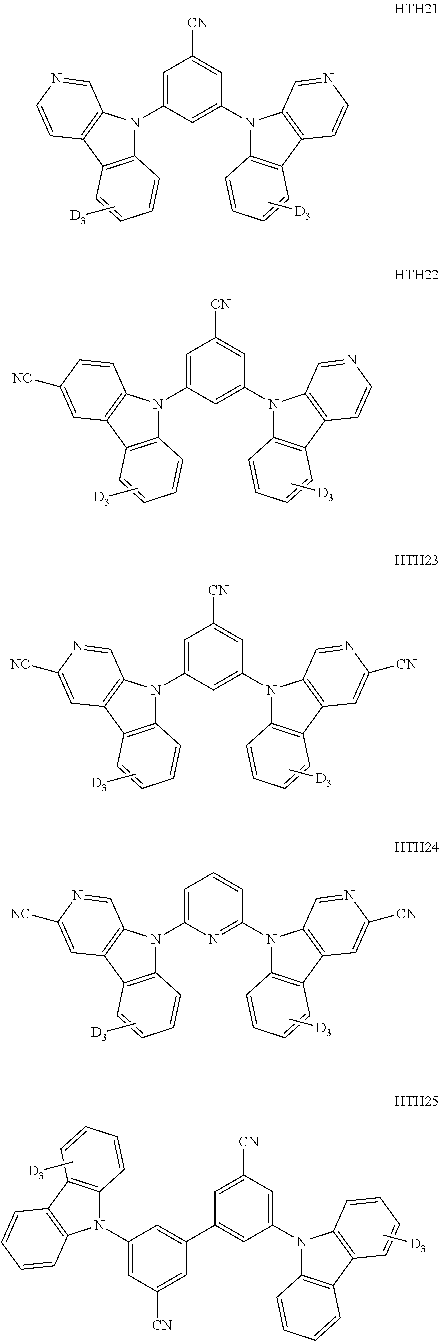

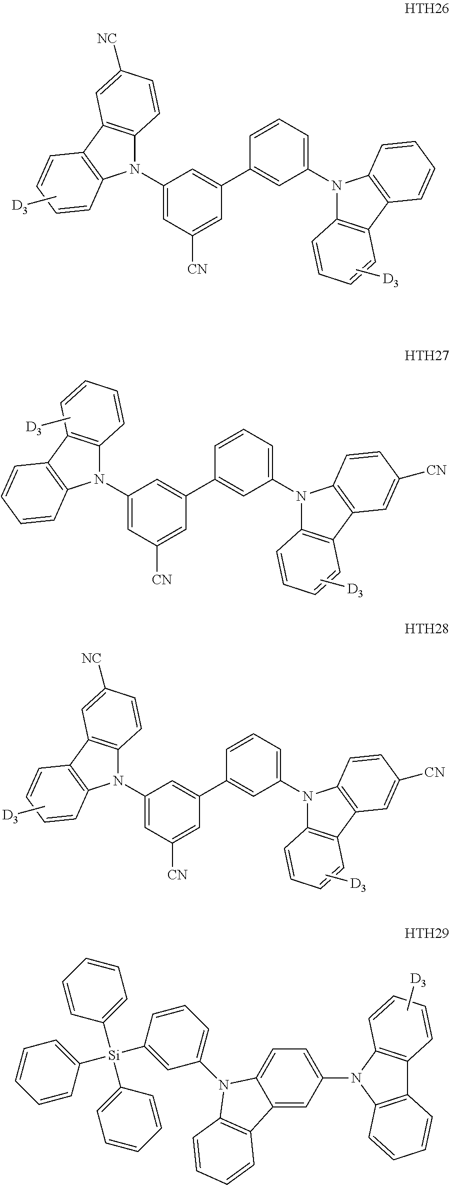

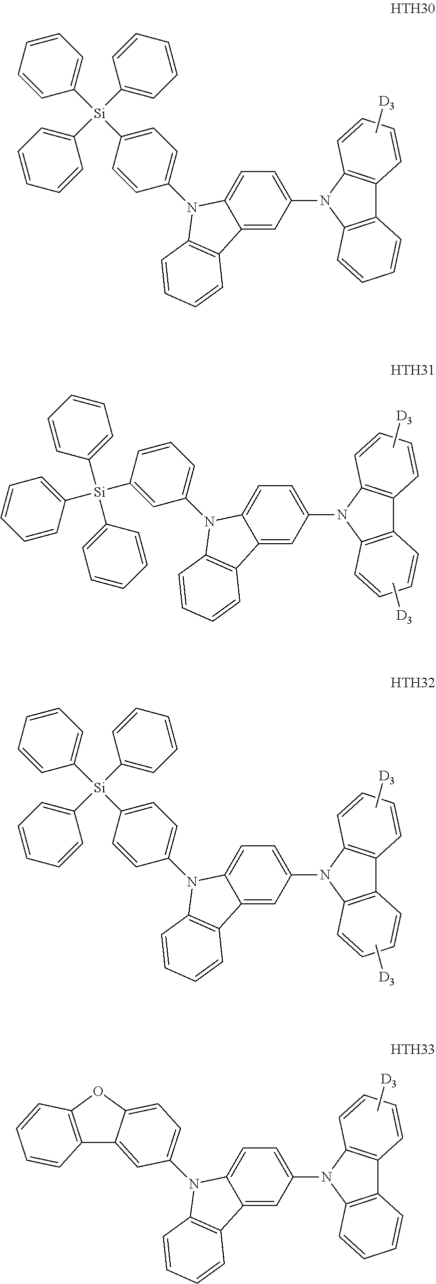

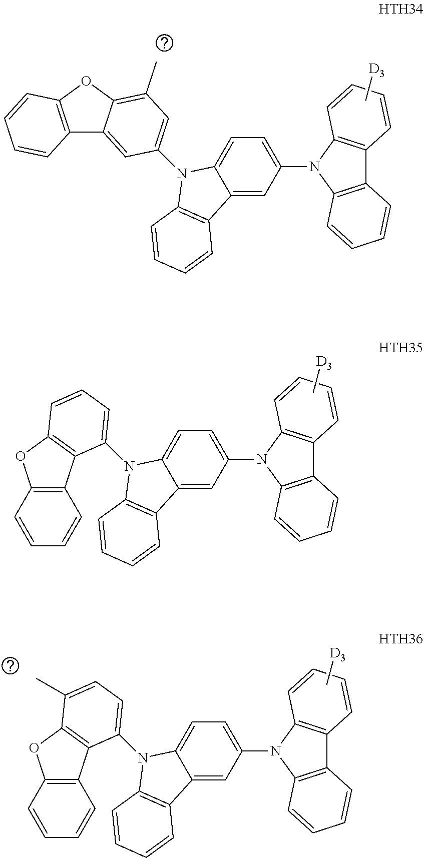

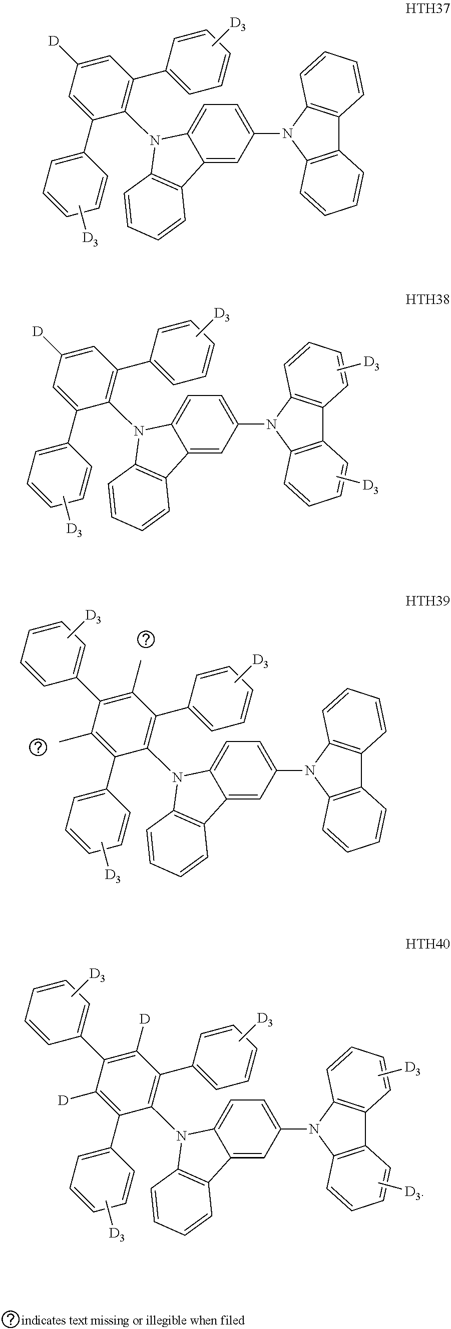

In the light-emitting device according to an embodiment, the first host and the second host may form an exciplex; however, the organometallic compound and the first host may not form an exciplex and the organometallic compound and the second host may not form an exciplex.

In the light-emitting device according to an embodiment, the emission layer may further include a fluorescent dopant. By further including a fluorescent dopant, the luminescence efficiency and lifespan of the light-emitting device may be further improved.

In the light-emitting device according to an embodiment, the fluorescent dopant may be delayed fluorescence dopant.

In the light-emitting device according to an embodiment, the fluorescent dopant may include a compound represented by Formula 3:

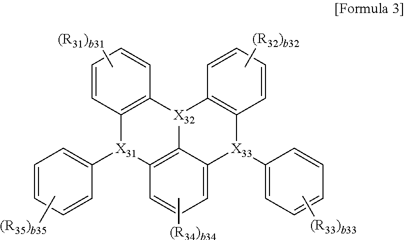

In Formula 3, X₃₁ to X₃₃ may each independently be B or N. For example, X₃₁ and X₃₃ may each be N, and X₃₂ may be B.

In Formula 3, R³¹ to R³⁵ may each independently be the same as described in connection with R₁₀ₐ in Formula 1.

In Formula 3, two or more of R³¹ to R³⁵ may be identical to or different from each other.

In Formula 3,
b31 and b32 may each independently be an integer from 0 to 4,
b33 and b35 may each independently be an integer from 0 to 5, and
b34 may be an integer from 0 to 3.

In the light-emitting device according to an embodiment, the fluorescent dopant may include a compound represented by Formula 4:

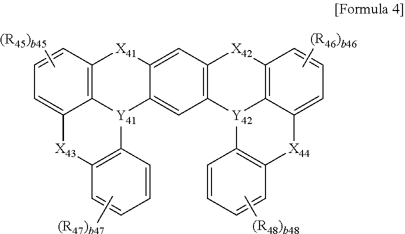

In Formula 4, Y₄₁ and Y₄₂ may each independently be B or N. For example, Y₄₁ and Y₄₂ may each be B.

In Formula 4, X₄₁ may be O, S, N(R₄₁ₐ), or C(R₄₁ₐ)(R_{41b}); X₄₂ may be O, S, N(R₄₂ₐ), or C(R₄₂ₐ)(R_{42b}); X₄₃ may be O, S, N(R₄₃ₐ), or C(R₄₃ₐ)(R_{43b}); and X₄₄ may be O, S, N(R₄₄ₐ), or C(R₄₄ₐ)(R_{44b}).

In an embodiment, X₄₁ may be N(R₄₁ₐ), X₄₂ may be N(R₄₂ₐ), X₄₃ may be N(R₄₃ₐ), and X₄₄ may be N(R₄₄ₐ). For example, X₄₁ may be N(R₄₁ₐ), and X₄₂ may be N(R₄₂ₐ). For example, X₄₁ may be N(R₄₁ₐ), X₄₂ may be N(R₄₂ₐ), and X₄₃ may be N(R₄₃ₐ). For example, X₄₁ may be N(R₄₁ₐ), X₄₂ may be N(R₄₂ₐ), and X₄₄ may be N(R₄₄ₐ). For example, X₄₂ may be N(R₄₂ₐ), X₄₃ may be N(R₄₃ₐ), and X₄₄ may be N(R₄₄ₐ). For example, X₄₁ may be N(R₄₁ₐ), X₄₂ may be N(R₄₂ₐ), X₄₃ may be N(R₄₃ₐ), and X₄₄ may be N(R₄₄ₐ).

In Formula 4, R₄₁ₐ, R_{41b}, R₄₂ₐ, R_{42b}, R₄₃ₐ, R_{43b}, R₄₄ₐ, R_{44b}, R₄₅, R₄₆, R₄₇, and R₄₈ may each independently be the same as described in connection with R₁₀ₐ in Formula 1.

In Formula 4, two or more of R₄₁ₐ, R_{41b}, R₄₂ₐ, R_{42b}, R₄₃ₐ, R_{43b}, R₄₄ₐ, R_{44b}, R₄₅, R₄₆, R₄₇, and R₄₈ may be identical to or different from each other.

In Formula 4, b45 and b46 may each independently be an integer from 0 to 3.

In Formula 4, b47 and b48 may each independently be an integer from 0 to 4.

In the light-emitting device according to an embodiment, the fluorescent dopant may include at least one of Compounds DFD1 to DFD29:

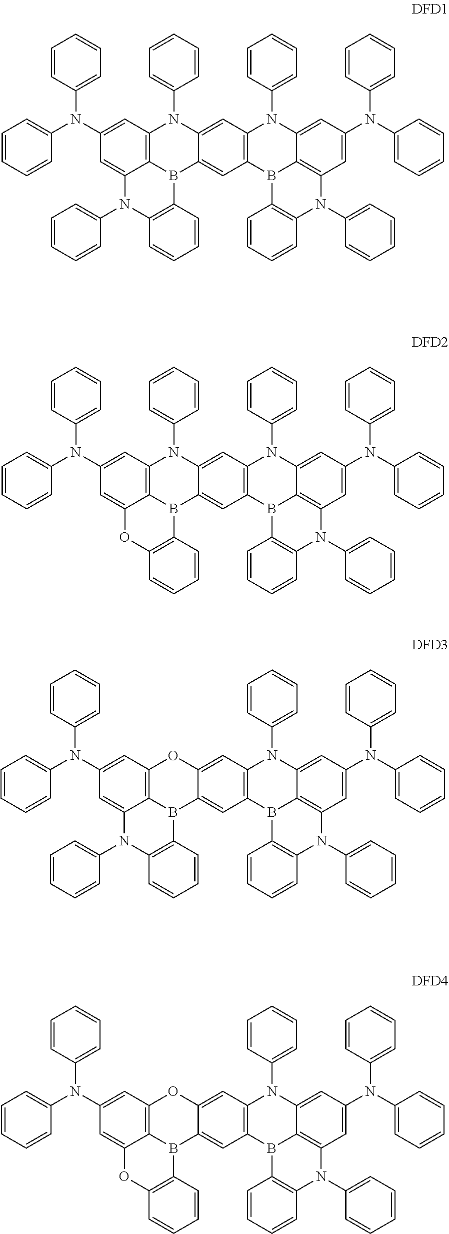

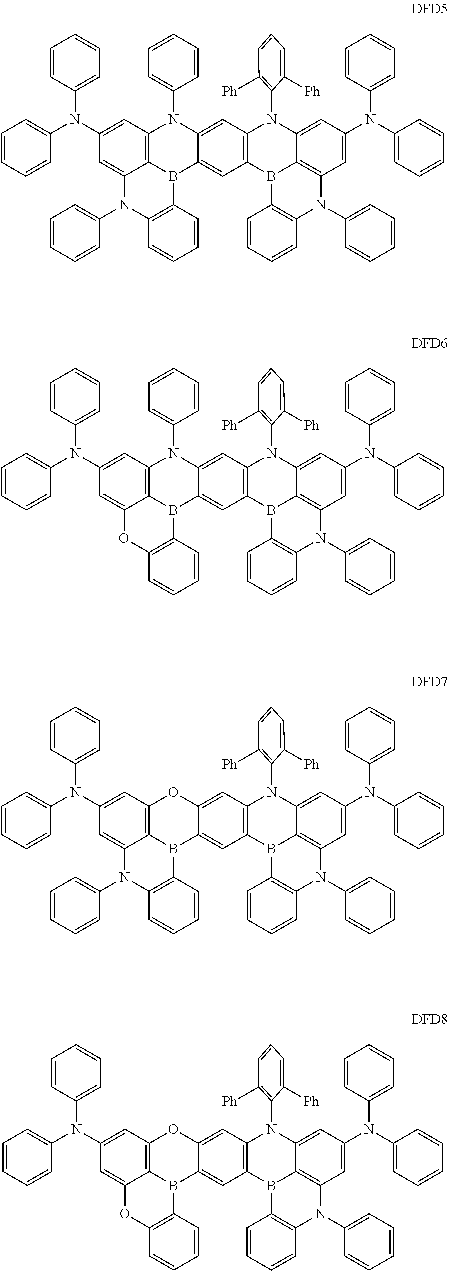

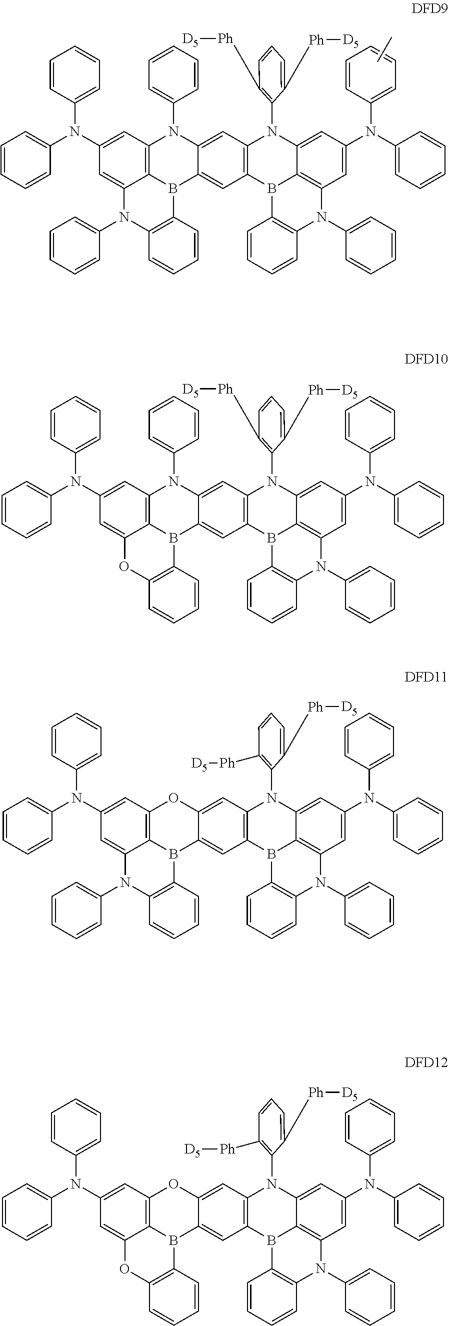

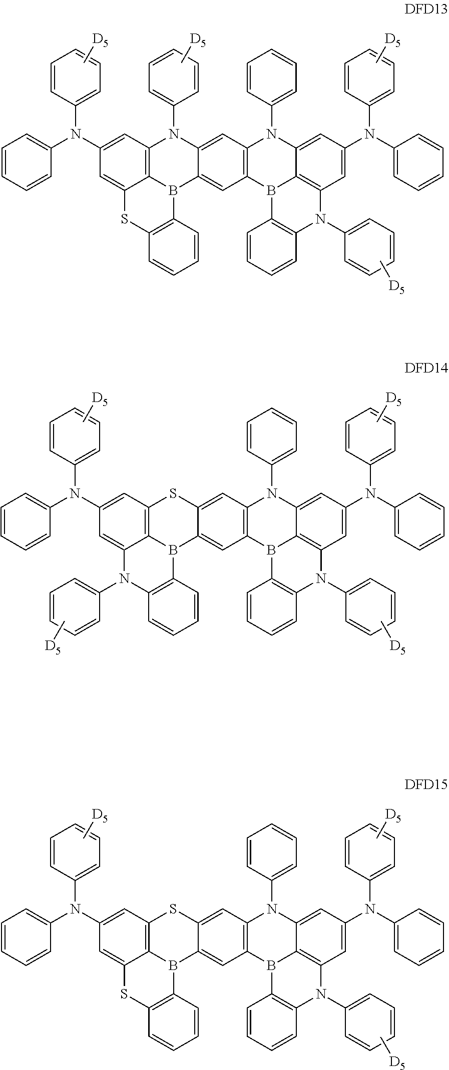

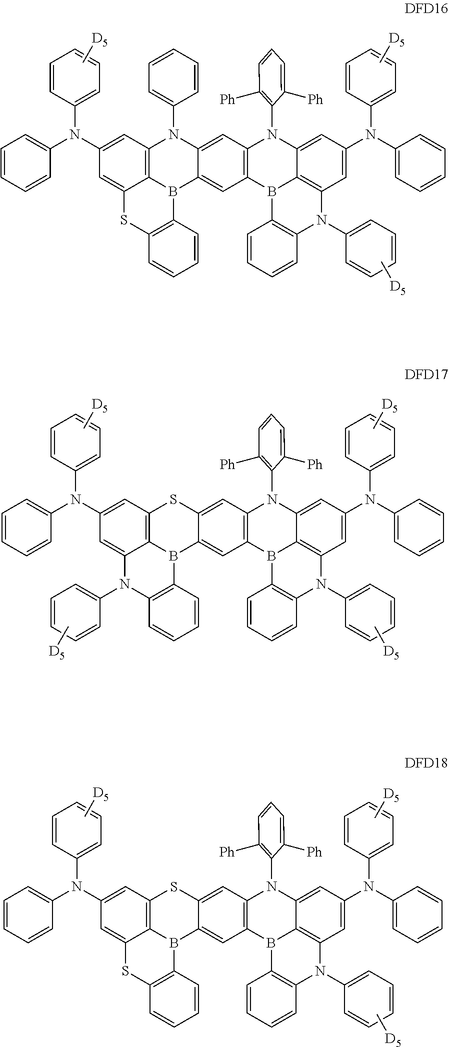

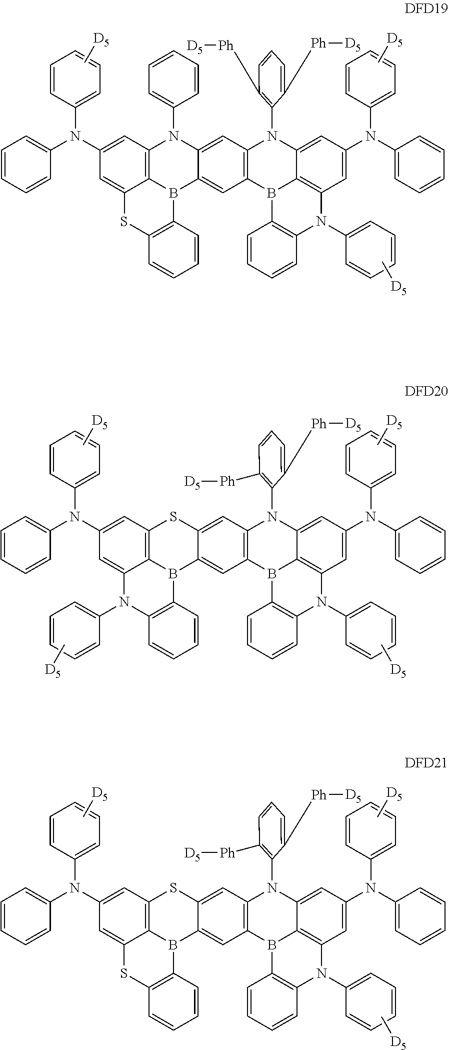

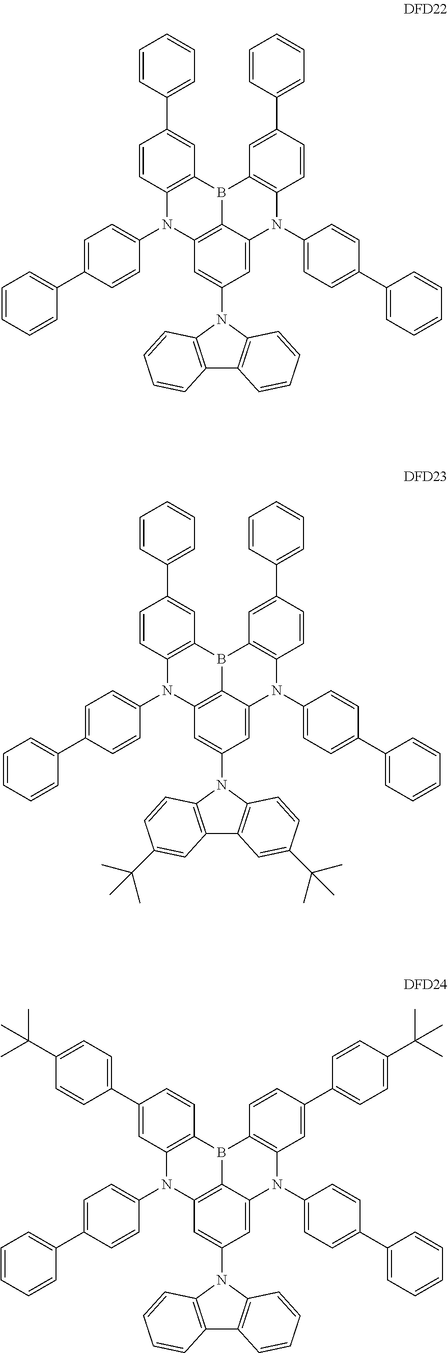 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1ccc2c(c1)c1cc(C(C)(C)C)ccc1n2-c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1ccc(-c2ccc3c(c2)N(c2ccc(-c4ccccc4)cc2)c2cc(-n4c5ccccc5c5ccccc54)cc4c2B3c2ccc(-c3ccc(C(C)(C)C)cc3)cc2N4c2ccc(-c3ccccc3)cc2)cc1]

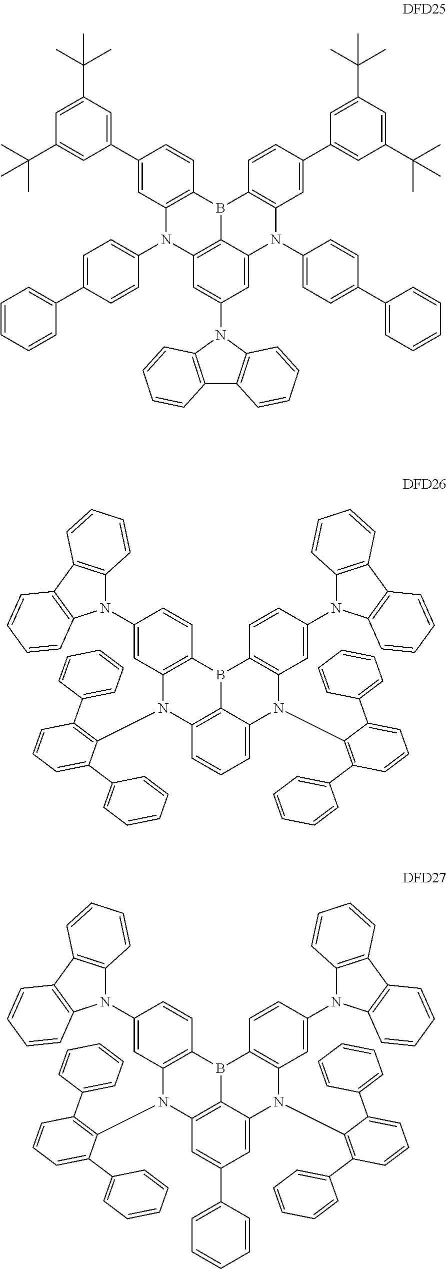 [SMILES: CC(C)(C)c1cc(-c2ccc3c(c2)N(c2ccc(-c4ccccc4)cc2)c2cc(-n4c5ccccc5c5ccccc54)cc4c2B3c2ccc(-c3cc(C(C)(C)C)cc(C(C)(C)C)c3)cc2N4c2ccc(-c3ccccc3)cc2)cc(C(C)(C)C)c1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1 ; c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2N3c2c(-c3ccccc3)cccc2-c2ccccc2)cc1]

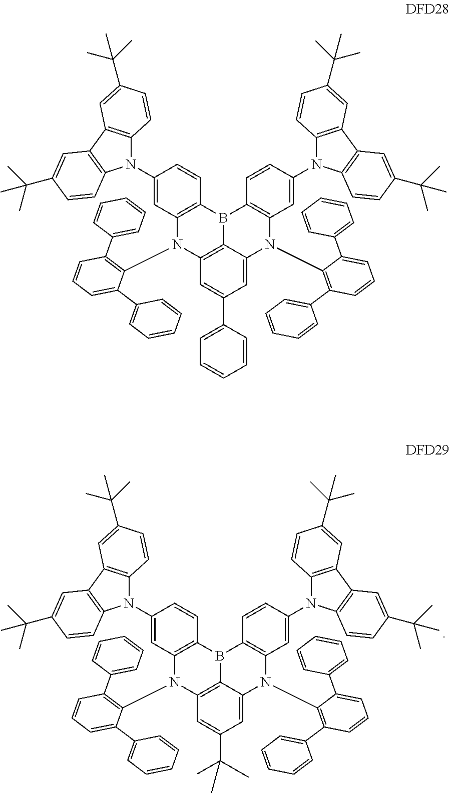

In the light-emitting device according to an embodiment, the emission layer may emit blue light.

In the light-emitting device according to an embodiment, the first electrode may be an anode, the second electrode may be a cathode, and the interlayer may further include a hole transport region between the first electrode and an electron transport region the emission layer and between the emission layer and the second electrode, wherein
the hole transport region may include a hole injection layer, a hole transport layer, an emission auxiliary layer, an electron blocking layer, or any combination thereof, and
the electron transport region may include a hole blocking layer, an electron transport layer, an electron injection layer, or any combination thereof.

In the light-emitting device according to an embodiment, the light-emitting device may further include a first capping layer and/or a second capping layer, wherein the first capping layer may be on a surface of the first electrode, and the second capping layer may be on a surface of the second electrode.

In the light-emitting device according to an embodiment, at least one of the first capping layer and the second capping layer may each independently include the organometallic compound represented by Formula 1.

An embodiment provides an electronic apparatus which may include the light-emitting device according to an embodiment.

In an embodiment, the electronic apparatus may further include:
a thin-film transistor; and
a color filter, a color conversion layer, a touch screen layer, a polarizing layer, or any combination thereof, wherein
thin-film transistor may include a source electrode and a drain electrode; and the first electrode of the light-emitting device may be electrically connected to the source electrode or the drain electrode of the thin-film transistor.

An embodiment provides an electronic equipment which may include the light-emitting device according to an embodiment.

In an embodiment, the electronic equipment may be a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signage.

An embodiment provides an organometallic compound which may be represented by Formula 1:

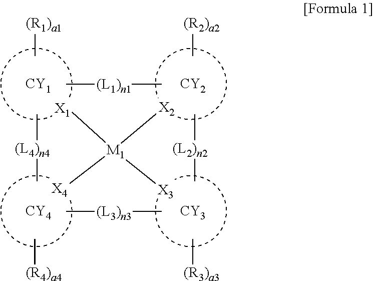

In Formula 1,
M₁ may be platinum (Pt), palladium (Pd), copper (Cu), silver (Ag), gold (Au), rhodium (Rh), iridium (Ir), ruthenium (Ru), or osmium (Os),
ring CY₁ to ring CY₄ may each independently be a C₅-C₆₀ carbocyclic group unsubstituted or substituted with R₁₀ₐ or a C₁-C₆₀ heterocyclic group unsubstituted or substituted with R₁₀ₐ,
X₁, X₂, X₃, and X₄ may each independently be a carbon atom (C) or a nitrogen atom (N),
L₁ may be a C₅-C₆₀ carbocyclic group unsubstituted or substituted with at least one R_{10b} or a C₁-C₆₀ heterocyclic group unsubstituted or substituted with at least one R_{10b},
L₂ to L₄ may each independently be *—O—*′, *—S—*′, *—C(R₅)(R₆)—*′, *—C(R₅)═*′, *═C(R₅)—*′, *—C(R₅)═C(R₆)—*′, *—C(═O)—*′, *—C(═S)—*′, *—C≡C—*′, *—B(R₅)—,*′ *—N(R₅)—*′, *—P(R₅)—*′, *—Si(R₅)(R₆)—*′, *—P(R₅)(R₆)—*′, or *—Ge(R₅)(R₆)—*′,
n1 may be an integer from 2 to 5,
n2 to n4 may each independently be an integer from 0 to 3,
a moiety represented by *-(L₂)ₙ₂-*′ may be a single bond when n2 is 0,
a moiety represented by *-(L₃)ₙ₃-*′ may be a single bond when n3 is 0,
a moiety represented by *-(L₄)ₙ₄-*′ may be a single bond when n4 is 0,
R¹ to R⁶, R₁₀ₐ, and R_{10b} may each independently be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof,
a1 to a4 may each independently be an integer from 0 to 8, and
* and *′ each indicate a binding site to a neighboring atom.

In the organometallic compound according to an embodiment, at least one of ring CY₁ to ring CY₄ may each independently include a carbene moiety.

In the organometallic compound according to an embodiment, ring CY₁ to ring CY₄ may include different groups.

In the organometallic compound according to an embodiment, ring CY₁ may include a condensed bicyclic group, wherein
the condensed bicyclic group may be a group in which a first ring and a second ring are condensed, and
the first ring and the second ring may each independently be a cyclopentane group, a cyclopentene group, a cyclopentadiene group, a cyclohexane group, a cyclohexene group, a cyclohexadiene group, a cycloheptane group, a cycloheptene group, a cycloheptadiene group, a cycloheptatriene group, an azepane group, a pyrrolidine group, an imidazolidine group, a dihydropyrrole group, a dihydroimidazole group, a piperidine group, a tetrahydropyridine group, a dihydropyridine group, a hexahydropyrimidine group, a dihydropyrimidine group, a piperazine group, a tetrahydropyrazine group, a dihydropyrazine group, a tetrahydroazepine group, a dihydroazepine group, a benzene group, a pyrrole group, a pyridine group, a pyridazine group, a pyrimidine group, a pyrazine group, an azepine group, a diazepine group, or a derivative thereof.

In the organometallic compound according to an embodiment, ring CY₁ may be represented by Formula 1-1-1 or Formula 1-1-2:

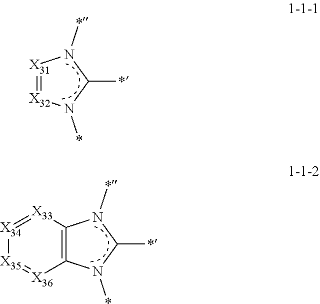

In Formulae 1-1-1 and 1-1-2,
X₃₁ to X₃₆ may each independently be C(R₇) or N,
R₇ may be the same as described in connection with R₁₀ₐ in Formula 1, and
*, *′, and *″ each indicate a binding site to a neighboring atom.

In the organometallic compound according to an embodiment, ring CY₁ may be represented by one of Formulae CY1-1 to CY1-25:

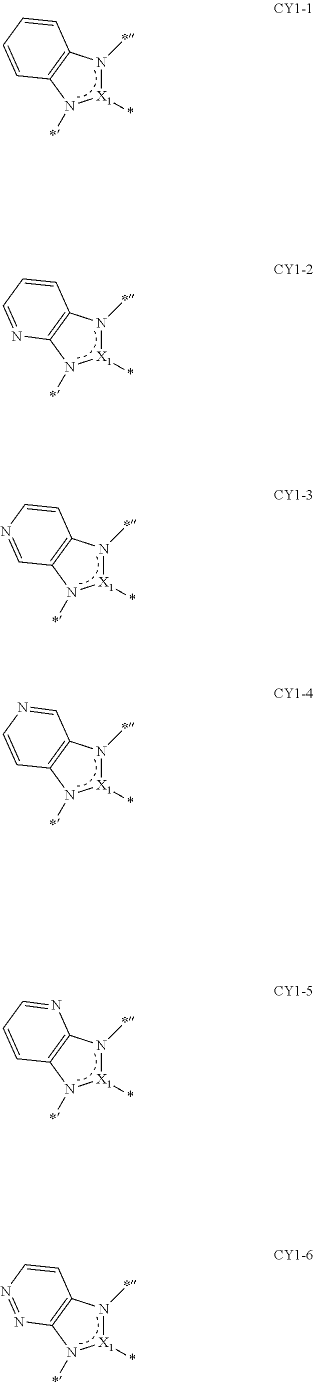

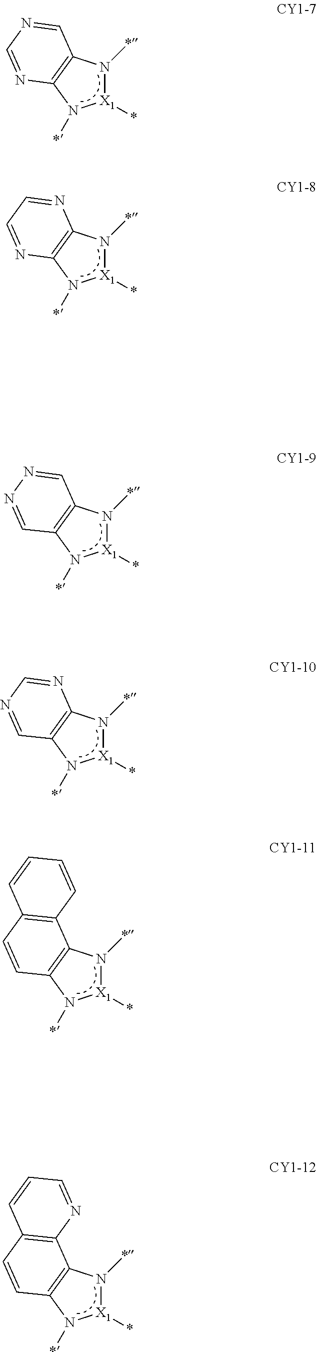

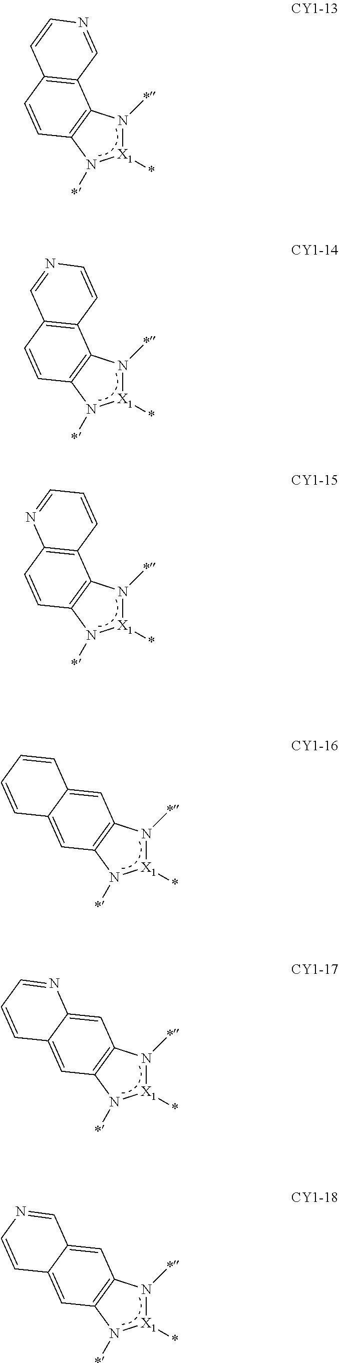

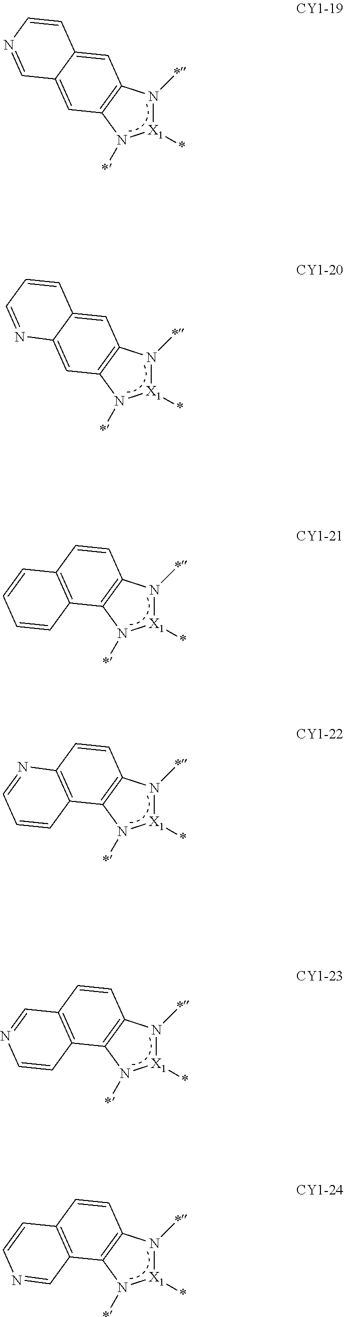

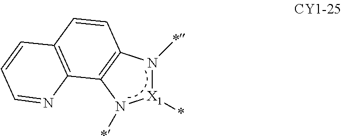

In Formulae CY1-1 to CY1-25,
X₁ may be the same as described in Formula 1, and
*, *′, and *″ each indicate a binding site to a neighboring atom.

In the organometallic compound according to an embodiment, ring CY₂ and ring CY₄ may each independently be a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

In the organometallic compound according to an embodiment, in Formula 1, a moiety represented by

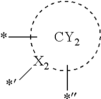

may be a moiety represented by one of Formulae CY2-1 to CY2-21:

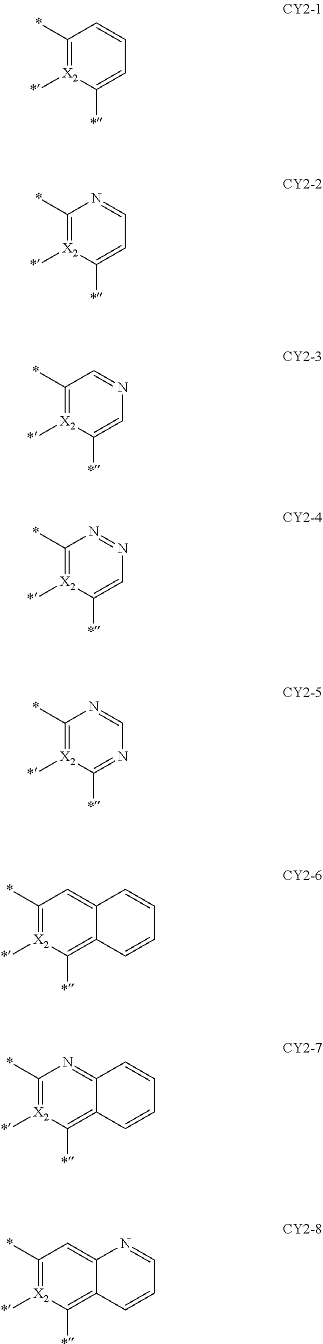

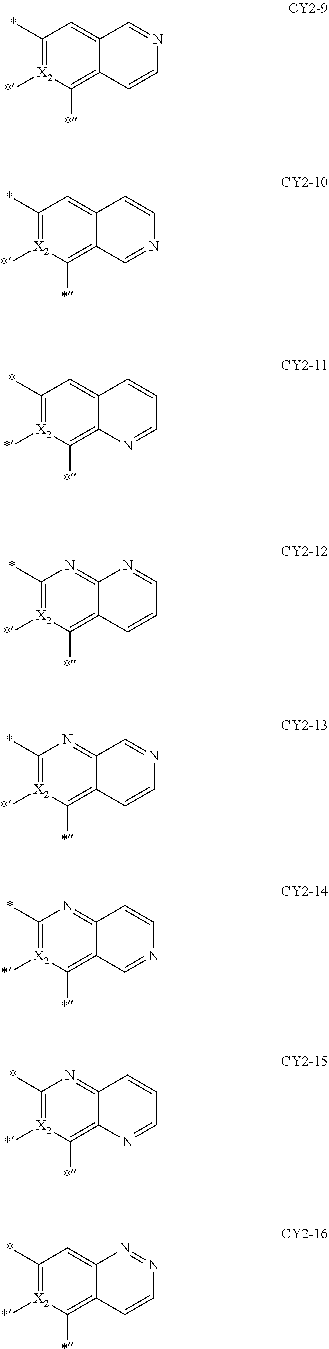

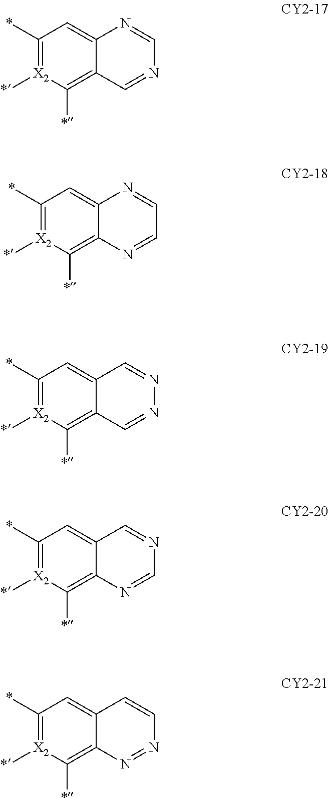

In Formulae CY2-1 to CY2-21,
X₂ may be the same as described in Formula 1, and
*, *′, and *″ each indicate a binding site to a neighboring atom.

In the organometallic compound according to an embodiment, at least one of X₁ to X₄ may each be N.

In the organometallic compound according to an embodiment, at least two of a bond between M₁ and X₁, a bond between M₁ and X₂, a bond between M₁ and X₃, and a bond between M₁ and X₄ may each be a coordinate bond. For example, a bond between M₁ and X₁ and a bond between M₁ and X₂ may each be a coordinate bond.

In the organometallic compound according to an embodiment, two or more of L₁ may each independently be a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

In the organometallic compound according to an embodiment, two or more of L₁ may each independently be a group represented by one of Formulae 1-2-1 to 1-2-3:

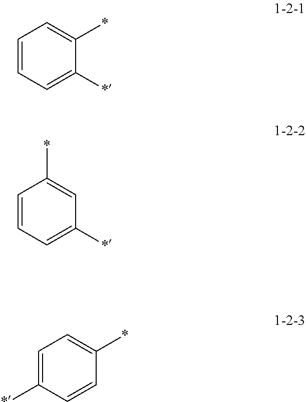

In Formulae 1-2-1 to 1-2-3,
* and *′ each indicate a binding site to a neighboring atom.

In the organometallic compound according to an embodiment, in Formula 1, a moiety represented by *-(L₁)ₙ₁-*′, may be a moiety represented by one of Formulae 1-3-1 to 1-3-3:

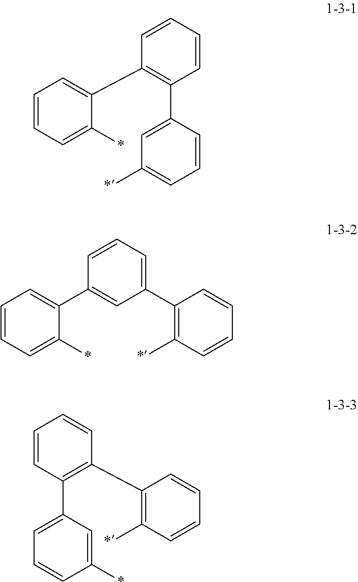

In Formulae 1-3-1 to 1-3-3,
* indicates a binding site to an atom included in ring CY₁, and *′ indicates a binding site to an atom included in ring CY₂.

In the organometallic compound according to an embodiment, R_{10b} may be:
F, —Cl, —Br, —I, a hydroxyl group, a cyano group, or a nitro group;
a methyl group, an ethyl group, a propyl group, an isopropyl group, a butyl group, an isobutyl group, a sec-butyl group, a tertbutyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl group, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, or a 3-cyclohexylpentyl group, each unsubstituted or substituted with —F, —Cl, —Br, —I, a hydroxyl group, a cyano group, or a nitro group; or
one of deuterated derivative groups of a methyl group, an ethyl group, a propyl group, an isopropyl group, a butyl group, an isobutyl group, a sec-butyl group, a tertbutyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl group, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, and a 3-cyclohexylpentyl group.

In the organometallic compound according to an embodiment,

the deuterated derivative group may be —CD₃, —CD₂H, —CDH₂, —C(CD₃)₃, —C(CD₃)₂H, —C(CD₃)₂D, —C(CD₃)(H)₂, —C(CD₃)(H)(D), —C(CD₃)(D)₂, —C(CD₃)₂(CH₃), —C(CD₃)(CH₃)₂, —C(CD₃)₂(CD₂H), —C(CD₃)(CD₂H)₂, —C(CD₃)₂(CDH₂), —C(CD₃)(CDH₂)₂, —C(CD₃)(CD₂H)(CDH₂), a phenyl-d-group, a phenyl-d₂-group, a phenyl-d₃-group, a phenyl-d₄-group, or a phenyl-d₅-group.

In the organometallic compound according to an embodiment,

when the organometallic compound represented by Formula 1 includes two or more of R_{10b}, the two or more of R_{10b} may be identical to or different from each other.

In the organometallic compound according to an embodiment, in Formula 1, a moiety represented by

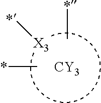

may be a moiety represented by one of Formulae 1-4-1 to 1-4-3:

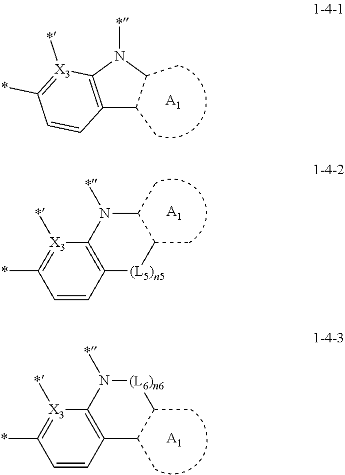

In Formulae 1-4-1 to 1-4-3,
ring A₁ may be a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group,
X₃ is the same as described in Formula 1,
L₅ and L₆ may each independently be the same as described in connection with L₂ in Formula 1,
n5 and n6 may each independently be the same as described in connection with n2 in Formula 1,
a moiety represented by *-(L₅)ₙ₅-*′ may be a single bond when n5 is 0,
a moiety represented by *-(L₆)ₙ₆-*′ may be a single bond when n6 is 0, and
*, *′, and *″ each indicate a binding site to a neighboring atom.

The organometallic compound according to an embodiment may be one of Compounds BD01 to BD91:

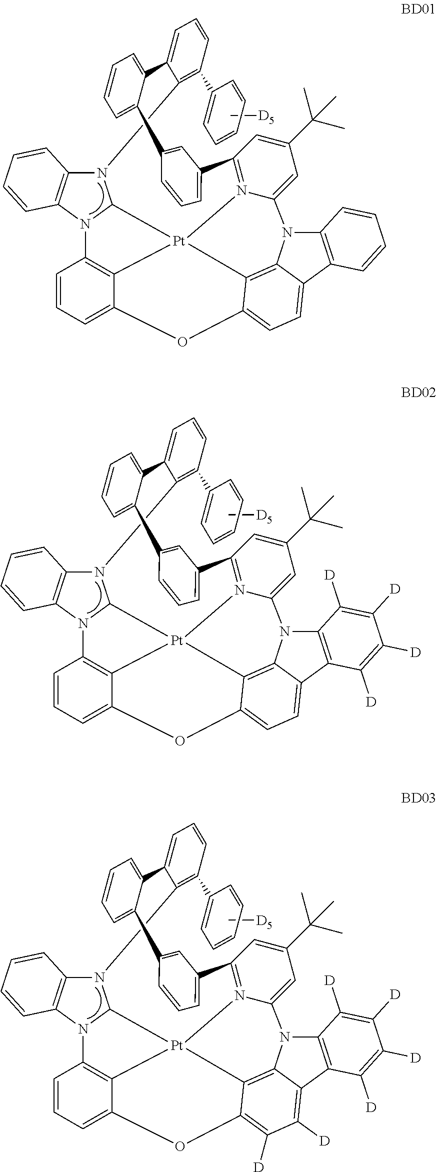

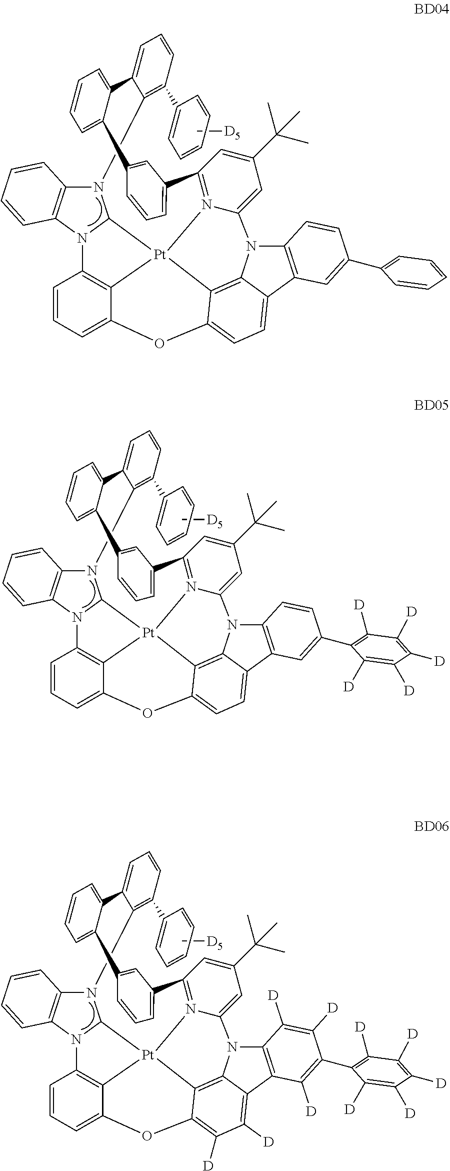

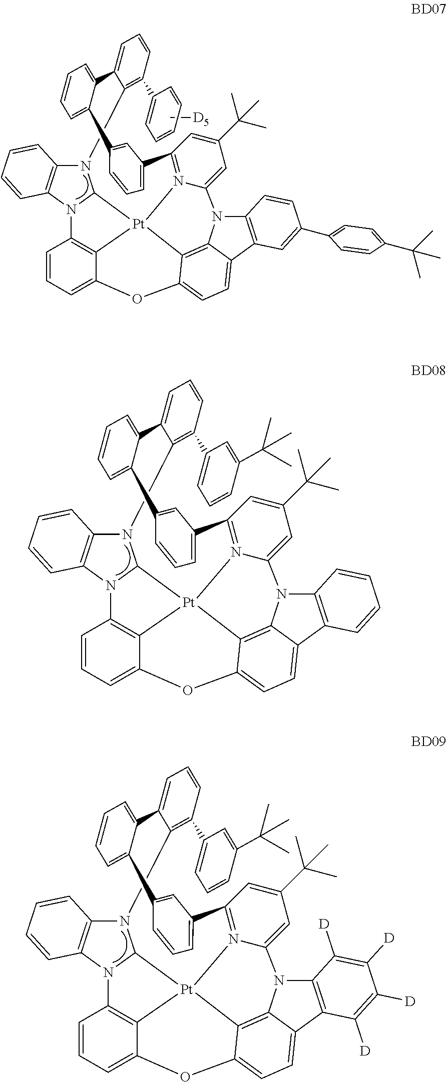

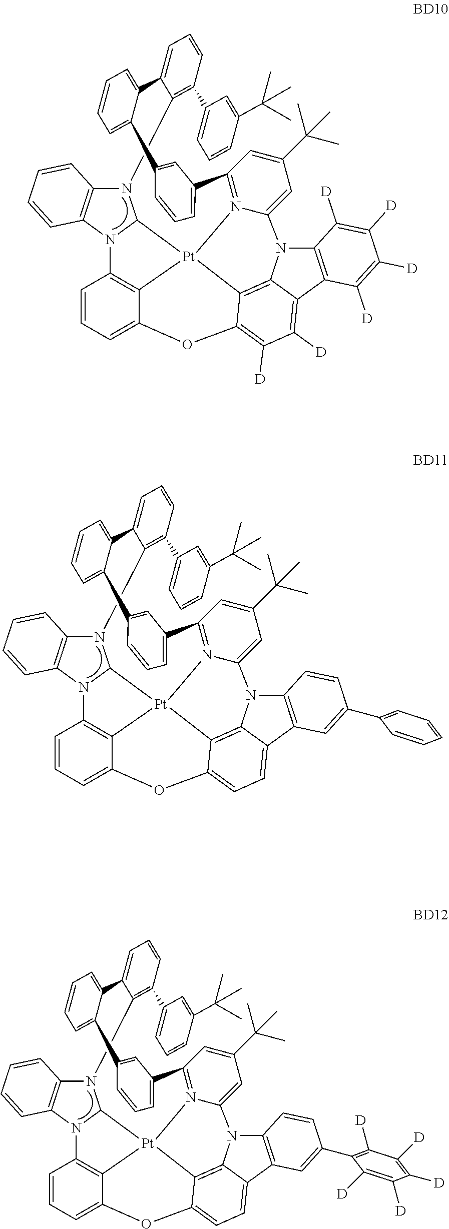

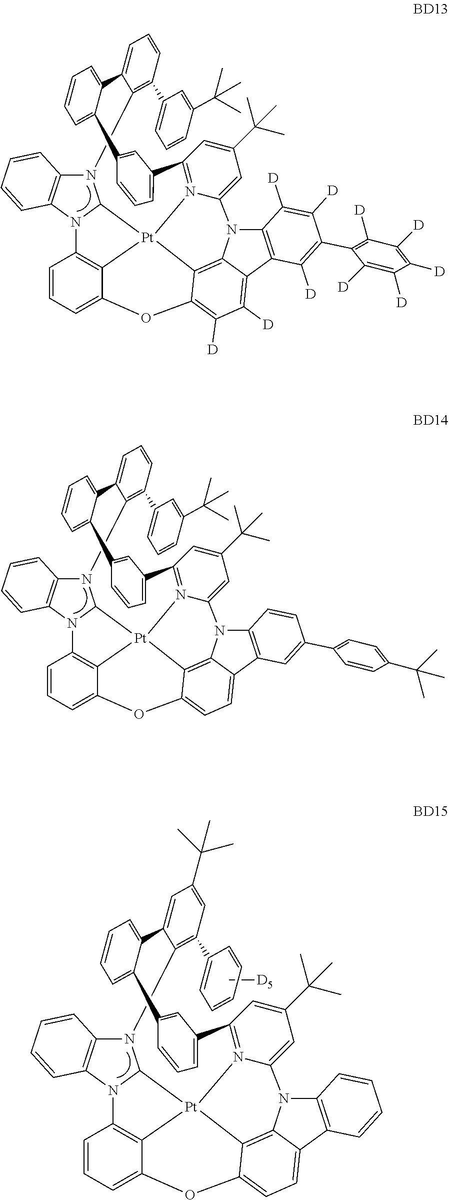

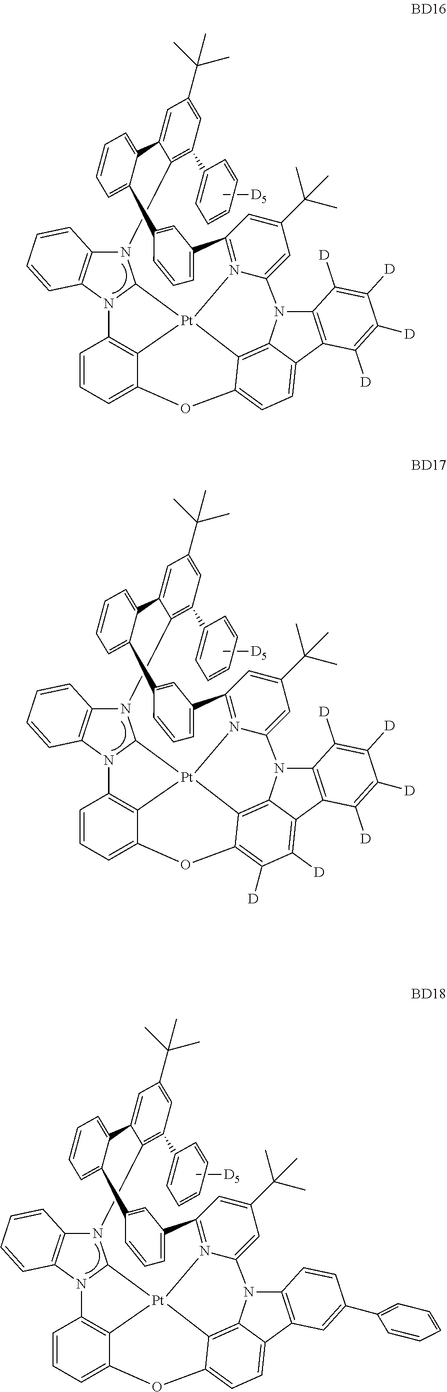

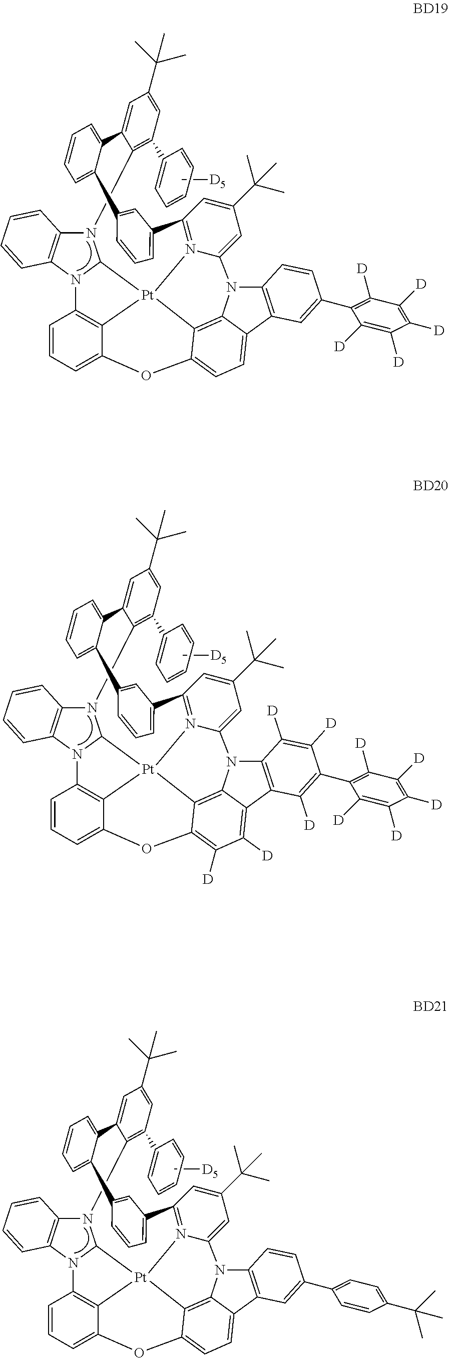

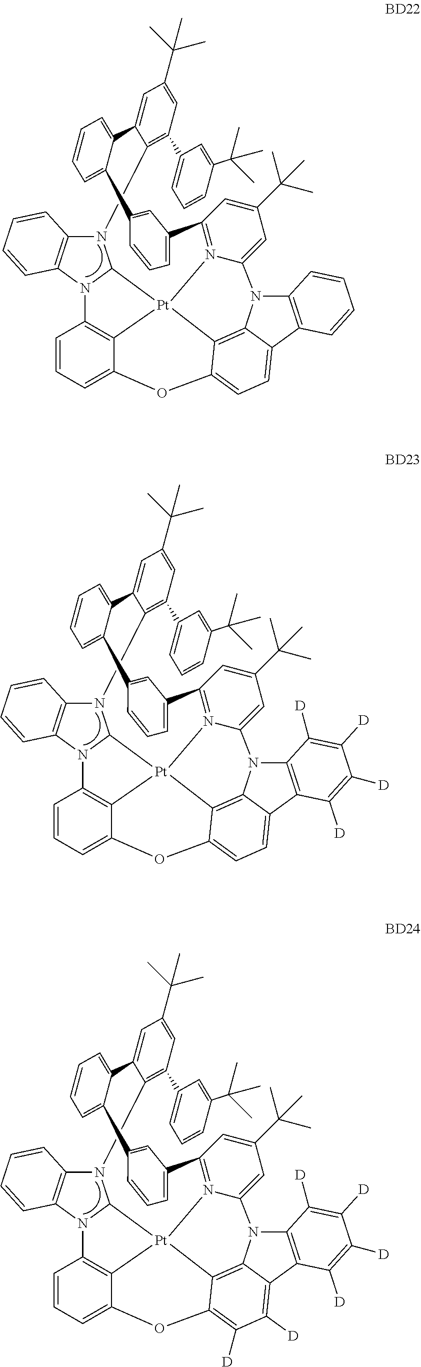

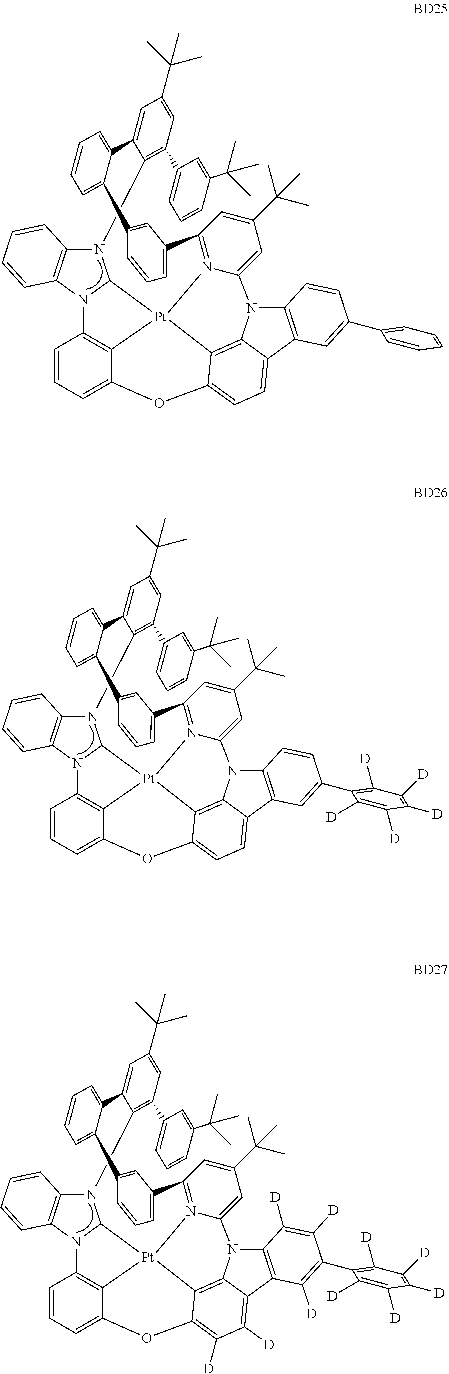

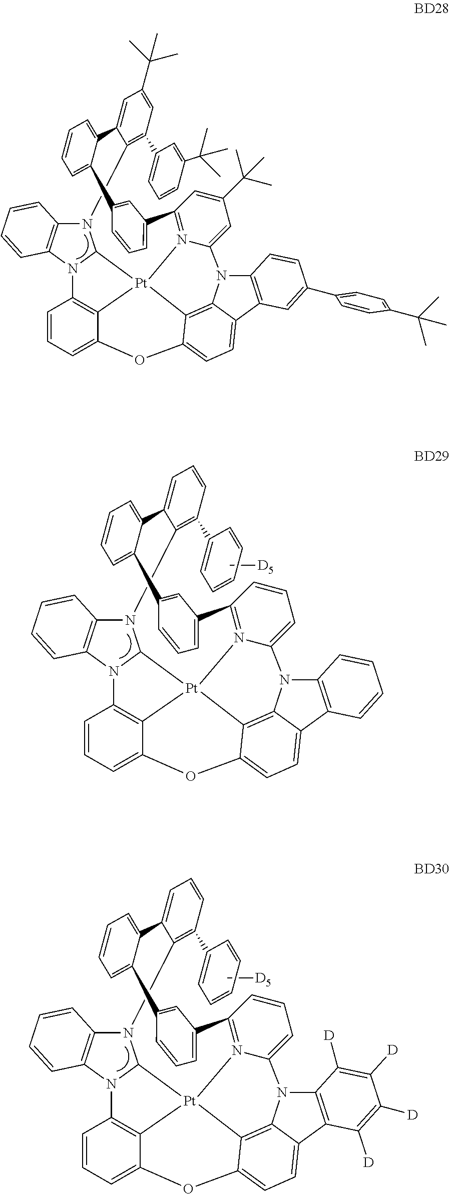

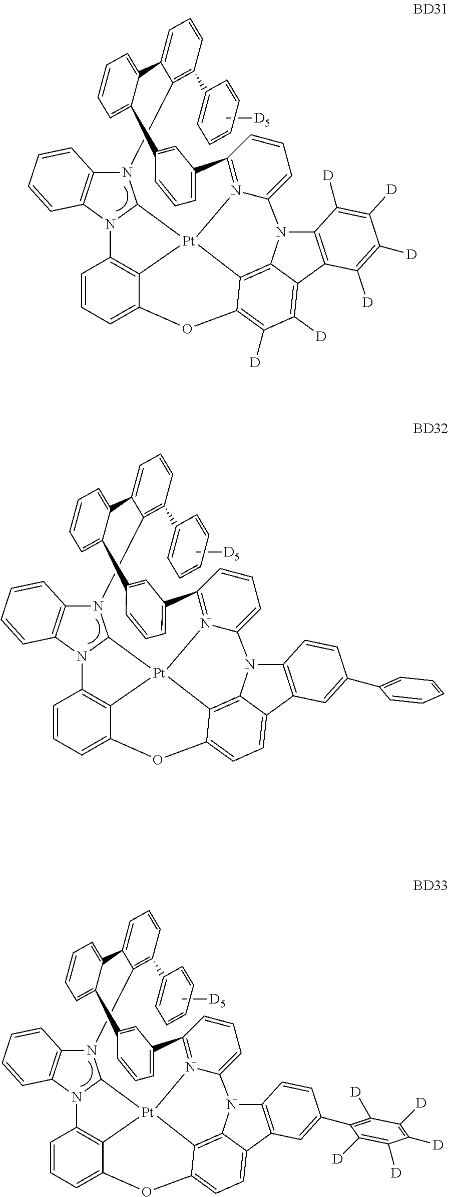

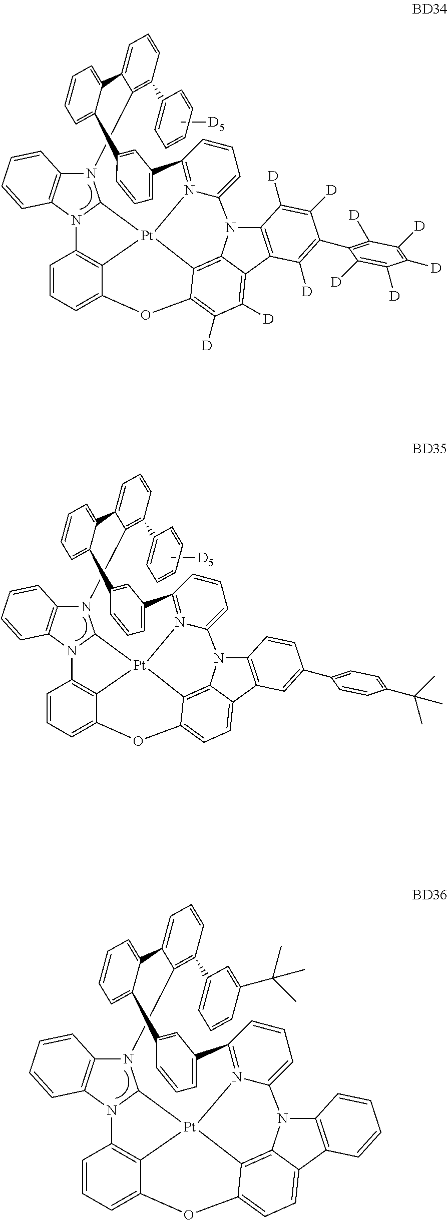

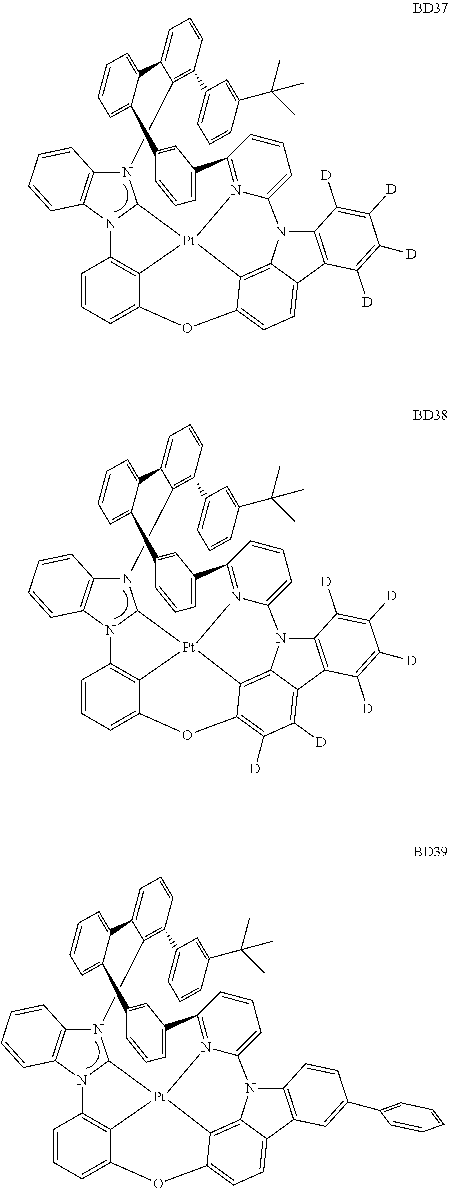

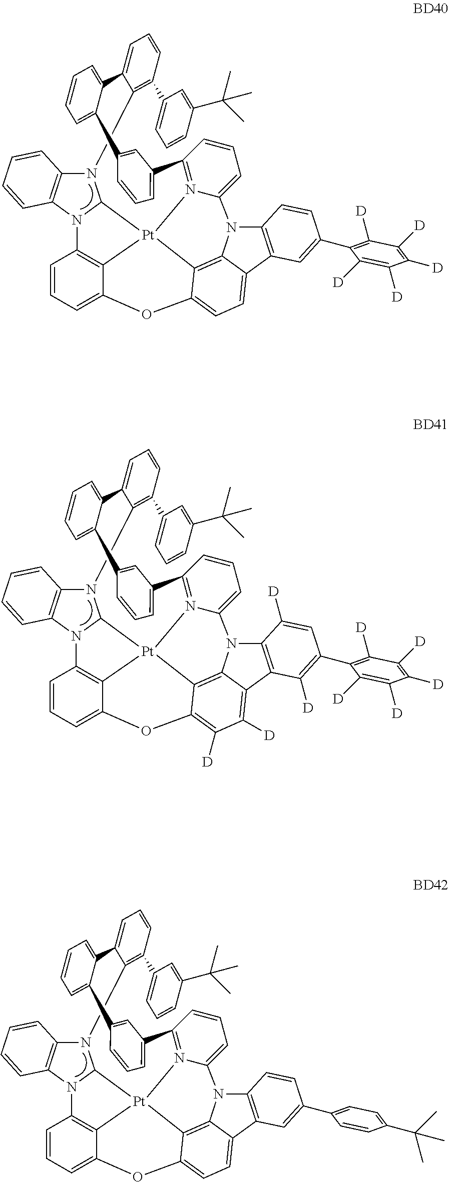

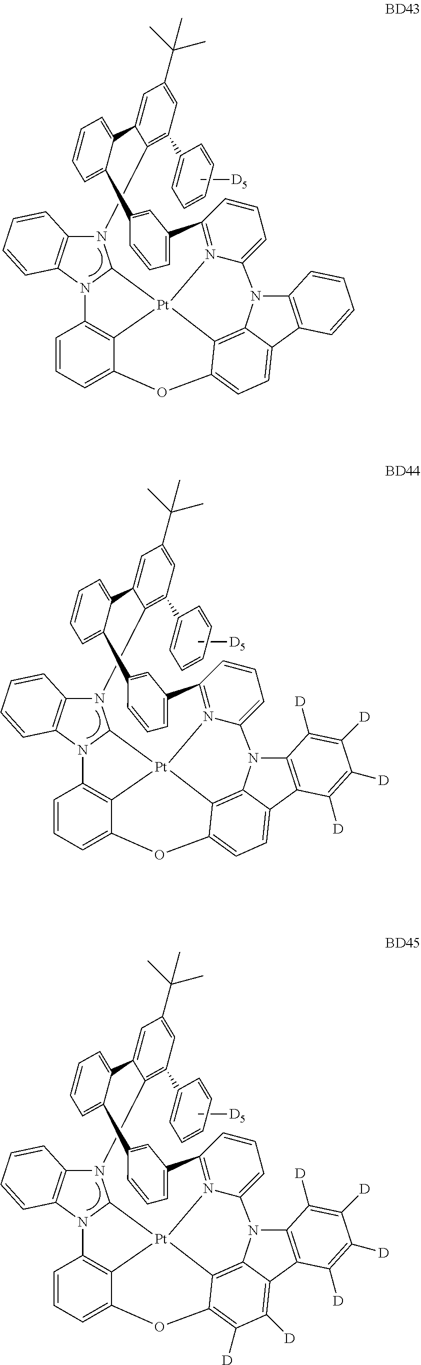

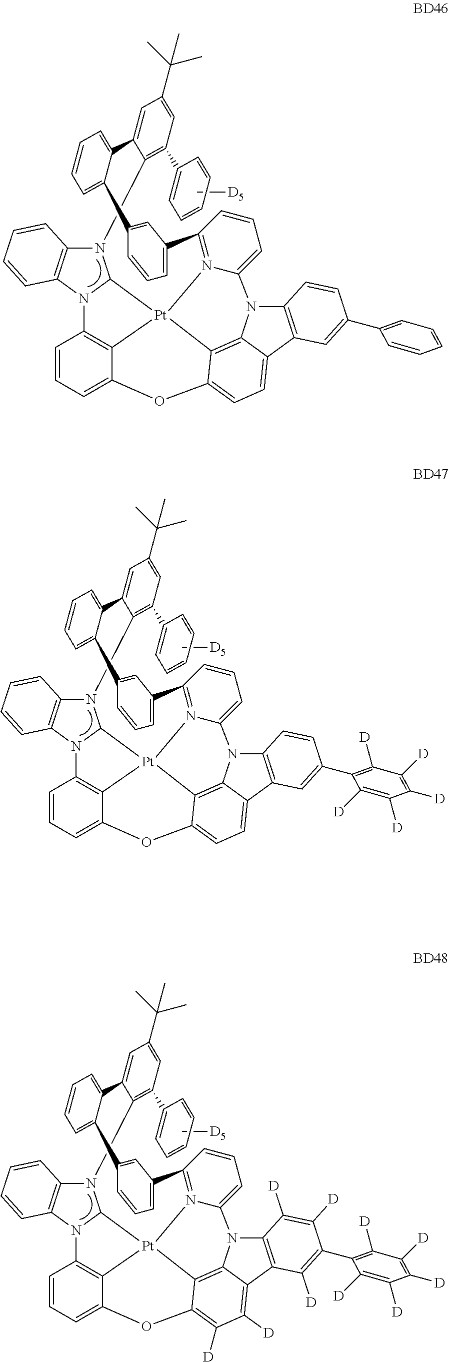

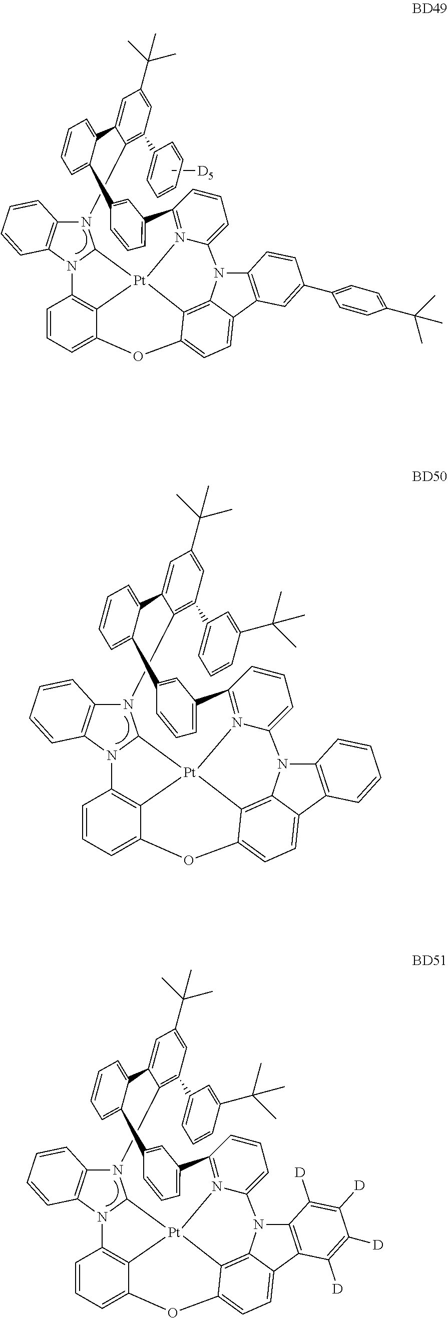

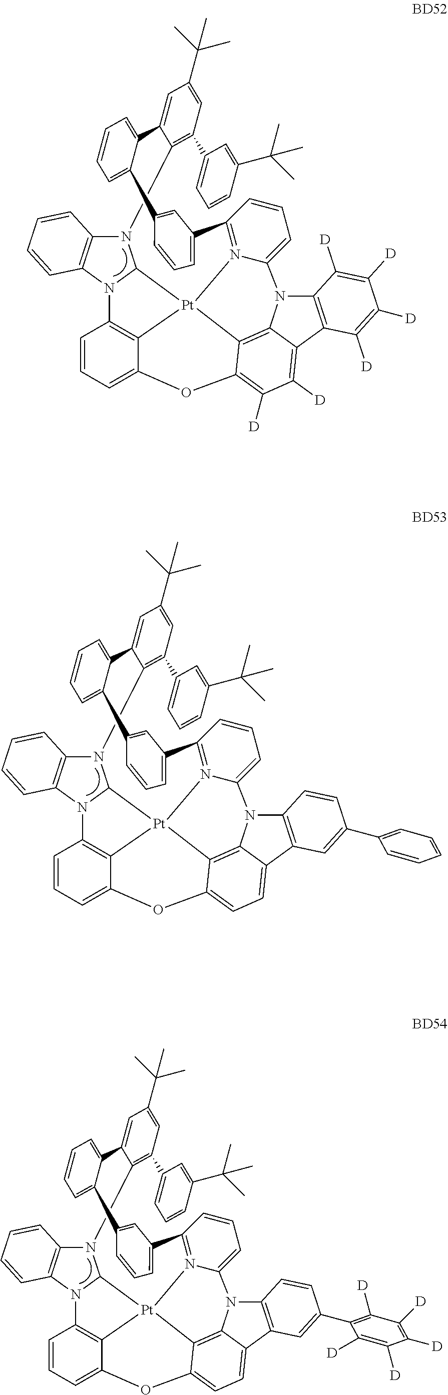

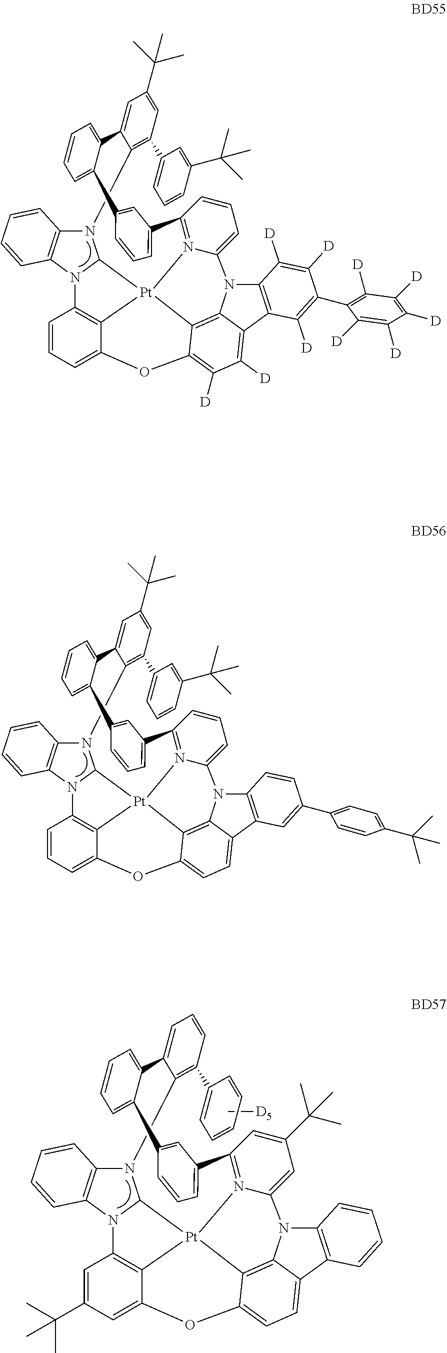

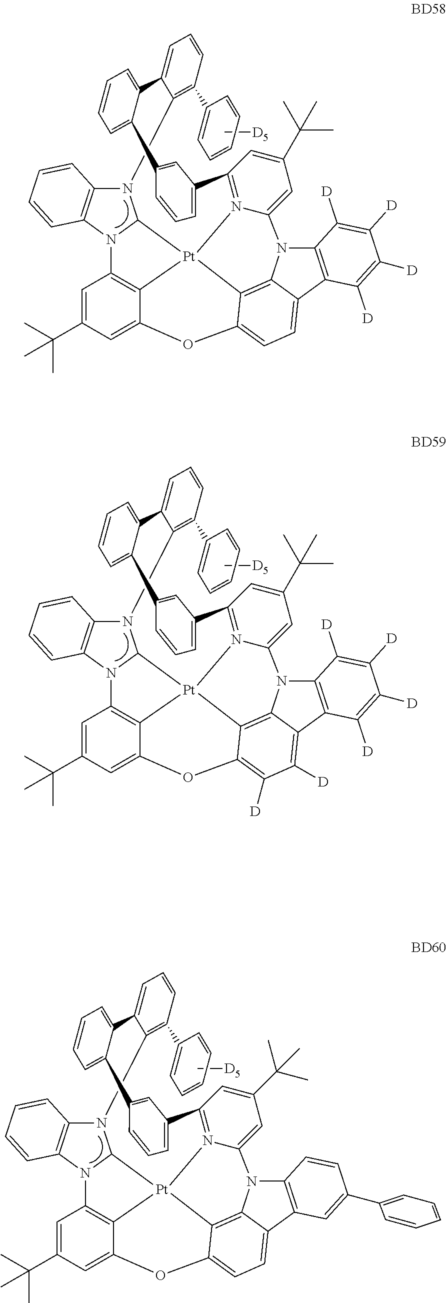

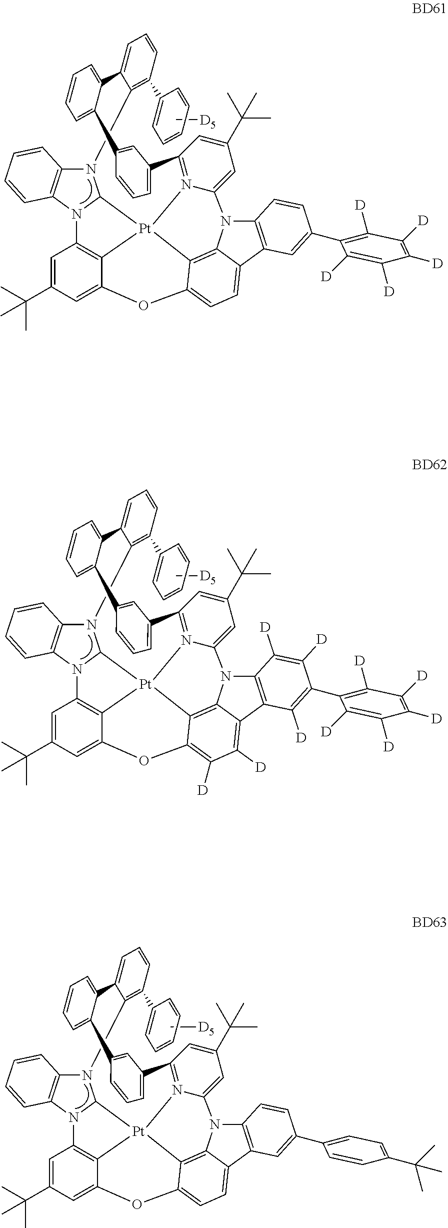

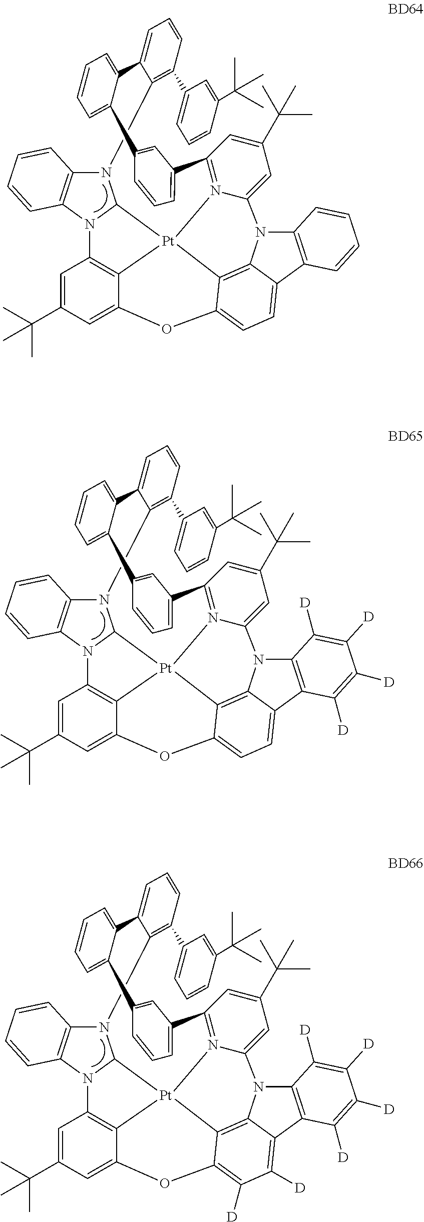

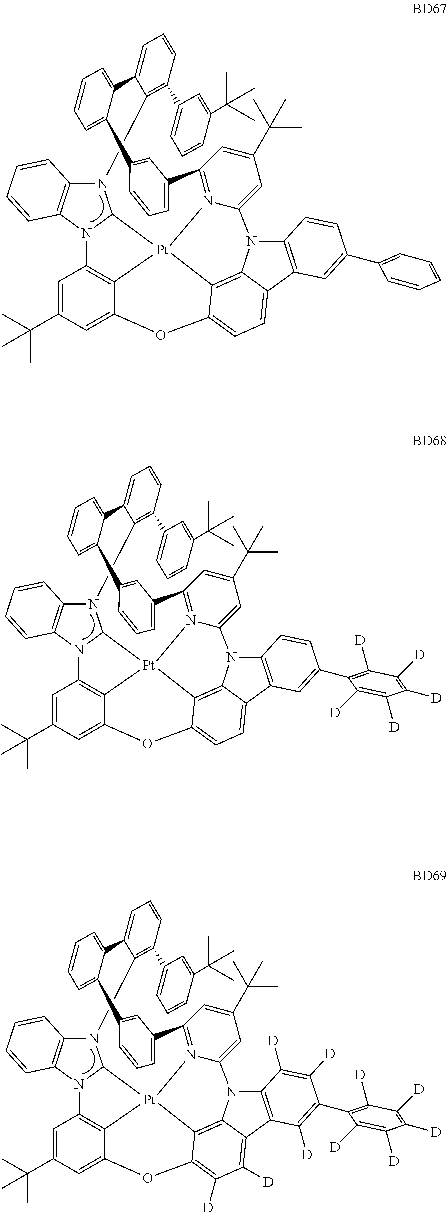

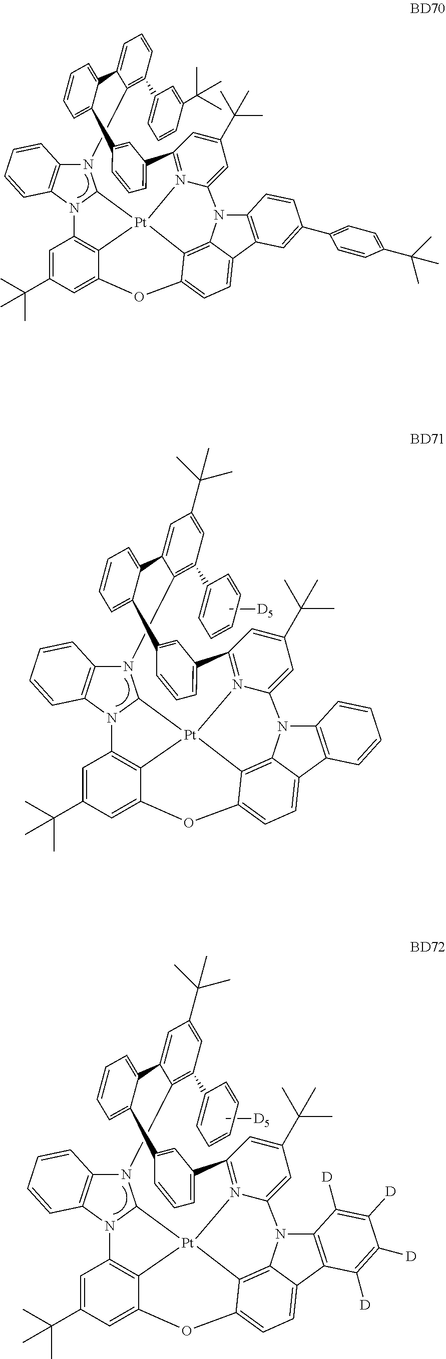

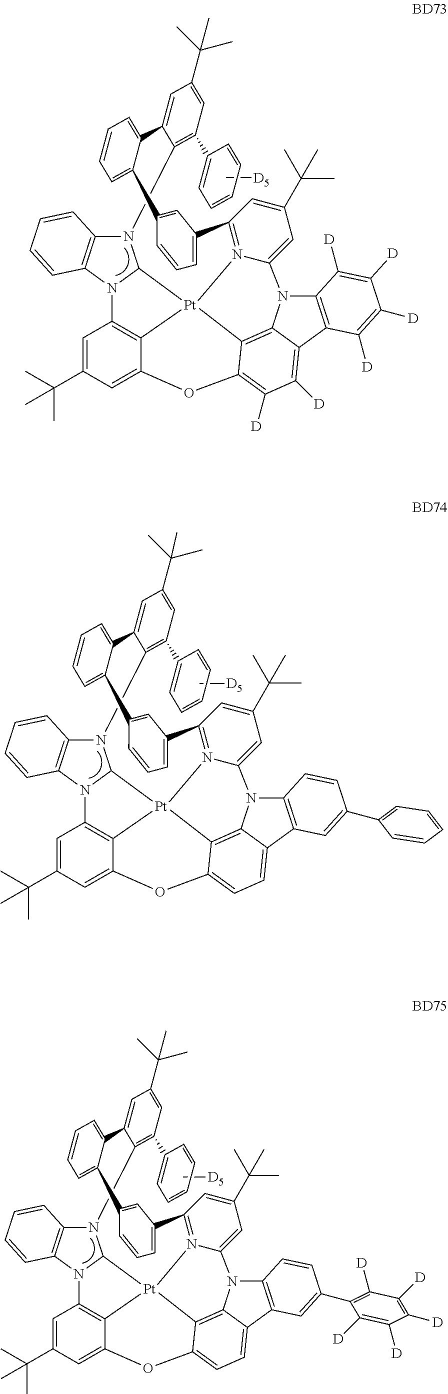

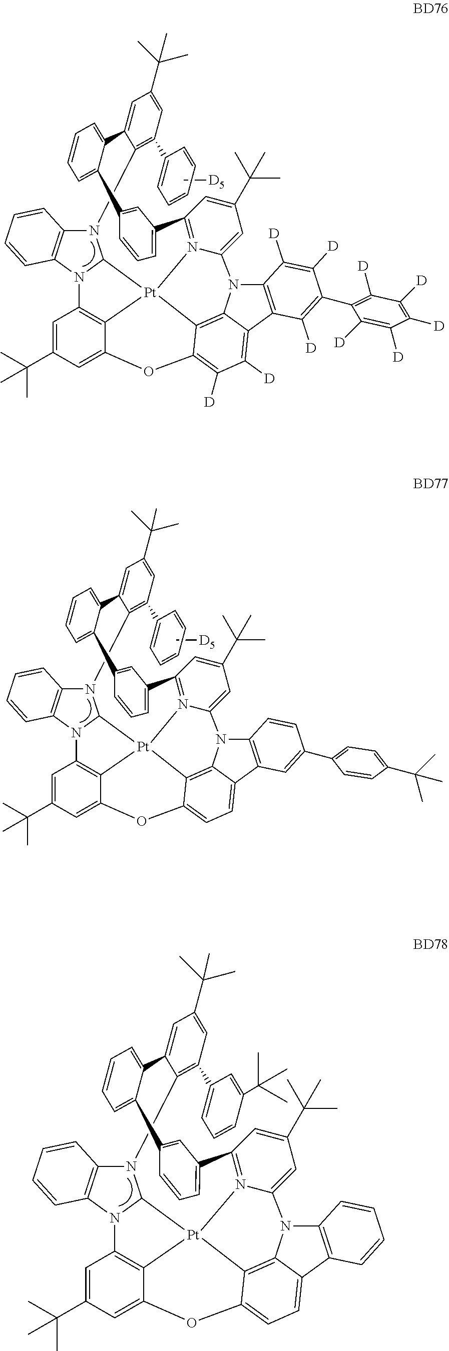

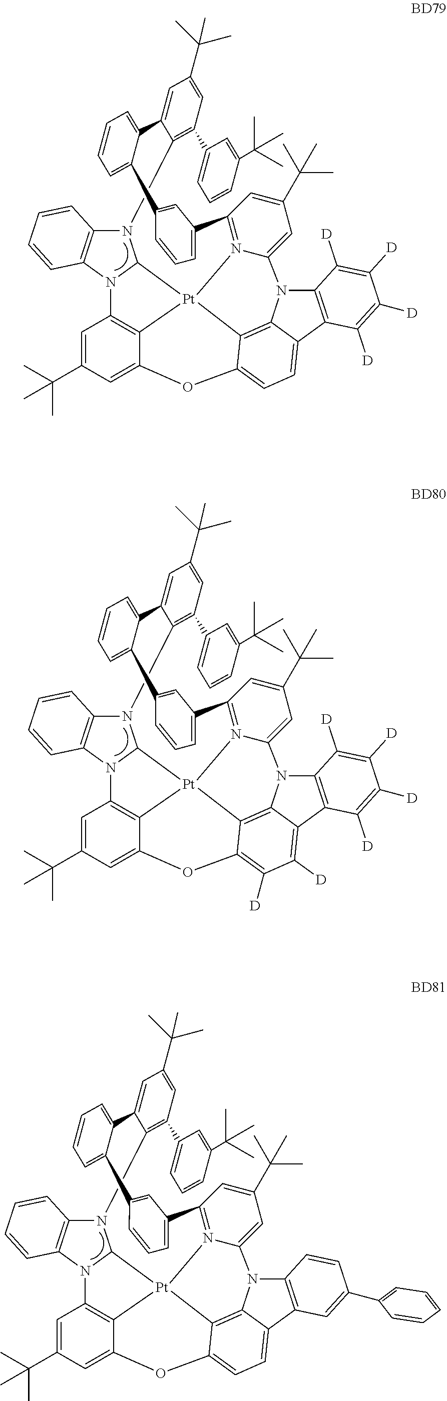

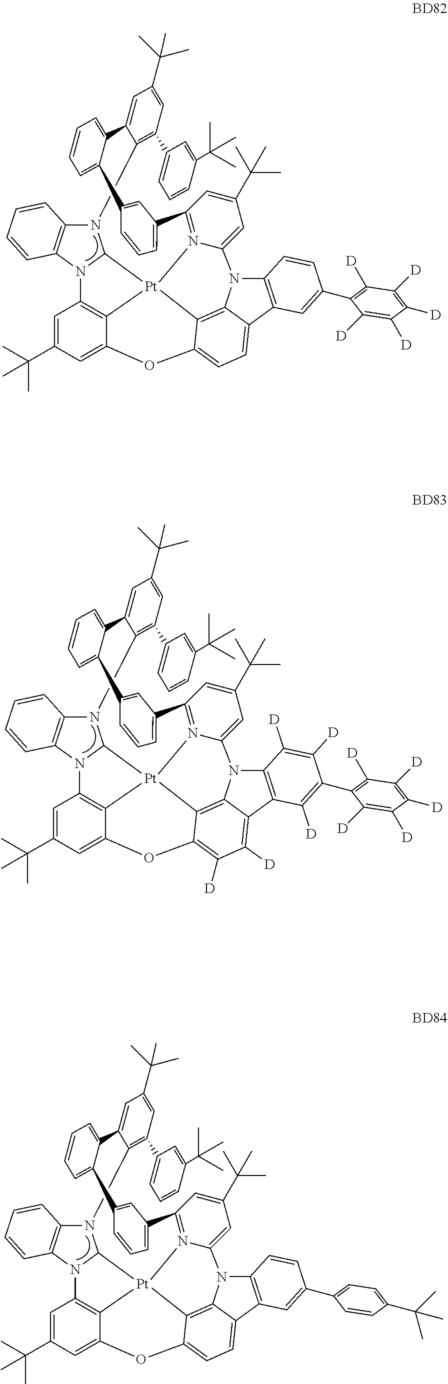

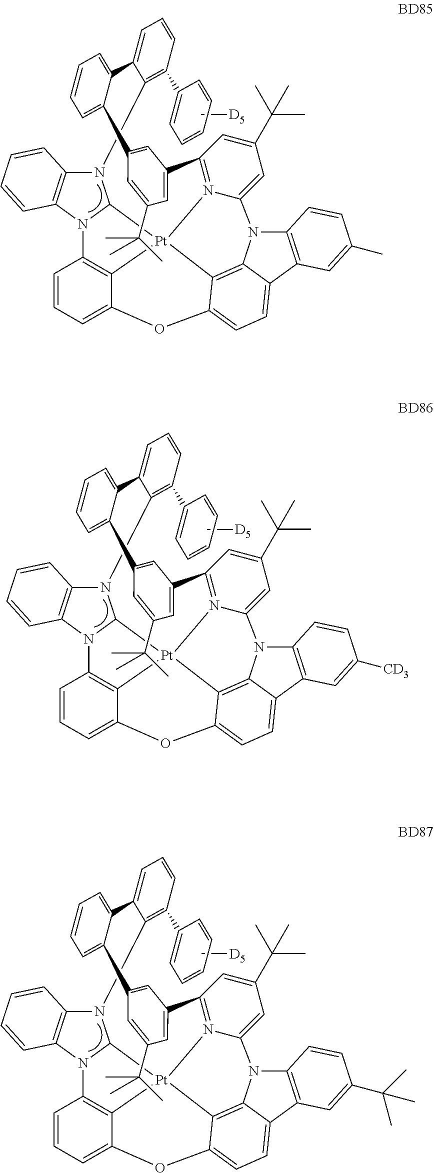

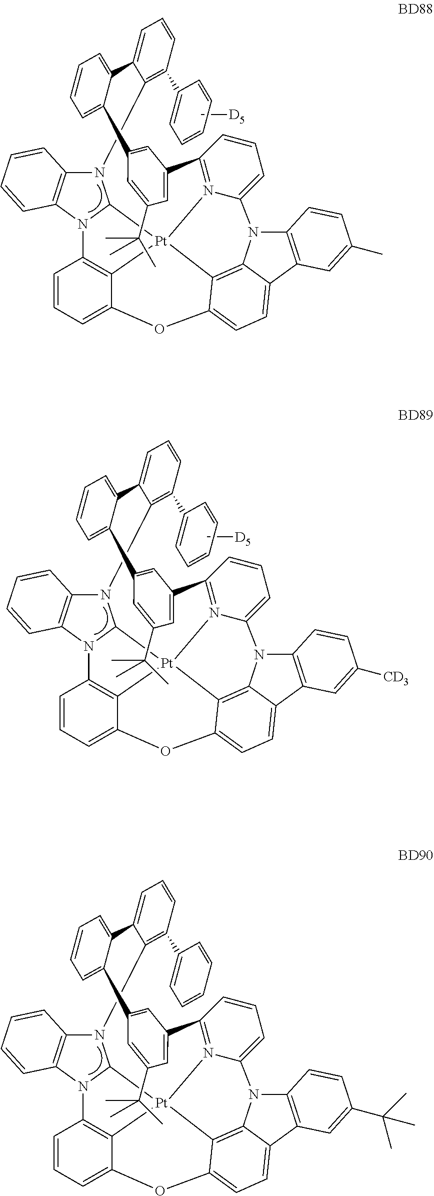

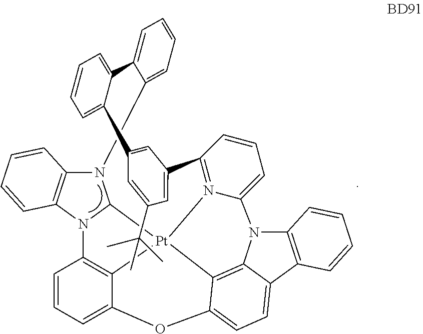

The organometallic compound represented by Formula 1 may include a metal nucleus and a tetradentate ligand, and the tetradentate ligand may form an integrally closed ring. As a result, four ring moieties including the metal nucleus may be formed. For example, the organometallic compound represented by Formula 1 may include a first cyclic moiety to a fourth cyclic moiety. When the organometallic compound includes all of the first cyclic moiety to the fourth cyclic moiety, the chelation effect of the ligand may be improved and the thermal stability of the organometallic compound may be improved accordingly. In this regard, vibrational modes (e.g., Huang-Rhys Factor (HRF)) in the transition state will be reduced to about 20 cm⁻¹ to about 30 cm⁻¹, thereby improving photoluminescence quantum efficiency (PLQY), and accordingly, decomposition energy of the materials. As a result, the lifespan of the light-emitting device may be improved when driving the light-emitting device.

Due to steric hindrance additionally caused by the first cyclic moiety, the formation of an exciplex between the organometallic compound and other compounds (e.g., an electron-transporting host) may be suppressed. As a result, the color purity of the light-emitting device including the organometallic compound may be maintained, and the service life of the light-emitting device may be increased.

Due to steric hindrance additionally caused by the first cyclic moiety, the organometallic compound may be appropriately dispersed.

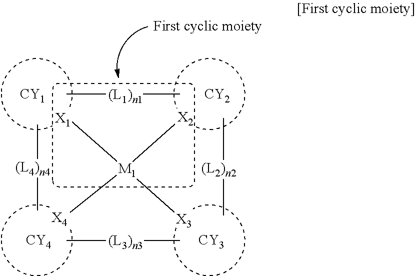

The first cyclic moiety may include two or more of the elements included in ring CY₁, two or more of the elements included in ring CY₂, L₁, and the metal M₁. For example, the first cyclic moiety may be a first ring including a total of 12 elements.

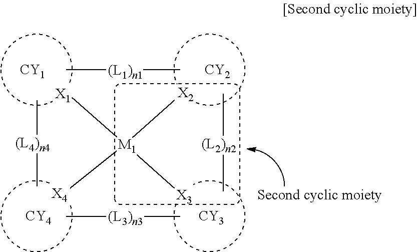

The second cyclic moiety may include two or more of the elements included in ring CY₂, two or more of the elements included in ring CY₃, L₂, and the metal M₁. For example, the second cyclic moiety may be a second ring including a total of 5 elements.

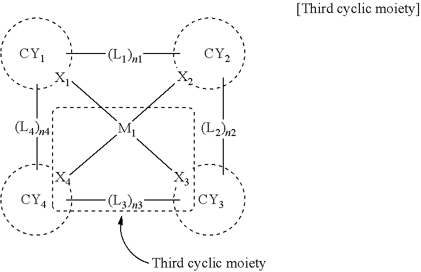

The third cyclic moiety may include two or more of the elements included in ring CY₃, two or more of the elements included in ring CY₄, L₃, and the metal M₁. For example, the third cyclic moiety may be a third ring including a total of 6 elements.

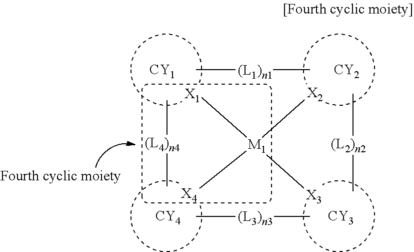

The fourth cyclic moiety may include two or more of the elements included in ring CY₁, two or more of the elements included in ring CY₄, L₄, and the metal M₁. For example, the fourth cyclic moiety may be a fourth ring including a total of 5 elements.

Thus, according to embodiments, an organometallic compound may satisfy one or more of Conditions i to iv, wherein at least Condition i is satisfied:

[Condition i]
the organometallic compound has a first cyclic moiety including a first ring including 12 elements;
[Condition ii]
the organometallic compound has a second cyclic moiety including a second ring including 5 elements;
[Condition iii]
the organometallic compound has a third cyclic moiety including a third ring including 6 elements;
[Condition iv]
the organometallic compound has a fourth cyclic moiety including a fourth ring including 5 elements.

For example, Compound BD01 may include all of the first cyclic moiety to the fourth cyclic moiety, wherein the first cyclic moiety may be a 12-membered ring, the second cyclic moiety and the fourth cyclic moiety may each be a 5-membered ring, and the third cyclic moiety may be a 6-membered ring. Referring to the numbers arbitrarily assigned to the elements of the first cyclic moiety, it can be confirmed that the first moiety may be a 12-membered ring.

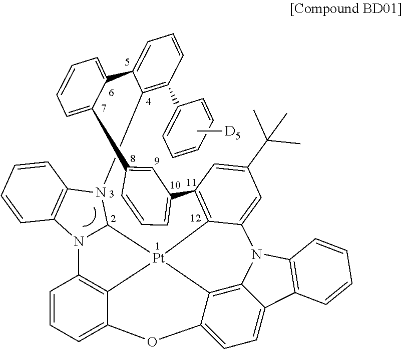

By comparison, Compound CE-A may include the second cyclic moiety to the fourth cyclic moiety, wherein the second cyclic moiety and the fourth cyclic moiety may each be a 5-membered ring, and the third cyclic moiety may be a 6-membered ring. However, Compound CE-A does not include the first cyclic moiety.

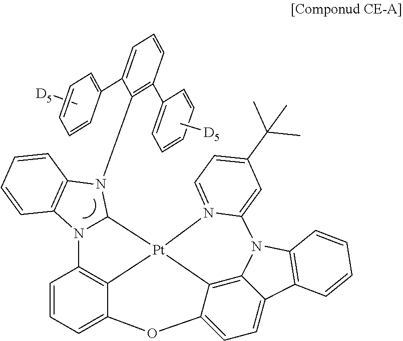

In comparison to a compound that does not include the first cyclic moiety, in the case of an organometallic compound that includes the first cyclic moiety which is a 10-membered or more (e.g., 12-membered or more) ring, the stability of the organometallic compound may be improved in an excited state to the T₁ level.

For example, the dihedral angle between ring CY₁ and the linker L₁ included in the organometallic compound may decrease, thereby reducing the vibrational intensity in the excited state. As a result, the decomposition of the organometallic compound due to excitation may be suppressed, and when ring CY₁ is stabilized accordingly, the PLQY may be improved.

As a result, an electronic device, e.g., an organic light-emitting device, including the organometallic compound according to an embodiment may have low driving voltage, high efficiency, and long lifespan.

Synthesis methods of the organometallic compound represented by Formula 1 may be recognizable by one of ordinary skill in the art by referring to Synthesis Examples and/or Examples provided below.

At least one organometallic compound represented by Formula 1 may be used in a light-emitting device (e.g., an organic light-emitting device). Accordingly, an embodiment provides a light-emitting device which may include: a first electrode; a second electrode facing the first electrode; an interlayer arranged between the first electrode and the second electrode and including an emission layer; and the organometallic compound represented by Formula 1.

In the light-emitting device according to an embodiment,
the first electrode may be an anode,
the second electrode may be a cathode, and
the interlayer may further include a hole transport region between the first electrode and the emission layer and an electron transport region between the emission layer and the second electrode, wherein
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

In embodiments, the organometallic compound may be included between the first electrode and the second electrode of the light-emitting device. Accordingly, the organometallic compound may be included in the interlayer of the light-emitting device, for example, in the emission layer of the interlayer.

In embodiments, the emission layer in the interlayer of the light-emitting device may include a dopant and a host, and the dopant may include the organometallic compound represented by Formula 1. For example, the organometallic compound may serve as a dopant. The emission layer may emit red light, green light, blue light, and/or white light. For example, the emission layer may emit blue light. The blue light may have a maximum emission wavelength in a range of, for example, about 400 nm to about 490 nm.

In embodiments, the emission layer in the interlayer of the light-emitting device may include a dopant and a host, the host may include the organometallic compound represented by Formula 1, and the dopant may emit blue light. For example, the dopant may include a transition metal and ligand(s) in the number of m, and m may be an integer from 1 to 6. The ligand(s) in the number of m may be identical to or different from each other, at least one of the ligand(s) in the number of m may be bonded to the transition metal via a carbon-transition metal bond, and the carbon-transition metal bond may be a coordinate bond. For example, at least one of the ligand(s) in the number of m may be a carbene ligand (e.g., Ir(pmp)₃ or the like). The transition metal may be, for example, iridium, platinum, osmium, palladium, rhodium, gold, or the like. Further details on the emission layer and the dopant may be the same as described herein.

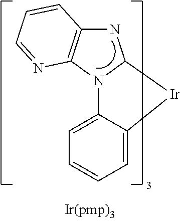

In an embodiment, the light-emitting device may include a capping layer outside the first electrode and/or outside the second electrode.

In an embodiment, the light-emitting device may further include at least one of a first capping layer outside the first electrode and a second capping layer outside the second electrode, and at least one of the first capping layer and the second capping layer may each independently include the organometallic compound represented by Formula 1. Further details on the first capping layer and/or the second capping layer may be the same as described herein.

In an embodiment, the light-emitting device may include:
a first capping layer outside the first electrode and including the organometallic compound represented by Formula 1;
a second capping layer outside the second electrode and including the organometallic compound represented by Formula 1; or
both the first capping layer and the second capping layer.

The wording “(interlayer and/or capping layer) includes an organometallic compound” as used herein may be understood as “(interlayer and/or capping layer) may include one kind of organometallic compound represented by Formula 1 or two or more different kinds of organometallic compounds, each independently represented by Formula 1.”

In an embodiment, the interlayer and/or the capping layer may include Compound 1 only as the organometallic compound. In this regard, Compound 1 may be present in the emission layer of the light-emitting device. In embodiments, the interlayer may include, as the organometallic compound, Compound 1 and Compound 2. In this regard, Compound 1 and Compound 2 may be present in a same layer (e.g., both Compound 1 and Compound 2 may be present in the emission layer), or may be present in different layers (e.g., Compound 1 may be present in the emission layer, and Compound 2 may be present in the electron transport region).

The term “interlayer” as used herein refers to a single layer and/or all layers between the first electrode and the second electrode of the light-emitting device.

An embodiment provides an electronic apparatus which may include the light-emitting device. The electronic apparatus may further include a thin-film transistor. In an embodiment, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or any combination thereof. Further details on the electronic apparatus may be the same as described herein.

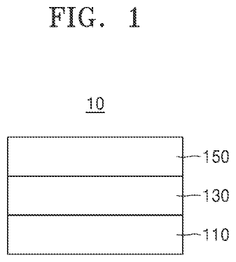

### [Description of FIG. 1]

FIG. 1 is a schematic cross-sectional view of a light-emitting device 20 according to an embodiment. The light-emitting device 10 includes a first electrode 110, an interlayer 130, and a second electrode 150.

Hereinafter, a structure of the light-emitting device 10 according to an embodiment and a method of manufacturing the light-emitting device 10 will be described with reference to FIG. 1.

### [First Electrode 110]

In FIG. 1, a substrate may be further included under the first electrode 110 or on the second electrode 150. In an embodiment, the substrate may be a glass substrate or a plastic substrate. In embodiments, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In an embodiment, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer, or a structure including multiple layers. For example, the first electrode 110 may have a three-layer structure of ITO/Ag/ITO.

### [Interlayer 130]

The interlayer 130 is arranged on the first electrode 110. The interlayer 130 may include an emission layer.

The interlayer 130 may further include a hole transport region between the first electrode 110 and the emission layer and an electron transport region between the emission layer and the second electrode 150.

The interlayer 130 may further include, in addition to various organic materials, a metal-containing compound such as an organometallic compound, an inorganic material such as quantum dots, or the like.

In an embodiment, the interlayer 130 may include two or more emitting units stacked between the first electrode 110 and the second electrode 150, and at least one charge generation layer between adjacent units among the two or more emitting units. When the interlayer 130 includes the two or more light-emitting units and the at least one charge generation layer, the light-emitting device 10 may be a tandem light-emitting device.

### [Hole Transport Region in Interlayer 130]

The hole transport region may have a structure consisting of a layer consisting of a single material, a structure consisting of a layer including different materials, or a structure including multiple layers including different materials.

The hole transport region may include a hole injection layer, a hole transport layer, an emission auxiliary layer, an electron blocking layer, or any combination thereof.

In embodiments, the hole transport region may have a multi-layer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein the layers of each structure may be stacked from the first electrode 110 in its respective stated order, but the structure of the hole transport region is not limited thereto.

In embodiments, the hole transport region may include a compound represented by Formula 201, a compound represented by Formula 202, or any combination thereof:

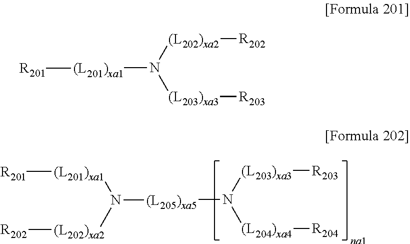

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (e.g., a carbazole group, etc.) unsubstituted or substituted with at least one R₁₀ₐ (e.g., Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In embodiments, the compound represented by Formula 201 and the compound represented by Formula 202 may each independently include at least one of groups represented by Formulae CY201 to CY217:

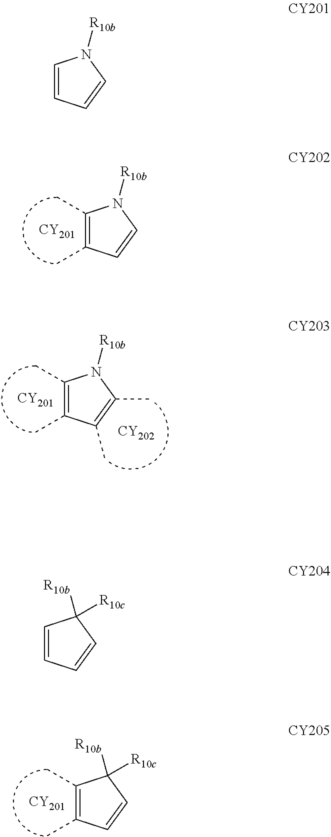

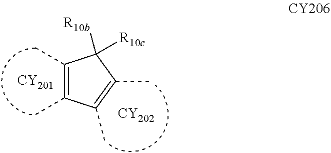

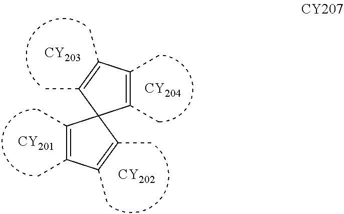

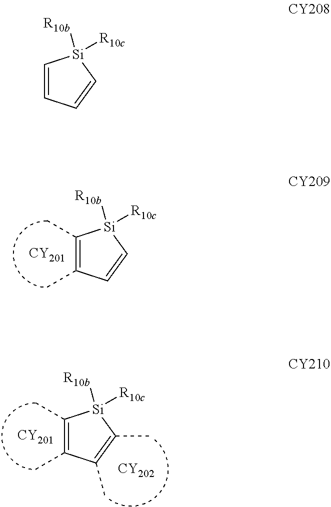

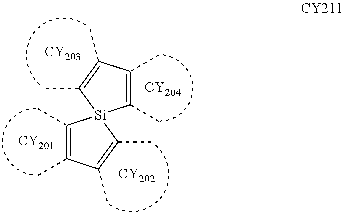

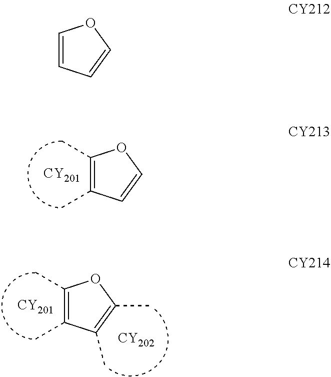

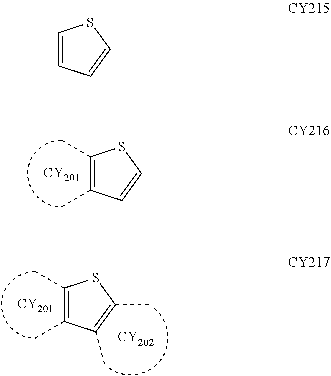

In Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, in Formulae CY201 to CY217, ring CY₂₀₁ to ring CY₂₀₄ may each independently be a benzene group, a naphthalene group, a phenanthrene group, or an anthracene group.

In embodiments, the compound represented by Formula 201 and the compound represented by Formula 202 may each independently include at least one of the groups represented by Formulae CY201 to CY203.

In embodiments, the compound represented by Formula 201 may include at least one of the groups represented by Formulae CY201 to CY203 and at least one of the groups represented by Formulae CY204 to CY217.

In embodiments, in Formula 201, xa1 may be 1, R₂₀₁ may include a group represented by one of Formulae CY201 to CY203, xa2 may be 0, and R₂₀₂ may be a group represented by one of Formulae CY204 to CY207.

In embodiments, the compound represented by Formula 201 and the compound represented by Formula 202 may each not include the groups represented by Formulae CY201 to CY203.

In embodiments, the compound represented by Formula 201 and the compound represented by Formula 202 may each not include the groups represented by Formulae CY201 to CY203, and may each independently include at least one of the groups represented by Formulae CY204 to CY217.

In embodiments, the compound represented by Formula 201 and the compound represented by Formula 202 may each not include the groups represented by Formulae CY201 to CY217.

In an embodiment, the hole transport region may include: one of Compounds HT1 to HT46; m-MTDATA; TDATA; 2-TNATA; NPB (NPD); β-NPB; TPD; spiro-TPD; spiro-NPB; methylated NPB; TAPC; HMTPD; 4,4′,4″-tris(N-carbazolyl)triphenylamine (TCTA); polyaniline/dodecylbenzenesulfonic acid (PANI/DBSA); poly(3,4-ethylenedioxythiophene)/poly(4-styrenesulfonate) (PEDOT/PSS); polyaniline/camphor sulfonic acid (PANI/CSA); polyaniline/poly(4-styrenesulfonate) (PANI/PSS); or any combination thereof:

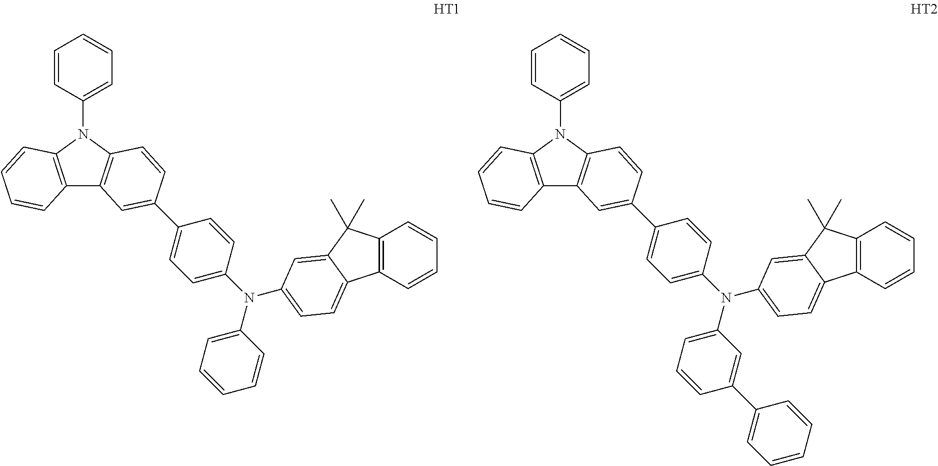 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21]

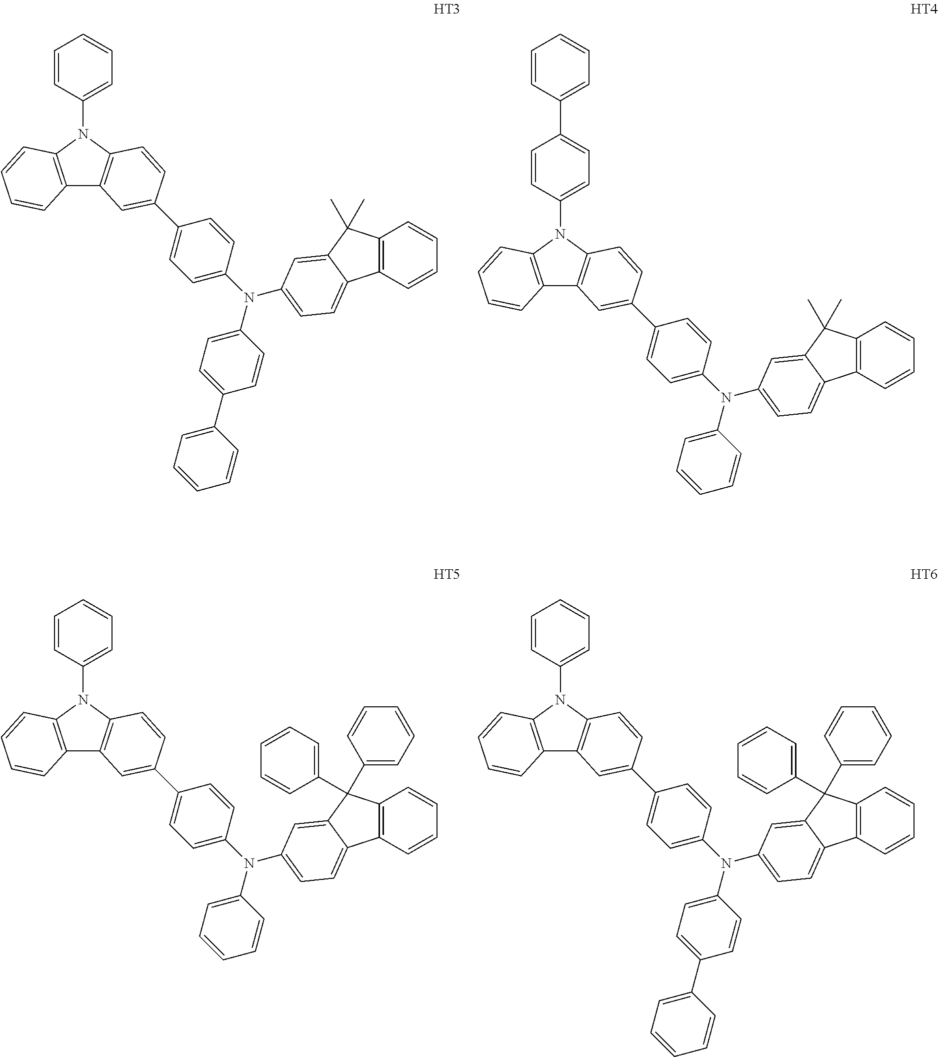

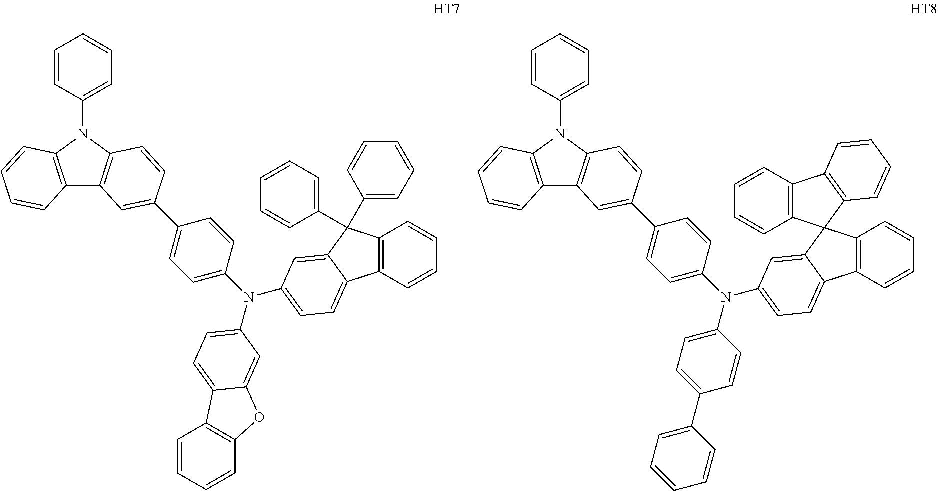 [SMILES: c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

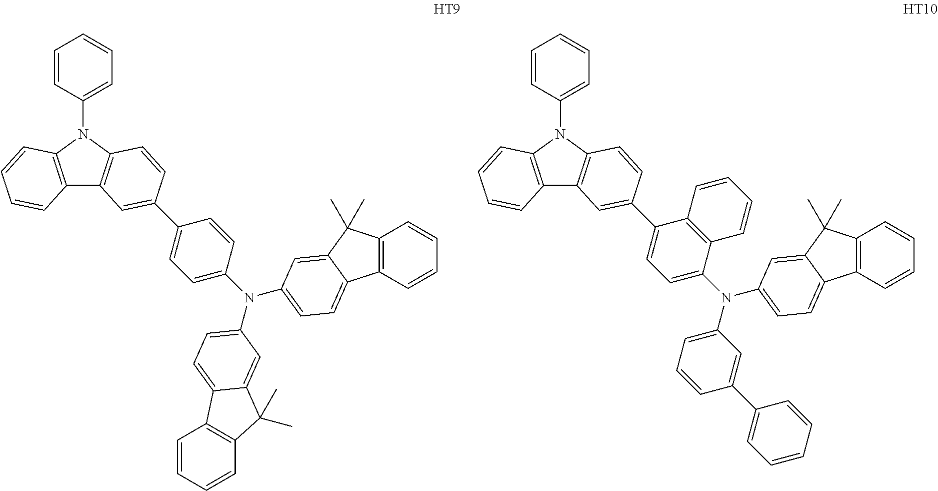 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21]

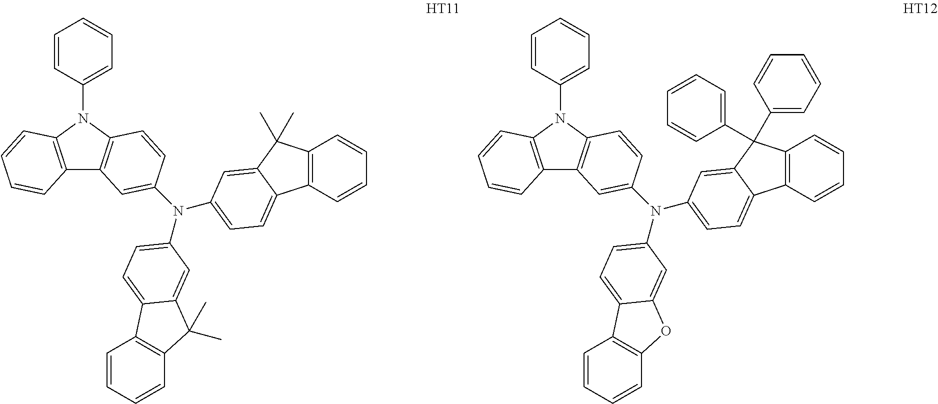 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

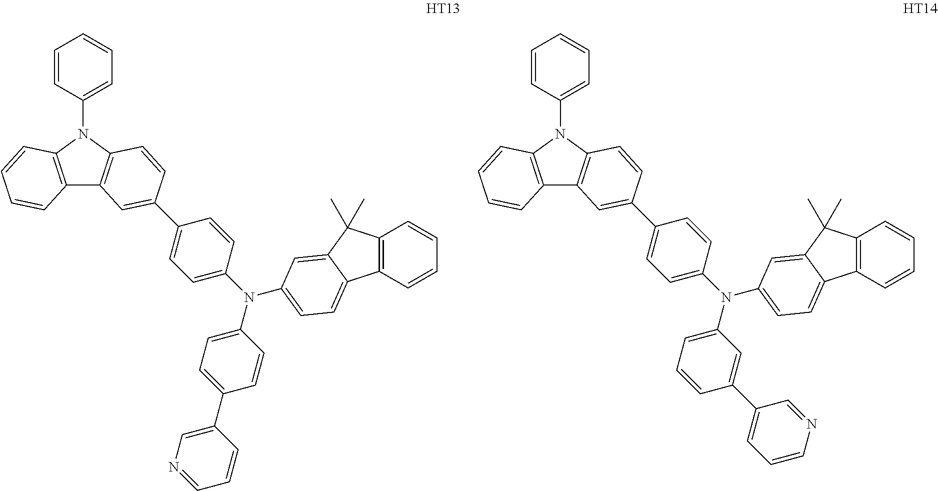 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

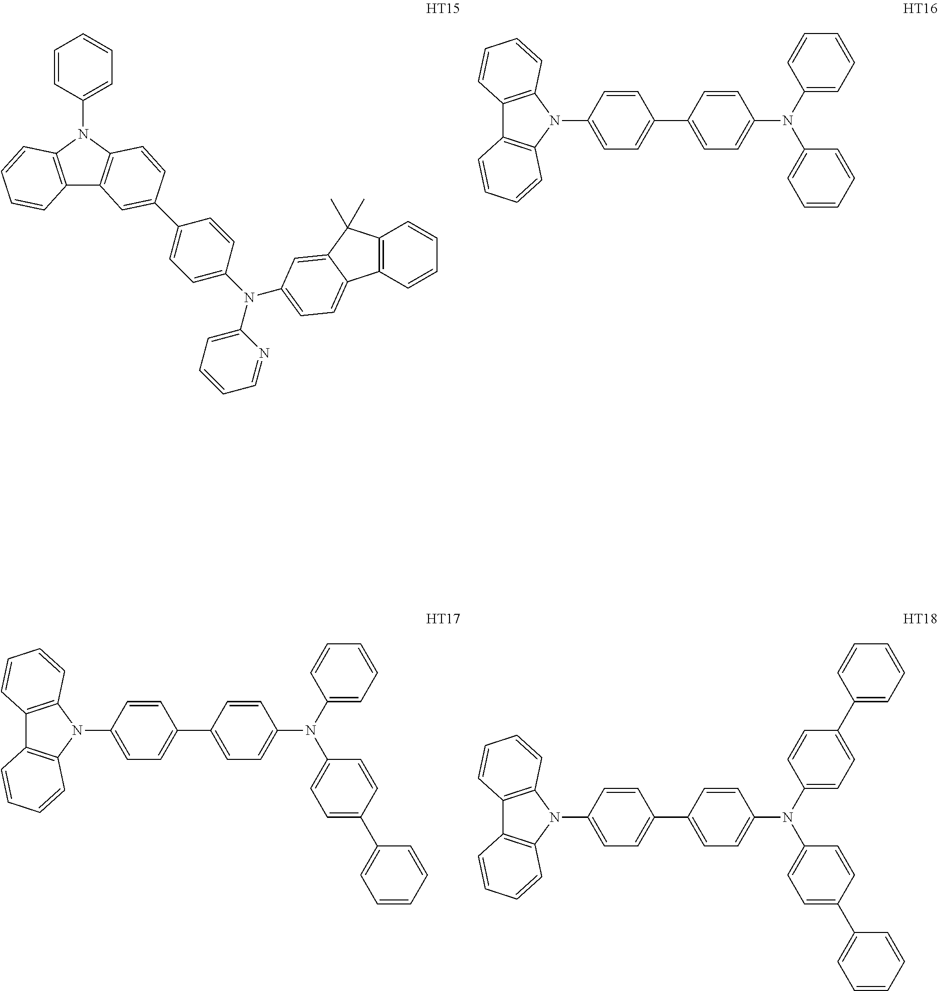 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

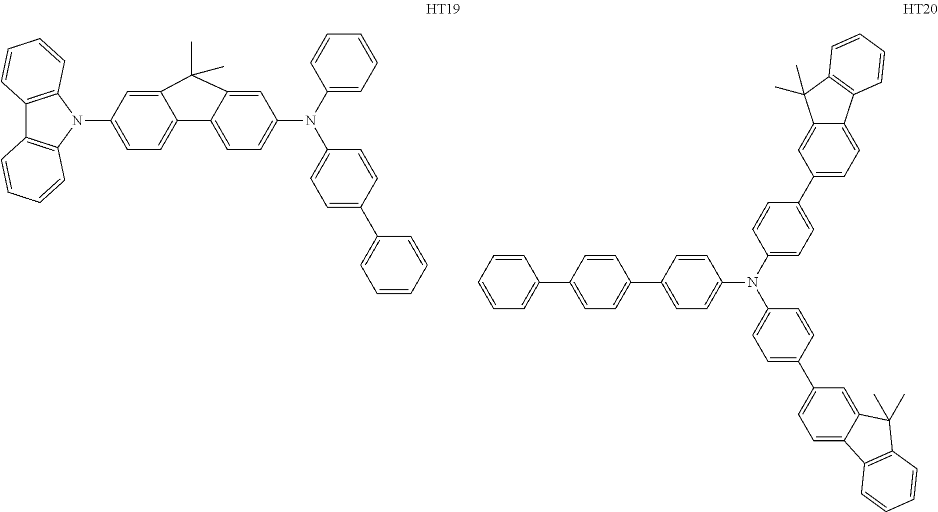 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

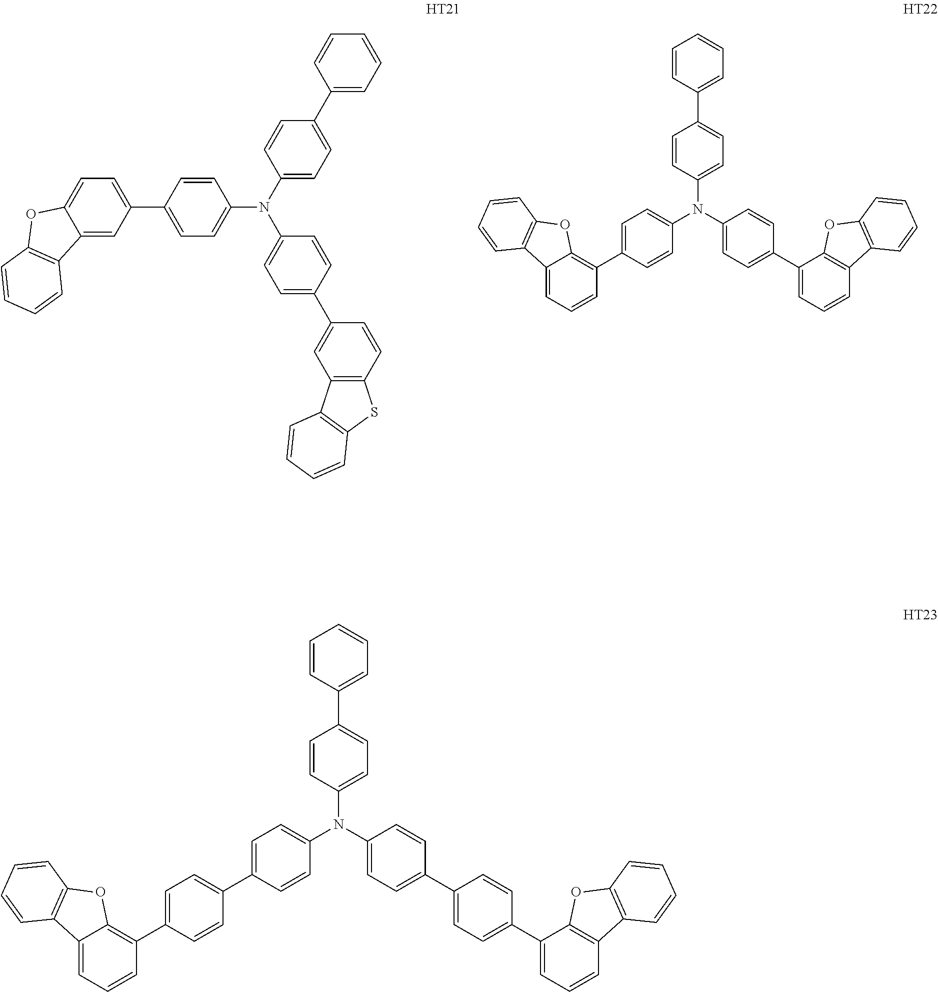 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

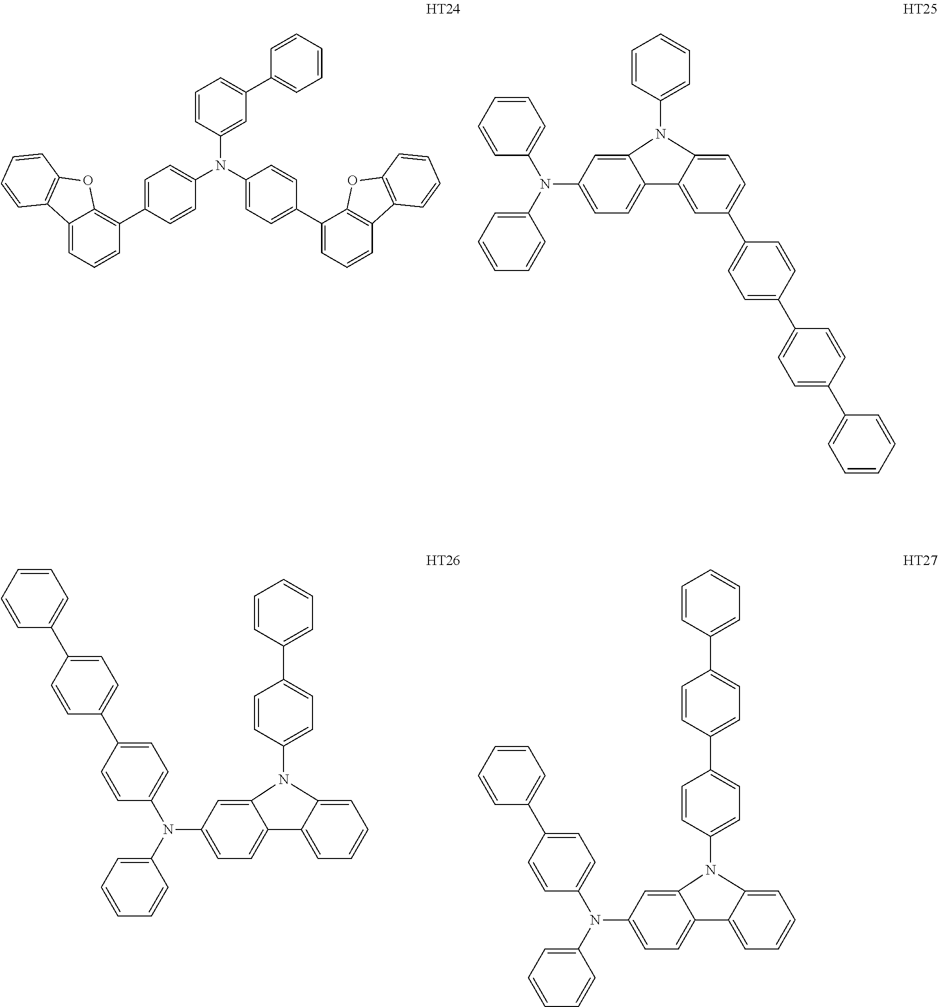 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

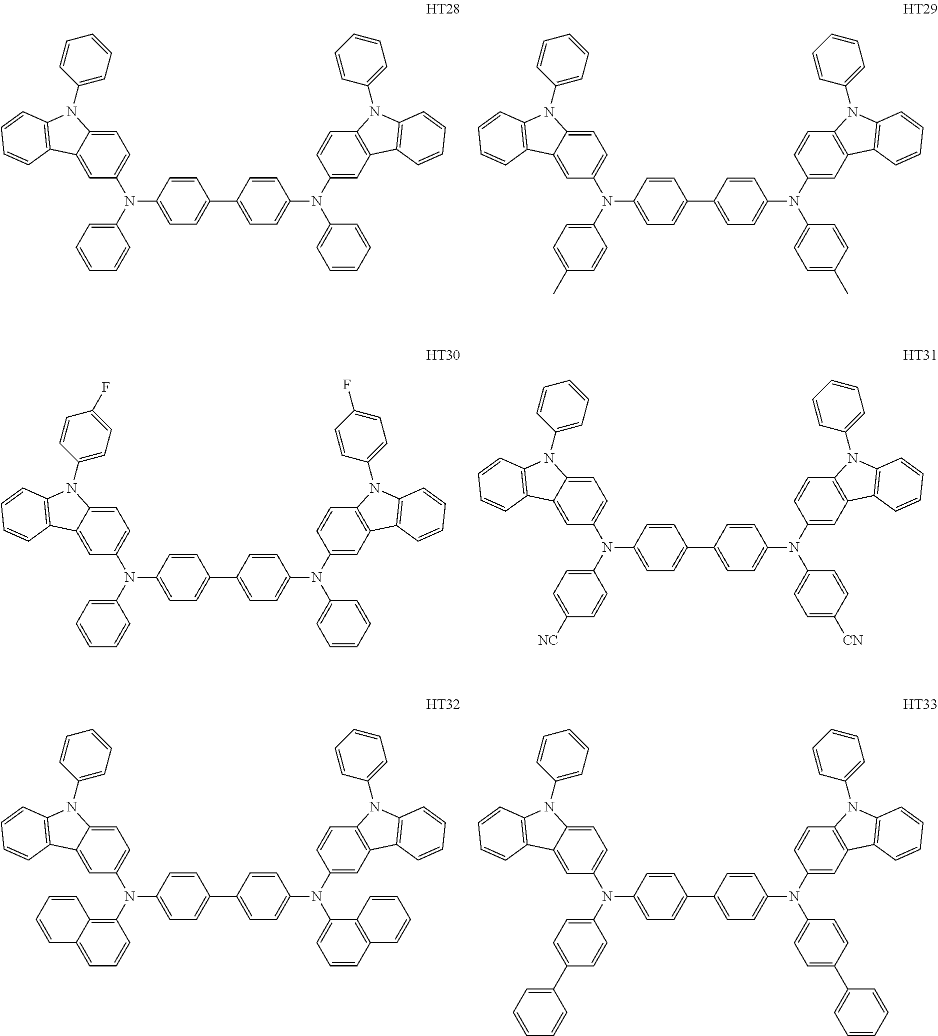

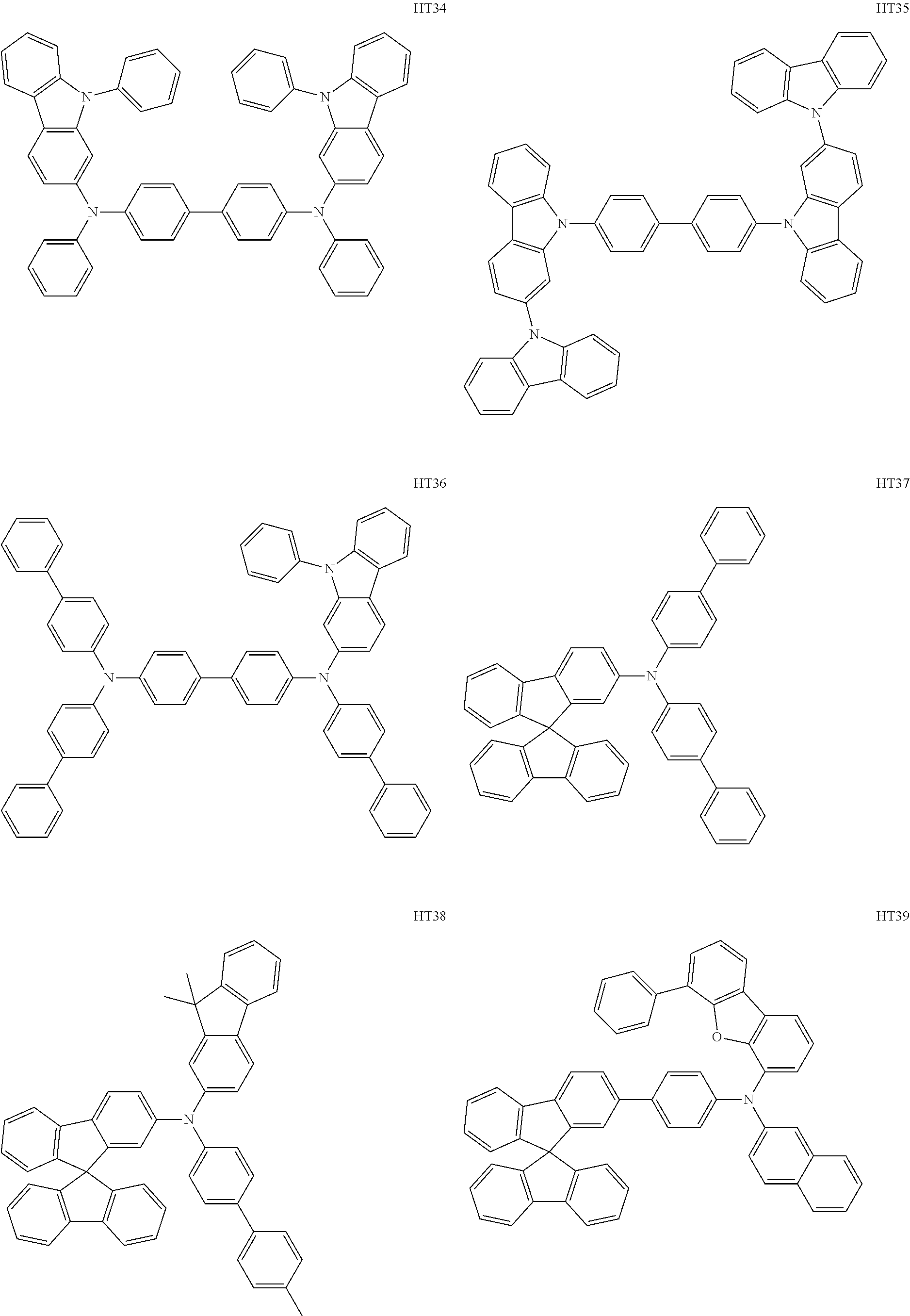

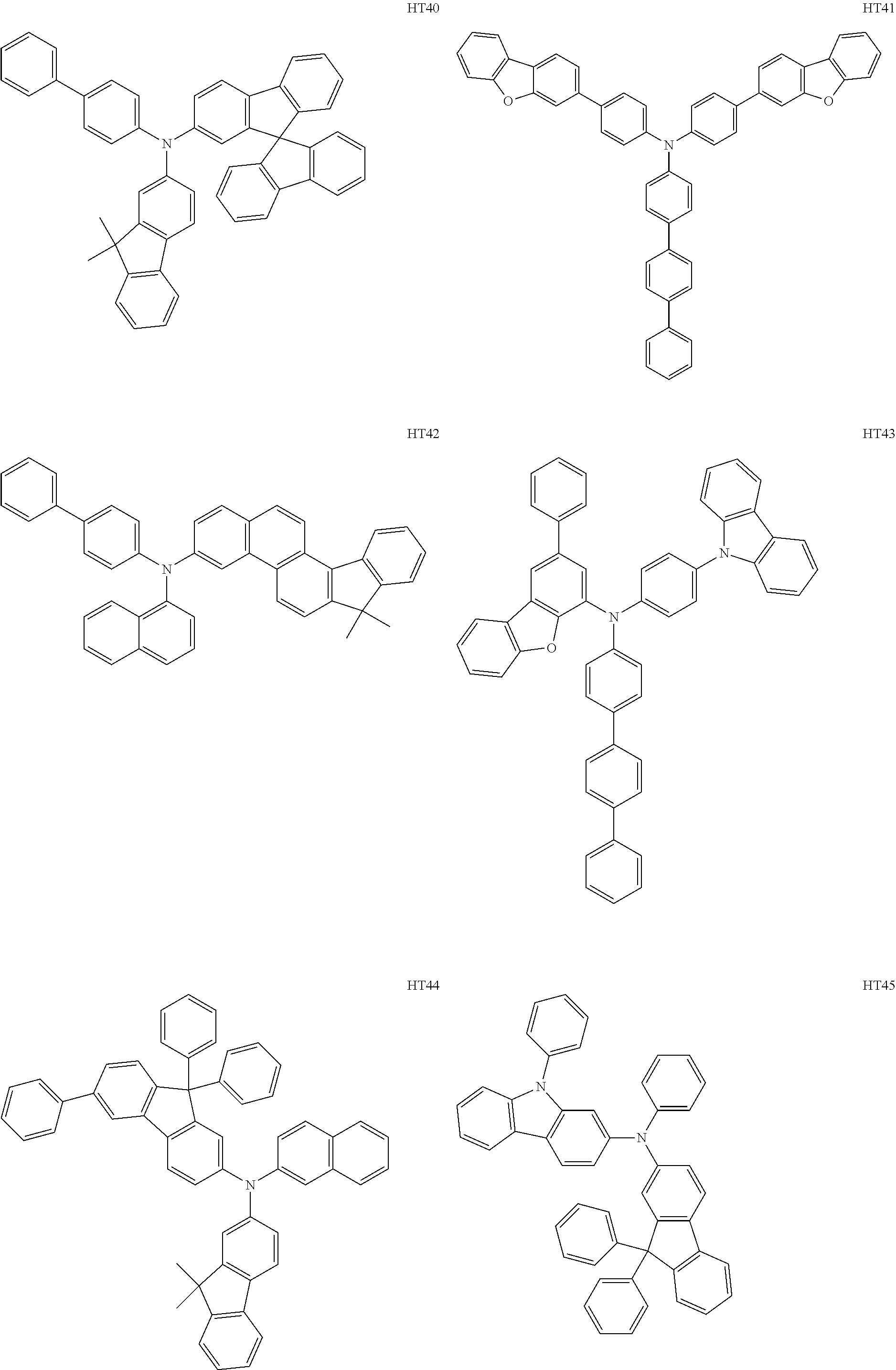

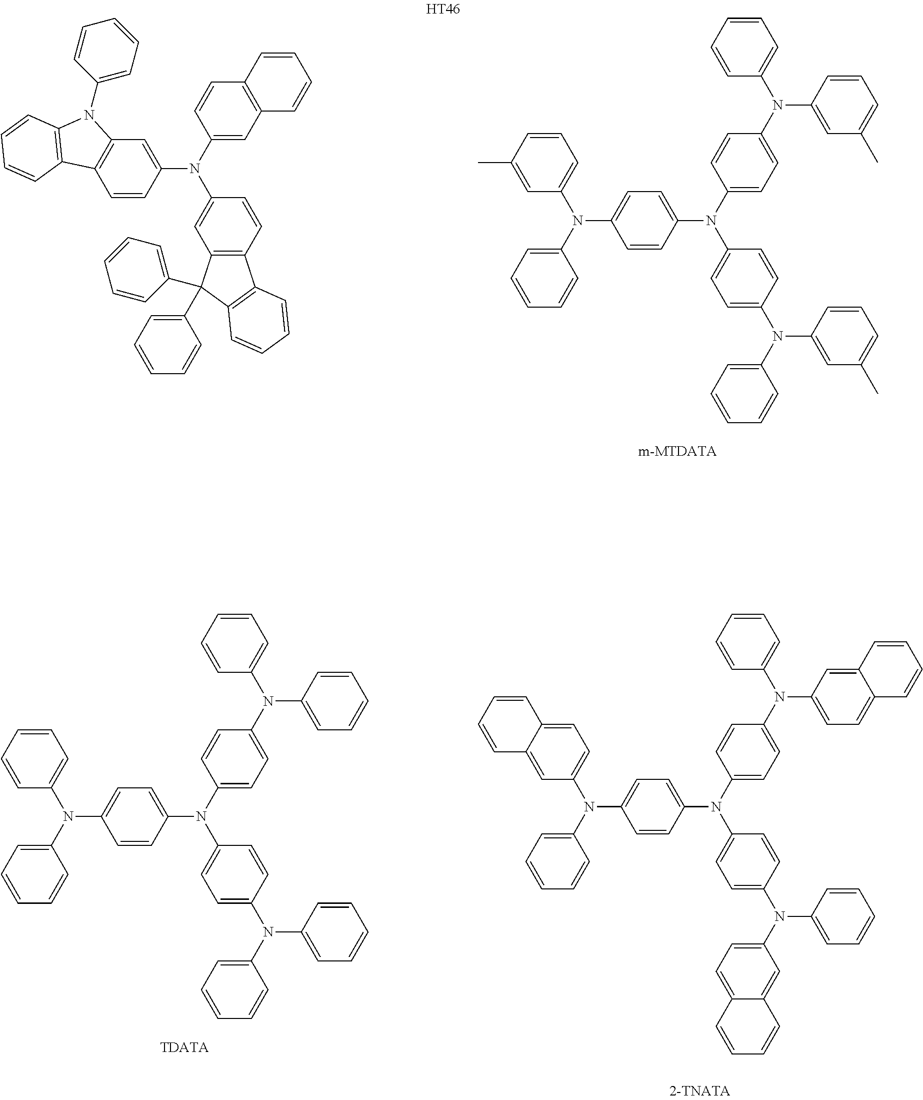

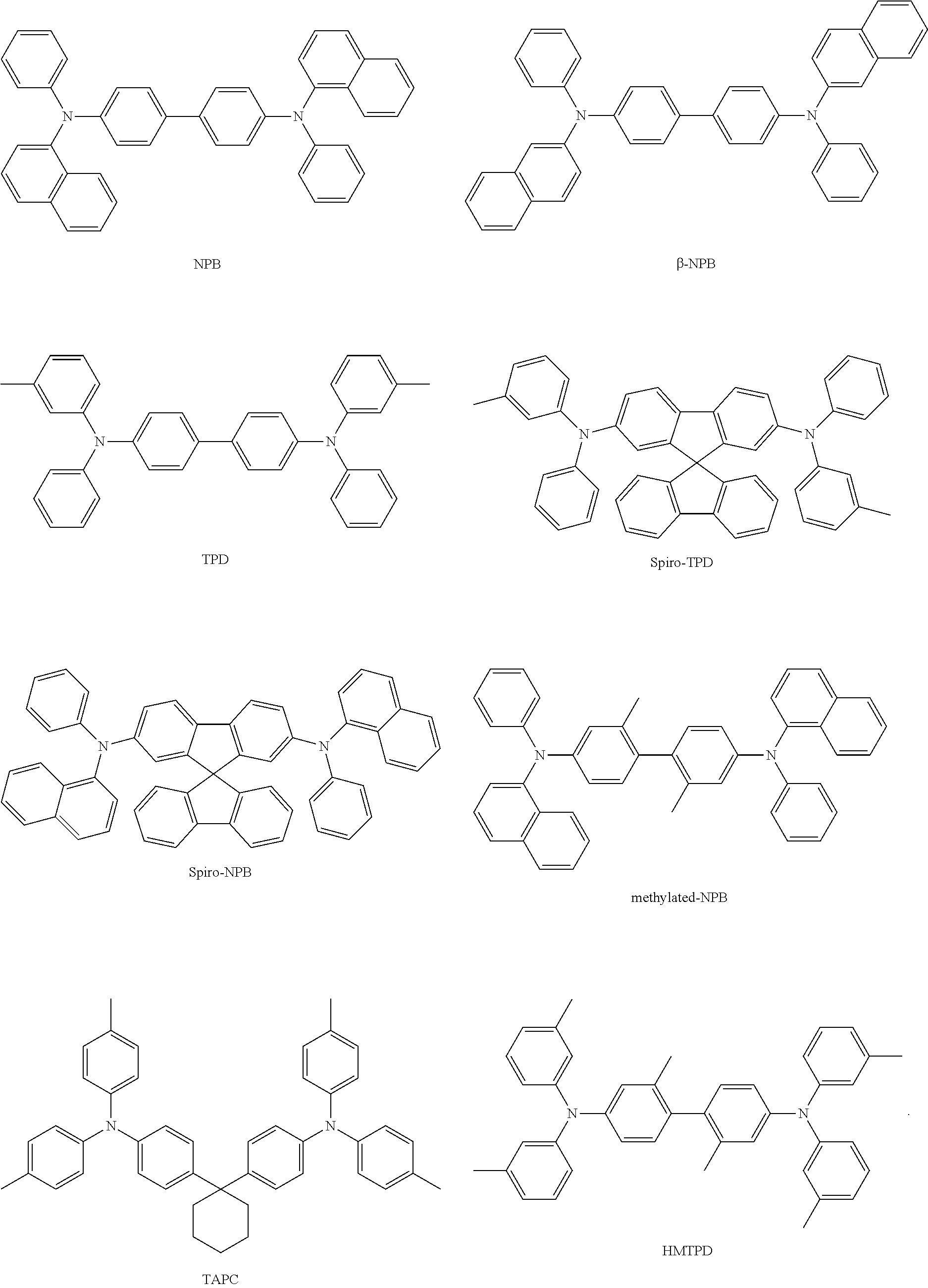

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light emission efficiency by compensating for an optical resonance distance according to a wavelength of light emitted by the emission layer, and the electron blocking layer may block the leakage of electrons from the emission layer to the hole transport region. Materials that may be included in the hole transport region may be included in the emission auxiliary layer and the electron blocking layer.

[p-Dopant]

The hole transport region may further include, in addition to the aforementioned materials, a charge-generation material for the improvement of conductive properties. The charge-generation material may be uniformly or non-uniformly dispersed in the hole transport region (e.g., in the form of a single layer consisting of the charge-generation material).

The charge-generation material may be, for example, a p-dopant.

In an embodiment, the p-dopant may have a lowest unoccupied molecular orbital (LUMO) energy level equal to or less than about −3.5 eV.

In an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

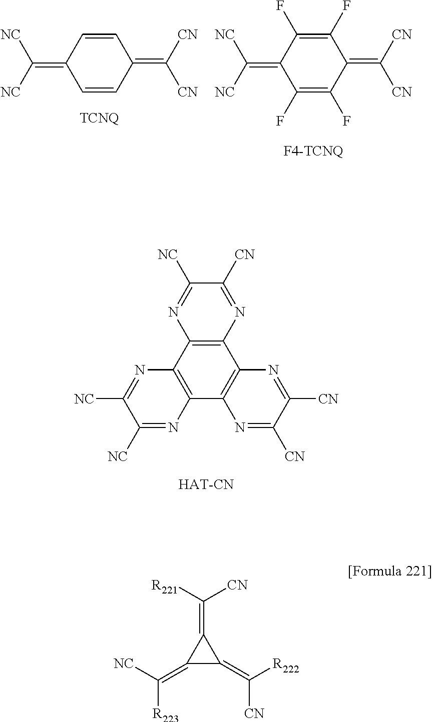

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R²²¹ to R²²³ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (e.g., lithium (Li), sodium (Na), potassium (K), rubidium (Rb), cesium (Cs), etc.); an alkaline earth metal (e.g., beryllium (Be), magnesium (Mg), calcium (Ca), strontium (Sr), barium (Ba), etc.); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (e.g., zinc (Zn), indium (In), tin (Sn), etc.); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of a metalloid may include silicon (Si), antimony (Sb), tellurium (Te), and the like.

Examples of a non-metal may include oxygen (O), a halogen (e.g., F, Cl, Br, I, etc.), and the like.

Examples of a compound containing element EL1 and element EL2 may include a metal oxide, a metal halide (e.g., a metal fluoride, a metal chloride, a metal bromide, a metal iodide, etc.), a metalloid halide (e.g., a metalloid fluoride, a metalloid chloride, a metalloid bromide, a metalloid iodide, etc.), a metal telluride, or any combination thereof.

Examples of a metal oxide may include a tungsten oxide (e.g., WO, W₂O₃, WO₂, WO₃, W₂O₅, etc.), a vanadium oxide (e.g., VO, V₂O₃, VO₂, V₂O₅, etc.), a molybdenum oxide (e.g., MoO, Mo₂O₃, MoO₂, MoO₃, Mo₂O₅, etc.), a rhenium oxide (e.g., ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, Cal₂, SrI₂, BaI₂, and the like.

Examples of a transition metal halide may include a titanium halide (e.g., TiF₄, TiCl₄, TiBr₄, TiI₄, etc.), a zirconium halide (e.g., ZrF₄, ZrCl₄, ZrBr₄, ZrI₄, etc.), a hafnium halide (e.g., HfF₄, HfCl₄, HfBr₄, HfI₄, etc.), a vanadium halide (e.g., VF₃, VCl₃, VBr₃, VI₃, etc.), a niobium halide (e.g., NbF₃, NbCl₃, NbBr₃, NbI₃, etc.), a tantalum halide (e.g., TaF₃, TaCl₃, TaBr₃, TaI₃, etc.), a chromium halide (e.g., CrF₃, CrO₃, CrBr₃, CrI₃, etc.), a molybdenum halide (e.g., MoF₃, MoCl₃, MoBr₃, MoI₃, etc.), a tungsten halide (e.g., WF₃, WCl₃, WBr₃, WI₃, etc.), a manganese halide (e.g., MnF₂, MnCl₂, MnBr₂, MnI₂, etc.), a technetium halide (e.g., TcF₂, TcCl₂, TcBr₂, Tc₁₂, etc.), a rhenium halide (e.g., ReF₂, ReCl₂, ReBr₂, Rel₂, etc.), an iron halide (e.g., FeF₂, FeCl₂, FeBr₂, FeI₂, etc.), a ruthenium halide (e.g., RuF₂, RuCl₂, RuBr₂, Rul₂, etc.), an osmium halide (e.g., OsF₂, OsCl₂, OsBr₂, OsI₂, etc.), a cobalt halide (e.g., CoF₂, COC₁₂, CoBr₂, CoI₂, etc.), a rhodium halide (e.g., RhF₂, RhCl₂, RhBr₂, RhI₂, etc.), an iridium halide (e.g., IrF₂, IrCl₂, IrBr₂, IrI₂, etc.), a nickel halide (e.g., NiF₂, NiCl₂, NiBr₂, NiI₂, etc.), a palladium halide (e.g., PdF₂, PdCl₂, PdBr₂, PdI₂, etc.), a platinum halide (e.g., PtF₂, PtCl₂, PtBr₂, PtI₂, etc.), a copper halide (e.g., CuF, CuCl, CuBr, CuI, etc.), a silver halide (e.g., AgF, AgCl, AgBr, AgI, etc.), a gold halide (e.g., AuF, AuCl, AuBr, AuI, etc.), and the like.

Examples of a post-transition metal halide may include a zinc halide (e.g., ZnF₂, ZnCl₂, ZnBr₂, ZnI₂, etc.), an indium halide (e.g., InI₃, etc.), a tin halide (e.g., SnI₂, etc.), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (e.g., SbCl₅, etc.) and the like.

Examples of a metal telluride may include an alkali metal telluride (e.g., Li₂Te, Na₂Te, K₂Te, Rb₂Te, Cs₂Te, etc.), an alkaline earth metal telluride (e.g., BeTe, MgTe, CaTe, SrTe, BaTe, etc.), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (e.g., ZnTe, etc.), a lanthanide metal telluride (e.g., LaTe, CeTe, PrTe, NdTe, PmTe, EuTe, GdTe, TbTe, DyTe, HoTe, ErTe, TmTe, YbTe, LuTe, etc.), and the like.

### [Emission Layer in Interlayer 130]

When the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other, to emit white light. In embodiments, the emission layer may include two or more materials of a red light-emitting material, a green light-emitting material, and a blue light-emitting material, in which the two or more materials are mixed with each other in a single layer, to emit white light.

In an embodiment, the emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight, based on 100 parts by weight of the host.

In embodiments, the emission layer may include quantum dots.

In embodiments, the emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within any of these ranges, excellent luminescence characteristics may be obtained without a substantial increase in driving voltage.

### [Host]

In an embodiment, the host may include a compound represented by Formula 301:

[Ar₃₀₁]_{xb11}-[(L₃₀₁)_{xb1}-R₃₀₁]_{xb21} [Formula 301]

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, in Formula 301, when xb11 is 2 or more, two or more of Ar₃₀₁ may be linked to each other via a single bond.

In embodiments, the host may include a compound represented by Formula 301-1, a compound represented by Formula 301-2, or any combination thereof:

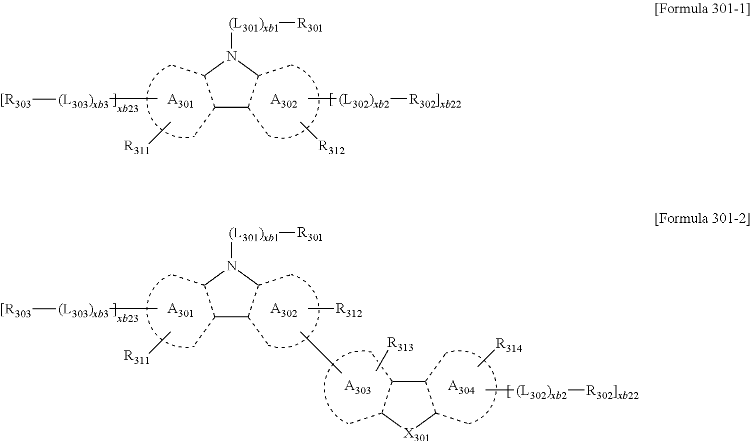

In Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ are each the same as described herein,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described herein in connection with R₃₀₁.

In embodiments, the host may include an alkali earth metal complex, a post-transition metal complex, or any combination thereof. For example, the host may include a Be complex (e.g., Compound H55), an Mg complex, a Zn complex, or any combination thereof.

In embodiments, the host may include: one of Compounds H1 to H128; 9,10-di(2-naphthyl)anthracene (ADN); 2-methyl-9,10-bis(naphthalen-2-yl)anthracene (MADN); 9,10-di-(2-naphthyl)-2-t-butyl-anthracene (TBADN); 4,4′-bis(N-carbazolyl)-1,1′-biphenyl (CBP); 1,3-di-9-carbazolylbenzene (mCP); 1,3,5-tri(carbazol-9-yl)benzene (TCP); or any combination thereof:

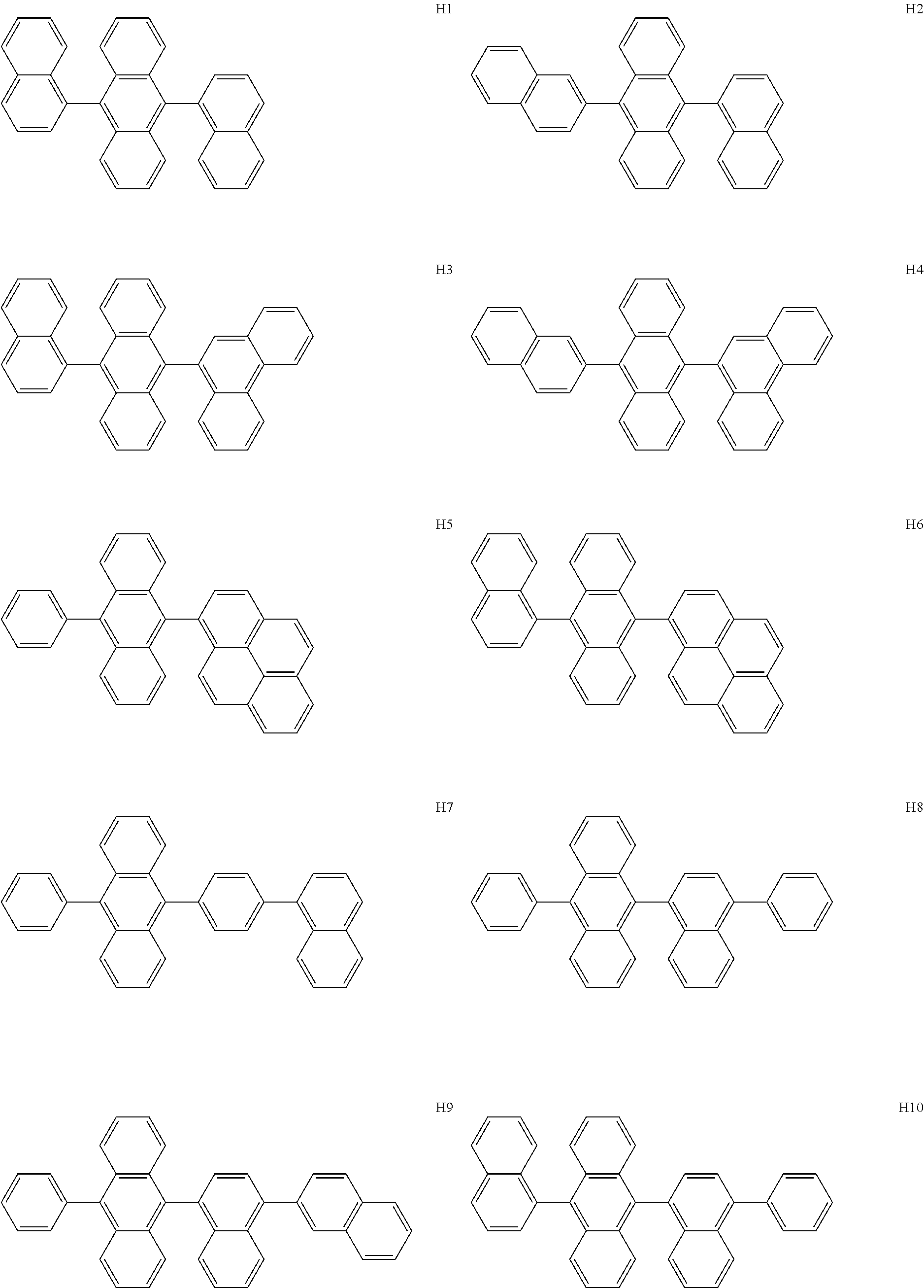

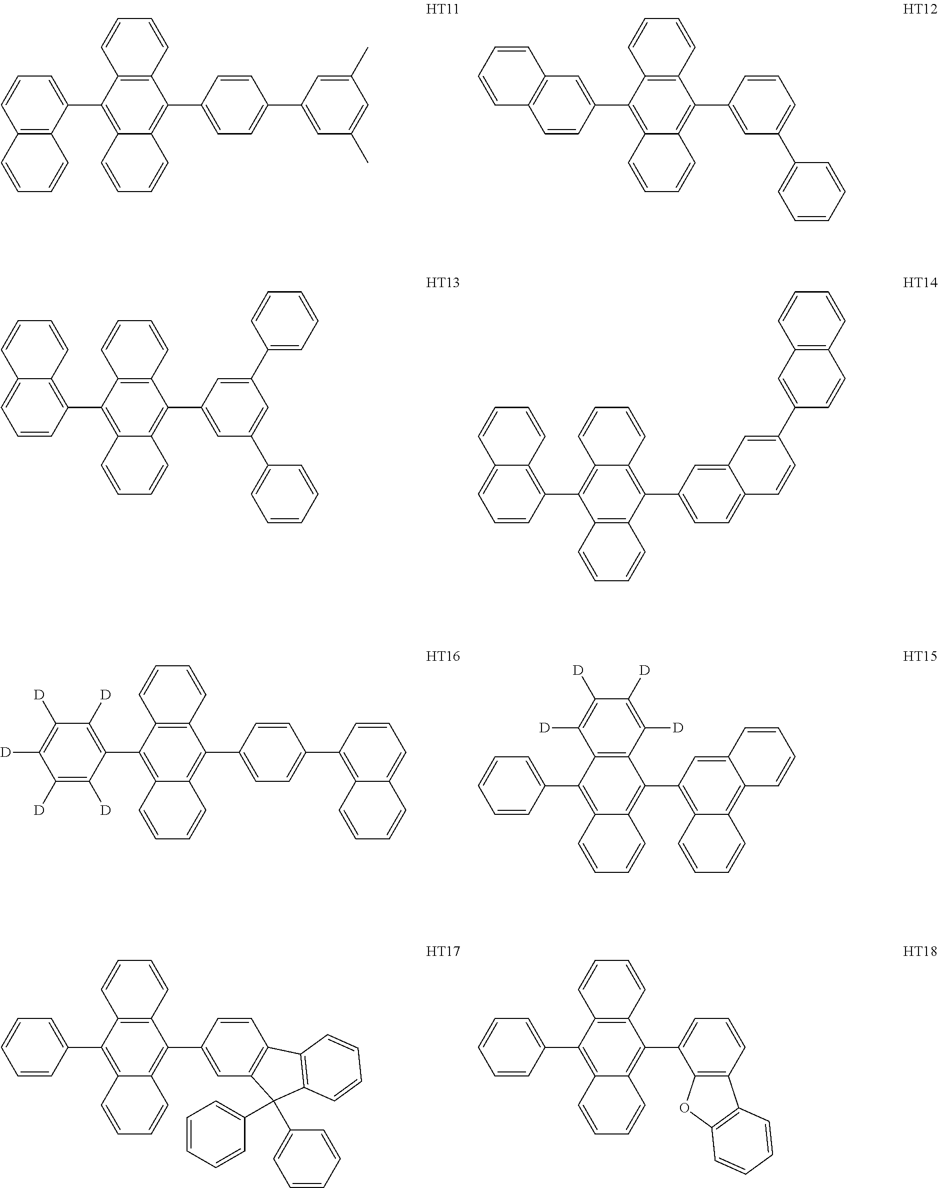

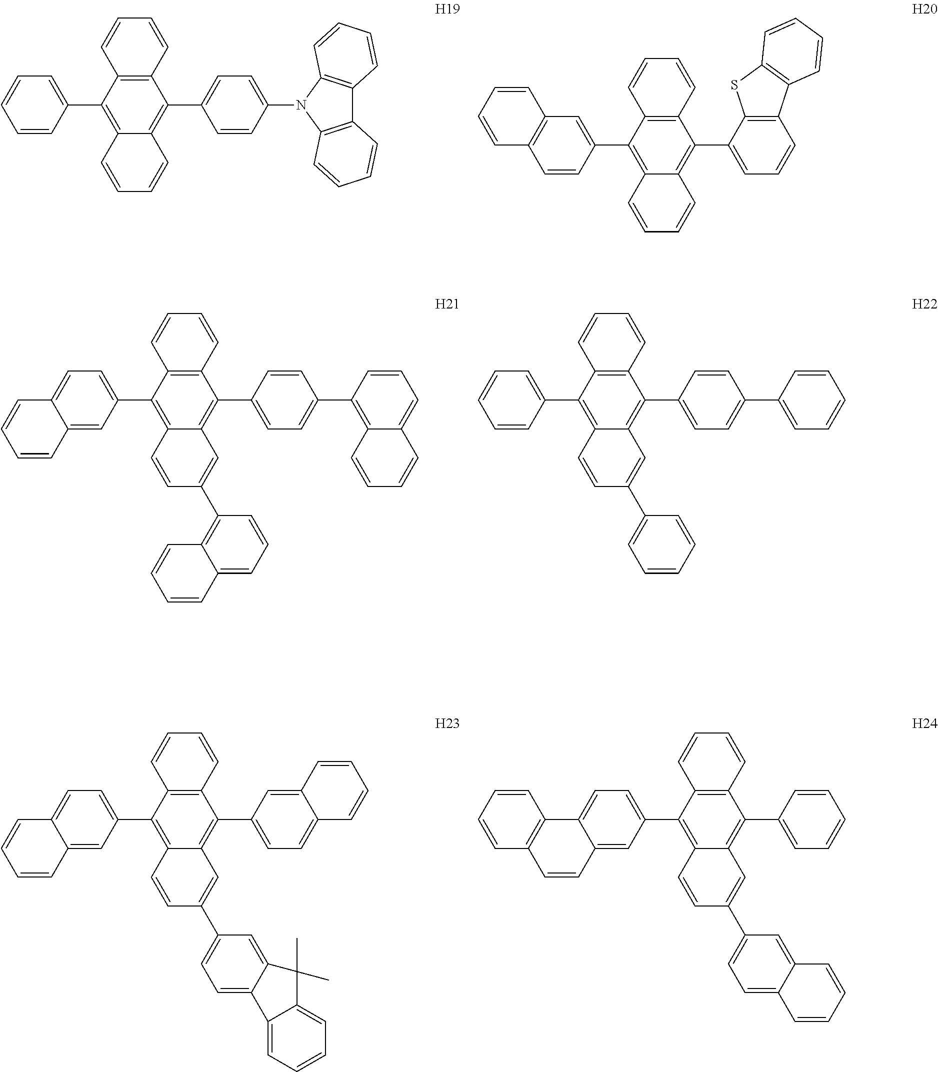

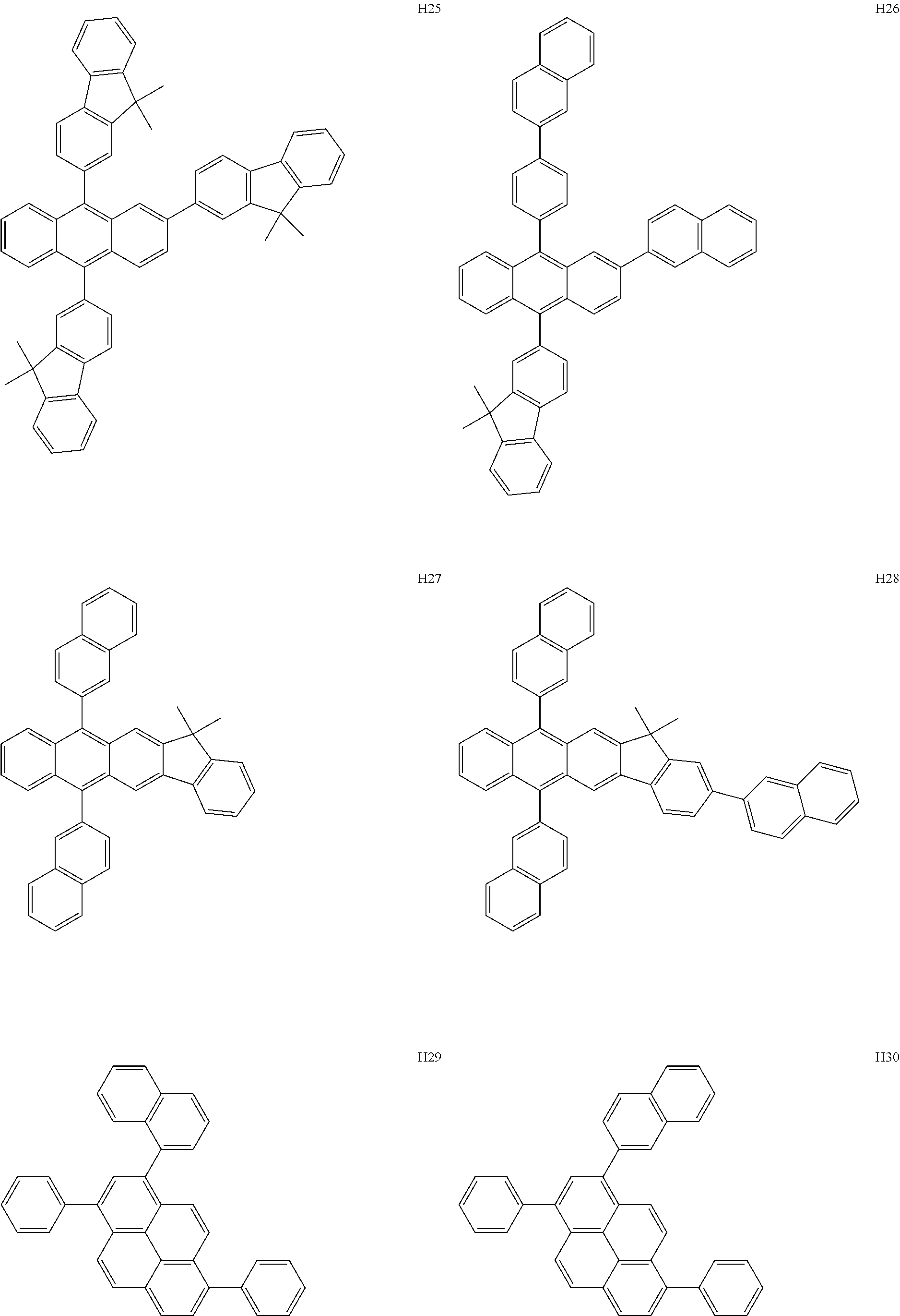

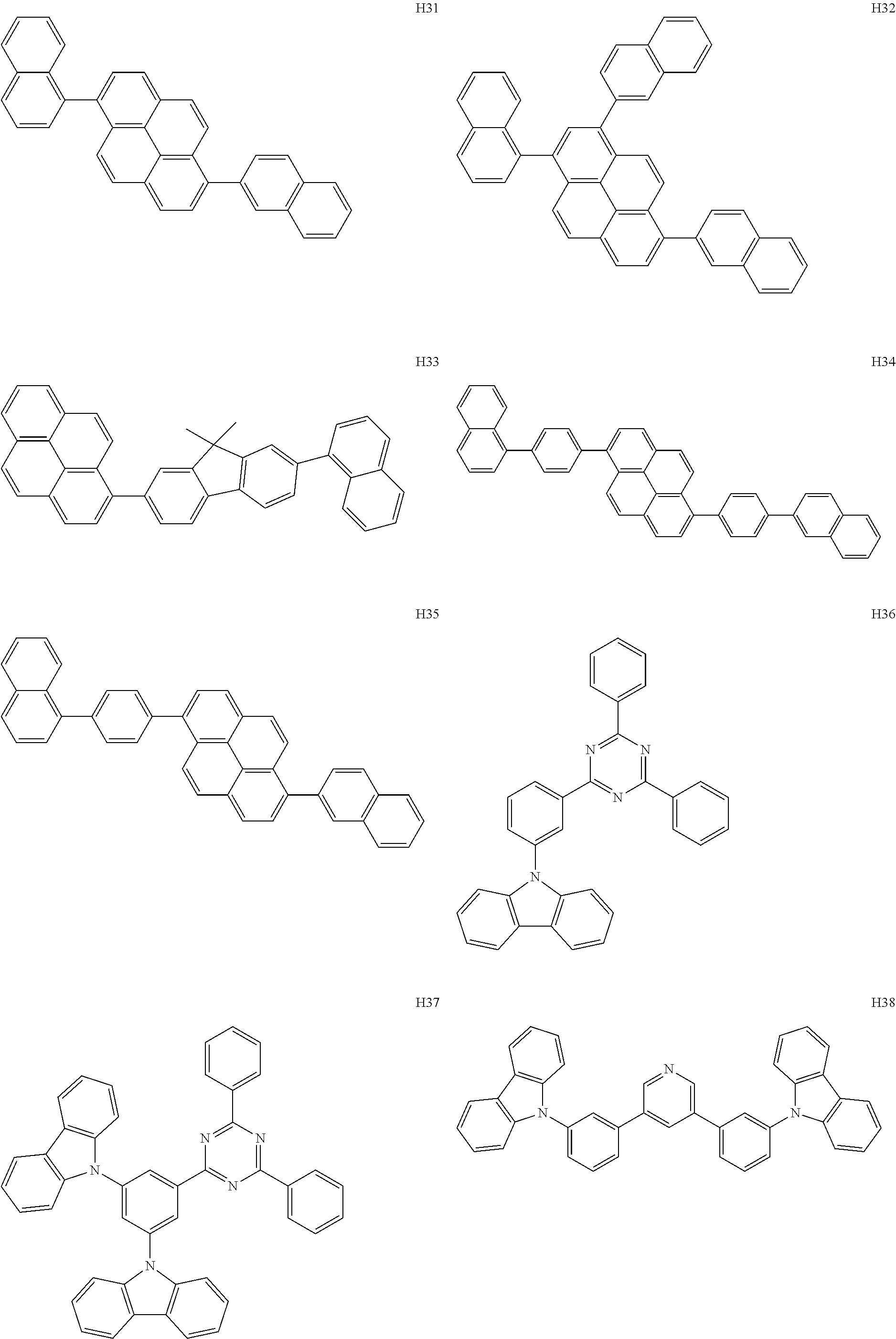

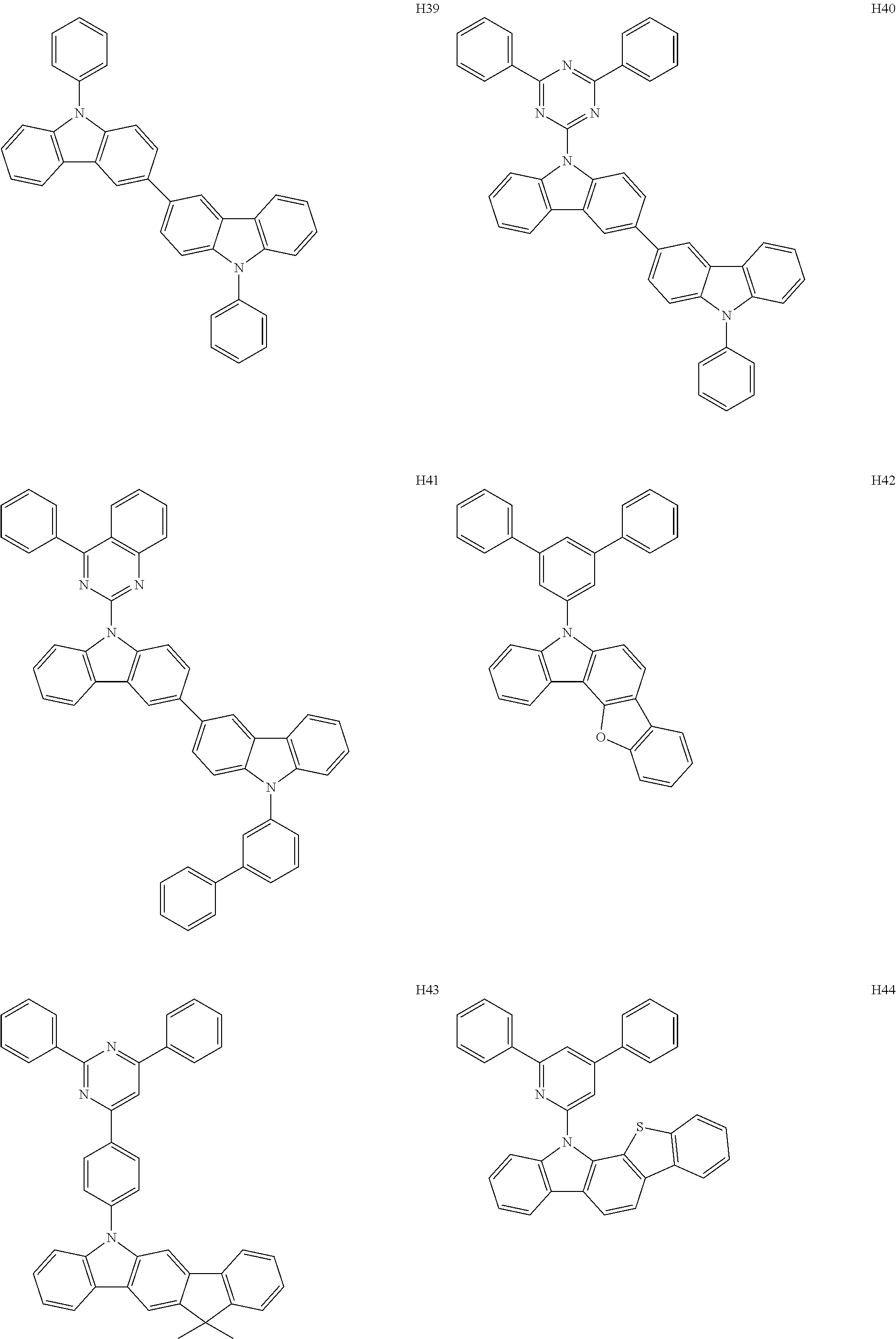 [SMILES: c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1]

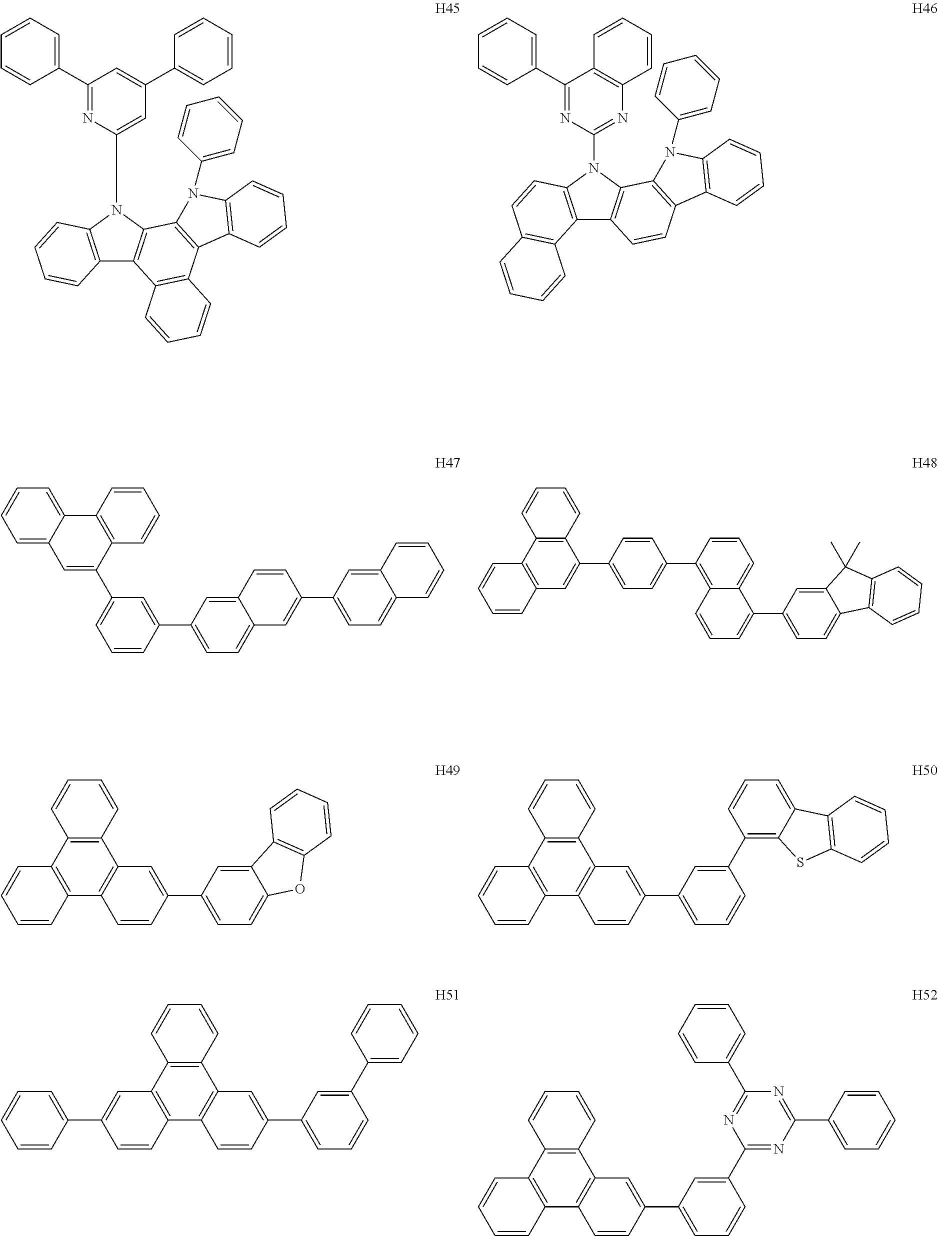

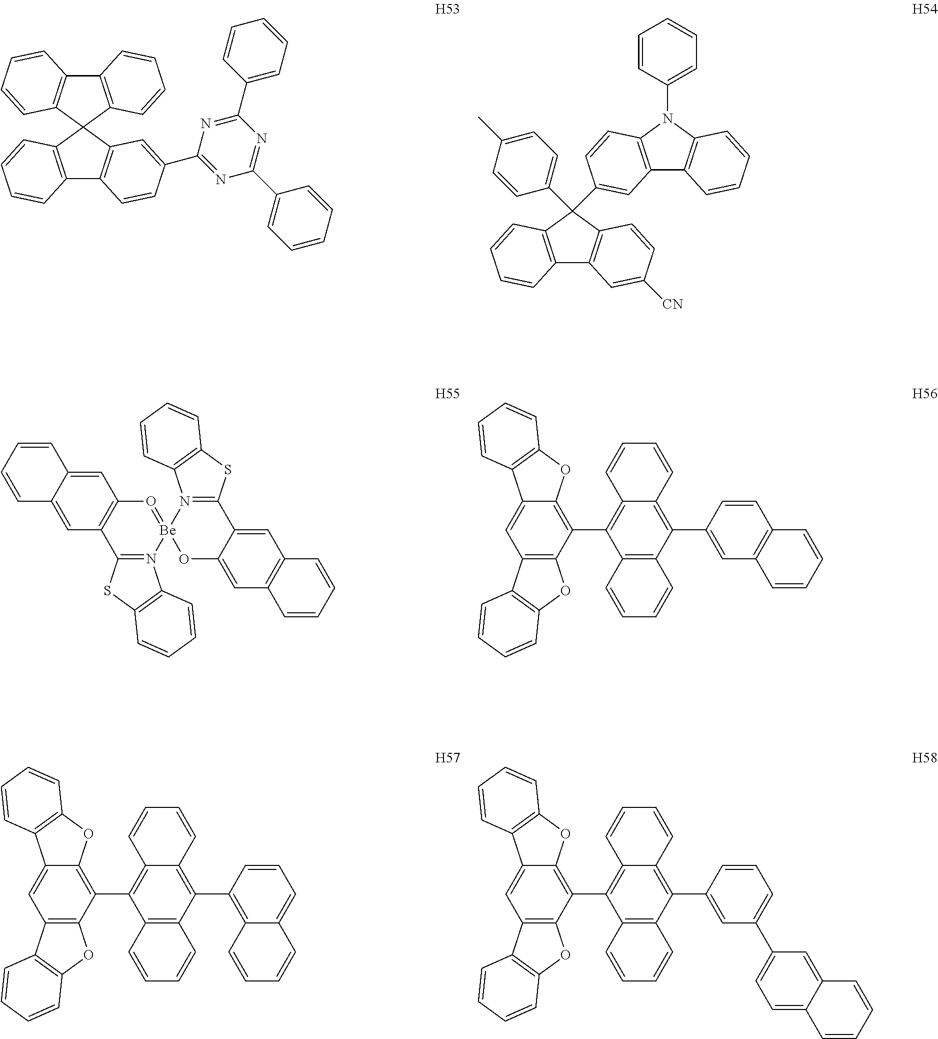

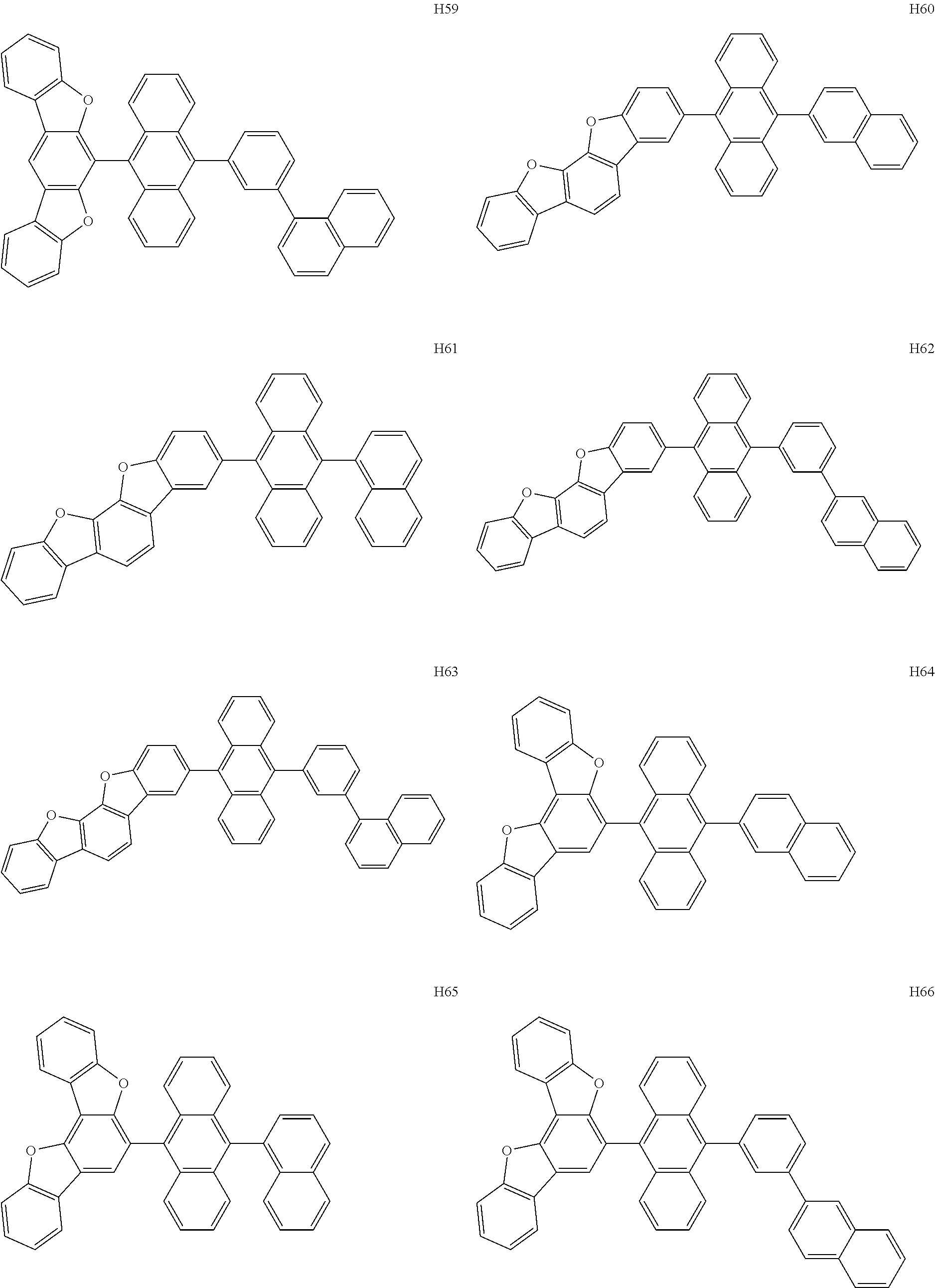

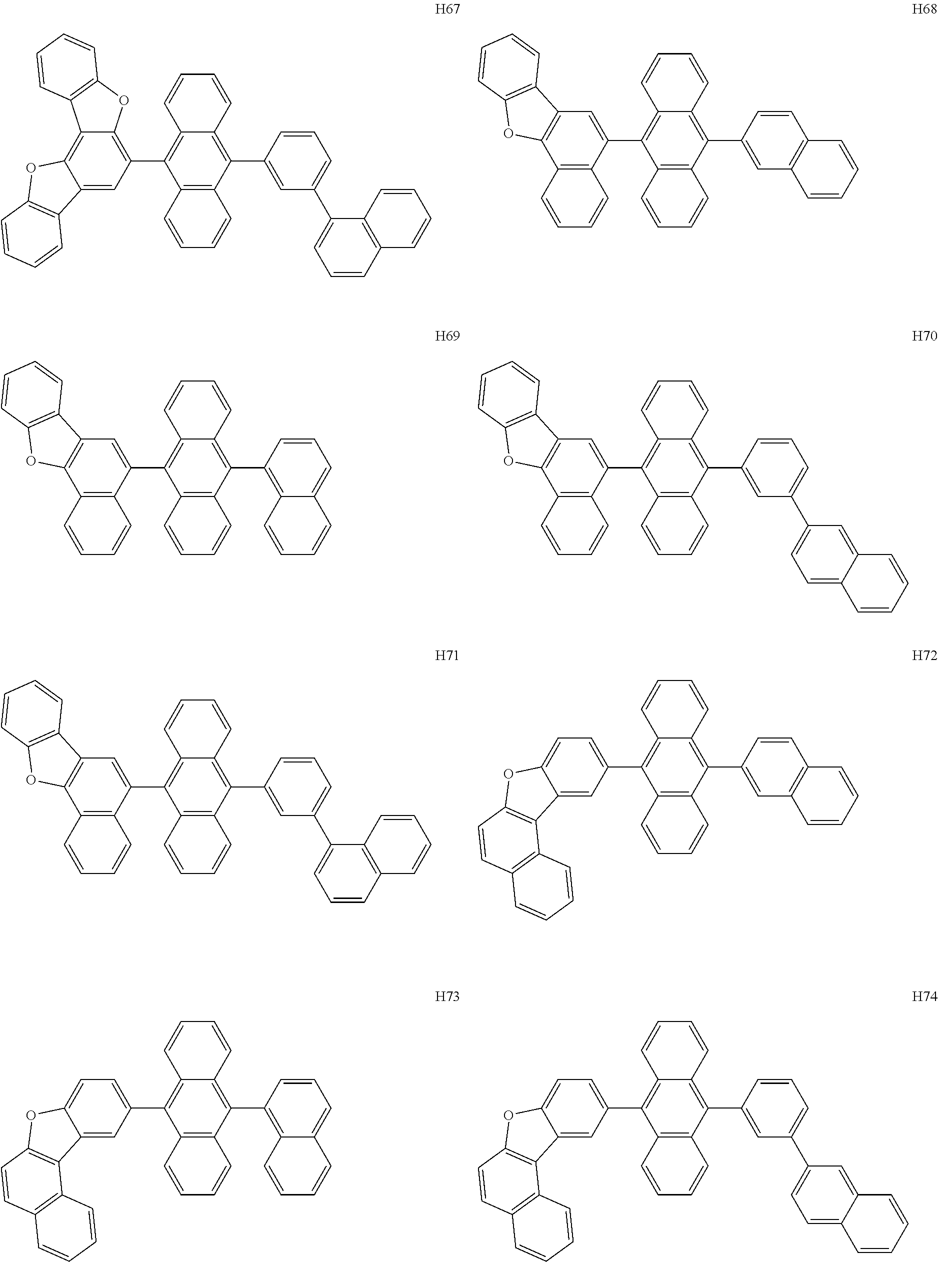

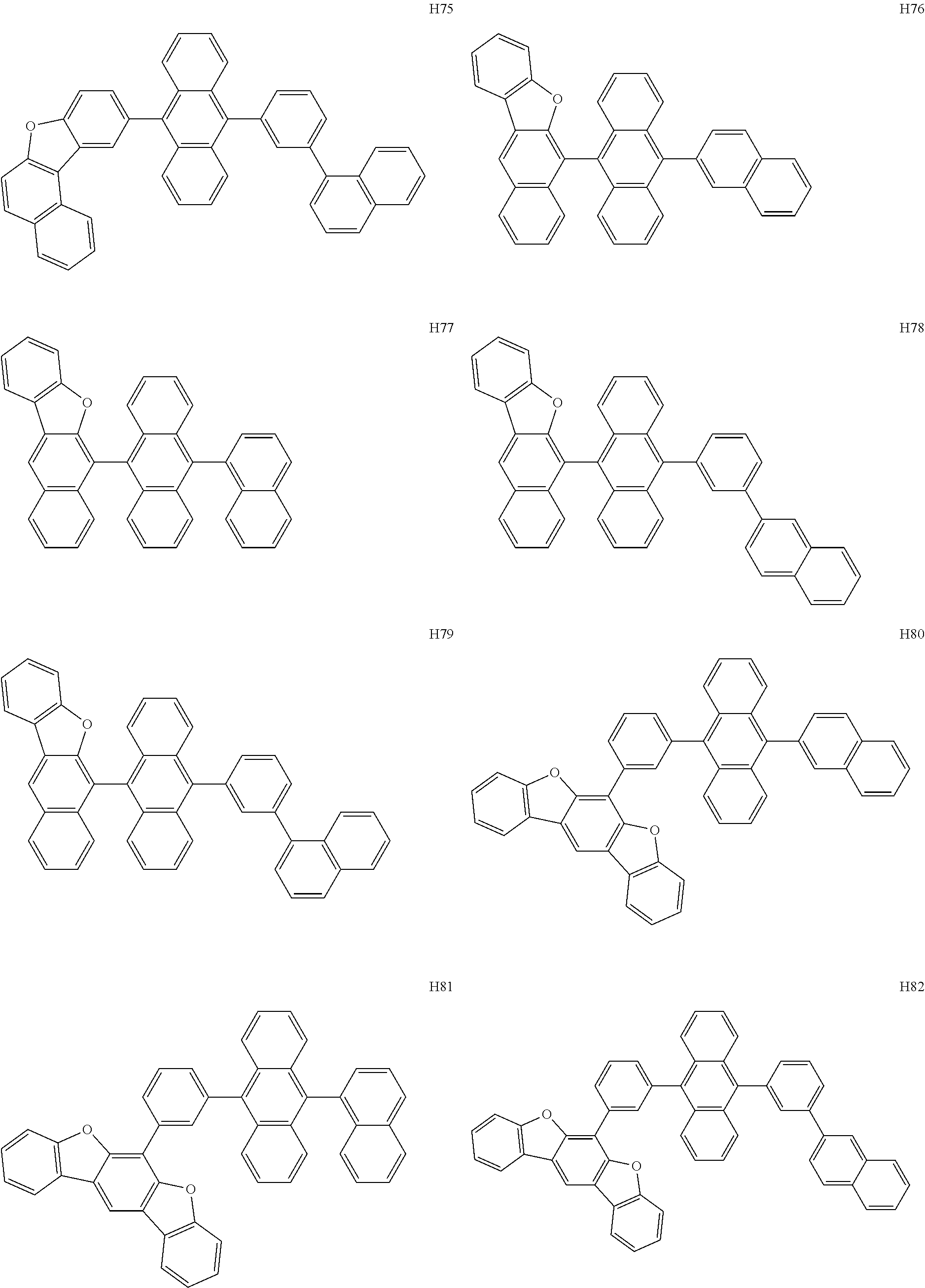

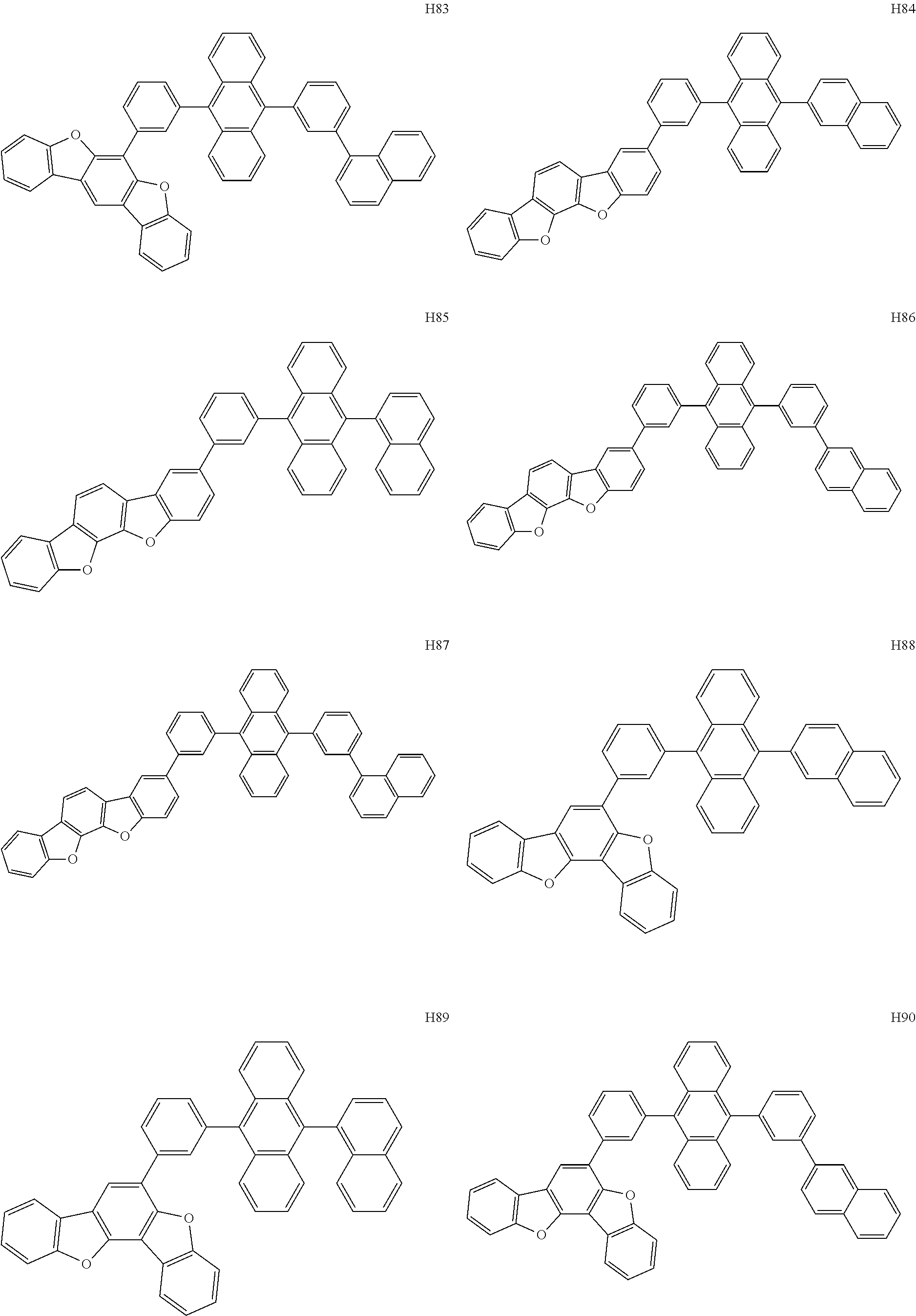

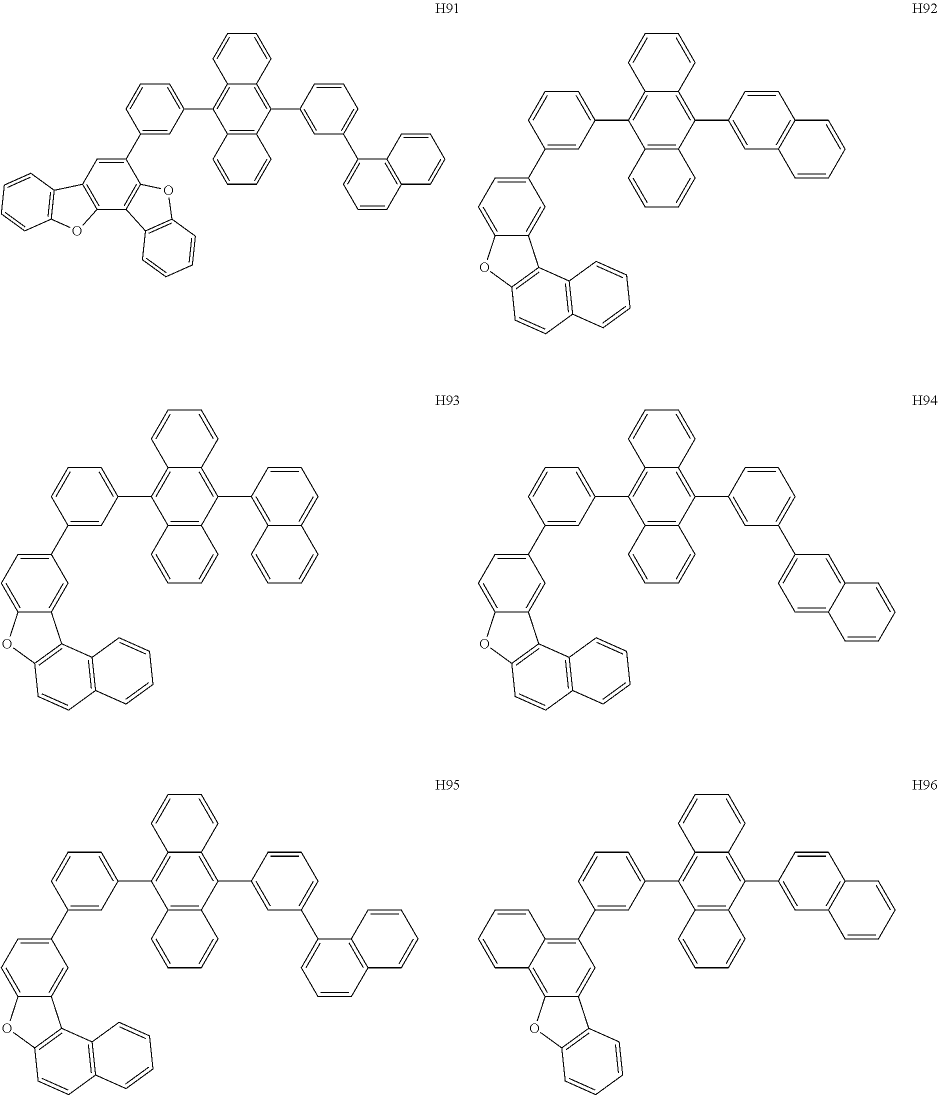

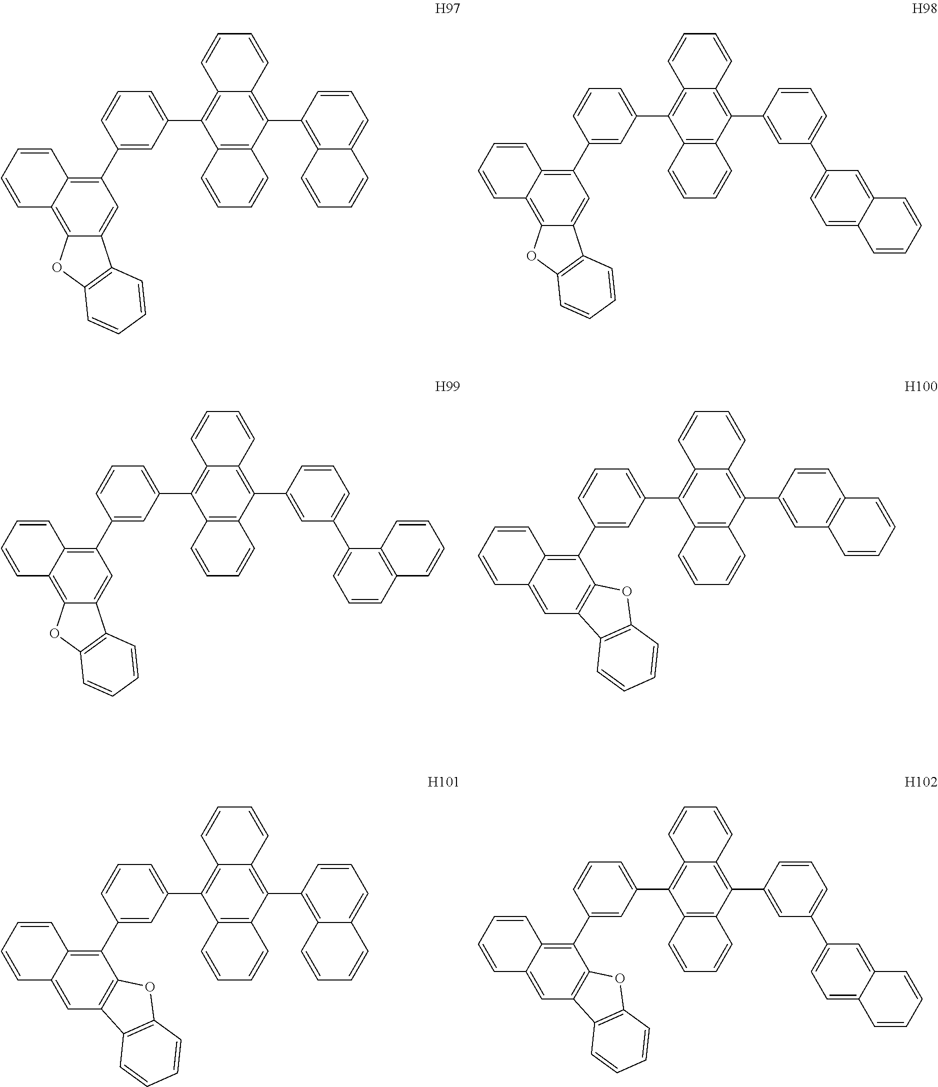

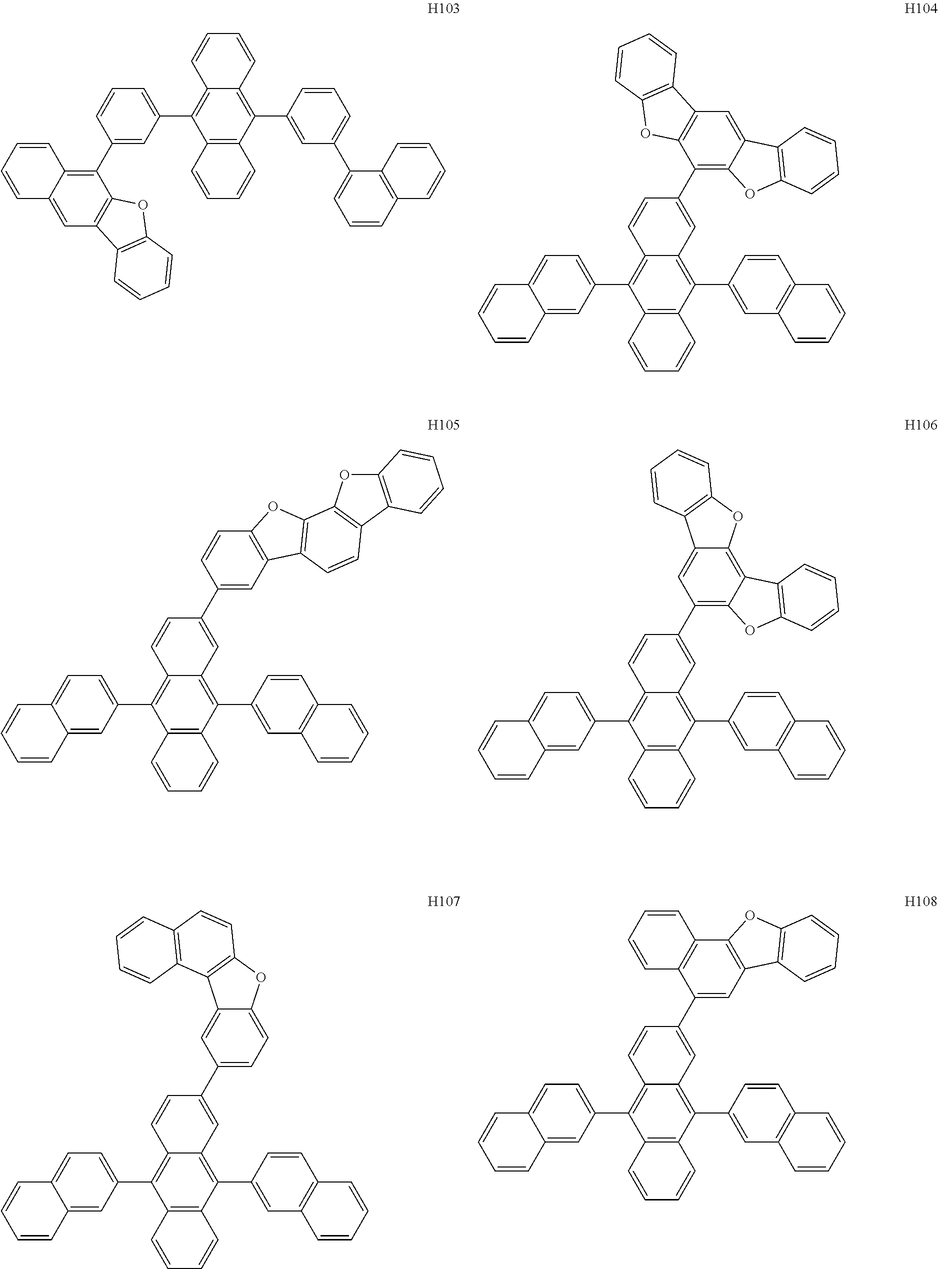

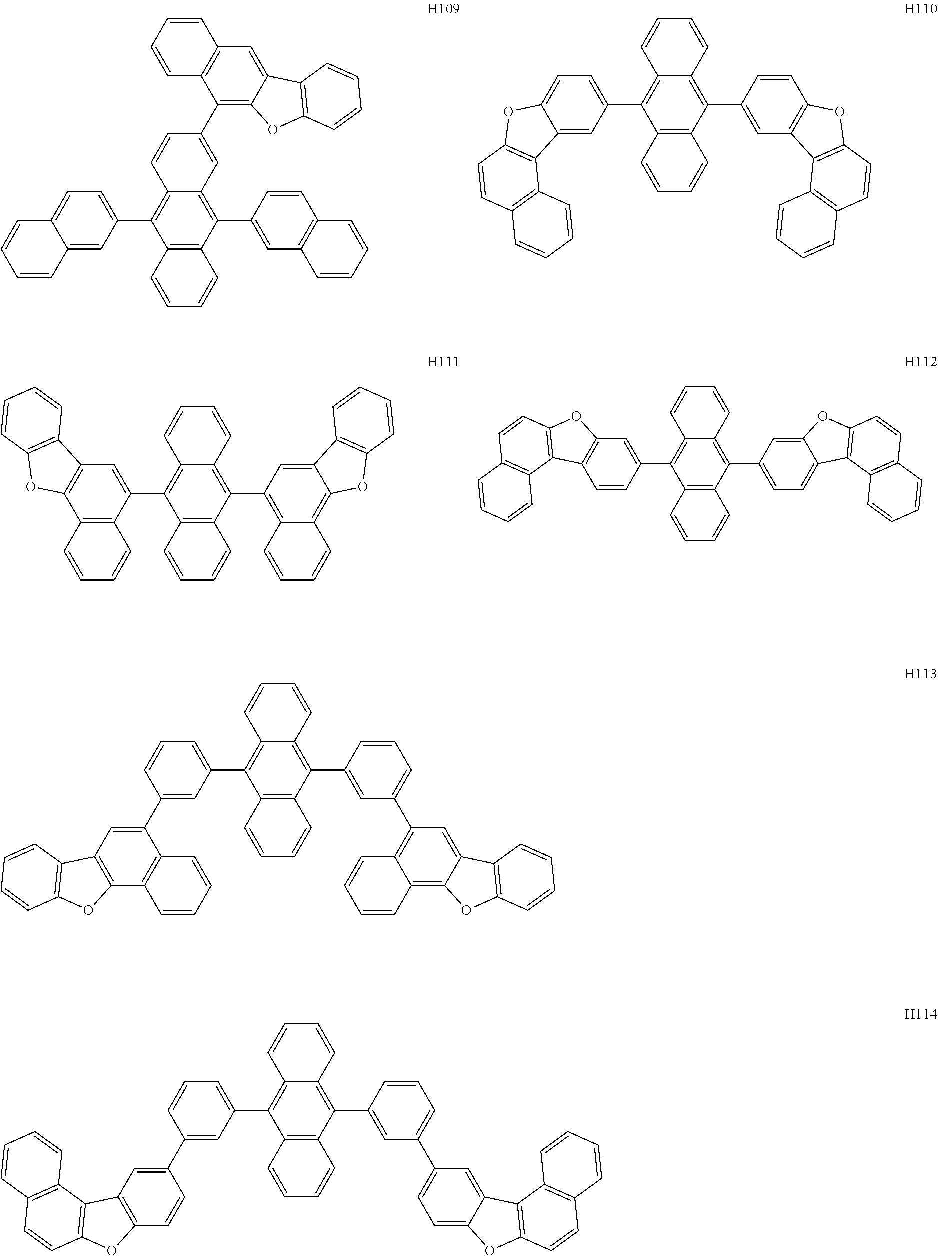

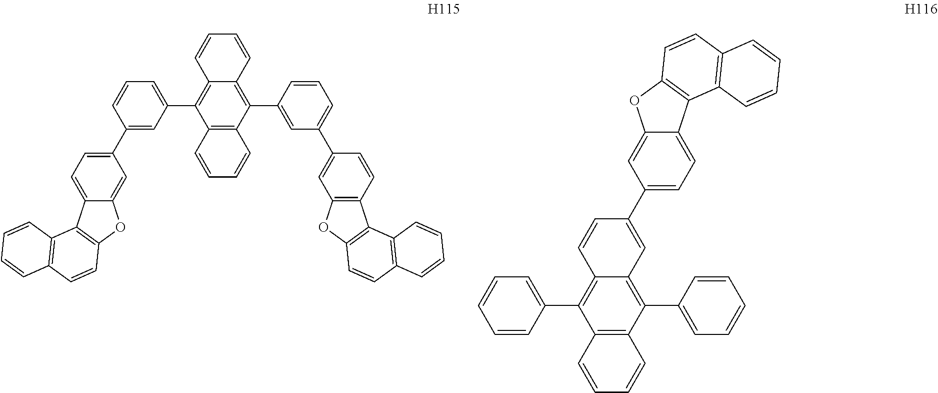 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

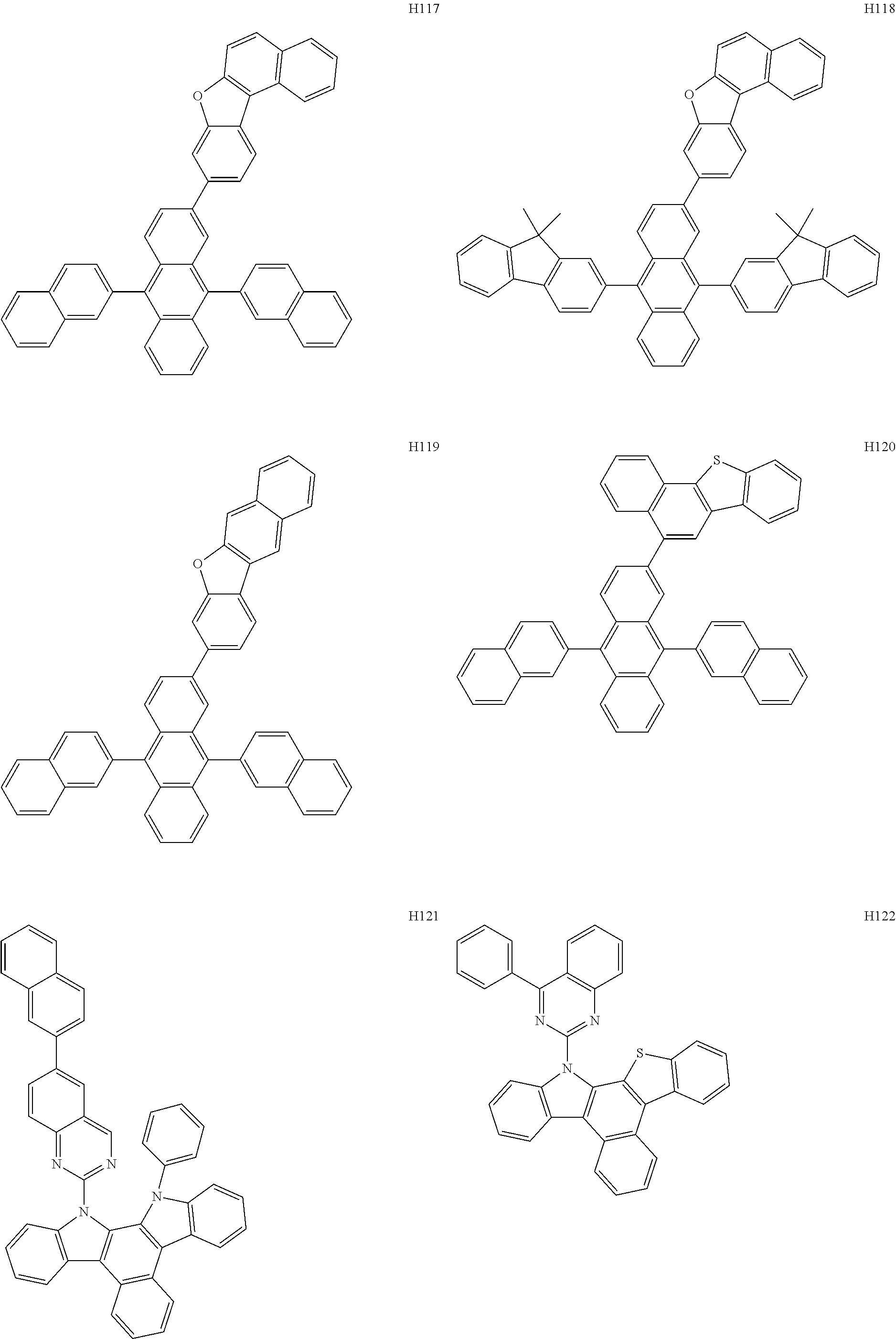

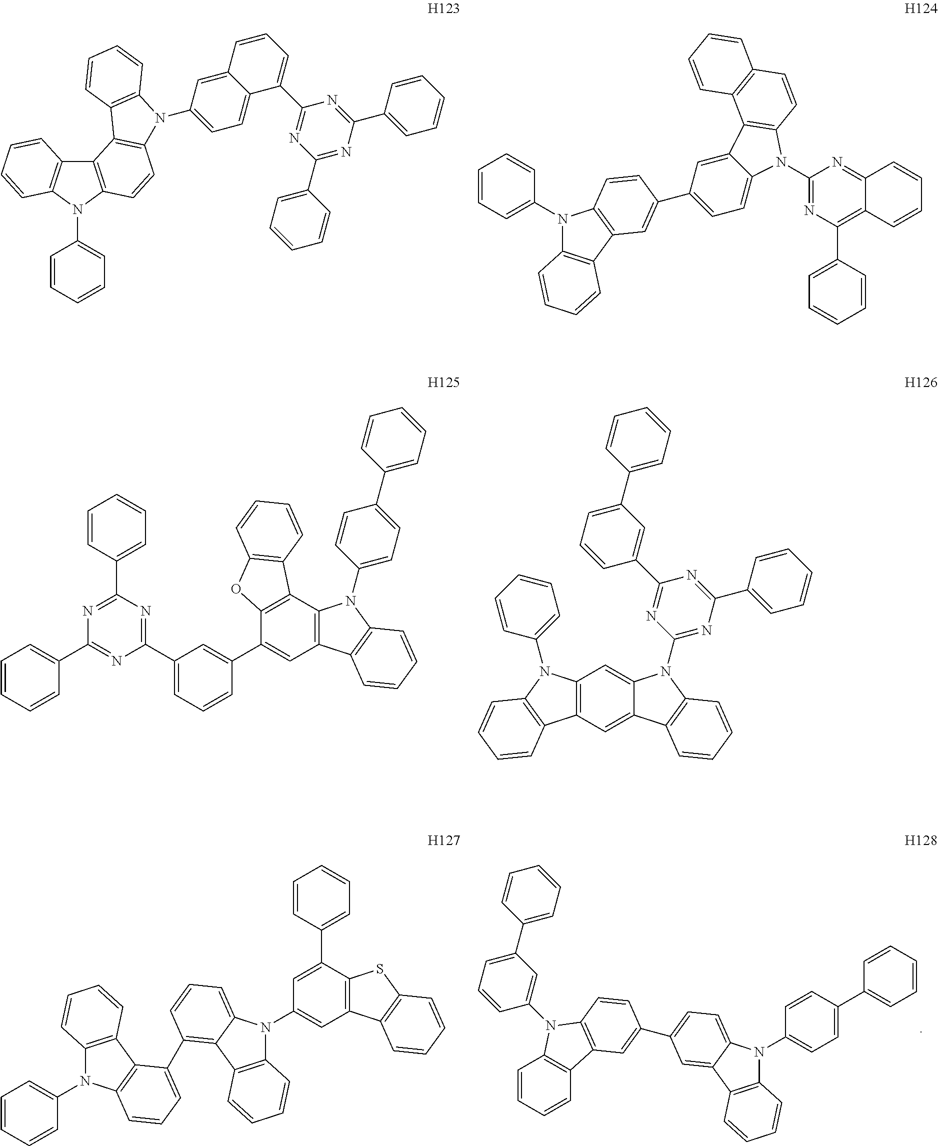

### [Phosphorescent Dopant]

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

M(L₄₀₁)_{xc1}(L₄₀₂)_{xc2} [Formula 401]

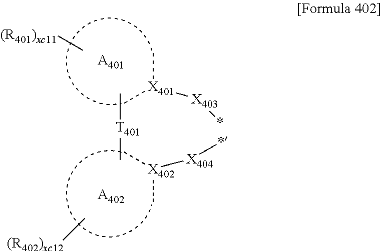

In Formulae 401 and 402,
M may be a transition metal (e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is 2 or more, two or more of L₄₀₁ may be identical to or different from each other,
L₄₀₂ may be an organic ligand, and xc2 may be 0, 1, 2, 3, or 4, wherein when xc2 is 2 or more, two or more of L₄₀₂ may be identical to or different from each other,
X₄₀₁ and X₄₀₂ may each independently be N or C,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)*′, *—C(Q₄₁₁)(Q₄₁₂)-*′, *—C(Q₄₁₁)═C(Q₄₁₂)═*′, *—C(Q₄₁₁)=*′, or *=C=*′,
X₄₀₃ and X₄₀₄ may each independently be a chemical bond (e.g., a covalent bond or a coordination bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
* and *′ in Formula 402 each indicate a binding site to M in Formula 401.

In an embodiment, in Formula 402, X₄₀₁ may be nitrogen and X₄₀₂ may be carbon, or X₄₀₁ and X₄₀₂ may each be nitrogen.

In embodiments, in Formula 401, when xc1 is 2 or more, two ring A₄₀₁(s) in two or more of L₄₀₁ (s) may optionally be linked to each other via T₄₀₂, which is a linking group, or two ring A₄₀₂(s) may optionally be linked to each other via T₄₀₃, which is a linking group (see Compounds PD1 to PD4 and PD7). T₄₀₂ and T₄₀₃ may each independently be the same as described in connection with T₄₀₁.

In Formula 401, L₄₀₂ may be an organic ligand. For example, L₄₀₂ may include a halogen group, a diketone group (e.g., an acetylacetonate group), a carboxylic acid group (e.g., a picolinate group), —C(═O), an isonitrile group, —CN group, a phosphorus group (e.g., a phosphine group, a phosphite group, etc.), or any combination thereof.

In an embodiment, the phosphorescent dopant may include, for example, one of Compounds PD1 to PD39, one of Compounds P40 to P45, or any combination thereof:

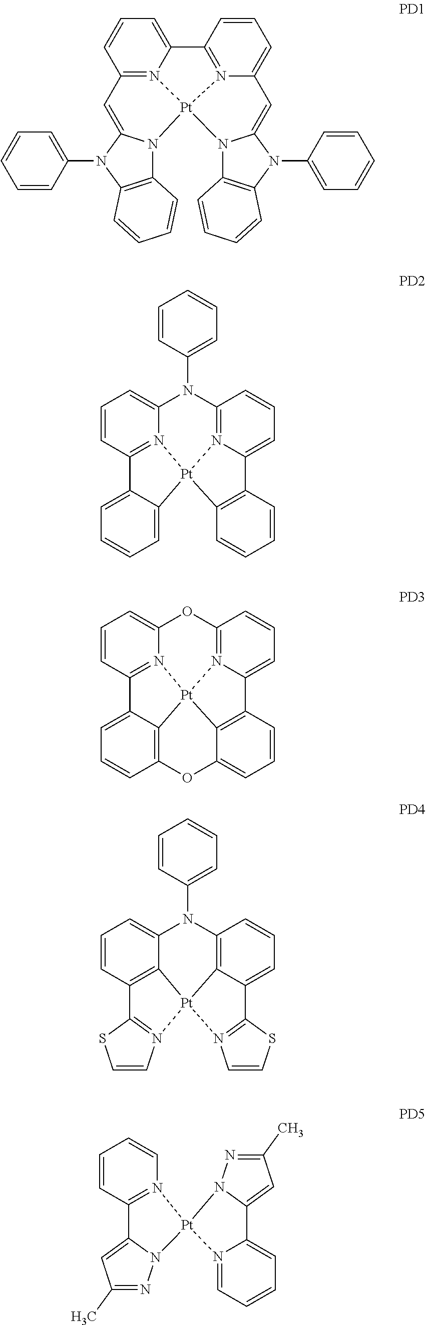

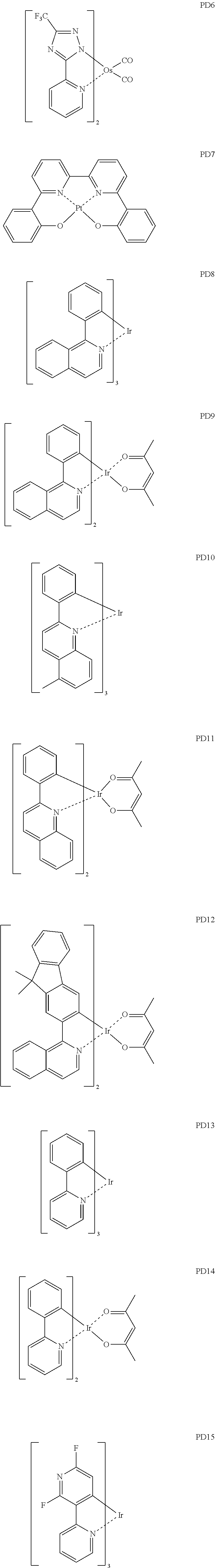

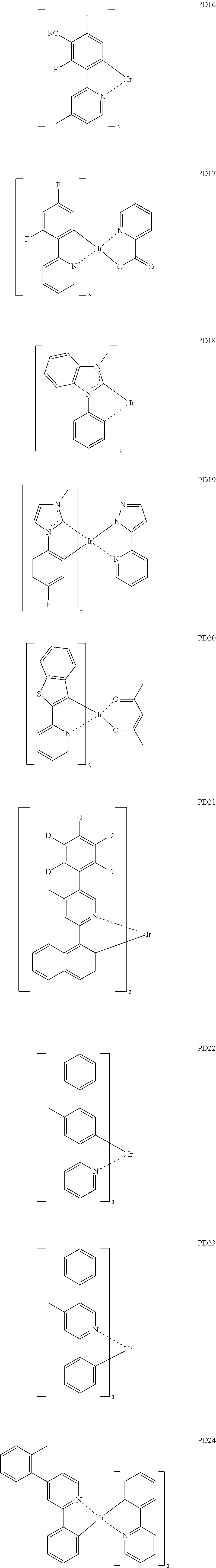

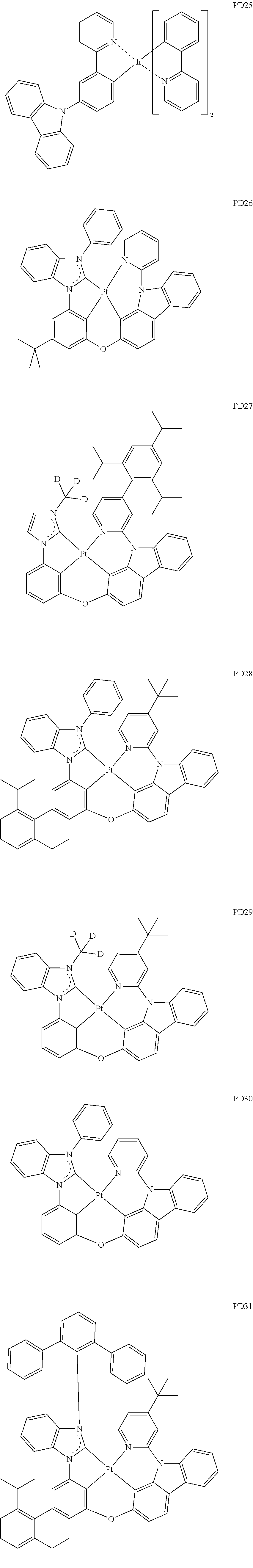

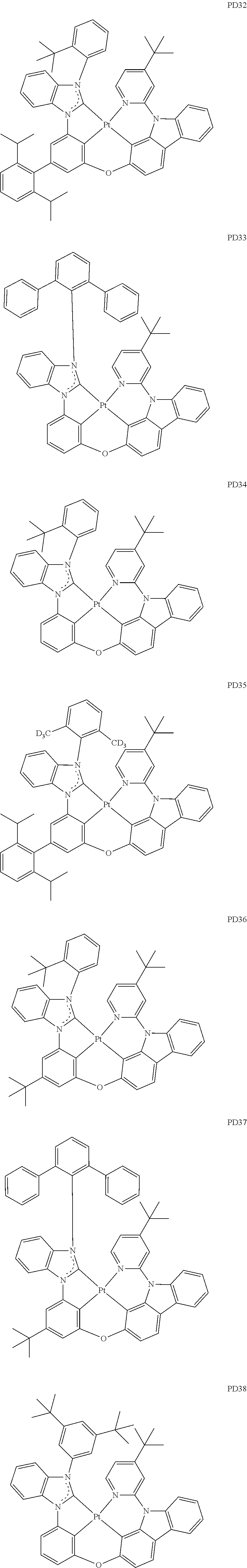

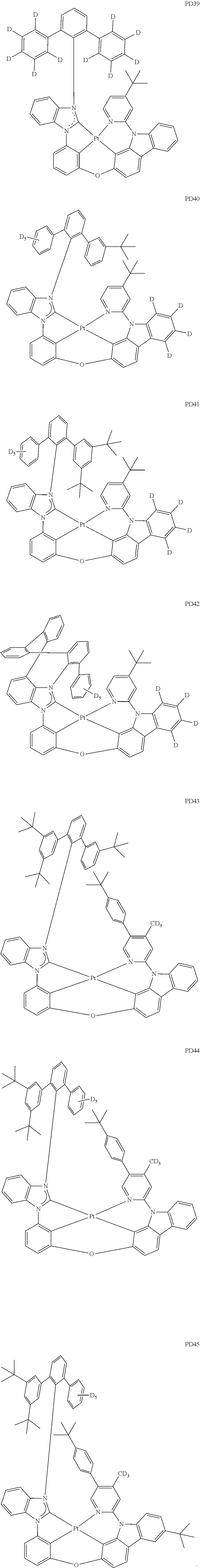

### [Fluorescent Dopant]

The fluorescent dopant may include an amine group-containing compound, a styryl group-containing compound, or any combination thereof.

In an embodiment, the fluorescent dopant may include a compound represented by Formula 501:

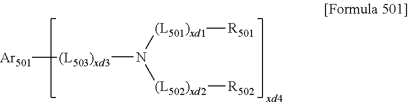

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (e.g., an anthracene group, a chrysene group, a pyrene group, etc.) in which three or more monocyclic groups are condensed together.

In an embodiment, in Formula 501, xd4 may be 2.

In an embodiment, the fluorescent dopant may include: one of Compounds FD1 to FD37; DPVBi; DPAVBi; or any combination thereof:

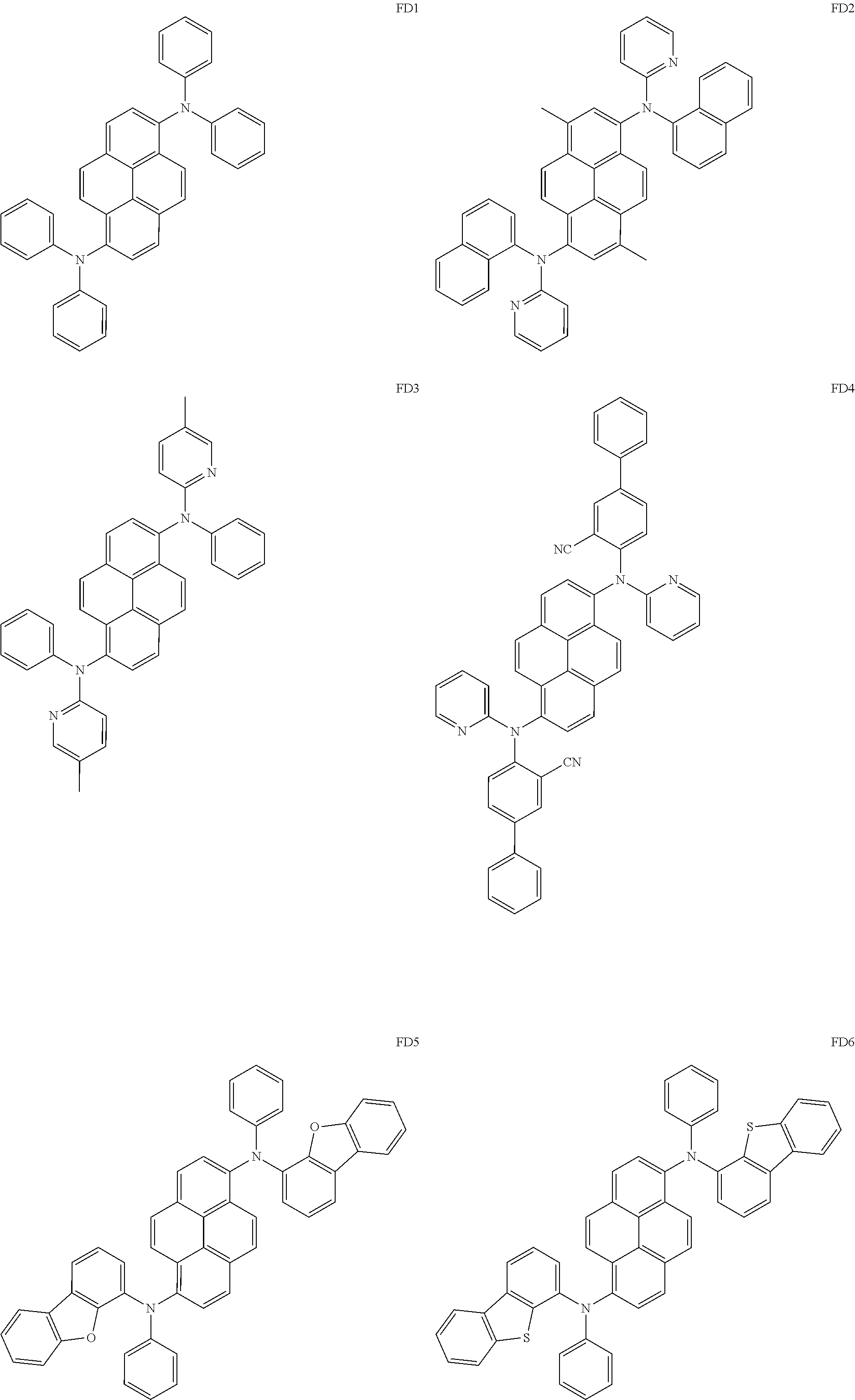

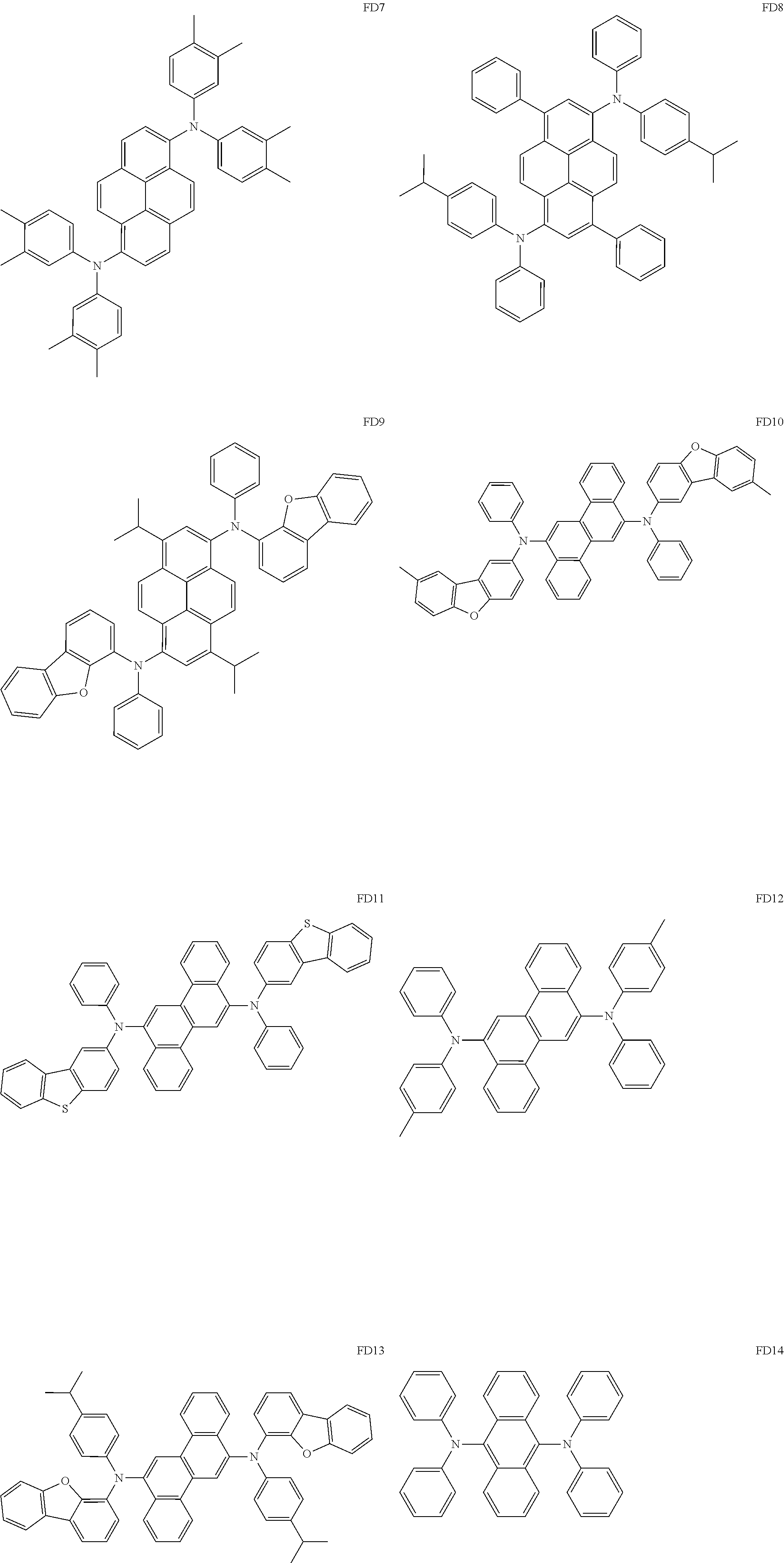

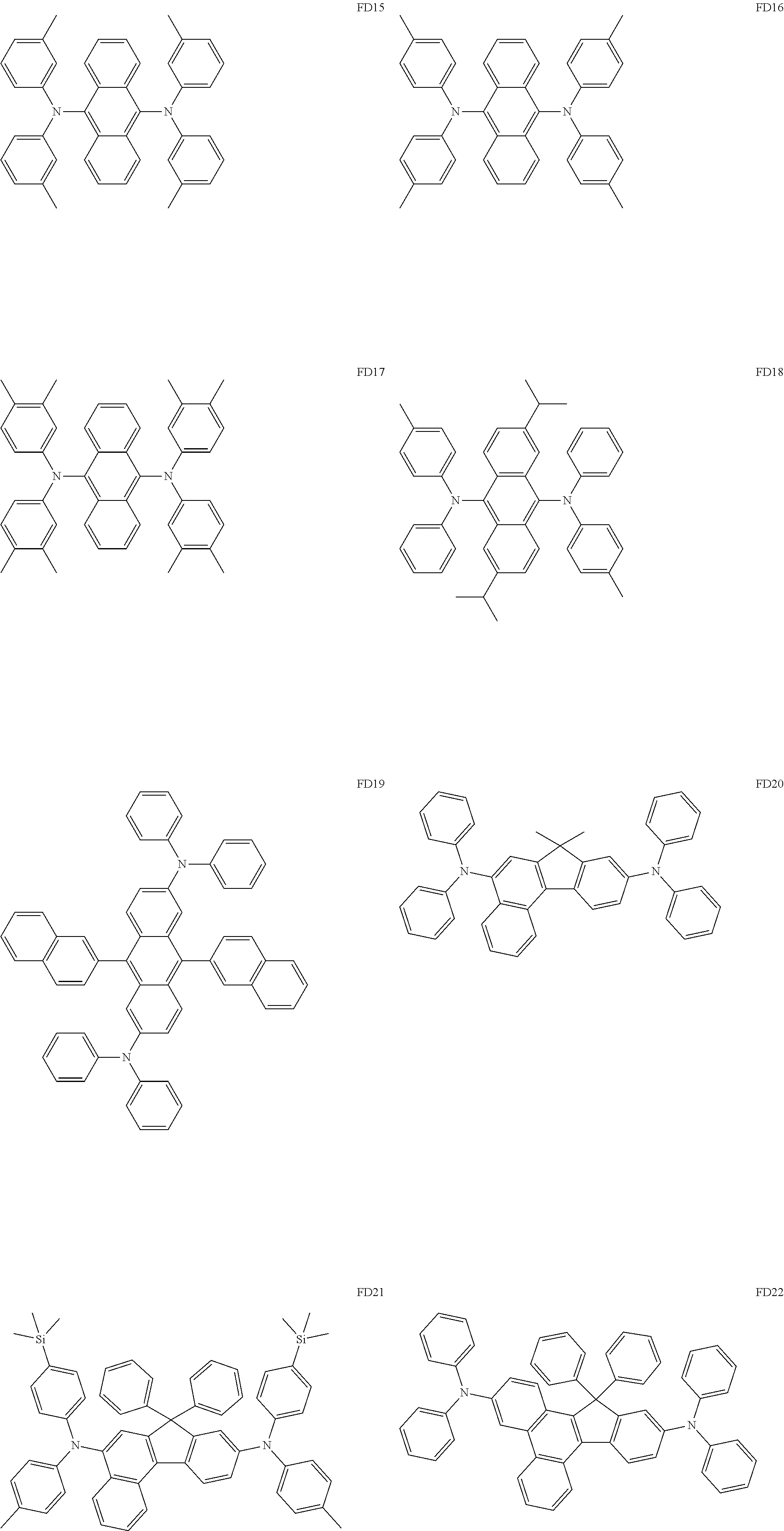

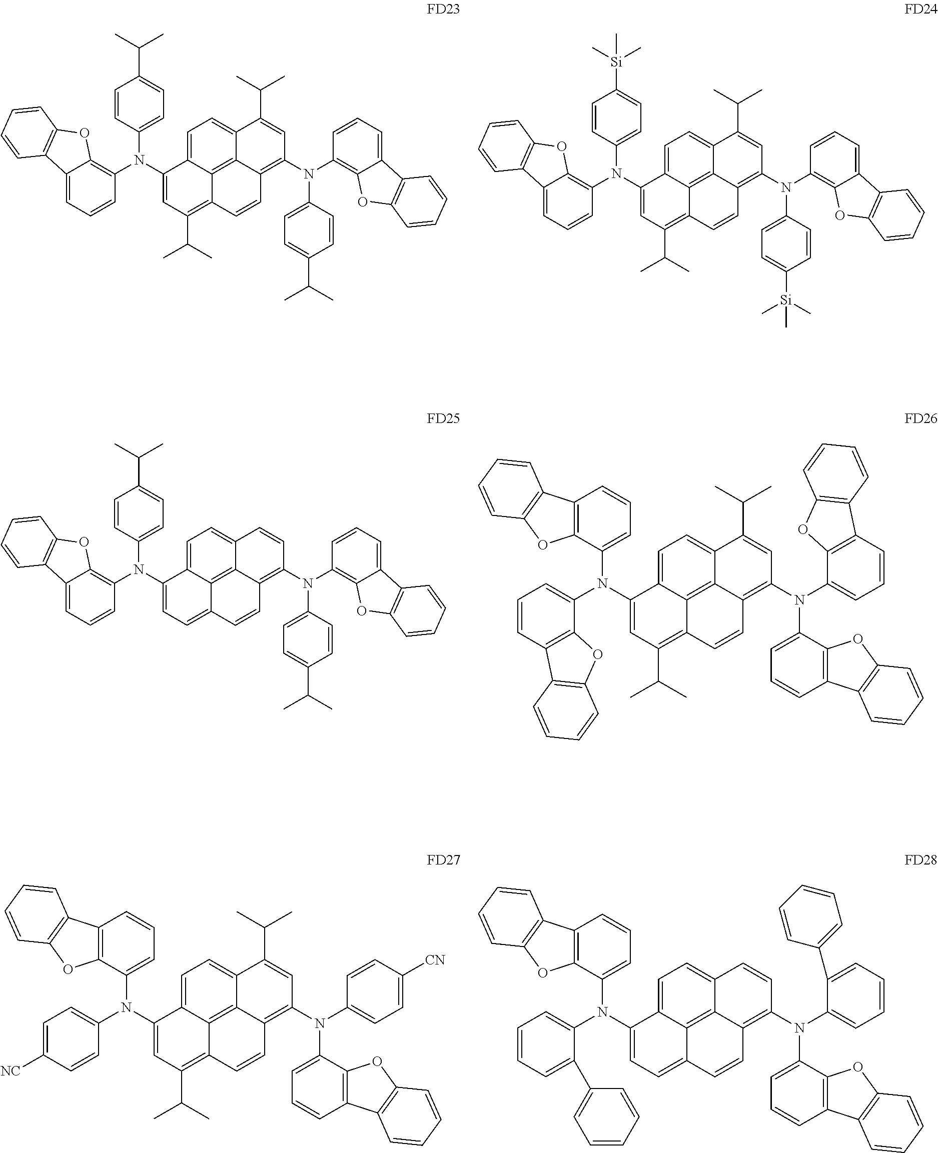

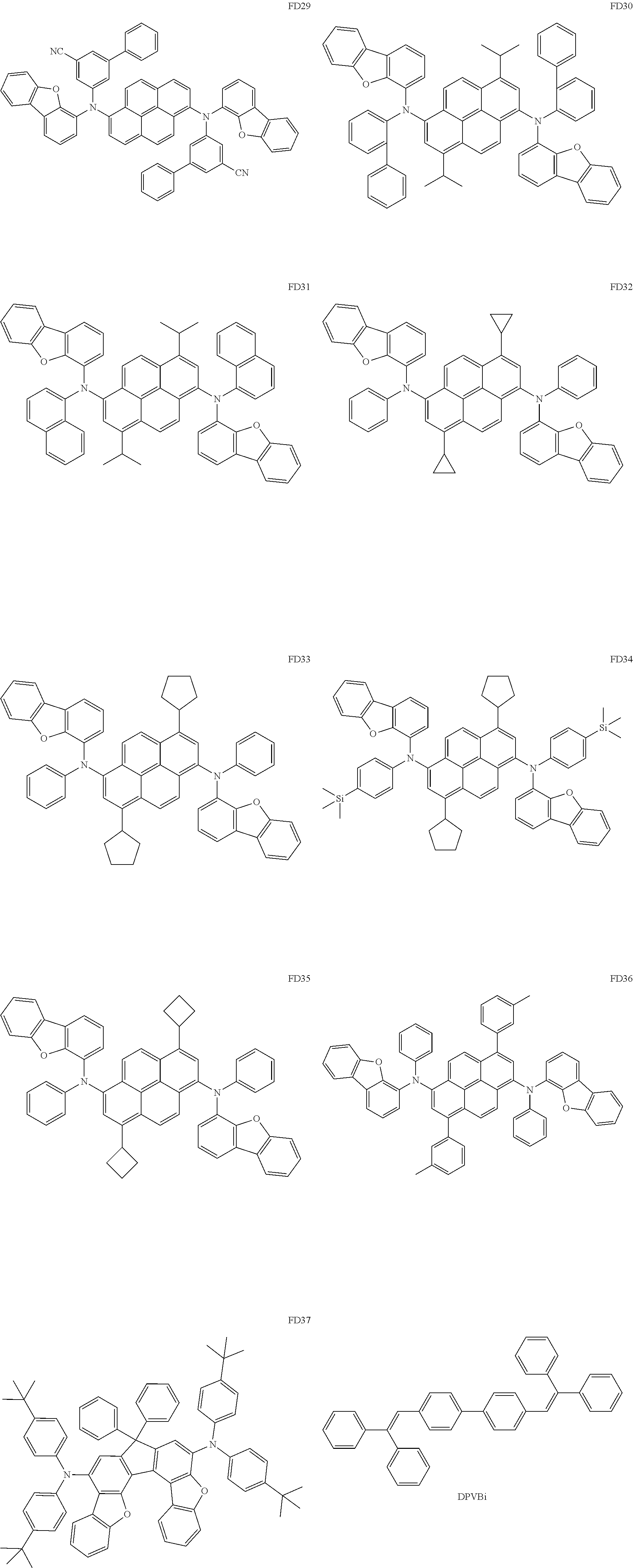

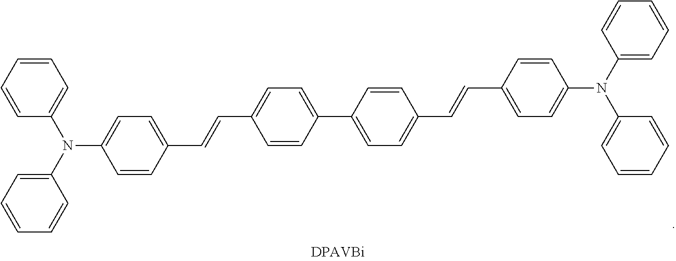 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

### [Delayed Fluorescence Material]

The emission layer may include a delayed fluorescence material.

In the specification, a delayed fluorescence material may be selected from compounds capable of emitting delayed fluorescence based on a delayed fluorescence emission mechanism.

The delayed fluorescence material included in the emission layer may serve as a host or as a dopant, depending on the types of other materials included in the emission layer.

In an embodiment, a difference between a triplet energy level (eV) of the delayed fluorescence material and the singlet energy level (eV) of the delayed fluorescence material may be in a range of about 0 eV to about 0.5 eV. When a difference between the triplet energy level (eV) of the delayed fluorescence material and the singlet energy level (eV) of the delayed fluorescence material is satisfied within the range above, up-conversion from a triplet state to a singlet state of the delayed fluorescence material may effectively occur, and thus, the light-emitting device 20 may have improved luminescence efficiency.

In embodiments, the delayed fluorescence material may include: a material including at least one electron donor (e.g., a π electron-rich C₃-C₆₀ cyclic group, such as a carbazole group, etc.) and at least one electron acceptor (e.g., a sulfoxide group, a cyano group, a π electron-deficient nitrogen-containing C₁-C₆₀ cyclic group, etc.); or a material including a C₈-C₆₀ polycyclic group in which two or more cyclic groups are condensed while sharing boron (B).

In an embodiment, the delayed fluorescence material may include, for example, at least one of Compounds DF1 to DF14:

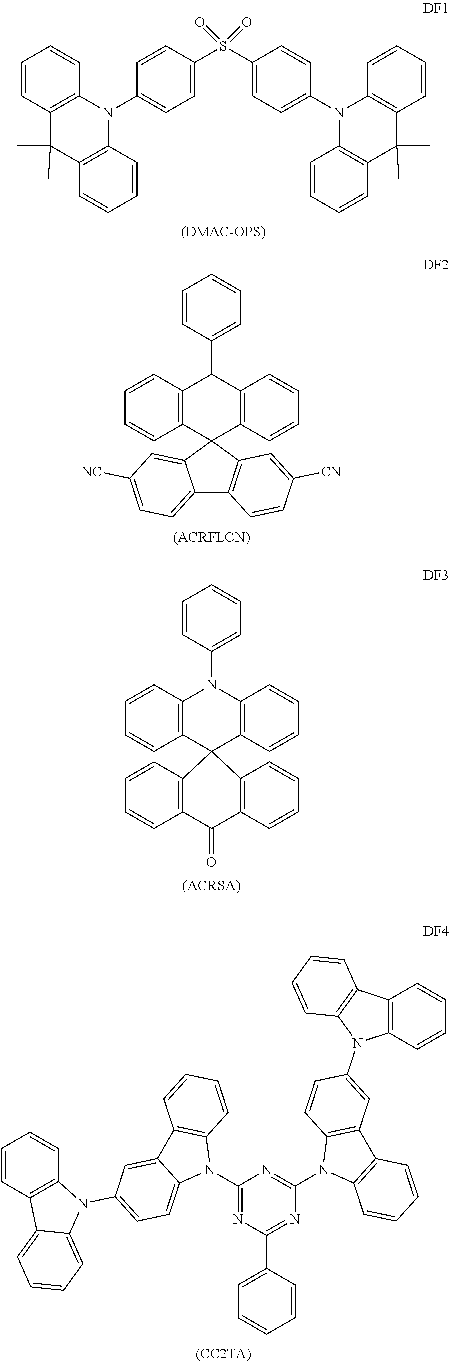

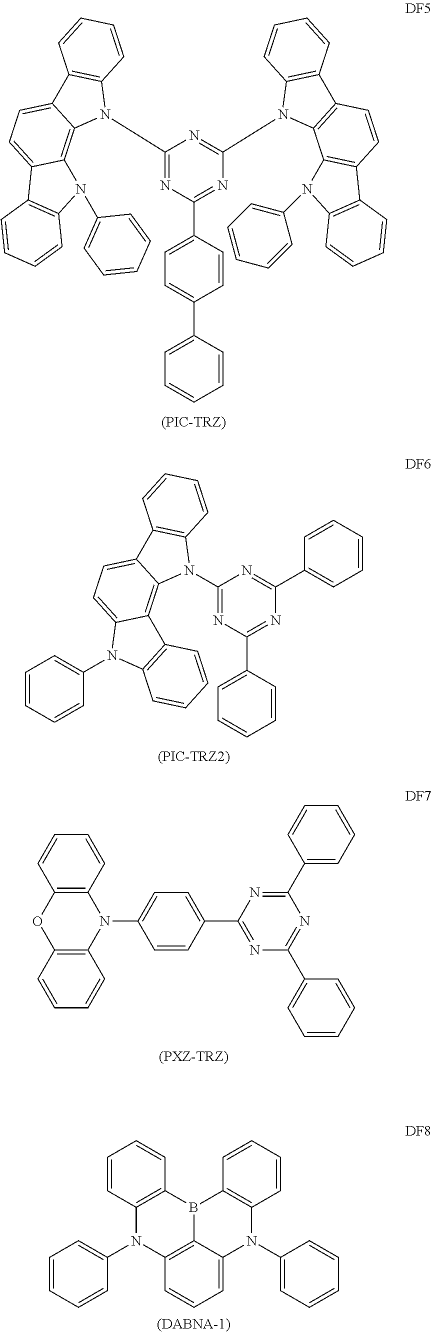

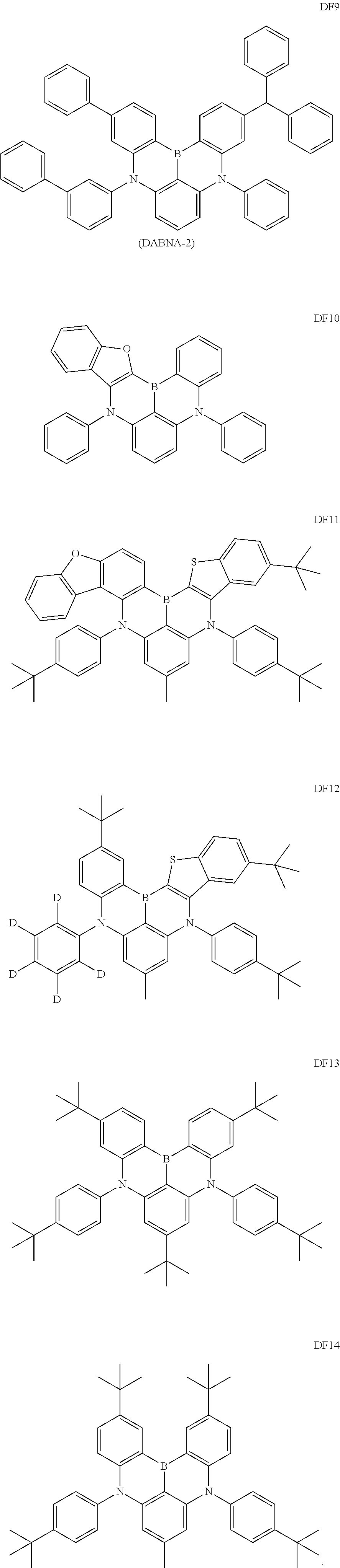

### [Quantum Dots]

The emission layer may include quantum dots.

In the specification, a quantum dot may be a crystal of a semiconductor compound, and may include any material capable of emitting light of various emission wavelengths according to a size of the crystal.

A diameter of a quantum dot may be, for example, in a range of about 1 nm to about 10 nm.

The quantum dots may be synthesized by a wet chemical process, a metal organic chemical vapor deposition process, a molecular beam epitaxy process, or any process similar thereto.

The wet chemical process is a method including mixing a precursor material with an organic solvent and growing quantum dot particle crystals. When the crystals grow, the organic solvent naturally acts as a dispersant coordinated on the surface of the quantum dot crystals and controls the growth of the crystals so that the growth of quantum dot particles may be controlled through a process which costs less and may be more readily performed than vapor deposition methods, such as metal organic chemical vapor deposition (MOCVD) or molecular beam epitaxy (MBE).

A quantum dot may include: a Group II-VI semiconductor compound; a Group III-V semiconductor compound; a Group III-VI semiconductor compound; a Group I-III-VI semiconductor compound; a Group IV-VI semiconductor compound; a Group IV element or compound; or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of a Group III-V semiconductor compound may include: a binary compound, such as GaN, GaP, GaAs, GaSb, AlN, AlP, AlAs, AlSb, InN, InP, InAs, InSb, etc.; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, etc.; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; or any combination thereof. In an embodiment, a Group III-V semiconductor compound may further include a Group II element. Examples of a Group III-V semiconductor compound further including a Group II element may include InZnP, InGaZnP, InAlZnP, etc.

Examples of a Group III-VI semiconductor compound may include: a binary compound, such as GaS, GaSe, Ga₂Se₃, GaTe, InS, InSe, In₂S₃, In₂Se₃, InTe, etc.; a ternary compound, such as InGaS₃, InGaSe₃, etc.; or any combination thereof.

Examples of a Group I-III-VI semiconductor compound may include: a ternary compound, such as AgInS, AgInS₂, CuInS, CuInS₂, CuGaO₂, AgGaO₂, AgAlO₂, etc.; or any combination thereof.

Examples of a Group IV-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, SnPbTe, etc.; a quaternary compound, such as SnPbSSe, SnPbSeTe, SnPbSTe, etc.; or any combination thereof.

Examples of a Group IV element or compound may include: a single element material, such as Si, Ge, etc.; a binary compound, such as SiC, SiGe, etc.; or any combination thereof.

Each element included in a multi-element compound, such as a binary compound, a ternary compound, or a quaternary compound, may be present in a particle at a uniform concentration or at a non-uniform concentration.

In embodiments, the quantum dot may have a single structure in which the concentration of each element in the quantum dot is uniform, or the quantum dot may have a core-shell structure. For example, a material included in the core and a material included in the shell may be different from each other.

The shell of a quantum dot may serve as a protective layer that prevents chemical degeneration of the core to maintain semiconductor characteristics, and/or may serve as a charging layer that imparts electrophoretic characteristics to the quantum dots. The shell may be single-layered or multi-layered. An interface between the core and the shell may have a concentration gradient in which the concentration of an element that is present in the shell decreases toward the core.

A shell of a quantum dot may include a metal oxide, a metalloid oxide, a non-metal oxide, a semiconductor compound, or any combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like; a ternary compound, such as MgAl₂O₄, CoFe₂O₄, NiFe₂O₄, CoMn₂O₄, and the like; or any combination thereof.

Examples of a semiconductor compound may include, as described above: a Group II-VI semiconductor compound; a Group III-V semiconductor compound; a Group III-VI semiconductor compound; a Group I-III-VI semiconductor compound; a Group IV-VI semiconductor compound; or any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dots may be equal to or less than about 45 nm. For example, a FWHM of an emission wavelength spectrum of the quantum dots may be equal to or less than about 40 nm. For example, a FWHM of an emission wavelength spectrum of the quantum dots may be equal to or less than about 30 nm. Within these ranges, color purity or color reproducibility of the quantum dots may be improved. Light emitted through the quantum dots may be emitted in all directions, so that a wide viewing angle may be improved.

In embodiments, a quantum dot may be in the form of a spherical particle, a pyramidal particle, a multi-arm particle, a cubic nanoparticle, a nanotube particle, a nanowire particle, a nanofiber particle, a nanoplate particle, or the like.

By controlling the size of a quantum dot, an energy band gap may be adjustable so that light having various wavelength bands may be obtained from an emission layer including the quantum dot. Accordingly, by using quantum dots of different sizes, a light-emitting device that emits light of various wavelengths may be implemented. In an embodiment, the size of quantum dots may be selected to emit red light, green light, and/or blue light. In an embodiment, the size of quantum dots may be configured to emit white light by combining light of various colors.

### [Electron Transport Region in Interlayer 130]

The electron transport region may have a structure consisting of a layer consisting of a single material, a structure consisting of a layer including different materials, or a structure including multiple layers including different materials.

The electron transport region may include a buffer layer, a hole blocking layer, an electron control layer, an electron transport layer, an electron injection layer, or any combination thereof.

In embodiments, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure may be stacked from the emission layer in its respective stated order, but the structure of the electron transport region is not limited thereto.

In an embodiment, the electron transport region (e.g., a buffer layer, a hole blocking layer, an electron control layer, or an electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁. [Formula 601]

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, when xe11 is 2 or more, two or more of Ar₆₀₁ may be linked to each other via a single bond.

In an embodiment, in Formula 601, Ar₆₀₁ may be a substituted or unsubstituted anthracene group.

In embodiments, the electron transport region may include a compound represented by Formula 601-1:

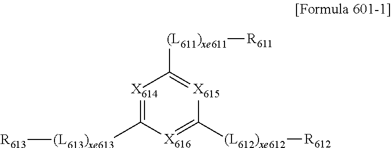

In Formula 601-1,
X₆₁₄ may be N or C(R₆₁₄), X₆₁₅ may be N or C(R₆₁₅), and X₆₁₆ may be N or C(R₆₁₆), wherein at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formulae 601 and 601-1, xe1 and xe611 to xe613 may each independently be 0, 1, or 2.

In embodiments, the electron transport region may include: one of Compounds ET1 to ET45; 2,9-dimethyl-4,7-diphenyl-1,10-phenanthroline (BCP); 4,7-diphenyl-1,10-phenanthroline (Bphen); Alq₃; BAlq; TAZ; NTAZ; or any combination thereof:

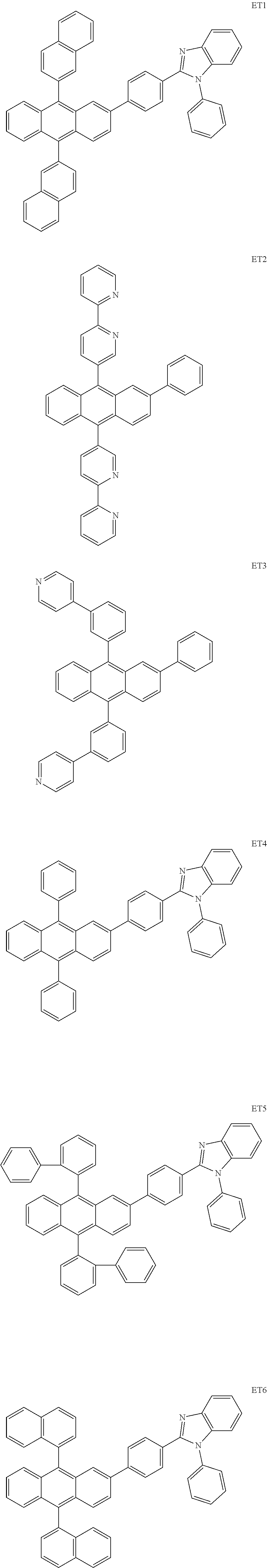

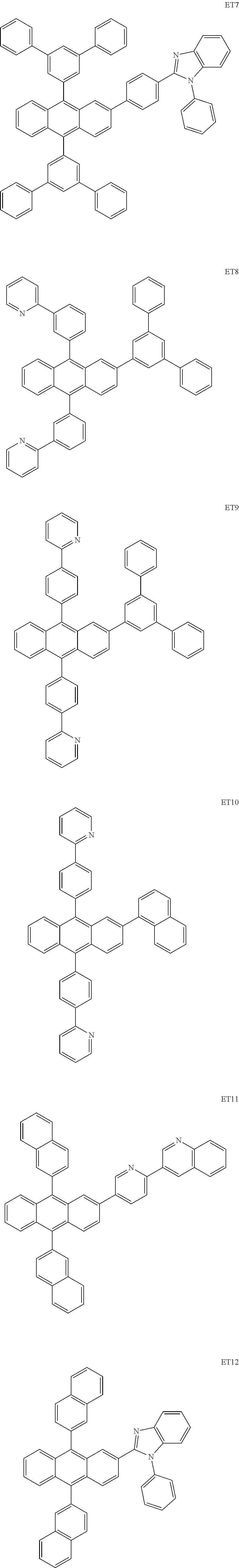

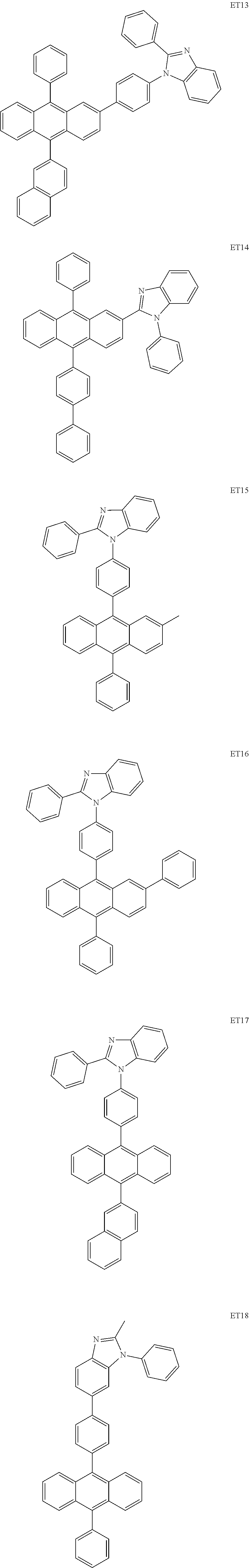 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

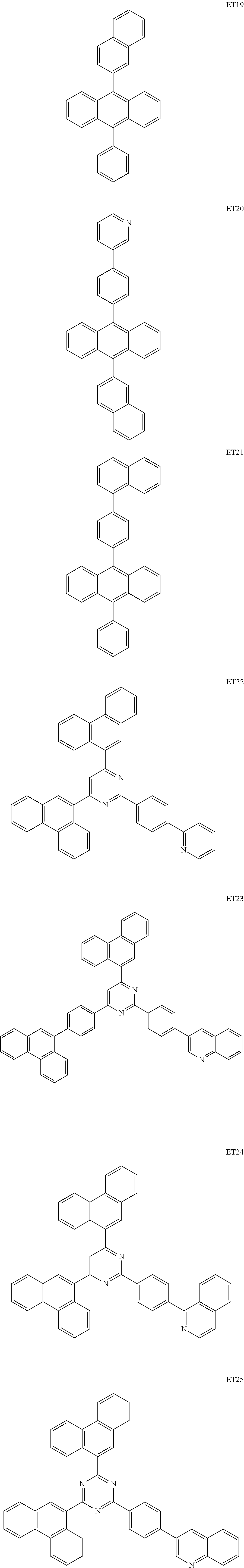

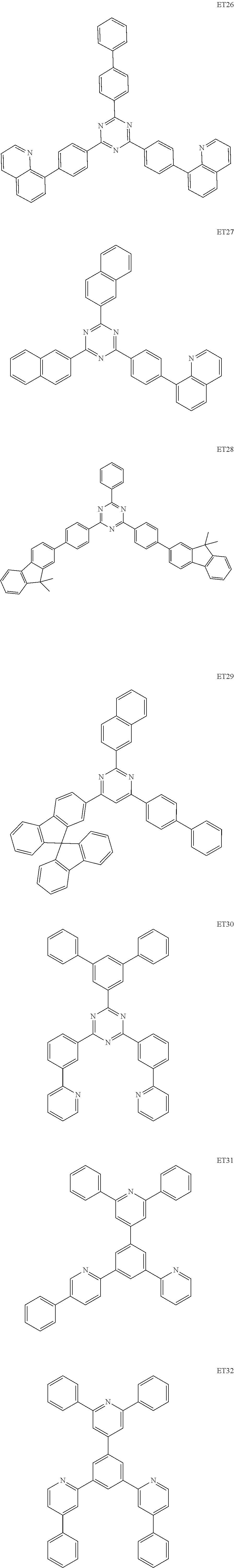

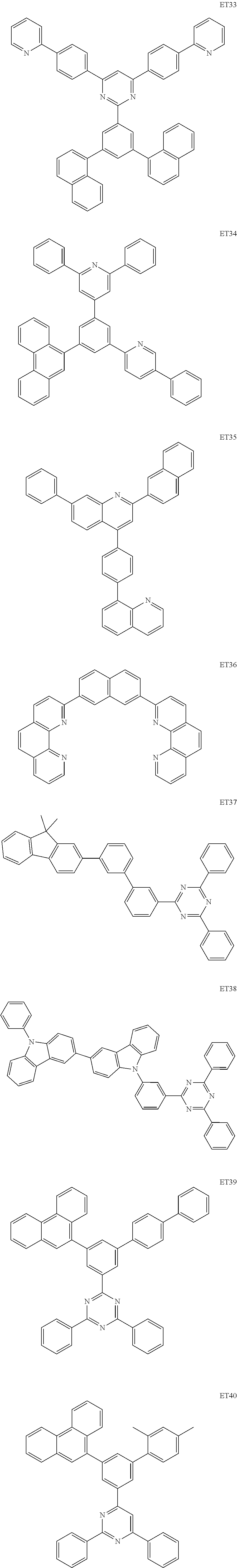

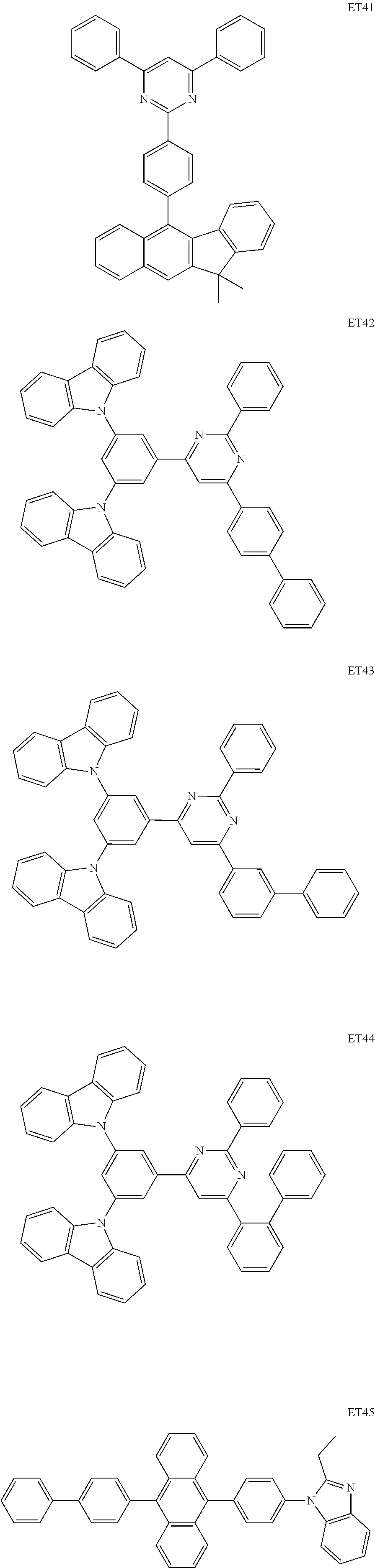 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

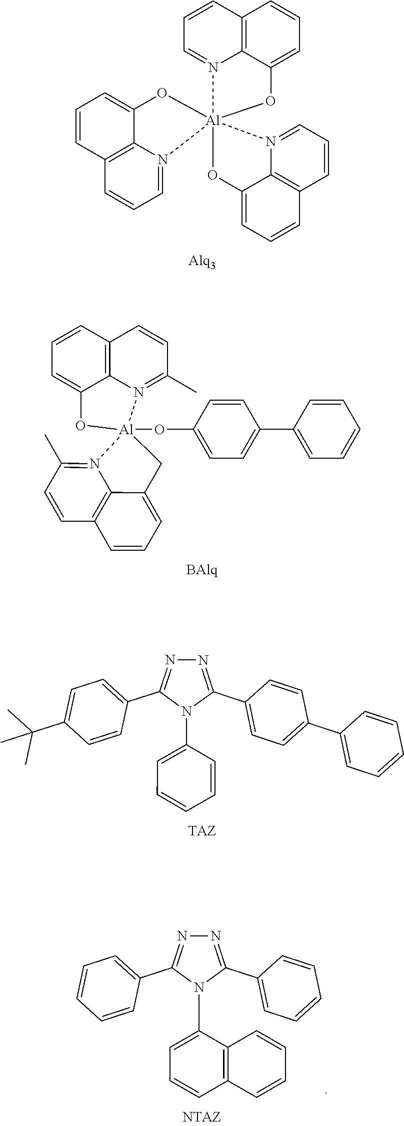

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region (e.g., an electron transport layer in the electron transport region) may further include, in addition to the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion; and a metal ion of the alkaline earth metal complex may be a Be ion, a Mg ion, a Ca ion, a Sr ion, or a Ba ion.

A ligand coordinated with a metal ion of an alkali metal complex or a metal ion of an alkaline earth-metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) or Compound ET-D2:

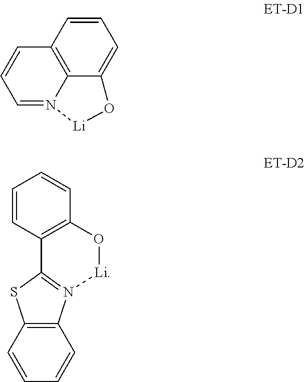

The electron transport region may include an electron injection layer that facilitates the injection of electrons from the second electrode 150. The electron injection layer may directly contact the second electrode 150.

The electron injection layer may have a structure consisting of a layer consisting of a single material, a structure consisting of a layer including different materials, or a structure including multiple layers including different materials.

In an embodiment, the electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include L₁, Na, K, Rb, Cs, or any combination thereof.

The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be oxides, halides (e.g., fluorides, chlorides, bromides, or iodides), or tellurides of the alkali metal, the alkaline earth metal, and the rare earth metal, or any combination thereof.

The alkali metal-containing compound may include: an alkali metal oxide, such as Li₂O, Cs₂O, K₂O, and the like; an alkali metal halide, such as LiF, NaF, CsF, KF, LiI, NaI, CsI, KI, and the like; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include: an alkali metal ion, an alkaline earth metal ion, or a rare earth metal ion; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (e.g., a compound represented by Formula 601).

In embodiments, the electron injection layer may consist of an alkali metal-containing compound (e.g., an alkali metal halide); or the electron injection layer may consist of an alkali metal-containing compound (e.g., an alkali metal halide), and an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, and the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within any of these ranges, satisfactory electron injection characteristics may be obtained without a substantial increase in driving voltage.

### [Second Electrode 150]

The second electrode 150 is arranged on the interlayer 130 having the aforementioned structure. The second electrode 150 may be a cathode, which is an electron injection electrode. When the second electrode 150 is a cathode, a material for forming the second electrode 150 may include a material having a low-work function, such as a metal, an alloy, an electrically conductive compound, or any combination thereof.

The second electrode 150 may include Li, Ag, Mg, Al, Al—Li, Ca, Mg—In, Mg—Ag, Yb, Ag—Yb, ITO, IZO, or any combination thereof. The second electrode 150 may be a transmissive electrode, a semi-transmissive electrode, or a reflective electrode.

The second electrode 150 may have a single-layer structure or a multi-layer structure.

### [Capping Layer]

The light-emitting device 10 may include a first capping layer arranged outside the first electrode 110, and/or a second capping layer arranged outside the second electrode 150. In embodiments, the light-emitting device 10 may have a structure in which the first capping layer, the first electrode 110, the interlayer 130, and the second electrode 150 are stacked in the stated order, a structure in which the first electrode 110, the interlayer 130, the second electrode 150, and the second capping layer are stacked in the stated order, or a structure in which the first capping layer, the first electrode 110, the interlayer 130, the second electrode 150, and the second capping layer are stacked in the stated order.

Light generated in an emission layer of the interlayer 130 of the light-emitting device 10 may be extracted through the first electrode 110, which may be a semi-transmissive electrode or a transmissive electrode, and through the first capping layer to the outside. Light generated in an emission layer of the interlayer 130 of the light-emitting device 10 may be extracted through the second electrode 150, which may be a semi-transmissive electrode or a transmissive electrode, and through the second capping layer to the outside.

The first capping layer and the second capping layer may each increase external emission efficiency according to the principle of constructive interference. Accordingly, light extraction efficiency of the light-emitting device 10 may be increased, and accordingly, the luminescence efficiency of the light-emitting device 10 may be improved.

The first capping layer and the second capping layer may each include a material having a refractive index equal to or greater than about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. In an embodiment, at least one of the first capping layer and the second capping layer may each independently include an amine group-containing compound.

In embodiments, at least one of the first capping layer and the second capping layer may each independently include a compound represented by Formula 201, a compound represented by Formula 202, or any combination thereof.

In embodiments, at least one of the first capping layer and the second capping layer may each independently include: one of Compounds HT28 to HT33; one of Compounds CP1 to CP6; β-NPB; or any combination thereof:

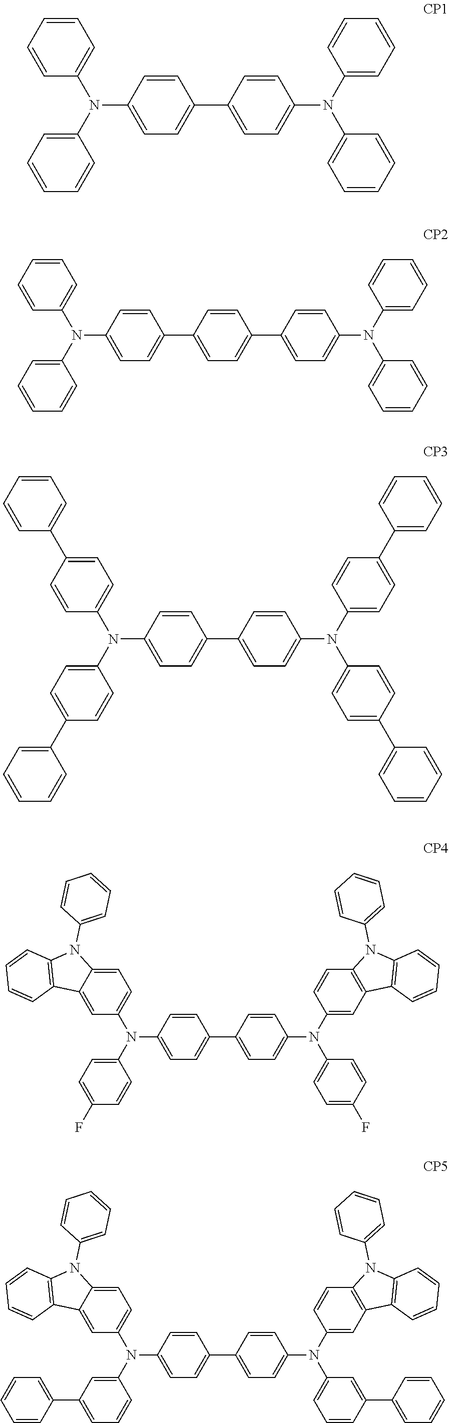 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

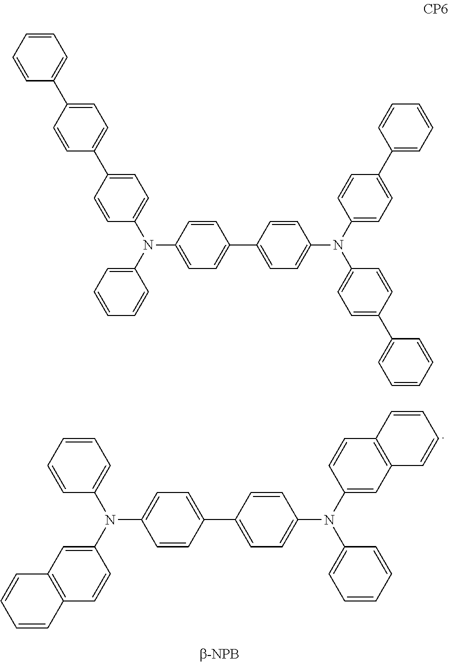

### [Film]

The organometallic compound represented by Formula 1 may be included in various films. Accordingly, another embodiment provides a film including an organometallic compound represented by Formula 1. The film may be, for example, an optical member (or a light control means) (e.g., a color filter, a color conversion member, a capping layer, a light extraction efficiency enhancement layer, a selective light absorbing layer, a polarizing layer, a quantum dot-containing layer, or like), a light blocking member (e.g., a light reflective layer, a light absorbing layer, or the like), or a protective member (e.g., an insulating layer, a dielectric layer, or the like).

### [Electronic Apparatus]

The light-emitting device may be included in various electronic apparatuses. For example, an electronic apparatus including the light-emitting device may be a light-emitting apparatus, an authentication apparatus, and the like.

The electronic apparatus (e.g., a light-emitting apparatus) may further include a color filter, a color conversion layer, or a color filter and a color conversion layer, in addition to the light-emitting device. The color filter and/or the color conversion layer may be arranged in at least one direction in which light emitted from the light-emitting device travels. For example, the light emitted from the light-emitting device may be blue light or white light. Further details on the light-emitting device may be the same as described herein. In an embodiment, the color conversion layer may include quantum dots. The quantum dots may be, for example, the same as the quantum dots as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include: a first area emitting first color light; a second area emitting second color light; and/or a third area emitting third color light, wherein the first color light, the second color light, and/or the third color light may have different maximum emission wavelengths from one another. For example, the first color light may be red light, the second color light may be green light, and the third color light may be blue light. In an embodiment, the color filter areas (or the color conversion areas) may include quantum dots. For example, the first area may include red quantum dots, the second area may include green quantum dots, and the third area may not include quantum dots. Further details on the quantum dots may be the same as described herein. The first area, the second area, and/or the third area may each further include a scatterer.

In an embodiment, the light-emitting device may emit first light, the first area may absorb the first light to emit first-first color light, the second area may absorb the first light to emit second-first color light, and the third area may absorb the first light to emit third-first color light. The first-first color light, the second-first color light, and the third-first color light may have different maximum emission wavelengths from one another. For example, the first light may be blue light, the first-first color light may be red light, the second-first color light may be green light, and the third-first color light may be blue light.

The electronic apparatus may further include a thin-film transistor, in addition to the aforementioned light-emitting device. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, and the like.

The active layer may include crystalline silicon, amorphous silicon, an organic semiconductor, an oxide semiconductor, or the like.

The electronic apparatus may further include a sealing portion for sealing the light-emitting device. The sealing portion may be arranged between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate that includes a transparent glass substrate or a plastic substrate. The sealing portion may be a thin-film encapsulation layer that includes at least one of an organic layer and an inorganic layer. When the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of a functional layer may include a touch screen layer, a polarizing layer, and the like. The touch screen layer may be a pressure-sensitive touch screen layer, a capacitive touch screen layer, or an infrared touch screen layer.

The authentication apparatus may be, for example, a biometric authentication apparatus that authenticates an individual by using biometric information of a living body (e.g., fingertips, pupils, etc.).

The authentication apparatus may further include, in addition to the light-emitting device as described above, a biometric information collector.

The electronic apparatus may be applied to various displays, light sources, lighting, personal computers (e.g., mobile personal computers), mobile phones, digital cameras, electronic organizers, electronic dictionaries, electronic game machines, medical instruments (e.g., electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (e.g., meters for a vehicle, an aircraft, and a vessel), projectors, and the like.

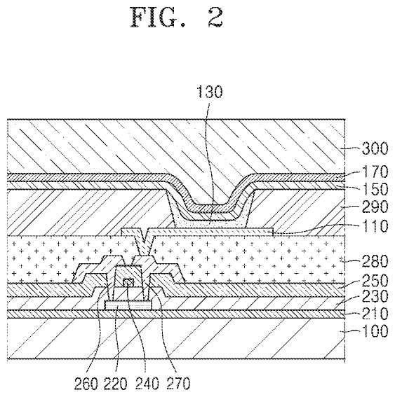

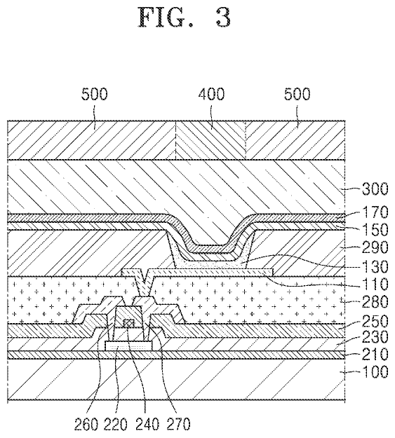

### [Description of FIGS. 2 and 3]

FIG. 2 is a schematic cross-sectional view of an electronic apparatus according to an embodiment.

The electronic apparatus (for example, a light-emitting apparatus) of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100, and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 and between the gate electrode 240 and the drain electrode 270, to insulate these electrodes from one another.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280. The passivation layer 280 may include an inorganic insulating film, an organic insulating film, or any combination thereof. The light-emitting device may be provided on the passivation layer 280. The light-emitting device may include the first electrode 110, the interlayer 130, and the second electrode 150.

The first electrode 110 may be arranged on the passivation layer 280. The passivation layer 280 may not completely cover the drain electrode 270 and may expose a portion of the drain electrode 270. The first electrode 110 may be connected (for example, electrically connected) to the exposed portion of the drain electrode 270.

A pixel defining layer 290 including an insulating material may be arranged on the first electrode 110. The pixel defining layer 290 may expose a region of the first electrode 110, and the interlayer 130 may be formed in the exposed region of the first electrode 110. The pixel defining layer 290 may be a polyimide-based organic film or a polyacrylic-based organic film. Although not shown in FIG. 2, at least some layers of the interlayer 130 may extend beyond the upper portion of the pixel defining layer 290 to be provided in the form of a common layer.

The second electrode 150 may be arranged on the interlayer 130, and a capping layer 170 may be further included on the second electrode 150. The capping layer 170 may be formed to cover the second electrode 150.

The encapsulation portion 300 may be arranged on the capping layer 170. The encapsulation portion 300 may be arranged on the light-emitting device to protect the light-emitting device from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy-based resin (e.g., aliphatic glycidyl ether (AGE), etc.), or any combination thereof; or any combination of the inorganic film and the organic film.

FIG. 3 is a schematic cross-sectional view of an electronic apparatus according to another embodiment.

The electronic apparatus (for example, a light-emitting apparatus) of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, a light-emitting device included in the electronic apparatus of FIG. 3 may be a tandem light-emitting device.

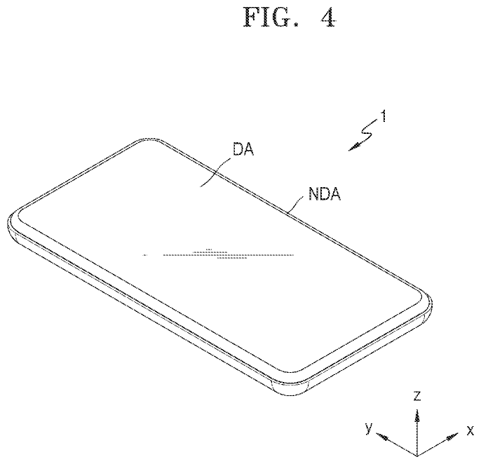

### [Description of FIG. 4]

FIG. 4 is a schematic perspective view of an electronic equipment 1 including a light-emitting device according to an embodiment.

The electronic equipment 1, which may be a device that displays a moving image or still image, may be not only a portable electronic equipment, such as a mobile phone, a smartphone, a tablet personal computer (PC), a mobile communication terminal, an electronic notebook, an electronic book, a portable multimedia player (PMP), a navigation device, or an ultra-mobile PC (UMPC), but may also be various products, such as a television, a laptop computer, a monitor, a billboard, or an Internet of things (IOT). The electronic equipment 1 may be any product as described above or a part thereof.

In embodiments, the electronic equipment 1 may be a wearable device, such as a smart watch, a watch phone, a glasses-type display, or a head mounted display (HMD), or a part of such a wearable device. However, embodiments of the disclosure are not limited thereto.

For example, the electronic equipment 1 may be a dashboard of a vehicle, a center information display on a center fascia or dashboard of a vehicle, a room mirror display that replaces a side mirror of a vehicle, an entertainment display arranged for a rear seat of a vehicle or arranged on the back of a front seat, a head-up display (HUD) installed at the front of a vehicle or projected on a front window glass, or a computer generated hologram augmented reality head up display (CGH AR HUD). FIG. 4 illustrates an embodiment in which the electronic equipment 1 is a smartphone, for convenience of explanation.

The electronic equipment 1 may include a display area DA and a non-display area NDA outside the display area DA. A display device may implement an image through a two-dimensional array of pixels that are arranged in the display area DA.

The non-display area NDA is an area that does not display an image, and may surround (for example, entirely surround) the display area DA. A driver for providing electrical signals or power to display devices arranged in the display area DA may be arranged in the non-display area NDA. A pad, which is an area to which an electronic element or a printed circuit board may be electrically connected, may be arranged in the non-display area NDA.

In the electronic equipment 1, a length in the x-axis direction and a length in the y-axis direction may be different from each other. In an embodiment, as shown in FIG. 4, the length in the x-axis direction may be shorter than the length in the y-axis direction. In embodiments, the length in the x-axis direction may be the same as the length in the y-axis direction. In embodiments, the length in the x-axis direction may be longer than the length in the y-axis direction.

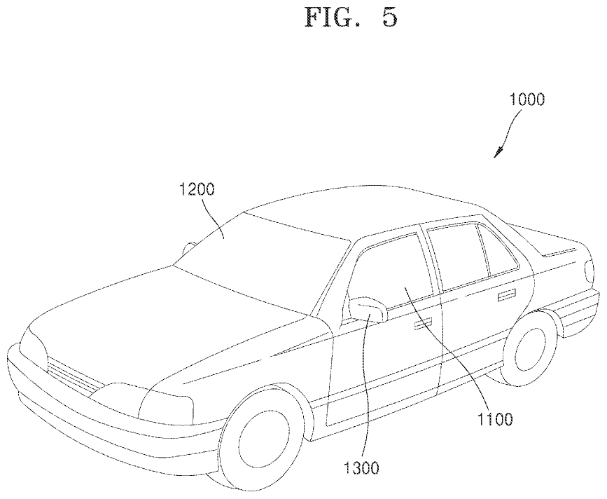

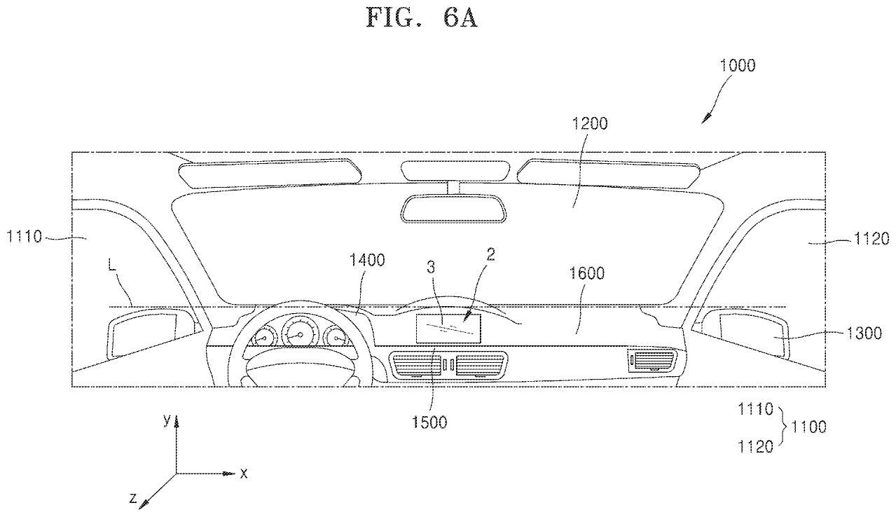

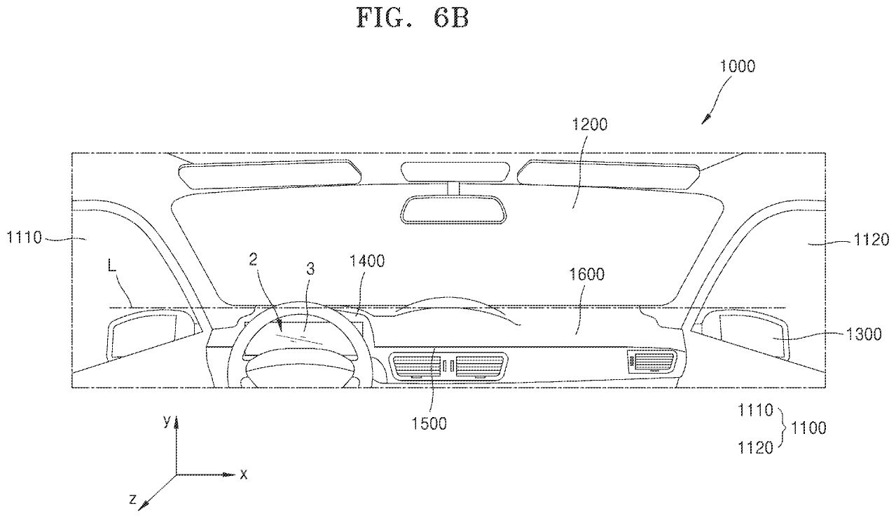

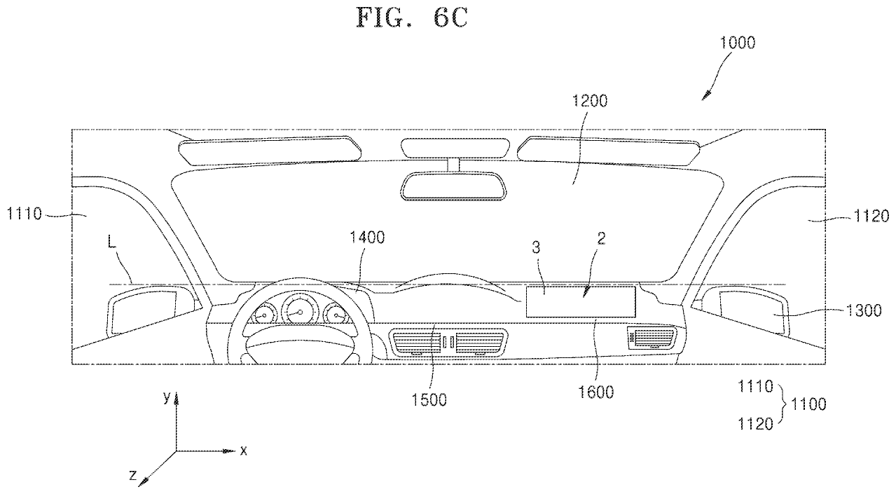

### [Description of FIGS. 5 and 6A to 6C]

FIG. 5 is a schematic perspective view of an exterior of a vehicle 1000 as electronic equipment including a light-emitting device according to an embodiment.

FIGS. 6A to 6C are each a schematic diagram of an interior of a vehicle 1000 according to embodiments.

Referring to FIGS. 5, 6A, 6B, and 6C, the vehicle 1000 may refer to various apparatuses for moving a subject to be transported, such as a person, an object, or an animal, from a departure point to a destination point. Examples of a vehicle 1000 may include a vehicle traveling on a road or a track, a vessel moving over the sea or river, an airplane flying in the sky using the action of air, and the like.

The vehicle 1000 may travel on a road or a track. The vehicle 1000 may move in a selected or given direction according to the rotation of at least one wheel.

Examples of a vehicle 1000 may include a three-wheeled or four-wheeled vehicle, a construction machine, a two-wheeled vehicle, a prime mover device, a bicycle, and a train running on a track.

The vehicle 1000 may include a body having an interior and an exterior, and a chassis that is a portion excluding the body in which mechanical apparatuses necessary for driving are installed. The exterior of the body of the vehicle 1000 may include a front panel, a bonnet, a roof panel, a rear panel, a trunk, a pillar provided at a boundary between doors, and the like. The chassis of the vehicle 1000 may include a power generating device, a power transmitting device, a driving device, a steering device, a braking device, a suspension device, a transmission device, a fuel device, front/rear and left/right wheels, and the like.

The vehicle 1000 may include a side window glass 1100, a front window glass 1200, a side mirror 1300, a cluster 1400, a center fascia 1500, a passenger seat dashboard 1600, and a display device 2.

The side window glass 1100 and the front window glass 1200 may be partitioned by a pillar arranged between the side window glass 1100 and the front window glass 1200.

The side window glass 1100 may be installed on a side of the vehicle 1000. In an embodiment, the side window glass 1100 may be installed on a door of the vehicle 1000. Multiple side window glasses 1100 may be provided and may face each other. In an embodiment, the side window glass 1100 may include a first side window glass 1110 and a second side window glass 1120. In an embodiment, the first side window glass 1110 may be arranged adjacent to the cluster 1400, and the second side window glass 1120 may be arranged adjacent to the passenger seat dashboard 1600.

In an embodiment, the side window glasses 1100 may be spaced apart from each other in the x-direction or the −x-direction. For example, the first side window glass 1110 and the second side window glass 1120 may be spaced apart from each other in the x direction or the −x direction. For example, a virtual straight line L connecting the side window glasses 1100 may extend in the x-direction or the −x-direction. For example, a virtual straight line L connecting the first side window glass 1110 and the second side window glass 1120 to each other may extend in the x direction or the −x direction.

The front window glass 1200 may be installed in the front of the vehicle 1000. The front window glass 1200 may be arranged between the side window glasses 1100 facing each other.

The side mirror 1300 may provide a rear view of the vehicle 1000. The side mirror 1300 may be installed on the exterior of the body of the vehicle 1000. In an embodiment, multiple side mirrors 1300 may be provided. One of the side mirrors 1300 may be arranged outside the first side window glass 1110, and another of the side mirrors 1300 may be arranged outside the second side window glass 1120.

The cluster 1400 may be arranged in front of a steering wheel. The cluster 1400 may include a tachometer, a speedometer, a coolant thermometer, a fuel gauge, a turn signal indicator, a high beam indicator, a warning light, a seat belt warning light, an odometer, a tachograph, an automatic shift selector indicator light, a door open warning light, an engine oil warning light, and/or a low fuel warning light.

The center fascia 1500 may include a control panel on which buttons for adjusting an audio device, an air conditioning device, and a seat heater are disposed. The center fascia 1500 may be arranged on a side of the cluster 1400.

A passenger seat dashboard 1600 may be spaced apart from the cluster 1400, and the center fascia 1500 may be arranged between the cluster 1400 and the passenger seat dashboard 1600. In an embodiment, the cluster 1400 may be arranged to correspond to a driver seat (not shown), and the passenger seat dashboard 1600 may be arranged to correspond to a passenger seat (not shown). In an embodiment, the cluster 1400 may be adjacent to the first side window glass 1110, and the passenger seat dashboard 1600 may be adjacent to the second side window glass 1120.

In an embodiment, the display device 2 may include a display panel 3, and the display panel 3 may display an image. The display device 2 may be arranged inside the vehicle 1000. In an embodiment, the display device 2 may be arranged between the side window glasses 1100 facing each other. The display device 2 may be arranged on at least one of the cluster 1400, the center fascia 1500, and the passenger seat dashboard 1600.

The display device 2 may include an organic light-emitting display device, an inorganic electroluminescent display device, a quantum dot display device, or the like. Hereinafter, an organic light-emitting display apparatus including the light-emitting device according to an embodiment will be described as an example of the display device 2. However, various types of display apparatuses as described above may be used in embodiments.

Referring to FIG. 6A, the display device 2 may be arranged on the center fascia 1500. In an embodiment, the display device 2 may display navigation information. In an embodiment, the display device 2 may display information regarding audio settings, video settings, or vehicle settings.

Referring to FIG. 6B, the display device 2 may be arranged on the cluster 1400. When the display device 2 is arranged on the cluster 1400, the cluster 1400 may display driving information and the like through the display device 2. For example, the cluster 1400 may digitally implement driving information and the like. The digital cluster 1400 may display vehicle information and driving information as images. For example, a needle and a gauge of a tachometer and various warning lights or icons may be displayed by a digital signal.

Referring to FIG. 6C, the display device 2 may be arranged on the passenger seat dashboard 1600. The display device 2 may be embedded in the passenger seat dashboard 1600 or arranged on the passenger seat dashboard 1600. In an embodiment, the display device 2 arranged on the passenger seat dashboard 1600 may display an image related to information displayed on the cluster 1400 and/or information displayed on the center fascia 1500. In embodiments, the display device 2 arranged on the passenger seat dashboard 1600 may display information that is different from information displayed on the cluster 1400 and/or information displayed on the center fascia 1500.

### [Manufacturing Method]

Layers constituting the hole transport region, the emission layer, and the layers constituting the electron transport region may be formed in a selected region by using various methods such as vacuum deposition, spin coating, casting, Langmuir-Blodgett (LB) deposition, ink-jet printing, laser-printing, laser-induced thermal imaging, and the like.

When layers constituting the hole transport region, the emission layer, and the layers constituting the electron transport region are formed by vacuum deposition, the deposition may be performed at a deposition temperature in a range of about 100° C. to about 500° C., at a vacuum degree in a range of about 10⁻⁸ torr to about 10⁻³ torr, and at a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having three to sixty carbon atoms. The term “C₁-C₆₀ heterocyclic group” as used herein may be a cyclic group that has 1 to 60 carbon atoms and further has, in addition to a carbon atom, at least one heteroatom as a ring-forming atom. The C₃-C₆₀ carbocyclic group and the C₁-C₆₀ heterocyclic group may each be a monocyclic group consisting of one ring, or a polycyclic group in which two or more rings are condensed with each other. For example, the number of ring-forming atoms in a C₁-C₆₀ heterocyclic group may be from 3 to 61.

The term “cyclic group” as used herein may be a C₃-C₆₀ carbocyclic group or a C₁-C₆₀ heterocyclic group.

The term “π electron-rich C₃-C₆₀ cyclic group” as used herein may be a cyclic group that has three to sixty carbon atoms and may not include *—N=*′ as a ring-forming moiety. The term “π electron-deficient nitrogen-containing C₁-C₆₀ cyclic group” as used herein may be a heterocyclic group that has one to sixty carbon atoms and may include *—N=*′ as a ring-forming moiety.

In embodiments,
a C₃-C₆₀ carbocyclic group may be a T1 group or a group in which two or more T1 groups are condensed with each other (e.g., a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which at least two T2 groups are condensed with each other, or a group in which at least one T2 group and at least one T1 group are condensed with each other (e.g., a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),
a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (e.g., a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, or the like),
a π electron-deficient nitrogen-containing C₁-C₆₀ cyclic group may be a T4 group, a group in which at least two T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (e.g., a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like), wherein
a T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
a T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
a T3 group may be a furan group, a thiophene group, a 1H-pyrrole group, a silole group, or a borole group, and
a T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, and “π electron-deficient nitrogen-containing C₁-C₆₀ cyclic group” as used herein may each be a group condensed to any cyclic group, a monovalent group, or a polyvalent group (e.g., a divalent group, a trivalent group, a tetravalent group, etc.) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched monovalent aliphatic hydrocarbon group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁ heterocycloalkyl group” as used herein may be a monovalent cyclic group having 1 to 10 carbon atoms, further including, in addition to carbon atoms, at least one heteroatom as ring-forming atoms, and examples thereof may include a 1,2,3,4-oxatriazolidinyl group, a tetrahydrofuranyl group, a tetrahydrothiophenyl group, and the like. The term “C₁-C₁ heterocycloalkylene group” as used herein may be a divalent group having a same structure as the C₁-C₁ heterocycloalkyl group.

The term “C₃-C₁₀ cycloalkenyl group” as used herein may be a monovalent cyclic group having 3 to 10 carbon atoms, at least one carbon-carbon double bond in the cyclic structure thereof, and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group having 1 to 10 carbon atoms, further including, in addition to carbon atoms, at least one heteroatom as ring-forming atoms and at least one carbon-carbon double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkylene group” as used herein may be a divalent group having a same structure as the C₁-C₁₀ heterocycloalkyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom as ring-forming atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. When the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group (e.g., having 8 to 60 carbon atoms) having two or more rings condensed to each other, only carbon atoms as ring-forming atoms, and no aromaticity in the molecular structure as a whole. Examples of a monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein may be a divalent group having a same structure as the monovalent non-aromatic condensed polycyclic group described above.

The term “monovalent non-aromatic condensed heteropolycyclic group” as used herein may be a monovalent group (e.g., having 1 to 60 carbon atoms) having two or more rings condensed to each other, further including, in addition to carbon atoms, at least one heteroatom, as ring-forming atoms, and having no aromaticity in its molecular structure as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indeno carbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the group “R₁₀ₐ” may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, and any combination thereof.

The term “third-row transition metal” as used herein may be Hf, Ta, W, Re, Os, Ir, Pt, Au, or the like.

In the specification, the term “Ph” refers to a phenyl group, the term “Me” refers to a methyl group, the term “Et” refers to an ethyl group, the terms “tert-Bu” or “Bu^{t}” each refers to a tert-butyl group, and the term “OMe” refers to a methoxy group.

The term “biphenyl group” as used herein may be a “phenyl group substituted with a phenyl group.” For example, a “biphenyl group” may be a substituted phenyl group having a C₆-C₆₀ aryl group as a substituent.

The term “terphenyl group” as used herein may be a “phenyl group substituted with a biphenyl group.” For example, a “terphenyl group” may be a substituted phenyl group having, as a substituent, a C₆-C₆₀ aryl group substituted with a C₆-C₆₀ aryl group.

In the specification, the symbols *, *′, and *″ as used herein, unless defined otherwise, each refer to a binding site to a neighboring atom in a corresponding formula or moiety.

In the specification, the terms “x-axis”, “y-axis”, and “z-axis” are not limited to three axes in an orthogonal coordinate system (for example, a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

Hereinafter, compounds according to embodiments and light-emitting devices according to embodiments will be described in detail with reference to the following Synthesis Examples and Examples. The wording “B was used instead of A” used in describing Synthesis Examples means that an identical molar equivalent of B was used in place of A.

### EXAMPLES

Organometallic compounds according to an embodiment may be, for example, synthesized as follows. However, methods for synthesizing the organometallic compound according to an embodiment are not limited thereto.

### [Summary of Reaction Schemes of Compound BD91]

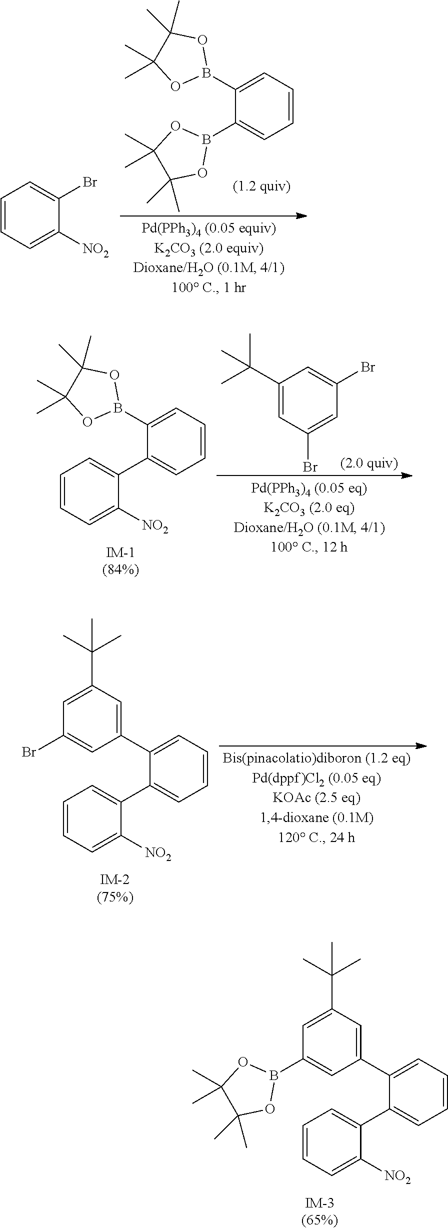

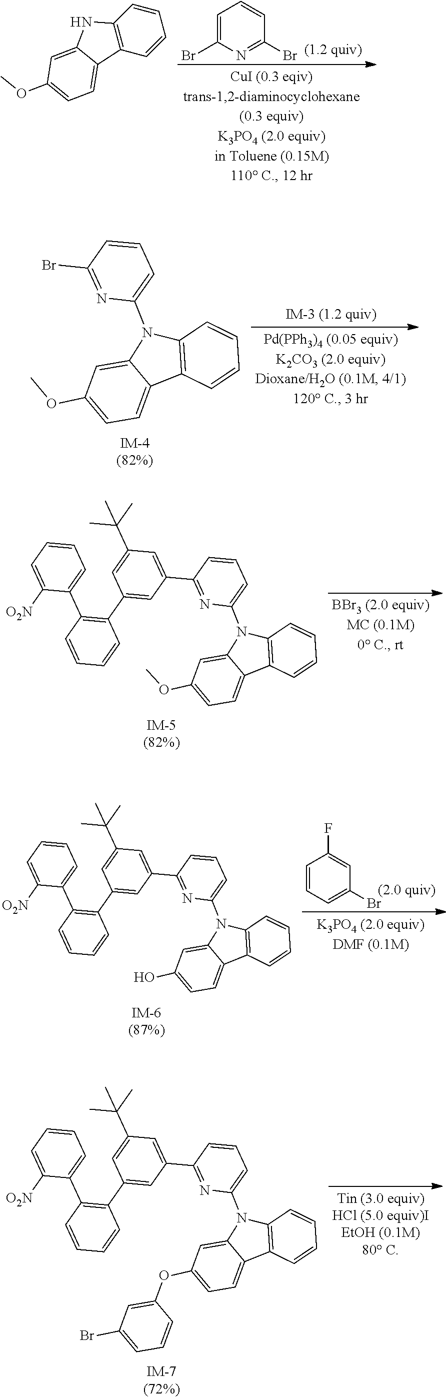

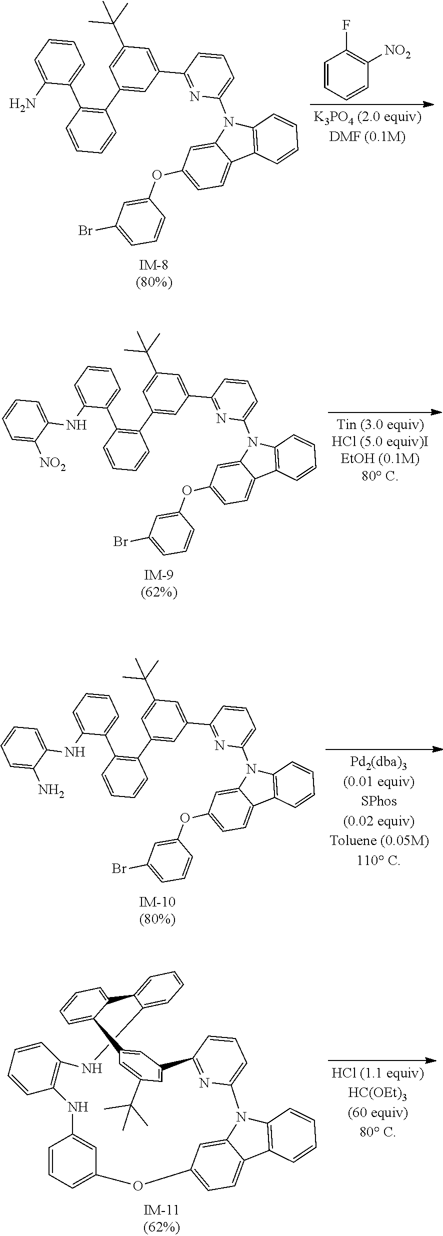

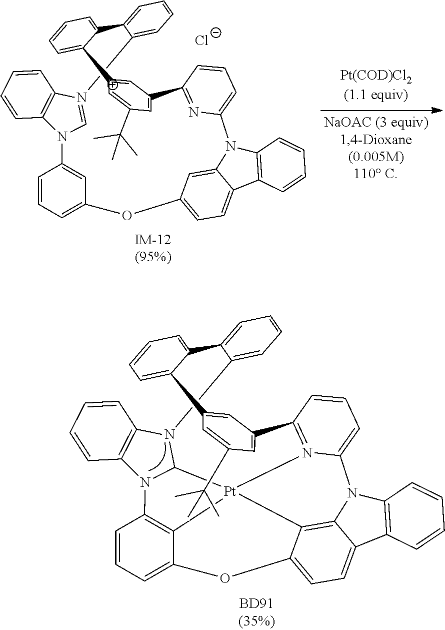

### Synthesis Example 1. Synthesis of Intermediate IM-1

A mixture including 1-bromo-2-nitrobenzene (50 g, 248 mmol), 1,2-bis(4,4,5,5-tetramethyl-1,3,2-dioxaborolan-2-yl)benzene (98 g, 298 mmol), Pd(PPh₃)₄ (14 g, 12 mmol), and K₂CO₃ (69 g, 496 mmol) was added to a reaction container, and the mixture was suspended in dioxane (1,984 ml) and distilled water (496 ml) to prepare a reaction solution. The reaction solution was heated and stirred at 100° C. for 1 hour. After completion of the reaction, the reaction solution was cooled to room temperature, and 1,500 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-1 (68 g, 208 mmol) in 84% yield.

### Synthesis Example 2. Synthesis of Intermediate IM-2

A mixture including Intermediate IM-1 (67 g, 206 mmol), 1,3-dibromo-5-(tert-butyl)benzene (77 ml, 412 mmol), Pd(PPh₃)₄ (12 g, 10 mmol), and K₂CO₃ (57 g, 412 mmol) was added to a reaction container, and the mixture was suspended in dioxane (1,648 ml) and distilled water (412 ml) under nitrogen to prepare a reaction solution. The reaction solution was heated and stirred at 100° C. for 12 hours. After completion of the reaction, the reaction solution was cooled to room temperature, and 1,200 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-2 (63 g, 155 mmol) in 75% yield.

### Synthesis Example 3. Synthesis of Intermediate IM-3

A mixture including Intermediate IM-2 (62 g, 151 mmol), bis(pinacolato)diboron (46 g, 181 mmol), Pd(dppf)Cl₂ (6 g, 8 mmol), and K₂CO₃ (37 g, 378 mmol) was added to a reaction container, and the mixture was suspended in dioxane (1,510 ml) under nitrogen to prepare a reaction solution. The reaction solution was heated and stirred at 120° C. for 24 hours. After completion of the reaction, the reaction solution was cooled to room temperature, and 1,500 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-3 (41 g, 91 mmol) in 65% yield.

### Synthesis Example 4. Synthesis of Intermediate IM-4

A mixture including 2-methoxy-9H-carbazole (25 g, 127 mmol), 2,6-dibromopyridine (36 g, 152 mmol), CuI (7 g, 38 mmol), trans-1,2-diaminocyclohexan (5 ml, 38 mmol), and K₃PO₄ (54 g, 254 mmol) was added to a reaction container, and the mixture was suspended in toluene (847 ml) under nitrogen to prepare a reaction solution. The reaction solution was heated and stirred at 110° C. for 12 hours. After completion of the reaction, the reaction solution was cooled to room temperature, and 800 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-4 (37 g, 104 mmol) in 82% yield.

### Synthesis Example 5. Synthesis of Intermediate IM-5

A mixture including Intermediate IM-3 (40 g, 87 mmol), Intermediate IM-4 (26 g, 73 mmol), Pd(PPh₃)₄ (5 g, 4 mmol), and K₂CO₃ (20 g, 146 mmol) was added to a reaction container, and the mixture was suspended in dioxane (584 ml) and distilled water (146 ml) under nitrogen to prepare a reaction solution. The reaction solution was heated and stirred at 120° C. for 3 hours. After completion of the reaction, the reaction solution was cooled to room temperature, and 300 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-5 (36 g, 60 mmol) in 82% yield.

### Synthesis Example 6. Synthesis of Intermediate IM-6

Intermediate IM-5 (35 g, 58 mmol) was dissolved in dichloromethane (580 ml) under nitrogen to prepare a reaction solution. The temperature of the reaction solution was adjusted to 0° C. BBr₃ 1.0 M solution in dichloromethane (1,160 mmol) was slowly added dropwise thereto. The resulting reaction solution was stirred at room temperature for 6 hours. 1,000 mL of distilled water was added thereto, and an extraction process was performed thereon to obtain an organic layer. The organic layer thus extracted was washed with a saturated aqueous solution of sodium chloride, and dried with sodium sulfate. The resulting product was subjected to column chromatography, so as to obtain Intermediate IM-6 (30 g, 50 mmol) in 87% yield.

### Synthesis Example 7. Synthesis of Intermediate IM-7

A mixture including Intermediate IM-6 (29 g, 49 mmol), 1-bromo-3-fluorobenzene (11 ml, 98 mmol), and Cs₂CO₃ (32 g, 98 mmol) was added to a reaction container, and the mixture was suspended in dimethylformamide (490 ml) under nitrogen to prepare a reaction solution. The reaction solution was heated and stirred at 120° C. for 12 hours. After completion of the reaction, the reaction solution was cooled to room temperature, and 300 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-7 (15 g, 21 mmol) in 72% yield.

### Synthesis Example 8. Synthesis of Intermediate IM-8

A mixture including Intermediate IM-7 (14 g, 19 mmol) and tin (7 g, 56 mmol) was added to a reaction container, and the mixture was suspended in ethanol (190 ml) to prepare a reaction solution. HCl (280 mmol) was added dropwise thereto, and the resulting reaction solution was stirred at 80° C. for 12 hours. After completion of the reaction, the reaction solution was cooled to room temperature, and 1,500 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-8 (11 g, 15 mmol) in 80% yield.

### Synthesis Example 9. Synthesis of Intermediate IM-9

A mixture including Intermediate IM-8 (10 g, 14 mmol), 1-fluoro-2-nitrobenzene (1.5 ml, 14 mmol), and K₃PO₄ (5.9 g, 28 mmol) was added to a reaction container, and the mixture was suspended in dimethylformamide (140 ml) to prepare a reaction solution. The reaction solution was heated and stirred at 140° C. for 18 hours. After completion of the reaction, the reaction solution was cooled to room temperature, and 140 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-9 (8 g, 9 mmol) in 62% yield.

### Synthesis Example 10. Synthesis of Intermediate IM-10

A mixture including Intermediate IM-9 (8 g, 9 mmol) and tin (3 g, 27 mmol) was added to a reaction container, and the mixture was suspended in ethanol (90 ml) to prepare a reaction solution. HCl (135 mmol) was added dropwise thereto, and the resulting reaction solution was stirred at 80° C. for 12 hours. After completion of the reaction, the reaction solution was cooled to room temperature, and 100 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-10 (6 g, 7 mmol) in 80% yield.

### Synthesis Example 11. Synthesis of Intermediate IM-11

A mixture including Intermediate IM-10 (6 g, 7 mmol), Pd₂(dba)₃ (0.1 g, 0.1 mmol), SPhos (0.08 g, 0.2 mmol), and NaOtBu (2.7 g, 28 mmol) was added to a reaction container, and the mixture was suspended in toluene (140 mL) under nitrogen to prepare a reaction solution. The reaction solution was heated and stirred at 120° C. for 12 hours. After completion of the reaction, the reaction solution was cooled to room temperature, and 150 mL of distilled water was added thereto. An extraction process was performed thereon by using ethyl acetate to obtain an organic layer. The organic layer thus extracted was washed with a saturated aqueous solution of sodium chloride, and dried with sodium sulfate. The resulting product was subjected to column chromatography, so as to obtain Intermediate IM-11 (2.3 g, 3.2 mmol) in 62% yield.

### Synthesis Example 12. Synthesis of Intermediate IM-12

A mixture including Intermediate IM-11 (2.3 g, 3.2 mmol), triethyl orthoformate (34 mL, 192 mmol), and HCl (37%, 0.4 mL, 3.8 mmol) was added to a reaction container, and the reaction solution was heated and stirred at 80° C. for 12 hours. After completion of the reaction, the resulting reaction solution was cooled to room temperature, and a solid was produced. The resulting product was filtered and washed with ether. The washed solid was dried, so as to obtain Intermediate IM-12 (2.2 g, 3.0 mmol) in 95% yield.

### Synthesis Example 13. Synthesis of Compound BD91

Intermediate IM-12 (2.2 g, 3.0 mmol), dichloro(1,5-cyclooctadiene)platinum (1.2 g, 3.3 mmol), and NaOAc (0.7 g, 9.0 mmol) were suspended in 65 ml of 1,4-dioxane 65 ml to prepare a reaction solution. The reaction solution was heated and stirred at 110° C. for 72 hours. After completion of the reaction, the reaction solution was cooled to room temperature, and 60 mL of distilled water was added thereto. An extraction process was performed thereon by using ethyl acetate to obtain an organic layer. The organic layer thus extracted was washed with a saturated aqueous solution of sodium chloride, and dried with sodium MgSO₄. The resulting product was subjected to column chromatography, so as to obtain Compound BD91 (0.9 g, 1.0 mmol) in 35% yield.

### Synthesis Example 14. Synthesis of Compound BD85

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 2,6-dibromo-4-(tert-butyl)pyridine was used instead of 2,6-dibromopyridine and 2-methoxy-6-(methyl)-9H-carbazole was used instead of 2-methoxy-9H-carbazole. Except for these, by using the same method as the synthesis example of Compound BD91, Compound BD85 (1.2 g, 1.1 mmol) was synthesized in 38% yield.

### Synthesis Example 15. Synthesis of Compound BD86

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 2,6-dibromo-4-(tert-butyl)pyridine was used instead of 2,6-dibromopyridine and 2-methoxy-6-(methyl-d₃)-9H-carbazole was used instead of 2-methoxy-9H-carbazole. Except for these, by using the same method as the synthesis example of Compound BD91, Compound BD86 (1.2 g, 1.1 mmol) was synthesized in 38% yield.

### Synthesis Example 16. Synthesis of Compound BD87

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 2,6-dibromo-4-(tert-butyl)pyridine was used instead of 2,6-dibromopyridine and 6-(tert-butyl)-2-methoxy-9H-carbazole was used instead of 2-methoxy-9H-carbazole. Except for these, by using the same method as the synthesis example of Compound BD91, Compound BD87 (1.3 g, 1.2 mmol) was synthesized in 40% yield.

### Synthesis Example 15. Synthesis of Compound BD88

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 2-methoxy-6-(methyl)-9H-carbazole was used instead of 2-methoxy-9H-carbazole. Except for these, by using the same method as the synthesis example of Compound BD91, Compound BD88 (1.0 g, 1.0 mmol) was synthesized in 32% yield.

### Synthesis Example 16. Synthesis of Compound BD89

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 2-methoxy-6-(methyl-d₃)-9H-carbazole was used instead of 2-methoxy-9H-carbazole. Except for these, by using the same method as the synthesis example of Compound BD91, Compound BD89 (1.0 g, 1.0 mmol) was synthesized in 34% yield.

### Synthesis Example 17. Synthesis of Compound BD90

The same synthesis method was performed as the synthesis example of Intermediate IM-1, except that 3-bromo-2-nitro-1,1′-biphenyl-2′,3′,4′,5′,6′-d₅ was introduced instead of 1-bromo-2-nitrobenzene. The same synthesis method was performed as the synthesis example of Intermediate IM-4, except that 6-(tert-butyl)-2-methoxy-9H-carbazole was used instead of 2-methoxy-9H-carbazole. Except for these, by using the same method as the synthesis example of Compound BD91, Compound BD90 (1.1 g, 1.1 mmol) was synthesized in 35% yield.

¹H NMR and HR-MS of the intermediates and the compounds synthesized according to the Synthesis Examples above are shown in Table 1:

TABLE 1

| | | HR-MS (m/z) | |
|---|---|---|---|
| | | [M⁺] | |
| Compound | ¹H NMR (CDCl₃, 500 MHz) | Calculated | Found |
| IM-1 | δ 8.03 (dd, ³J_{H-H} = 8.2 Hz, ⁴J_{H-H} = 1.2 Hz, 1H), 7.84 | 325.14854 | 325.14858 |
| | (dd, ³J_{H-H} = 7.5 Hz, ⁴J_{H-H} = 1.1 Hz, 1H), 7.57 (td, ³J_{H-H} = | | |
| | 7.5 Hz, ⁴J_{H-H} = 1.3 Hz, 1H), 7.50 (td, ³J_{H-H} = 7.6 Hz, | | |
| | ⁴J_{H-H} = 1.5 Hz, 1H), 7.48 (dd, ³J_{H-H} = 7.5 Hz, ⁴J_{H-H} = | | |
| | 1.5 Hz, 1H), 7.39 (td, ³J_{H-H} = 7.5 Hz, ⁴J_{H-H} = 1.2 Hz, | | |
| | 1H), 7.29 (dd, ³J_{H-H} = 7.6 Hz, ⁴J_{H-H} = 1.5 Hz, 1H), 7.23 | | |
| | (dd, ³J_{H-H} = 7.6 Hz, ⁴J_{H-H} = 0.6 Hz, 1H), 1.10 (s, 6H), | | |
| | 1.06 (s, 6H). | | |
| IM-2 | δ 7.83 (dd, ³J_{H-H} = 8.2 Hz, ⁴J_{H-H} = 1.3 Hz, 1H), 7.57- | 409.06774 | 409.06792 |
| | 7.53 (m, 2H), 7.50 (t, ⁴J_{H-H} = 1.7 Hz, 1H), 7.49-7.48 | | |
| | (m, 1H), 7.44 (dd, ³J_{H-H} = 7.6 Hz, ⁴J_{H-H} = 1.5 Hz, 1H), | | |
| | 7.38 (t, ⁴J_{H-H} = 1.8 Hz, 1H), 7.36-7.34 (m, 1H), 7.27 | | |
| | (dd, ³J_{H-H} = 7.7 Hz, ⁴J_{H-H} = 1.4 Hz, 1H), 7.26 (t, ⁴J_{H-H} = | | |
| | 1.7 Hz, 1H), 7.01 (t, ⁴J_{H-H} = 1.7 Hz, 1H), 1.08 (s, 9H). | | |
| IM-3 | δ 7.80 (dd, ³J_{H-H} = 7.8 Hz, ⁴J_{H-H} = 1.0 Hz, 1H), | 457.37700 | 457.37712 |
| | 7.64 (t, ⁴J_{H-H} = 0.9 Hz, 1H), 7.60 (t, ⁴J_{H-H} = 0.9 Hz, | | |
| | 1H), 7.57 (dd, ³J_{H-H} = 7.7 Hz, ⁴J_{H-H} = 0.6 Hz, 1H), 7.49 | | |
| | (dd, ³J_{H-H} = 7.5 Hz, ⁴J_{H-H} = 0.8 Hz, 1H), 7.42-7.39 (m, | | |
| | 2H), 7.34 (dd, ³J_{H-H} = 7.5 Hz, ⁴J_{H-H} = 1.5 Hz, 1H), | | |
| | 7.28-7.26 (m, 1H), 7.19 (td, ⁴J_{H-H} = 0.9 Hz, 1H), 7.15 | | |
| | (dd, ³J_{H-H} = 7.5 Hz, ⁴J_{H-H} = 1.2 Hz, 1H), 1.36 (s, 12H), | | |
| | 1.07 (s, 9H). | | |
| IM-4 | δ 7.99 (dd, ³J_{H-H} = 7.8 Hz, ⁴J_{H-H} = 1.2 Hz, 1H), 7.95 (d, | 352.02113 | 352.02121 |
| | ³J_{H-H} = 8.6 Hz, 1H), 7.80 (d, ³J_{H-H} = 8.2 Hz, 1H), 7.76 | | |
| | (t, ³J_{H-H} = 7.8 Hz, 1H), 7.62 (dd, ³J_{H-H} = 7.9 Hz, ⁴J_{H-H} = | | |
| | 0.6 Hz, 1H), 7.47-7.46 (m, 2H), 7.38 (td, ³J_{H-H} = 7.7 | | |
| | Hz, ⁴J_{H-H} = 1.2 Hz, 1H), 7.30 (td, ³J_{H-H} = 7.7 Hz, ⁴J_{H-H} = | | |
| | 1.0 Hz, 1H), 6.95 (dd, ³J_{H-H} = 8.5 Hz, ⁴J_{H-H} = 2.3 Hz, | | |
| | 1H), 3.90 (s, 3H). | | |
| IM-5 | δ 8.09 (t, ⁴J_{H-H} = 1.8 Hz, 1H), 8.06 (dd, ³J_{H-H} = 7.6 Hz, | 603.72200 | 603.72206 |
| | ⁴J_{H-H} = 0.5 Hz, 1H), 8.02 (d, ³J_{H-H} = 8.5 Hz, 1H), 7.98 | | |
| | (t, ³J_{H-H} = 7.9 Hz, 1H), 7.91 (d, ³J_{H-H} = 8.2 Hz, 1H), | | |
| | 7.83 (t, ⁴J_{H-H} = 1.7 Hz, 1H), 7.75 (dd, ³J_{H-H} = 8.1 Hz, | | |
| | ⁴J_{H-H} = 1.2 Hz, 1H), 7.68 (dd, ³J_{H-H} = 7.7 Hz, ⁴J_{H-H} = | | |
| | 0.5 Hz, 1H), 7.61-7.52 (m, 4H), 7.47 (td, ³J_{H-H} = 7.5 | | |
| | Hz, ⁴J_{H-H} = 1.4 Hz, 1H), 7.39-7.26 (m, 6H), 7.18 (t, ⁴J_{H-H} = | | |
| | 1.7 Hz, 1H), 6.97 (dd, ³J_{H-H} = 8.5 Hz, ⁴J_{H-H} = 2.3 | | |
| | Hz, 1H), 3.86 (s, 3H), 1.17 (s, 9H). | | |
| IM-6 | δ 8.02 (t, ⁴J_{H-H} = 1.6 Hz, 1H), 8.01 (d, ³J_{H-H} = 7.5 Hz, | 589.23654 | 589.236554 |
| | 1H), 7.95-7.92 (m, 3H), 7.85 (d, ³J_{H-H} = 8.2 Hz, 1H), | | |
| | 7.76-7.74 (m, 2H), 7.68 (d, ³J_{H-H} = 7.7 Hz, 1H), 7.58 | | |
| | (d, ³J_{H-H} = 8.1 Hz, 1H), 7.55 (dd, ³J_{H-H} = 7.6 Hz, ⁴J_{H-H} = | | |
| | 1.3 Hz, 1H), 7.50-7.46 (m, 4H), 7.39-7.33 (m, 3H), | | |
| | 7.28 (td, ³J_{H-H} = 7.4 Hz, ⁴J_{H-H} = 0.9 Hz, 1H), 6.96 (t, | | |
| | ⁴J_{H-H} = 7.4 Hz, ⁴J_{H-H} = 0.9 Hz, 1H), 6.85 (dd, ³J_{H-H} = | | |
| | 8.4 Hz, ⁴J_{H-H} = 2.3 Hz, 1H), 5.85 (br s, 1H), 1.13 (s, | | |
| | 9H). | | |
| IM-7 | δ 8.12 (d, ³J_{H-H} = 8.3 Hz, 2H), 8.08 (t, ⁴J_{H-H} = 1.8 Hz, | 743.17835 | 743.71841 |
| | 1H), 7.98-7.95 (m, 2H), 7.79 (d, ⁴J_{H-H} = 2.1 Hz, 1H), | | |
| | 7.77-7.75 (m, 2H), 7.66 (d, ³J_{H-H} = 7.7 Hz, 1H), 7.59- | | |
| | 7.56 (m, 2H), 7.51 (td, ³J_{H-H} = 7.5 Hz, ⁴J_{H-H} = 1.4 Hz, | | |
| | 1H), 7.48-7.44 (m, 2H), 7.40-7.30 (m, 4H), 7.26-7.23 | | |
| | (m, 1H), 7.18-7.16 (m, 2H), 7.14-7.12 (m, 2H), 7.03 | | |
| | (dd, ³J_{H-H} = 8.4 Hz, ⁴J_{H-H} = 2.1 Hz, 1H), 6.93 (dd, ³J_{H-H} = | | |
| | 8.2 Hz, ⁴J_{H-H} = 2.3 Hz, 1H), 1.13 (s, 9H). | | |
| IM-8 | δ 8.09 (d, ³J_{H-H} = 8.3 Hz, 2H), 8.07 (t, ⁴J_{H-H} = 1.8 Hz, | 713.20418 | 713.20423 |
| | 1H), 7.95 (d, ³J_{H-H} = 8.2 Hz, 1H), 7.94 (t, ³J_{H-H} = 7.9 | | |
| | Hz, 1H), 7.87 (t, ⁴J_{H-H} = 1.6 Hz, 1H), 7.79 (d, ⁴J_{H-H} = | | |
| | 2.1 Hz, 1H), 7.61-7.60 (m, 2H), 7.54 (d, ³J_{H-H} = 7.7 | | |
| | Hz, 1H), 7.46-7.41 (m, 4H), 7.34 (td, ³J_{H-H} = 7.5 Hz, | | |
| | ⁴J_{H-H} = 0.8 Hz, 1H), 7.24 (t, ⁴J_{H-H} = 1.7 Hz, 1H), 7.16- | | |
| | 7.14 (m, 1H), 7.12-7.09 (m, 2H), 7.03-6.99 (m, 3H), | | |
| | 6.91 (dd, ³J_{H-H} = 8.2 Hz, ⁴J_{H-H} = 2.3 Hz, 1H), 6.69 (td, | | |
| | ³J_{H-H} = 7.5 Hz, ⁴J_{H-H} = 1.1 Hz, 1H), 6.55 (dd, ³J_{H-H} = | | |
| | 8.0 Hz, ⁴J_{H-H} = 0.8 Hz, 1H), 3.45 (br s, 2H), 1.13 (s, | | |
| | 9H). | | |
| IM-9 | δ 9.16 (s, 1H), 8.15 (d, ³J_{H-H} = 8.3 Hz, 2H), 8.12 (t, | 834.22055 | 834.22061 |
| | ⁴J_{H-H} = 1.8 Hz, 1H), 7.96-7.93 (m, 2H), 7.76 (d, ⁴J_{H-H} = | | |
| | 2.1 Hz, 1H), 7.78-7.68 (m, 4H), 7.67 (d, ³J_{H-H} = 7.7 | | |
| | Hz, 1H), 7.59-7.56 (m, 3H), 7.50 (td, ³J_{H-H} = 7.5 Hz, | | |
| | ⁴J_{H-H} = 1.4 Hz, 1H), 7.49-7.43 (m, 3H), 7.38-7.39 (m, | | |
| | 4H), 7.26-7.23 (m, 1H), 7.17-7.15 (m, 2H), 7.13-7.10 | | |
| | (m, 2H), 7.02 (dd, ³J_{H-H} = 8.4 Hz, ⁴J_{H-H} = 2.1 Hz, 1H), | | |
| | 6.94 (dd, ³J_{H-H} = 8.2 Hz, ⁴J_{H-H} = 2.3 Hz, 1H), 1.13 (s, | | |
| | 9H). | | |
| IM-10 | δ 9.14 (s, 1H), 8.08 (d, ³J_{H-H} = 8.3 Hz, 2H), 8.06 (t, | 804.24637 | 804.24641 |
| | ⁴J_{H-H} = 1.8 Hz, 1H), 7.96 (d, ³J_{H-H} = 8.2 Hz, 1H), 7.92 | | |
| | (t, ³J_{H-H} = 7.9 Hz, 1H), 7.86 (t, ⁴J_{H-H} = 1.6 Hz, 1H), | | |
| | 7.79 (d, ⁴J_{H-H} = 2.1 Hz, 1H), 7.61-7.60 (m, 2H), 7.54 | | |
| | (d, ³J_{H-H} = 7.7 Hz, 1H), 7.46-7.41 (m, 4H), 7.34 (td, | | |
| | ³J_{H-H} = 7.5 Hz, ⁴J_{H-H} = 0.8 Hz, 1H), 7.24 (t, ⁴J_{H-H} = 1.7 | | |
| | Hz, 1H), 7.16-7.14 (m, 2H), 7.12-7.09 (m, 3H), 7.03- | | |
| | 6.99 (m, 4H), 6.91 (dd, ³J_{H-H} = 8.2 Hz, ⁴J_{H-H} = 2.3 Hz, | | |
| | 1H), 6.69 (td, ³J_{H-H} = 7.5 Hz, ⁴J_{H-H} = 1.1 Hz, 1H), 6.55 | | |
| | (dd, ³J_{H-H} = 8.0 Hz, ⁴J_{H-H} = 0.8 Hz, 1H), 6.37 (dd, ³J_{H-H} = | | |
| | 7.8 Hz, ⁴J_{H-H} = 1.2 Hz, 1H), 3.33 (br s, 2H), 1.15 (s, | | |
| | 9H). | | |
| IM-11 | δ 8.07 (d, ³J_{H-H} = 8.3 Hz, 2H), 8.04 (t, ⁴J_{H-H} = 1.8 Hz, | 724.32021 | 724.32032 |
| | 1H), 7.94 (d, ³J_{H-H} = 8.2 Hz, 1H), 7.91 (t, ³J_{H-H} = 7.9 | | |
| | Hz, 1H), 7.87 (t, ⁴J_{H-H} = 1.6 Hz, 1H), 7.80 (d, ⁴J_{H-H} = | | |
| | 2.1 Hz, 1H), 7.62-7.61 (m, 2H), 7.52 (d, ³J_{H-H} = 7.7 | | |
| | Hz, 1H), 7.44-7.40 (m, 4H), 7.32 (td, ³J_{H-H} = 7.5 Hz, | | |
| | ⁴J_{H-H} = 0.8 Hz, 1H), 7.21 (t, ⁴J_{H-H} = 1.7 Hz, 1H), 7.16- | | |
| | 7.14 (m, 2H), 7.12-7.09 (m, 3H), 7.03-6.99 (m, 4H), | | |
| | 6.91 (dd, ³J_{H-H} = 8.2 Hz, ⁴J_{H-H} = 2.3 Hz, 1H), 6.67 (td, | | |
| | ³J_{H-H} = 7.5 Hz, ⁴J_{H-H} = 1.1 Hz, 1H), 6.41 (dd, ³J_{H-H} = | | |
| | 8.0 Hz, ⁴J_{H-H} = 0.8 Hz, 1H), 6.37 (dd, ³J_{H-H} = 7.8 Hz, | | |
| | ⁴J_{H-H} = 1.2 Hz, 1H), 5.36 (s, 1H), 4.96 (s, 1H), 1.14 (s, | | |
| | 9H). | | |
| IM-12 | δ 12.1 (s, 1H), 8.08 (d, ³J_{H-H} = 8.3 Hz, 2H), 8.04 (t, | 770.28124 | 770.28128 |
| | ⁴J_{H-H} = 1.8 Hz, 1H), 7.93 (d, ³J_{H-H} = 8.2 Hz, 1H), 7.90 | | |
| | (t, ³J_{H-H} = 7.9 Hz, 1H), 7.88 (t, ⁴J_{H-H} = 1.6 Hz, 1H), | | |
| | 7.79 (d, ⁴J_{H-H} = 2.1 Hz, 1H), 7.60-7.58 (m, 2H), 7.50 | | |
| | (d, ³J_{H-H} = 7.7 Hz, 1H), 7.42-7.38 (m, 4H), 7.32 (td, | | |
| | ³J_{H-H} = 7.5 Hz, ⁴J_{H-H} = 0.8 Hz, 1H), 7.21 (t, ⁴J_{H-H} = 1.7 | | |
| | Hz, 1H), 7.16-7.14 (m, 2H), 7.12-7.09 (m, 3H), 7.03- | | |
| | 6.99 (m, 4H), 6.91 (dd, ³J_{H-H} = 8.2 Hz, ⁴J_{H-H} = 2.3 Hz, | | |
| | 1H), 6.67 (td, ³J_{H-H} = 7.5 Hz, ⁴J_{H-H} = 1.1 Hz, 1H), 6.41 | | |
| | (dd, ³J_{H-H} = 8.0 Hz, ⁴J_{H-H} = 0.8 Hz, 1H), 6.37 (dd, ³J_{H-H} = | | |
| | 7.8 Hz, ⁴J_{H-H} = 1.2 Hz, 1H), 1.06 (s, 9H). | | |
| BD91 | δ 8.52 (d, ³J_{H-H} = 8.3 Hz, 2H), 8.08 (t, ⁴J_{H-H} = 1.8 Hz, | 927.25370 | 927.25375 |
| | 1H), 7.93 (d, ³J_{H-H} = 8.2 Hz, 1H), 7.91 (t, ³J_{H-H} = 7.9 | | |
| | Hz, 1H), 7.84 (t, ⁴J_{H-H} = 1.6 Hz, 1H), 7.76 (d, ⁴J_{H-H} = | | |
| | 2.1 Hz, 1H), 7.58-7.52 (m, 2H), 7.48 (d, ³J_{H-H} = 7.7 | | |
| | Hz, 1H), 7.40-7.36 (m, 2H), 7.30 (td, ³J_{H-H} = 7.5 Hz, | | |
| | ⁴J_{H-H} = 0.8 Hz, 1H), 7.18 (t, ⁴J_{H-H} = 1.7 Hz, 1H), 7.15- | | |
| | 7.12 (m, 2H), 7.10-7.02 (m, 3H), 7.01-6.95 (m, 4H), | | |
| | 6.90 (dd, ³J_{H-H} = 8.2 Hz, ⁴J_{H-H} = 2.3 Hz, 1H), 6.60 (td, | | |
| | 3 J_{H-H} = 7.5 Hz, ⁴J_{H-H} = 1.1 Hz, 1H), 6.52 (dd, ³J_{H-H} = | | |
| | 8.0 Hz, ⁴J_{H-H} = 0.8 Hz, 1H), 6.23 (dd, ³J_{H-H} = 7.8 Hz, | | |
| | ⁴J_{H-H} = 1.2 Hz, 1H), 1.06 (s, 9H). | | |
| BD85 | δ 8.44 (d, ³J_{H-H} = 8.3 Hz, 2H), 8.16 (t, ⁴J_{H-H} = 1.8 Hz, | 1078.39464 | 1078.39471 |
| | 1H), 7.94 (d, ³J_{H-H} = 8.2 Hz, 1H), 7.91 (t, ³J_{H-H} = 7.9 | | |
| | Hz, 1H), 7.80 (t, ⁴J_{H-H} = 1.6 Hz, 1H), 7.76 (d, ⁴J_{H-H} = | | |
| | 2.1 Hz, 1H), 7.68-7.62 (m, 1H), 7.48 (d, ³J_{H-H} = 7.7 | | |
| | Hz, 1H), 7.40-7.36 (m, 2H), 7.18 (t, ⁴J_{H-H} = 1.7 Hz, | | |
| | 1H), 7.15-7.12 (m, 2H), 7.10-7.02 (m, 2H), 7.01-6.95 | | |
| | (m, 4H), 6.90 (dd, ³J_{H-H} = 8.2 Hz, ⁴J_{H-H} = 2.3 Hz, 1H), | | |
| | 6.60 (td, ³J_{H-H} = 7.5 Hz, ⁴J_{H-H} = 1.1 Hz, 1H), 6.52 (dd, | | |
| | ³J_{H-H} = 8.0 Hz, ⁴J_{H-H} = 0.8 Hz, 1H), 6.23 (dd, ³J_{H-H} = | | |
| | 7.8 Hz, ⁴J_{H-H} = 1.2 Hz, 1H), 2.26 (s, 3H), 1.30 (s, 9H), | | |
| | 1.06 (s, 9H). | | |
| BD86 | δ 8.44 (d, ³J_{H-H} = 8.3 Hz, 2H), 8.16 (t, ⁴J_{H-H} = 1.8 Hz, | 1081.41347 | 1081.41353 |
| | 1H), 7.94 (d, ³J_{H-H} = 8.2 Hz, 1H), 7.91 (t, ³J_{H-H} = 7.9 | | |
| | Hz, 1H), 7.80 (t, ⁴J_{H-H} = 1.6 Hz, 1H), 7.76 (d, ⁴J_{H-H} = | | |
| | 2.1 Hz, 1H), 7.68-7.62 (m, 1H), 7.48 (d, ³J_{H-H} = 7.7 | | |
| | Hz, 1H), 7.40-7.36 (m, 2H), 7.18 (t, ⁴J_{H-H} = 1.7 Hz, | | |
| | 1H), 7.15-7.12 (m, 2H), 7.10-7.02 (m, 2H), 7.01-6.95 | | |
| | (m, 4H), 6.90 (dd, ³J_{H-H} = 8.2 Hz, ⁴J_{H-H} = 2.3 Hz, 1H), | | |
| | 6.60 (td, ³J_{H-H} = 7.5 Hz, ⁴J_{H-H} = 1.1 Hz, 1H), 6.52 (dd, | | |
| | ³J_{H-H} = 8.0 Hz, ⁴J_{H-H} = 0.8 Hz, 1H), 6.23 (dd, ³J_{H-H} = | | |
| | 7.8 Hz, ⁴J_{H-H} = 1.2 Hz, 1H), 1.30 (s, 9H), 1.06 (s, 9H). | | |
| BD87 | δ 8.38 (d, ³J_{H-H} = 8.3 Hz, 2H), 8.20 (t, ⁴J_{H-H} = 1.8 Hz, | 1121.31551 | 1121.31566 |
| | 1H), 7.94 (d, ³J_{H-H} = 8.2 Hz, 1H), 7.91 (t, ³J_{H-H} = 7.9 | | |
| | Hz, 1H), 7.81 (t, ⁴J_{H-H} = 1.6 Hz, 1H), 7.77 (d, ⁴J_{H-H} = | | |
| | 2.1 Hz, 1H), 7.66-7.62 (m, 1H), 7.48 (d, ³J_{H-H} = 7.7 | | |
| | Hz, 1H), 7.41-7.36 (m, 2H), 7.18 (t, ⁴J_{H-H} = 1.7 Hz, | | |
| | 1H), 7.15-7.12 (m, 2H), 7.10-7.02 (m, 2H), 7.01-6.95 | | |
| | (m, 4H), 6.90 (dd, ³J_{H-H} = 8.2 Hz, ⁴J_{H-H} = 2.3 Hz, 1H), | | |
| | 6.60 (td, ³J_{H-H} = 7.5 Hz, ⁴J_{H-H} = 1.1 Hz, 1H), 6.52 (dd, | | |
| | ³J_{H-H} = 8.0 Hz, ⁴J_{H-H} = 0.8 Hz, 1H), 6.23 (dd, ³J_{H-H} = | | |
| | 7.8 Hz, ⁴J_{H-H} = 1.2 Hz, 1H), 1.33 (s, 9H), 1.30 (s, 9H), | | |
| | 1.06 (s, 9H). | | |
| BD88 | δ 8.42 (d, ³J_{H-H} = 8.3 Hz, 2H), 8.18 (t, ⁴J_{H-H} = 1.8 Hz, | 1023.33204 | 1023.33218 |
| | 1H), 7.92 (d, ³J_{H-H} = 8.2 Hz, 1H), 7.91 (t, ³J_{H-H} = 7.9 | | |
| | Hz, 1H), 7.82 (t, ⁴J_{H-H} = 1.6 Hz, 1H), 7.77 (d, ⁴J_{H-H} = | | |
| | 2.1 Hz, 1H), 7.68-7.62 (m, 1H), 7.48 (d, ³J_{H-H} = 7.7 | | |
| | Hz, 1H), 7.40-7.36 (m, 2H), 7.30 (td, ³J_{H-H} = 7.5 Hz, | | |
| | ⁴J_{H-H} = 0.8 Hz, 1H), 7.18 (t, ⁴J_{H-H} = 1.7 Hz, 1H), 7.15- | | |
| | 7.12 (m, 2H), 7.10-7.02 (m, 2H), 7.01-6.95 (m, 4H), | | |
| | 6.90 (dd, ³J_{H-H} = 8.2 Hz, ⁴J_{H-H} = 2.3 Hz, 1H), 6.60 (td, | | |
| | ³J_{H-H} = 7.5 Hz, ⁴J_{H-H} = 1.1 Hz, 1H), 6.52 (dd, ³J_{H-H} = | | |
| | 8.0 Hz, ⁴J_{H-H} = 0.8 Hz, 1H), 6.23 (dd, ³J_{H-H} = 7.8 Hz, | | |
| | ⁴J_{H-H} = 1.2 Hz, 1H), 2.26 (s, 3H), 1.06 (s, 9H). | | |
| BD89 | δ 8.42 (d, ³J_{H-H} = 8.3 Hz, 2H), 8.18 (t, ⁴J_{H-H} = 1.8 Hz, | 1025.35087 | 1025.35094 |
| | 1H), 7.92 (d, ³J_{H-H} = 8.2 Hz, 1H), 7.91 (t, ³J_{H-H} = 7.9 | | |
| | Hz, 1H), 7.82 (t, ⁴J_{H-H} = 1.6 Hz, 1H), 7.77 (d, ⁴J_{H-H} = | | |
| | 2.1 Hz, 1H), 7.68-7.62 (m, 1H), 7.48 (d, ³J_{H-H} = 7.7 | | |
| | Hz, 1H), 7.40-7.36 (m, 2H), 7.30 (td, ³J_{H-H} = 7.5 Hz, | | |
| | ⁴J_{H-H} = 0.8 Hz, 1H), 7.18 (t, ⁴J_{H-H} = 1.7 Hz, 1H), 7.15- | | |
| | 7.12 (m, 2H), 7.10-7.02 (m, 2H), 7.01-6.95 (m, 4H), | | |
| | 6.90 (dd, ³J_{H-H} = 8.2 Hz, ⁴J_{H-H} = 2.3 Hz, 1H), 6.60 (td, | | |
| | ³J_{H-H} = 7.5 Hz, ⁴J_{H-H} = 1.1 Hz, 1H), 6.52 (dd, ³J_{H-H} = | | |
| | 8.0 Hz, ⁴J_{H-H} = 0.8 Hz, 1H), 6.23 (dd, ³J_{H-H} = 7.8 Hz, | | |
| | ⁴J_{H-H} = 1.2 Hz, 1H), 1.06 (s, 9H). | | |
| BD90 | δ 8.40 (d, ³J_{H-H} = 8.3 Hz, 2H), 8.17 (t, ⁴J_{H-H} = 1.8 Hz, | 1064.37899 | 1064.37911 |
| | 1H), 7.93 (d, ³J_{H-H} = 8.2 Hz, 1H), 7.90 (t, ³J_{H-H} = 7.9 | | |
| | Hz, 1H), 7.81 (t, ⁴J_{H-H} = 1.6 Hz, 1H), 7.77 (d, ⁴J_{H-H} = | | |
| | 2.1 Hz, 1H), 7.66-7.62 (m, 1H), 7.48 (d, ³J_{H-H} = 7.7 | | |
| | Hz, 1H), 7.41-7.36 (m, 2H), 7.30 (td, ³J_{H-H} = 7.5 Hz, | | |
| | ⁴J_{H-H} = 0.8 Hz, 1H), 7.18 (t, ⁴J_{H-H} = 1.7 Hz, 1H), 7.15- | | |
| | 7.12 (m, 2H), 7.10-7.02 (m, 2H), 7.01-6.95 (m, 4H), | | |
| | 6.90 (dd, ³J_{H-H} = 8.2 Hz, ⁴J_{H-H} = 2.3 Hz, 1H), 6.60 (td, | | |
| | ³J_{H-H} = 7.5 Hz, ⁴J_{H-H} = 1.1 Hz, 1H), 6.52 (dd, ³J_{H-H} = | | |
| | 8.0 Hz, ⁴J_{H-H} = 0.8 Hz, 1H), 6.23 (dd, ³J_{H-H} = 7.8 Hz, | | |
| | ⁴J_{H-H} = 1.2 Hz, 1H), 1.33 (s, 9H), 1.06 (s, 9H). | | |

### Evaluation Example 1

According to methods described in Table 2, the highest occupied molecular orbital (HOMO) and lowest unoccupied molecular orbital (LUMO) energy levels of each of Compounds BD85 to BD91, CE-A, and CE-B were evaluated, and the results are shown in Table 3. Films were formed according to the compositions of each film as shown in Table 4, and the characteristics of light emitted from the films were evaluated.

TABLE 2

| | |
|---|---|
| HOMO | By using cyclic voltammetry (CV) (electrolyte: 0.1M Bu₄NPF₆/ |
| energy | solvent: dimethylforamide (DMF)/electrode: 3-electrode system |
| level | (working electrode: GC, reference electrode: Ag/AgCl, and |
| evalu- | auxiliary electrode: Pt)), the potential (V)-current (A) |
| ation | graph of each compound was obtained, and from the oxidation |
| method | onset of the graph, the HOMO energy level of each compound |
| | was calculated. |
| LUMO | By using cyclic voltammetry (CV) (electrolyte: 0.1M Bu₄NPF₆/ |
| energy | solvent: dimethylforamide (DMF)/electrode: 3-electrode system |
| level | (working electrode: GC, reference electrode: Ag/AgCl, and |
| evalu- | auxiliary electrode: Pt)), the potential (V)-current (A) |
| ation | graph of each compound was obtained, and from the reduction |
| method | onset of the graph, the LUMO energy level of each compound |
| | was calculated. |

TABLE 3

| Compound No. | HOMO (eV) | LUMO (eV) |
|---|---|---|
| BD91 | −5.38 | −2.03 |
| BD85 | −5.40 | −2.21 |
| BD86 | −5.40 | −2.21 |
| BD87 | −5.39 | −2.23 |
| BD88 | −5.39 | −2.23 |
| BD89 | −5.40 | −2.21 |
| BD90 | −5.39 | −2.23 |
| CE-A | −5.28 | −2.11 |
| CE-B | −5.30 | −2.15 |

TABLE 4

| | | Maximum | | |
|---|---|---|---|---|
| | Film composition | emission | | |
| Film | (4 parts by | wavelength | FWHM | PLQY |
| No. | weight in PMMA) | (nm) | (nm) | (%) |
| 1 | BD91 | 453 | 20 | 97 |
| 2 | BD85 | 453 | 20 | 97 |
| 3 | BD86 | 453 | 20 | 97 |
| 4 | BD87 | 453 | 20 | 97 |
| 5 | BD88 | 453 | 20 | 97 |
| 6 | BD89 | 453 | 20 | 97 |
| 7 | BD90 | 454 | 20 | 97 |
| 8 | CE-A | 456 | 41 | 90 |
| 9 | CE-B | 454 | 21 | 93 |

Referring to Table 4, Compounds BD85 to BD91 were able to provide improved PLQY (%) compared to Compounds CE-A and CE-B.

### Evaluation Example 2

By using a TRPL measurement system, FluoTime 300, manufactured by PicoQuant Company and a pumping source, PLS340 (excitation wavelength=340 nm, spectral width=20 nm) manufactured by PicoQuant Company, photoluminescence (PL) spectra were photographed and evaluated at room temperature for each of Films 1 to 9. The wavelength of a main peak was determined from each spectrum.

Based on photon pulses (pulse width=500 picoseconds) applied to each film by the PLS340, the number of photons emitted from each film at the wavelength of the main peak was measured. Here, the photon measurements were repeated based on the time-correlated single photon counting (TCSPC), and a TRPL curve that was sufficiently suitable for fitting was derived.

By fitting one or more exponential decay functions to the results obtained therefrom, T_{decay} (Ex), e.g., decay time, of each of Films 1 to 9 was obtained, and the results are shown in Table 5.

A function used for the fitting is as shown in Equation 1, and the largest T_{decay} value from among the T_{decay} values obtained from each exponential decay function used for the fitting was determined as T_{decay} (Ex).

Here, as the baseline of the fitting, a baseline (or background signal) curve measured when the pumping signal applied to each film was blocked (e.g., in a dark state) was used. The TRPL measurements to obtain the baseline curve were performed under the same conditions as the measurements for each film.

$$f ( t ) = {\sum }_{i = 1}^{n} {A}_{i} exp ( - t / {T}_{decay , i} ) \qquad [ Equation 1 ]$$

TABLE 5

| Film | Film composition | T_{decay} |
|---|---|---|
| No. | (4 parts by weight in PMMA) | (EX) (μs) |
| 1 | BD91 | 2.63 |
| 2 | BD85 | 2.53 |
| 3 | BD86 | 2.62 |
| 4 | BD87 | 2.61 |
| 5 | BD88 | 2.50 |
| 6 | BD89 | 2.59 |
| 7 | BD90 | 2.64 |
| 8 | CE-A | 2.40 |
| 9 | CE-B | 2.13 |

Referring to Table 5, Compounds BD85 to BD91 had a longer luminescence decay time than Compounds CE-A and CE-B. As a result, Compounds BD85 to BD91 were expected to have improved Kr (decay radiative rate constant) values.

### Example 1

As an anode, a glass substrate with ITO deposited thereon at 15 Ω/cm² (1,200 Å) was prepared with a size of 50 mm×50 mm×0.7 mm. The glass substrate with ITO was ultrasonically cleaned by using isopropyl and alcohol for 5 minutes each. Ultraviolet rays were irradiated for 30 minutes, and the resulting glass substrate with ITO was cleaned by exposure to ozone. The glass substrate with ITO was loaded in a vacuum deposition apparatus.

2-TNATA was vacuum-deposited on the glass substrate with ITO to form a hole injection layer having a thickness of 600 Å, and NPB was vacuum-deposited on the hole injection layer to form a hole transport layer having a thickness of 300 Å.

A first host (ETH2), a second host (HTH29), and Compound BD91 of Synthesis Example 1 were co-deposited at a weight ratio of 27:60:13 on the hole transport layer to form an emission layer having a thickness of 350 Å.

Compound HBL-1 was deposited on the emission layer to form a hole blocking layer having a thickness of 50 Å. CNNPTRZ and Alq₃ were co-deposited at a weight ratio of 40:60 on the hole blocking layer to form an electron transport layer having a thickness of 310 Å, Yb was deposited on the electron transport layer to form an electron injection layer having a thickness of 15 Å, and Mg was vacuum-deposited on the electron injection layer to form a cathode having a thickness of 800 Å, thereby completing the manufacture of a light-emitting device.

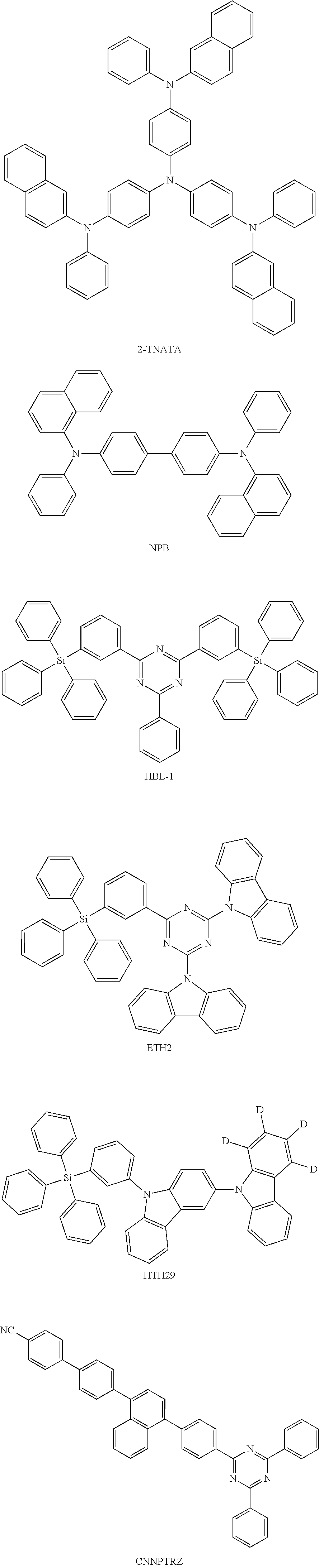

### Examples 2 to 10 and Comparative Examples 1 and 2

Light-emitting devices of Examples 2 to Example 10 and Comparative Examples 1 and 2 were prepared in the same manner as in Example 1, except that different compositions as shown in Table 6 were used for forming an emission layer. Here, each part by weight was measured with respect to 100 parts by weight of the total weight of the first host and the second host included in the emission layer.

TABLE 6

| | | | | Fluorescent | Weight ratio |
|---|---|---|---|---|---|
| | Dopant | | | dopant | of first |
| | (parts by | First | Second | (parts by | host to |
| No. | weight) | host | host | weight) | second host |
| Example 1 | BD91 (13) | ETH2 | HTH29 | — | 2.7:6.0 |
| Example 2 | BD85 (13) | ETH2 | HTH29 | — | 2.7:6.0 |
| Example 3 | BD86 (13) | ETH2 | HTH29 | — | 2.7:6.0 |
| Example 4 | BD87 (13) | ETH2 | HTH29 | — | 2.7:6.0 |
| Example 5 | BD88 (13) | ETH2 | HTH29 | — | 2.7:6.0 |
| Example 6 | BD89 (13) | ETH2 | HTH29 | — | 2.7:6.0 |
| Example 7 | BD90 (13) | ETH2 | HTH29 | — | 2.7:6.0 |
| Example 8 | BD91 (13) | ETH18 | HTH29 | — | 3.0:6.3 |
| Example 9 | BD87 (13) | ETH18 | HTH29 | DFD7 (0.4) | 2.7:6.0 |
| Example 10 | BD87 (13) | ETH18 | HTH29 | DFD29 (1.2) | 2.7:6.0 |
| Comparative | CE-A (13) | ETH2 | HTH29 | — | 2.7:6.0 |
| Example 1 | | | | | |
| Comparative | CE-B (13) | ETH2 | HTH29 | — | 2.7:6.0 |
| Example 2 | | | | | |

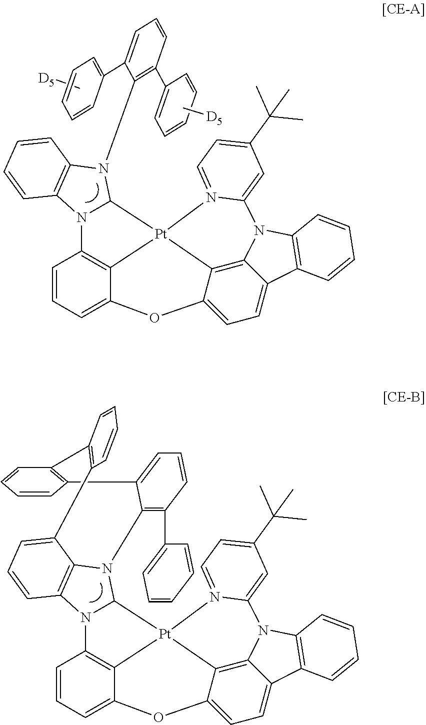

A voltage was applied so that the light-emitting device of Examples 1 to 10 and Comparative Examples 1 and 2 emitted light having a luminance of 1,000 cd/m². The driving voltage (V), color purity (CIEx,y), luminescence efficiency (cd/A), color conversion efficiency (cd/A/y), maximum emission wavelength (nm), and lifespan (T₉₅) were each measured by using a Keithley MU 236 and a luminance meter PR650, and the results are shown in Table 7. In Table 7, the lifespan (T₉₅) is a measure of the time (hr) taken for the luminance to reach 95% of the initial luminance.

TABLE 7

| | | | | | Color | Maximum | |
|---|---|---|---|---|---|---|---|
| | | Driving | | Luminescence | conversion | emission | |
| | | Voltage | Color purity | efficiency | efficiency | wavelength | Lifespan |
| No. | Dopant | (V) | (CIEx, y) | (cd/A) | (cd/A/y) | (nm) | (T₉₅, hr) |
| Example 1 | BD91 | 4.0 | 0.137, 0.157 | 22.2 | 141.0 | 460 | 164.2 |
| Example 2 | BD85 | 4.1 | 0.132, 0.154 | 22.1 | 142.9 | 460 | 165.0 |
| Example 3 | BD86 | 4.1 | 0.132, 0.154 | 22.1 | 142.9 | 460 | 169.0 |
| Example 4 | BD87 | 4.1 | 0.134, 0.164 | 23.2 | 141.8 | 460 | 166.0 |
| Example 5 | BD88 | 4.1 | 0.133, 0.147 | 22.8 | 154.7 | 460 | 165.4 |
| Example 6 | BD89 | 4.1 | 0.133, 0.147 | 22.8 | 154.7 | 460 | 177.4 |
| Example 7 | BD90 | 4.1 | 0.133, 0.147 | 22.8 | 154.7 | 461 | 178.4 |
| Example 8 | BD91 | 4.1 | 0.133, 0.147 | 22.8 | 154.7 | 461 | 182.4 |
| Example 9 | BD87 | 4.1 | 0.136, 0.119 | 23.8 | 171.1 | 462 | 226.4 |
| Example 10 | BD87 | 4.1 | 0.132, 0.121 | 25.2 | 177.9 | 463 | 235.0 |
| Comparative | CE-A | 4.2 | 0.137, 0.204 | 23.4 | 114.8 | 463 | 99.4 |
| Example 1 | | | | | | | |
| Comparative | CE-B | 4.8 | 0.137, 0.168 | 22.8 | 123.5 | 461 | 119.4 |
| Example 2 | | | | | | | |

Referring to Table 7, it was confirmed that the light-emitting devices including the organometallic compound according to an embodiment had excellent characteristics evenly in terms of the driving voltage (V), luminescence efficiency (cd/A), color conversion efficiency (Cd/A/y), and device lifespan (T₉₅), as compared to the light-emitting devices of Comparative Examples 1 and 2. It was confirmed that, as compared to the light-emitting devices of Comparative Examples 1 and 2, all the light-emitting devices of Examples 1 to 10 were able to provide improved color conversion efficiency and improved lifespan.

According to embodiments, use of an organometallic compound may enable the manufacture of a light-emitting device having high efficiency and a long lifespan and a high-quality electronic apparatus including the light-emitting device.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting device comprising:
a first electrode;
a second electrode facing the first electrode;
an interlayer between the first electrode and the second electrode and comprising an emission layer; and
an organometallic compound represented by Formula 1: 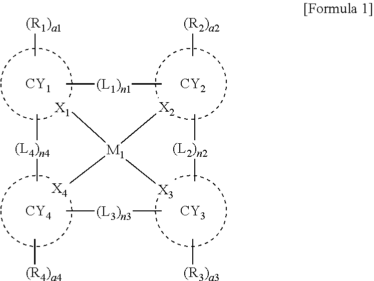
wherein in Formula 1,
M₁ is platinum (Pt), palladium (Pd), copper (Cu), silver (Ag), gold (Au), rhodium (Rh), iridium (Ir), ruthenium (Ru), or osmium (Os),
ring CY₁ to ring CY₄ are each independently a C₅-C₆₀ carbocyclic group unsubstituted or substituted with R₁₀ₐ or a C₁-C₆₀ heterocyclic group unsubstituted or substituted with R₁₀ₐ,
X₁, X₂, X₃, and X₄ are each independently a carbon atom (C) or a nitrogen atom (N),
L₁ is a C₅-C₆₀ carbocyclic group unsubstituted or substituted with at least one R_{10b} or a C₁-C₆₀ heterocyclic group unsubstituted or substituted with at least one R_{10b},
L₂ to L₄ are each independently *—O—*′, *—S—*′, *—C(R₅)(R₆)—*′, *—C(R₅)=*′, *═C(R₅)—*—C(R₅)═C(R₆)—*′, *—C(═O)—*′, *—C(═S)—*′, *—C≡C—*′, *—B(R₅)—*′, *—N(R₅)—*′, *—P(R₅)—*′, *—Si(R₅)(R₆)—*′, *—P(R₅)(R₆)—*′, or *—Ge(R₅)(R₆)—*′,
n1 is an integer from 2 to 5,
n2 to n4 are each independently an integer from 0 to 3,
a moiety represented by *-(L₂)ₙ₂-*′ is a single bond when n2 is 0,
a moiety represented by *-(L₃)ₙ₃-*′ is a single bond when n3 is 0,
a moiety represented by *-(L₄)ₙ₄-*′ is a single bond when n4 is 0,
R¹ to R⁶, R₁₀ₐ, and R_{10b} are each independently:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof,
a1 to a4 are each independently an integer from 0 to 8, and
* and *′ each indicate a binding site to a neighboring atom.

2. The light-emitting device of claim 1, wherein the interlayer comprises the organometallic compound.

3. The light-emitting device of claim 1, wherein the emission layer comprises the organometallic compound.

4. The light-emitting device of claim 1, wherein the emission layer emits blue light.

5. The light-emitting device of claim 1, wherein
the first electrode is an anode,
the second electrode is a cathode,
the interlayer further comprises:
a hole transport region between the first electrode and the emission layer; and
an electron transport region between the emission layer and the second electrode,
the hole transport region comprises a hole injection layer, a hole transport layer, an emission auxiliary layer, an electron blocking layer, or a combination thereof, and
the electron transport region comprises a hole blocking layer, an electron transport layer, an electron injection layer, or a combination thereof.

6. An electronic apparatus comprising the light-emitting device of claim 1.

7. The electronic apparatus of claim 6, further comprising:
a thin-film transistor; and
a color filter, a color-conversion layer, a touch screen layer, a polarizing layer, or a combination thereof, wherein
the thin-film transistor includes a source electrode and a drain electrode, and
the first electrode of the light-emitting device is electrically connected to the source electrode or the drain electrode.

8. An electronic equipment comprising the light-emitting device of claim 1, wherein
the electronic equipment is a flat panel display, a curved display, a computer monitor, a medical monitor, a television, an advertisement board, an indoor light, an outdoor light, a signal light, a head-up display, a fully transparent display, a partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a microdisplay, a three-dimensional (3D) display, a virtual reality display, an augmented reality display, a vehicle, a video wall including multiple displays tiled together, a theater screen, a stadium screen, a phototherapy device, or a signage.

9. An organometallic compound represented by Formula 1: 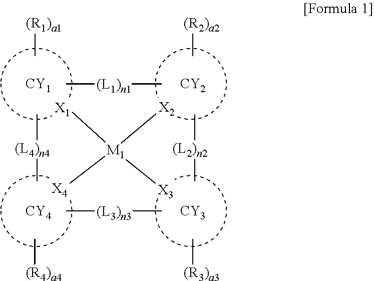
wherein in Formula 1,
M₁ is platinum (Pt), palladium (Pd), copper (Cu), silver (Ag), gold (Au), rhodium (Rh), iridium (Ir), ruthenium (Ru), or osmium (Os),
ring CY₁ to ring CY₄ are each independently a C₅-C₆₀ carbocyclic group unsubstituted or substituted with R₁₀ₐ or a C₁-C₆₀ heterocyclic group unsubstituted or substituted with R₁₀ₐ,
X₁, X₂, X₃, and X₄ are each independently a carbon atom (C) or a nitrogen atom (N),
L₁ is a C₅-C₆₀ carbocyclic group unsubstituted or substituted with at least one R_{10b} or a C₁-C₆₀ heterocyclic group unsubstituted or substituted with at least one R_{10b},
L₂ to L₄ are each independently *—O—*′, *—S—*′, *—C(R₅)(R₆)—*′, *—C(R₅)=*′, *═C(R₅)—*—C(R₅)═C(R₆)—*′, *—C(═O)—*′, *—C(═S)—*′, *—C≡C—*′, *—B(R₅)—*′, *—N(R₅)—*′, *—P(R₅)—*′, *—Si(R₅)(R₆)—*′, *—P(R₅)(R₆)—*′, or *—Ge(R₅)(R₆)—*′,
n1 is an integer from 2 to 5,
n2 to n4 are each independently an integer from 0 to 3,
a moiety represented by *-(L₂)ₙ₂-*′ is a single bond when n2 is 0,
a moiety represented by *-(L₃)ₙ₃-*′ is a single bond when n3 is 0,
a moiety represented by *-(L₄)ₙ₄-*′ is a single bond when n4 is 0,
R₁ to R₆, R₁₀ₐ, and R_{10b} are each independently:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof,
a1 to a4 are each independently an integer from 0 to 8, and
* and *′ each indicate a binding site to a neighboring atom.

10. The organometallic compound of claim 9, wherein at least one of ring CY₁ to ring CY₄ each independently comprises a carbene moiety.

11. The organometallic compound of claim 9, wherein ring CY₁ is represented by Formula 1-1-1 or Formula 1-1-2: 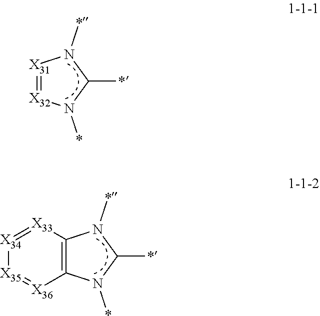
wherein in Formulae 1-1-1 and 1-1-2,
X₃₁ to X₃₆ are each independently C(R₇) or N,
R₇ is the same as defined in connection with R₁₀ₐ in Formula 1, and
*, *′, and *″ each indicate a binding site to a neighboring atom.

12. The organometallic compound of claim 9, wherein ring CY₂ and ring CY₄ are each independently a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

13. The organometallic compound of claim 9, wherein at least one of X₁ to X₄ is each a nitrogen atom (N).

14. The organometallic compound of claim 9, wherein at least two of a bond between M₁ and X₁, a bond between M₁ and X₂, a bond between M₁ and X₃, and a bond between M₁ and X₄ are each a coordinate bond.

15. The organometallic compound of claim 9, wherein two or more of Li are each independently a benzene group, a naphthalene group, a pyridine group, a pyridazine group, a pyrimidine group, a pyrazine group, a triazine group, a cyclopentadiene group, a pyrrole group, a pyrazole group, an imidazole group, or a triazole group.

16. The organometallic compound of claim 9, wherein two or more of Li are each independently a group represented by one of Formulae 1-2-1 to 1-2-3: 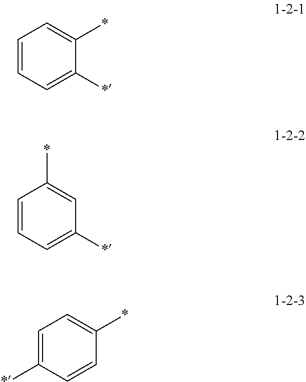
wherein in Formulae 1-2-1 to 1-2-3,
* and *′ each indicate a binding site to a neighboring atom.

17. The organometallic compound of claim 9, wherein in Formula 1, a moiety represented by *-(L₁)ₙ₁-*′ is a moiety represented by one of Formulae 1-3-1 to 1-3-3: 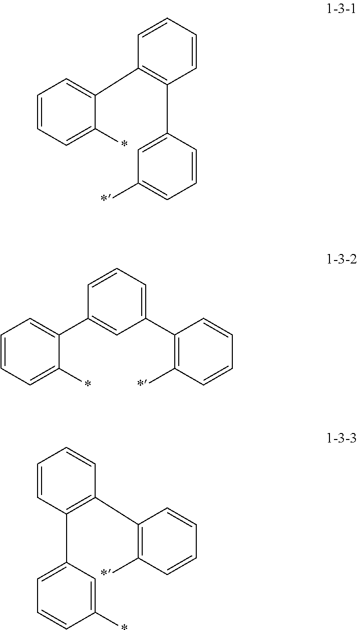
wherein in Formulae 1-3-1 to 1-3-3,
* indicates a binding site to an atom included in ring CY₁, and
*′ indicates a binding site to an atom included in ring CY₂.

18. The organometallic compound of claim 9, wherein R_{10b} is:
—F, —Cl, —Br, —I, a hydroxyl group, a cyano group, or a nitro group; or
a methyl group, an ethyl group, a propyl group, an isopropyl group, a butyl group, an isobutyl group, a sec-butyl group, a tertbutyl group, a pentyl group, an isopentyl group, a sec-pentyl group, a tert-pentyl group, a neopentyl group, a 1-phenylpropyl group, a 2-phenylpropyl group, a 1-phenylbutyl group, a 2-phenylbutyl group, a 1-phenylpentyl group, a 2-phenylpentyl group, a 3-phenylpentyl group, a 1-cyclohexylpropyl group, a 2-cyclohexylpropyl group, a 1-cyclohexylbutyl group, a 2-cyclohexylbutyl group, a 1-cyclohexylpentyl group, a 2-cyclohexylpentyl group, a 3-cyclohexylpentyl group, or a deuterated derivative group thereof.

19. The organometallic compound of claim 9, wherein the organometallic compound is one of Compounds BD01 to BD91:

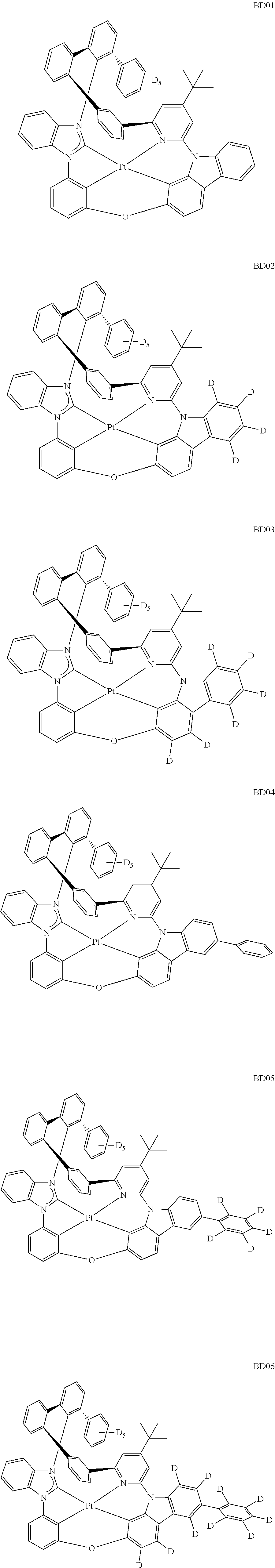

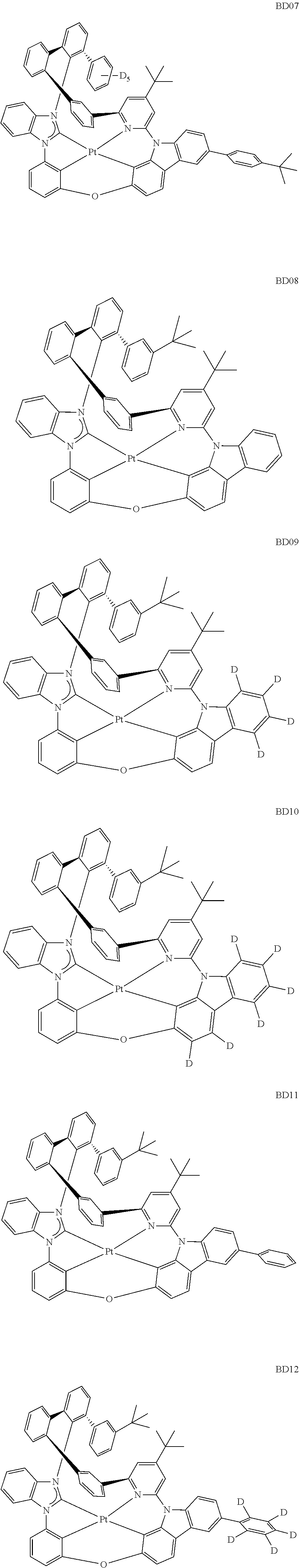

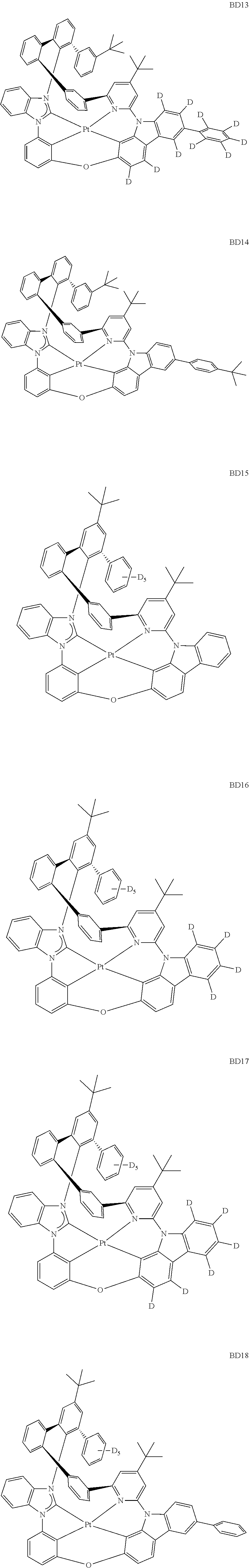

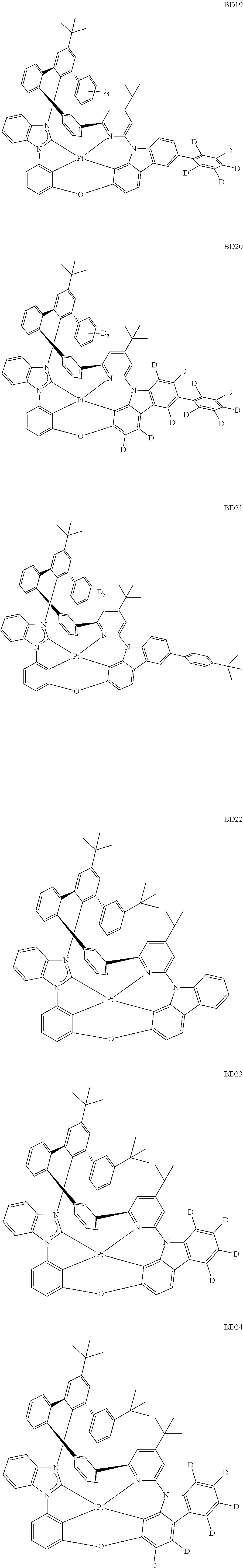

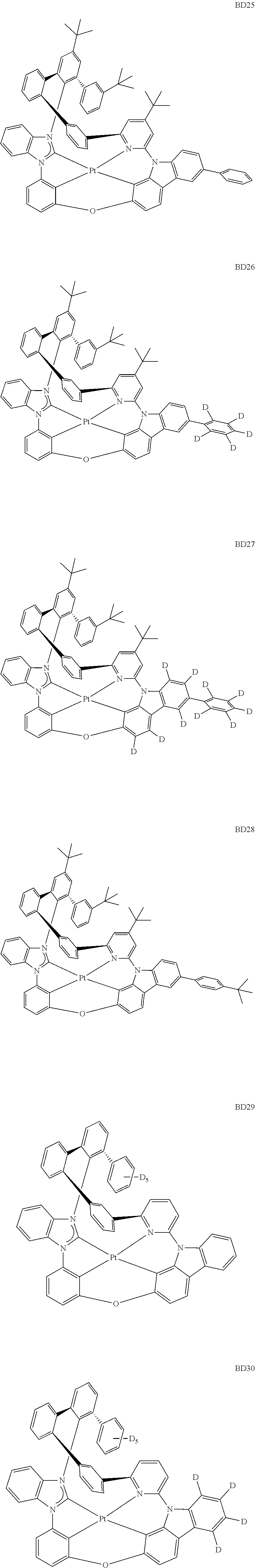

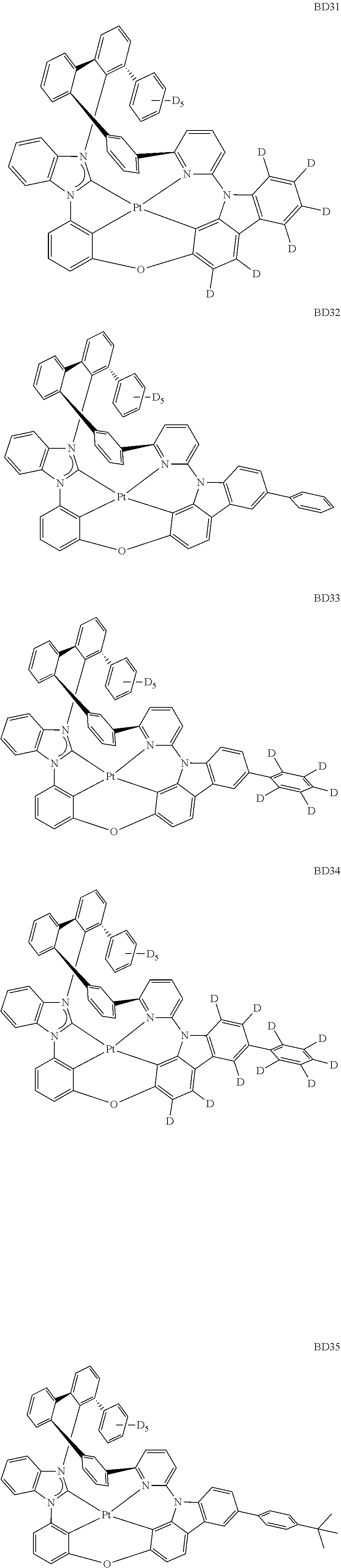

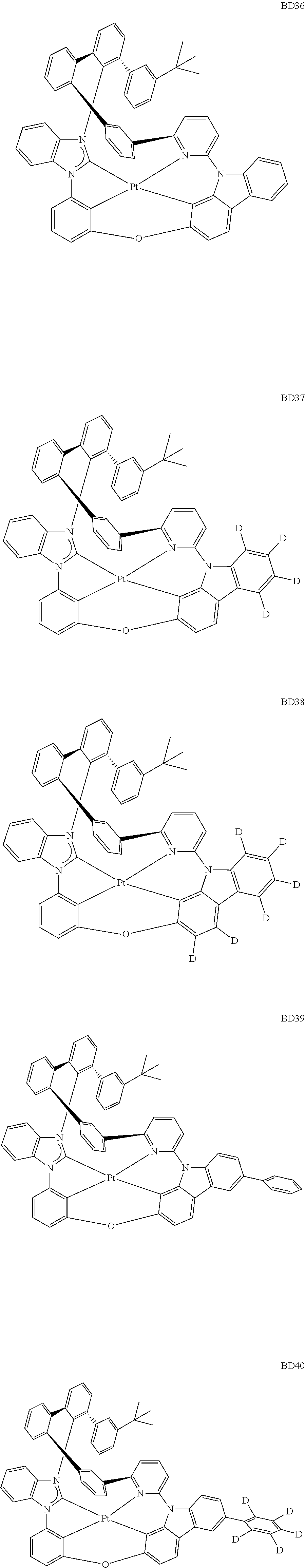

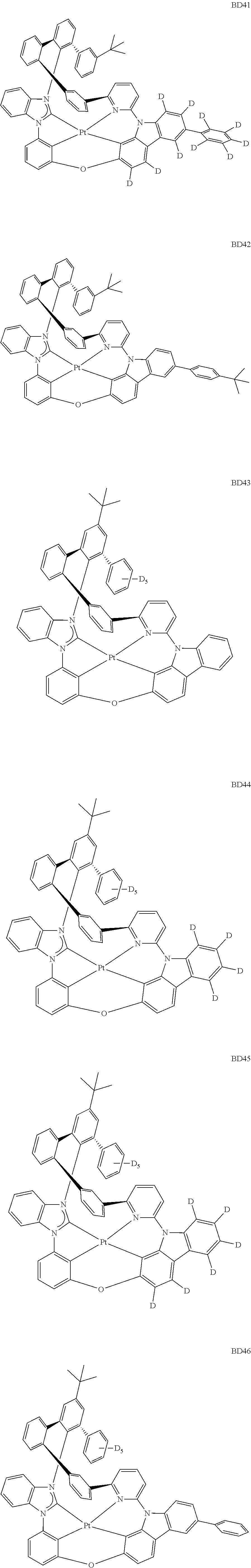

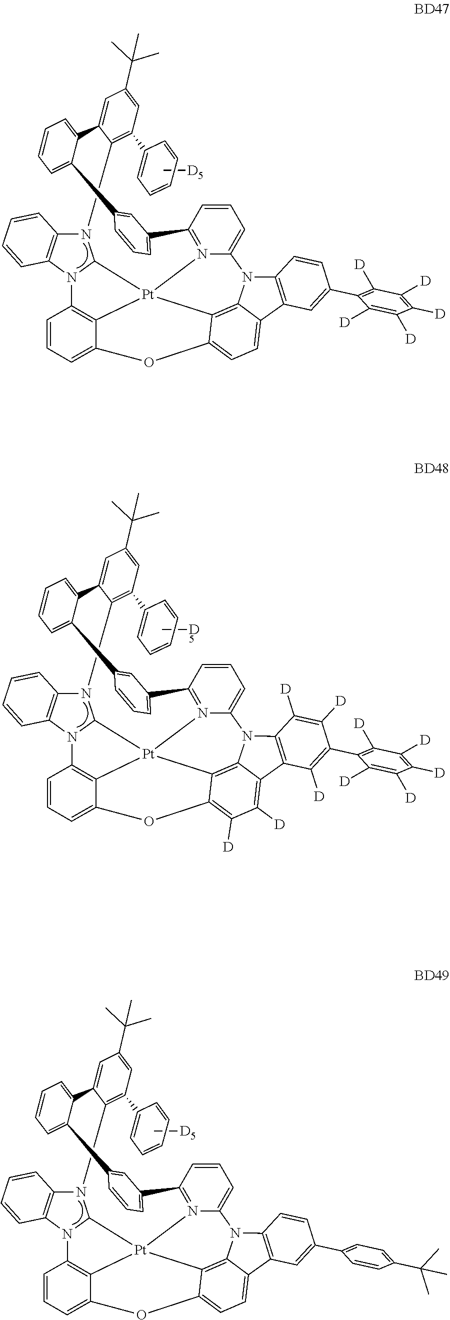

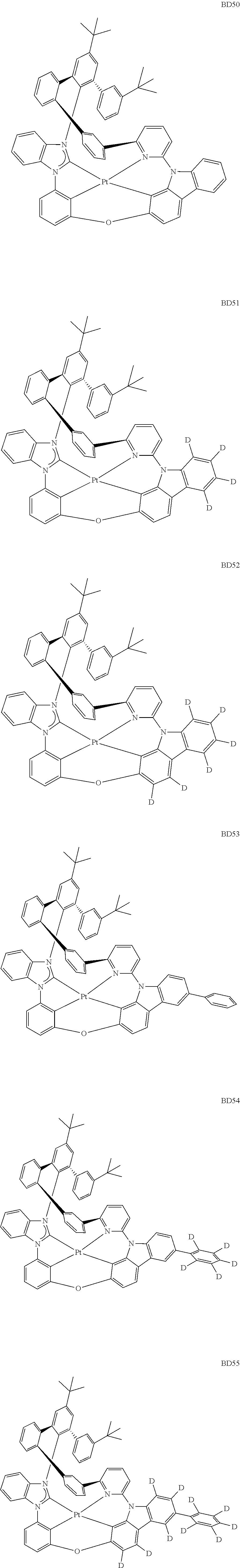

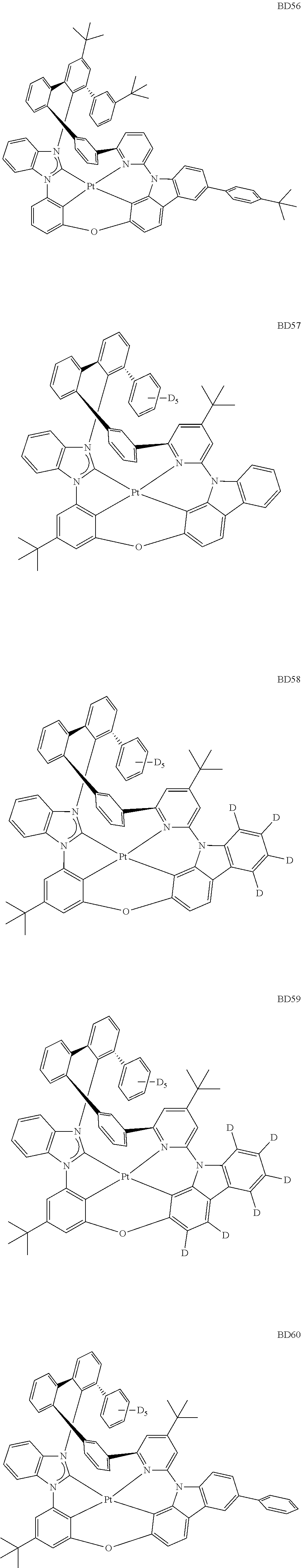

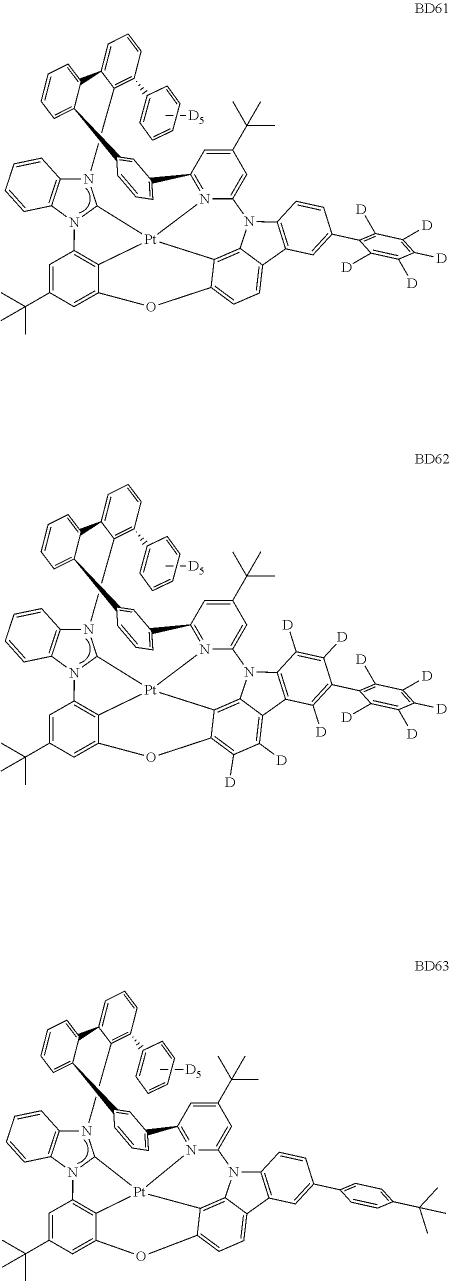

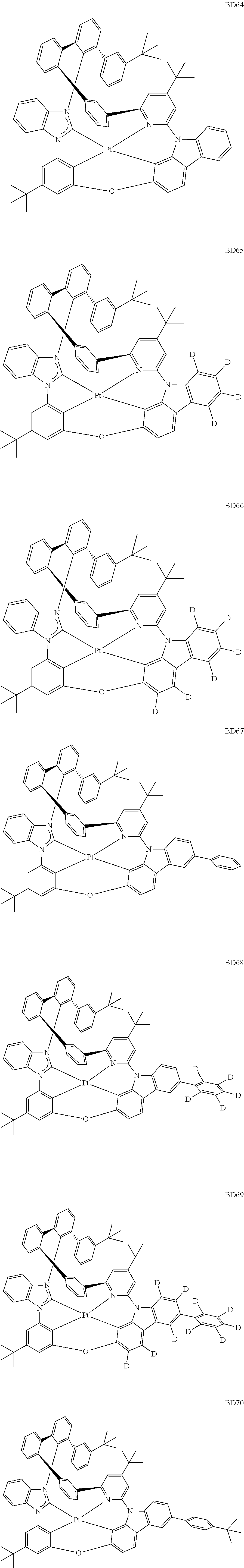

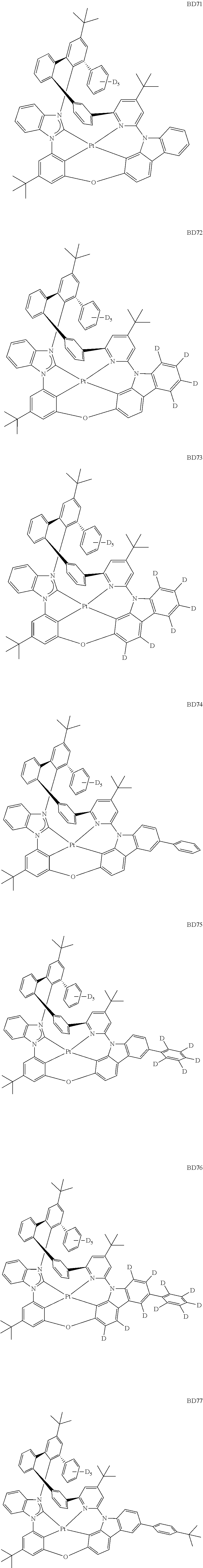

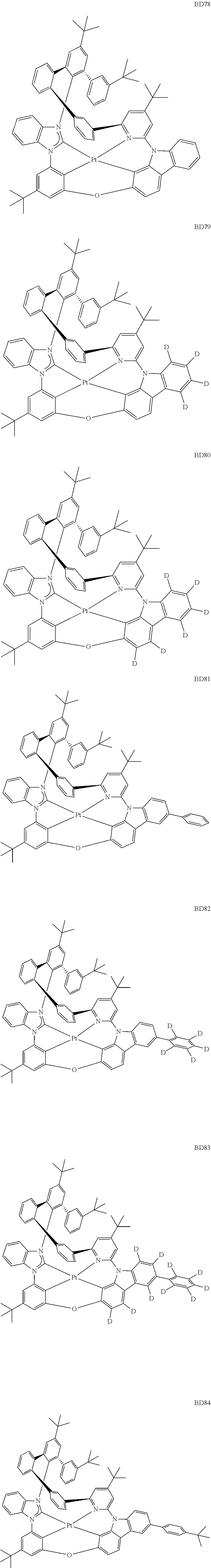

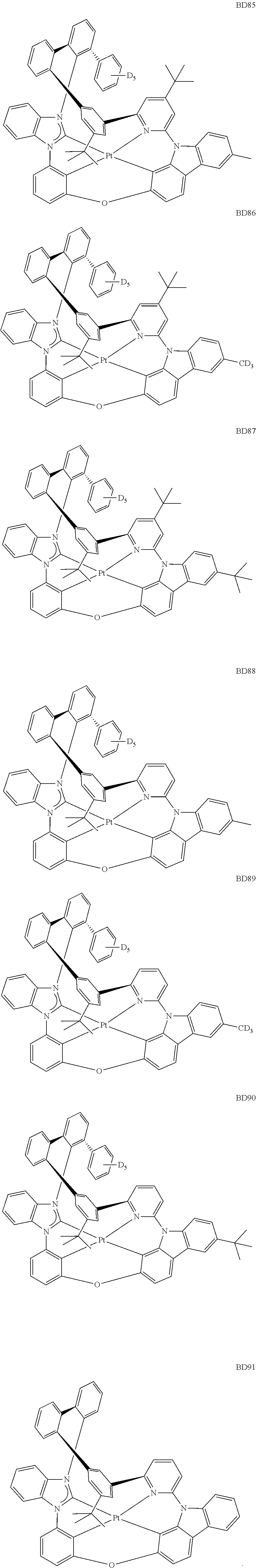

20. An organometallic compound satisfying one or more of Conditions i to iv, wherein at least Condition i is satisfied:
[Condition i]
the organometallic compound has a first cyclic moiety comprising a first ring comprising 12 elements;
[Condition ii]
the organometallic compound has a second cyclic moiety comprising a second ring comprising 5 elements;
[Condition iii]
the organometallic compound has a third cyclic moiety comprising a third ring comprising 6 elements;
[Condition iv]
the organometallic compound has a fourth cyclic moiety comprising a fourth ring comprising 5 elements.
